(19) United States
(12) Patent Application Publication
(10) Pub. No.: US 2014/0217393 A1
(43) Pub. Date: Aug. 7, 2014

(54) ORGANIC ELECTROLUMINESCENCE ELEMENT

(71) Applicants: Tomoki Kato, Sodegaura-shi Chiba (JP); Nobuhiro Yabunouchi, Sodegaura-shi Chiba (JP); Takayasu Sado, Sodegaura-shi Chiba (JP)

(72) Inventors: Tomoki Kato, Sodegaura-shi Chiba (JP); Nobuhiro Yabunouchi, Sodegaura-shi Chiba (JP); Takayasu Sado, Sodegaura-shi Chiba (JP)

(73) Assignee: Idemitsu Kosan Co., Ltd.

(21) Appl. No.: 14/343,841

(22) PCT Filed: Sep. 6, 2012
(86) PCT No.: PCT/JP2012/005652

§ 371 Date: Mar. 7, 2014

(30) Foreign Application Priority Data
Sep. 9, 2011 (JP) 2011-196638

(51) Int. Cl. H01L 51/00

(52) U.S. Cl. CPC H01L 51/0072; H01L 51/0071
USPC 257/40; 548/305.1; 546/121; 546/88

(57) ABSTRACT

An organic electroluminescence device including an anode and a cathode being opposed, wherein a first organic thin film layer and a second organic thin film layer are provided between the anode and the cathode sequentially from the anode side; the first organic thin film layer including an aromatic heterocyclic derivative A represented by the following formula (1-1) and a phosphorescent emitting material; and the second organic thin film layer including an aromatic heterocyclic derivative B represented by the following formula (2-1):

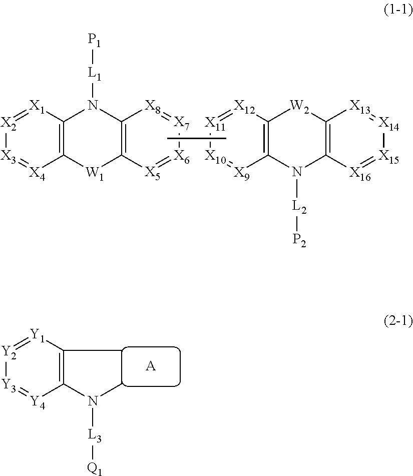

### TECHNICAL FIELD

The invention relates to an organic electroluminescence device.

### BACKGROUND ART

An organic electroluminescence (EL) device includes a fluorescent organic EL device or a phosphorescent organic EL device, and a device design optimum for the emission mechanism of each type of organic EL device has been studied. It is known that a highly efficient phosphorescent organic EL device cannot be obtained by merely applying fluorescent device technology due to the emission characteristics. The reasons therefor are generally considered to be as follows.

Specifically, since phosphorescence emission utilizes triplet excitons, a compound used for forming an emitting layer must have a large energy gap. This is because the energy gap (hereinafter often referred to as “singlet energy”) of a compound is normally larger than the triplet energy (in the invention, the difference in energy between the lowest excited triplet state and the ground state) of the compound.

In order to confine the triplet energy of a phosphorescent dopant material efficiently in a device, it is required to use, in an emitting layer, a host material having a triplet energy larger than that of the phosphorescent dopant material. Further, an electron-transporting layer and a hole-transporting layer are required to be provided adjacent to the emitting layer, and a compound having a triplet energy larger than that of a phosphorescent dopant material is required to be used in an electron-transporting layer and a hole-transporting layer.

As mentioned above, if based on the conventional design concept of an organic EL device, it leads to the use of a compound having a larger energy gap as compared with a compound used in a fluorescent organic EL device in a phosphorescent organic EL device. As a result, the driving voltage of the entire organic EL device is increased.

Further, a hydrocarbon-based compound having a high resistance to oxidation or reduction, which has been useful in a fluorescent device, the 7 electron cloud spreads largely, and hence it has a small energy gap. Therefore, in a phosphorescent organic EL device, such a hydrocarbon-based compound is hardly selected. As a result, an organic compound including a hetero atom such as oxygen and nitrogen is selected, and hence a phosphorescent organic EL device has a problem that it has a short lifetime as compared with a fluorescent organic EL device.

In addition, a significantly long exciton relaxation speed of a triplet exciton of a phosphorescent dopant as compared with that of a singlet exciton greatly effects the device performance. That is, emission from the singlet exciton has a high relaxation speed that leads to emission, and hence, diffusion of excitons to peripheral layers of emitting layers (a hole-transporting layer or an electron-transporting layer, for example) hardly occurs, whereby efficient emission is expected. On the other hand, in the case of emission from the triplet exciton, since it is spin-forbidden and has a slow relaxation speed, diffusion of excitons to the peripheral layers tends to occur easily, and as a result, thermal energy deactivation occurs from other compounds than a specific phosphorescent emitting compound. That is, in a phosphorescent organic EL device, control of a recombination region of electrons and holes is more important than that of a fluorescent organic EL device.

For the reasons mentioned above, in order to improve the performance of a phosphorescent organic EL device, material selection and device design that are different from a fluorescent organic EL device have come to be required.

Under such circumstances, in a phosphorescent organic EL device, in many cases, a carbazole derivative is used in a host material of an emitting layer or a hole-transporting layer. The reason therefor is that a carbazole derivative has a large triplet energy and has a high hole-transporting property.

For example, Patent Document 1 discloses an organic EL device in which a blocking layer formed of bathocuproin or the like is disposed between a phosphorescent emitting layer using carbazolebiphenyl and an electron-transporting layer (Alq). A blocking layer serves to prevent holes from reaching an electron-transportation region, thereby to suppress deterioration of an electron-transporting layer.

Patent Document 2 discloses a device in which a carbazole derivative is used in a hole-transporting layer, an emitting layer and an electron-transporting layer. In this device, two hole-transporting layers are provided, and a carbazole derivative having electron-blocking property and electron resistance is used in a hole-transporting layer on the emitting layer side. As mentioned above, the technology disclosed in Patent Document 2 is a technology noting the interface of a hole-transporting region and an emitting layer.

### RELATED ART DOCUMENTS

### Patent Documents

Patent Document 1: JP-T-2002-525808
Patent Document 2: WO2009/041635

### SUMMARY OF THE INVENTION

The invention is aimed at providing an organic EL device having a long life and a high luminous efficiency.

The inventors made intensive studies, and have found that, by using in combination a first organic thin film layer comprising an aromatic heterocyclic derivative A mentioned later and a second organic thin film layer comprising an aromatic heterocyclic derivative B mentioned later, an organic EL device having a long life and a high luminous efficiency can be obtained. The invention has been made based on this finding.

According to the invention, the following organic EL device is provided.

1. An organic electroluminescence device comprising an anode and a cathode being opposed, wherein a first organic thin film layer and a second organic thin film layer are provided between the anode and the cathode sequentially from the anode side;

the first organic thin film layer comprising an aromatic heterocyclic derivative A represented by the following formula (1-1) and a phosphorescent emitting material; and

the second organic thin film layer comprising an aromatic heterocyclic derivative B represented by the following formula (2-1):

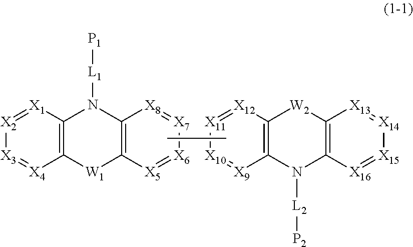

wherein in the formula (1-1),

W₁ and W₂ are independently a single bond, CR₁R₂ or SiR₁R₂,

R₁ and R₂ are independently a hydrogen atom, a substituted or unsubstituted alkyl group including 1 to 20 carbon atoms, a substituted or unsubstituted cycloalkyl group including 3 to 20 carbon atoms, a substituted or unsubstituted haloalkyl group including 1 to 20 carbon atoms, a substituted or unsubstituted aralkyl group including 7 to 30 carbon atoms, a substituted or unsubstituted aryl group including 6 to 30 carbon atoms that form a ring (hereinafter referred to as “ring carbon atoms”) or a substituted or unsubstituted heteroaryl group including 5 to 30 atoms that form a ring (hereinafter referred to as “ring atoms”);

L₁ and L₂ are independently a single bond, a substituted or unsubstituted arylene group including 6 to 30 ring carbon atoms or a substituted or unsubstituted heteroarylene group including 5 to 30 ring atoms;

among X₁ to X₁₆, one of X₅ to X₈ and one of X₉ to X₁₂ are a carbon atom that is bonded with each other, the remainder of X₁ to X₁₆ are a carbon atom that is bonded to the following R₃, or a nitrogen atom, provided that, among X₁ to X₁₆, if adjacent two atoms are carbon atoms, a ring including the adjacent carbon atoms may be formed with the adjacent carbon atoms being not bonded to R₃;

R₃ is independently a hydrogen atom, a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atom or a substituted or unsubstituted heteroaryl group including 5 to 30 ring atoms;

P₁ and P₂ are independently a substituted or unsubstituted aryl group including 6 to 30 ring carbon atoms or a substituted or unsubstituted heteroaryl group including 5 to 30 ring atoms;

provided that at least one of P₁ and P₂ are a group represented by the following formula (1-a), (1-b) or (1-c);

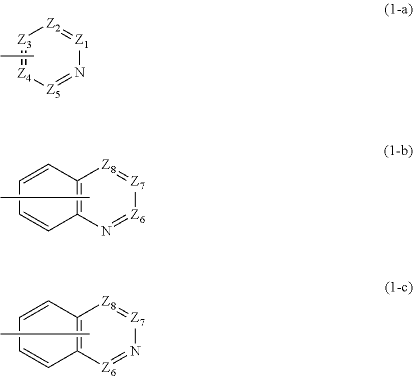

wherein in the formulas (1-a), (1-b) and (1-c),

Z₁ to Z₈ are independently a carbon atom that is bonded to L₁, L₂, a carbon atom that is bonded to the following R₄, or a nitrogen atom; provided that if adjacent two atoms are carbon atoms, a ring including the adjacent carbon atoms may be formed with the adjacent carbon atoms being not bonded to R₄,

R₄ is independently a hydrogen atom, a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms;

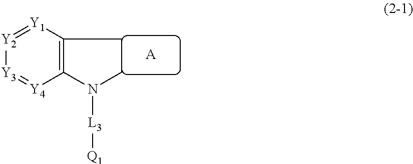

wherein in the formula (2-1),

the ring A is a substituted or unsubstituted aromatic ring that is fused to an adjacent ring;

Y₁ to Y₄ are independently a carbon atom that is bonded to the following R₅, or a nitrogen atom; provided that if adjacent two atoms are carbon atoms, a ring including the adjacent carbon atoms may be formed with the adjacent carbon atoms being not bonded to R₅;

R₅ is independently a hydrogen atom, a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms (excluding a substituted or unsubstituted carbazolyl group);

L₃ is a single bond, a substituted or unsubstituted arylene group including 6 to 30 ring carbon atoms or a substituted or unsubstituted heteroarylene group including 5 to 30 ring atoms;

Q₁ is a group represented by the above formula (1-a), (1-b) or (1-c) or the following formula (2-c), (2-d), (2-e) or (2-f);

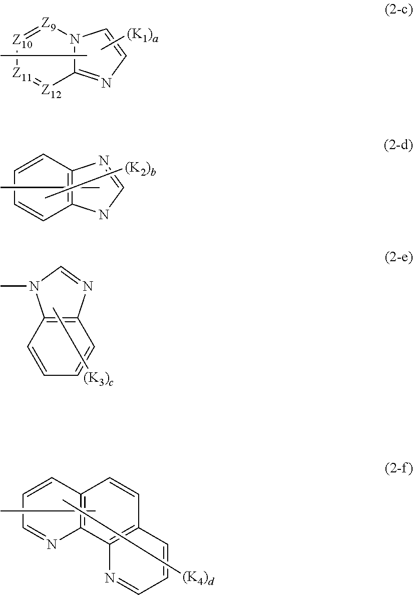

wherein in the formulas (2-c), (2-d), (2-e) and (2-f),

Z₉ to Z₁₂ are independently a carbon atom that is bonded to L₃, a carbon atom that is bonded to the following R₆, or a nitrogen atom, provided that if adjacent two atoms are carbon atoms, a ring including the adjacent carbon atoms may be formed with the adjacent carbon atoms being not bonded to R₆;

R₆ and K₁ to K₄ are independently a hydrogen atom, a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted

aralkyl group including 7 to 30 carbon atoms, a substituted or unsubstituted aryl group including 6 to 30 ring carbon atoms or a substituted or unsubstituted heteroaryl group including 5 to 30 ring atoms;

a is an integer of 0 to 2;

b is an integer of 0 to 4;

c is an integer of 0 to 5; and

d is an integer of 0 to 7.

2. The organic electroluminescence device according to 1, wherein the aromatic heterocyclic derivative B is represented by any of the following formulas (2-2) to (2-4):

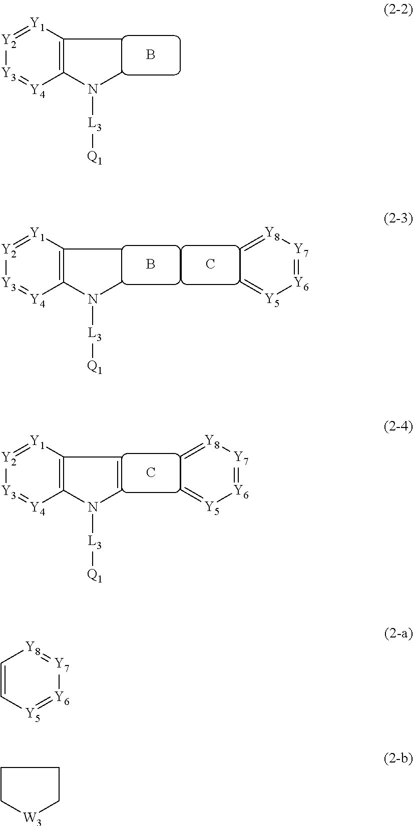

wherein in the formulas (2-2) to (2-4),

the ring B is a ring represented by the formula (2-a) that is fused to an adjacent ring (s) and the ring C is a ring represented by the formula (2-b) that is fused to adjacent rings;

W₃ is NR₇, CR₈R₉, SiR₈R₉, an oxygen atom or a sulfur atom;

R₇ to R₉ are independently a hydrogen atom, a substituted or unsubstituted alkyl group including 1 to 20 carbon atoms, a substituted or unsubstituted cycloalkyl group including 3 to 20 carbon atoms, a substituted or unsubstituted haloalkyl group including 1 to 20 carbon atoms, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms;

Y₁ to Y₈ are independently a carbon atom that is bonded to the following R₁₀, or a nitrogen atom, provided that if adjacent two atoms are carbon atoms, a ring including the two adjacent carbon atoms may be formed with the adjacent carbon atoms being not bonded to R₁₀;

R₁₀ is independently a hydrogen atom, a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms (excluding a substituted or unsubstituted carbazolyl group);

L₃ is a single bond, a substituted or unsubstituted arylene group including 6 to 30 ring carbon atoms or a substituted or unsubstituted heteroarylene group including 5 to 30 ring atoms; and

Q₁ is a group represented by the above formula (1-a), (1-b), (1-c), (2-c), (2-d), (2-e) or (2-f).

3. The organic electroluminescence device according to 1 or 2, wherein the aromatic heterocyclic derivative A is represented by the following formula (1-2):

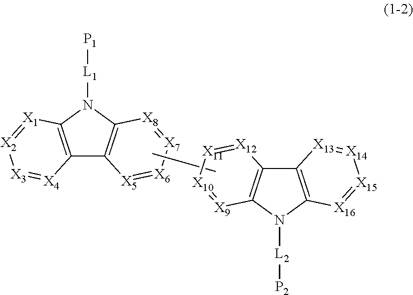

wherein X₁ to X₁₆, L₁, L₂, P₁ and P₂ are independently a group similar to X₁ to X₁₆, L₁, L₂, P₁ and P₂ in the formula (1-1).
4. The organic electroluminescence device according to any of 1 to 3, wherein the aromatic heterocyclic derivative A is represented by the following formula (1-3):

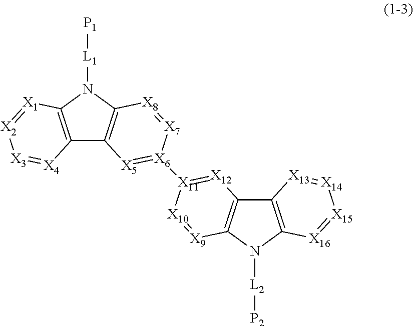

wherein X₁ to X₁₆, L₁, L₂, P₁ and P₂ are independently a group similar to X₁ to X₁₆, L₁, L₂, P₁ and P₂ in the formula (1-1).
5. The organic electroluminescence device according to any of 1 to 3, wherein the aromatic heterocyclic derivative A is represented by the following formula (1-4) or (1-5):

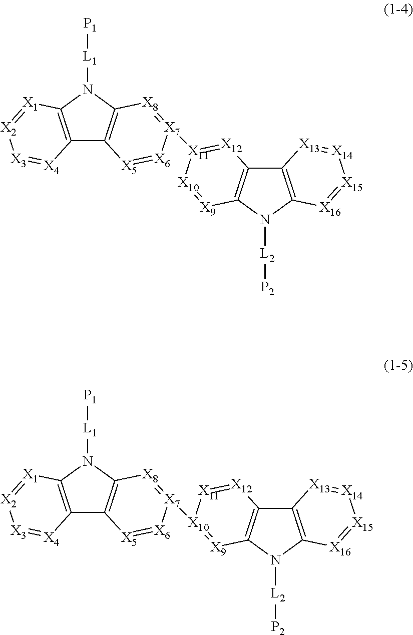

wherein X₁ to X₁₆, L₁, L₂, P₁ and P₂ are independently a group similar to X₁ to X₁₆, L₁, L₂, P₁ and P₂ in the formula (1-1).
6. The organic electroluminescence device according to any of 1 to 5, wherein the aromatic heterocyclic derivative B is represented by the formula (3-1):

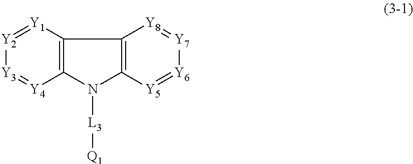

wherein L₃, Y₁ to Y₈ and Q₁ are independently a group similar to L₃, Y₁ to Y₄ and Q₁ in the formula (2-1).
7. The organic electroluminescence device according to any of 2 to 5, wherein the aromatic heterocyclic derivative B is represented by the following formula (4-1) or (4-2):

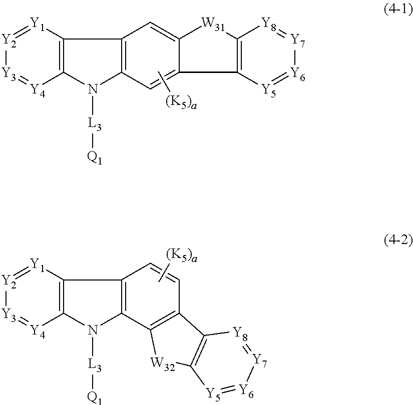

wherein in the formula (4-1) or (4-2),

L₃, Y₁ to Y₈ and Q₁ are independently a group similar to L₃, Y₁ to Y₈ and Q₁ in the above formula (2-3);

K₅ is a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms;

a is an integer of 0 to 2;

W₃₁ is CR₈R₉, SiR₈R₉, an oxygen atom or a sulfur atom;

W₃₂ is NR₇, CR₈R₉, SiR₈R₉, an oxygen atom or a sulfur atom; and

R₇ to R₉ are independently a group similar to R₇ to R₉ in W₃ in the formula (2-b).

8. The organic electroluminescence device according to any of 2 to 5, wherein the aromatic heterocyclic derivative B is represented by the following formula (5-1), (5-2) or (5-3):

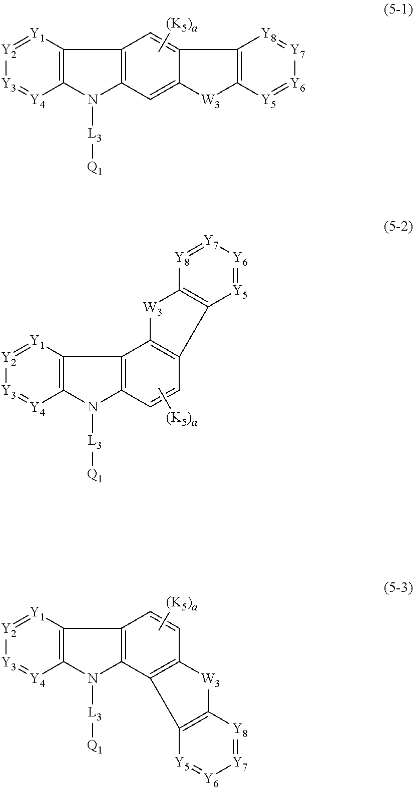

wherein in the formulas (5-1) to (5-3),

W₃, L₃, Y₁ to Y₈ and Q₁ are independently a group similar to W₃, L₃, Y₁ to Y₈ and Q₁ in the formula (2-3);

K₅ is a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms; and

a is an integer of 0 to 2.

9. The organic electroluminescence device according to any of 2 to 5, wherein the aromatic heterocyclic derivative B is represented by the following formula (6-1):

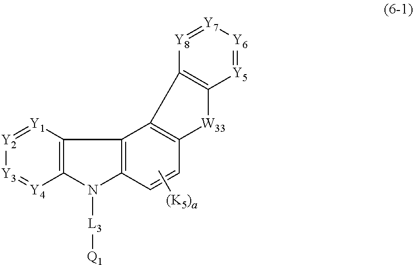

wherein in the formula (6-1),

L₃, Y₁ to Y₈ and Q₁ are independently a group similar to L₃, Y₁ to Y₈ and Q₁ in the formula (2-3);

K₅ is a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms;

a is an integer of 0 to 2;

W₃₃ is CR₈R₉, SiR₈R₉, an oxygen atom or a sulfur atom; and

R₇ to R₉ are independently a group similar to R₇ to R₉ in W₃ in the formula (2-b).

10. The organic electroluminescence device according to any of 2 to 5, wherein the aromatic heterocyclic derivative B is represented by the following formula (7-1):

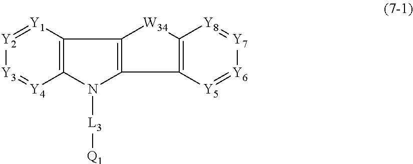

wherein in the formula (7-1),

L₃, Y₁ to Y₈ and Q₁ are independently a group similar to L₃, Y₁ to Y₈ and Q₁ in the formula (2-3);

W₃₄ is CR₈R₉ or SiR₈R₉; and

R₈ and R₉ are independently a group similar to R₈ and R₉ in W₃ in the formula (2-b).

11. The organic electroluminescence device according to any of 1 to 10, wherein a layer comprising a compound represented by the following formula (10) is bonded to the anode:

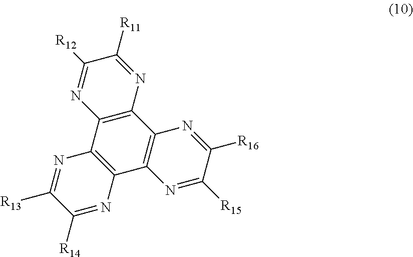

wherein R₁₁ to R₁₆ are independently a cyano group, —CONH₂, a carboxy group or —COOR₁₇ (R₁₇ is an alkyl group including 1 to 20 carbon atoms), or R₁₁ and R₁₂, R₁₃ and R₁₄ or R₁₅ and R₁₆ are bonded with each other to form —CO—O—CO—.
12. The organic electroluminescence device according to any of 1 to 11, wherein the phosphorescent emitting material is an ortho-metalated complex of iridium (Ir), osmium (Os) or platinum (Pt).
13. An organic electroluminescence emitting apparatus comprising a first device that is the organic electroluminescence device according to any of claims 1 to 12 and an organic electroluminescence device (second device) that emits fluorescent light,

the first device and the second device being provided in parallel on a substrate,

wherein at least one of layers forming a hole-transporting region or an electron-transporting region in the first device and the second device is a common layer.

14. A nitrogen-containing aromatic heterocyclic derivative represented by the formula (11-1) or (11-2):

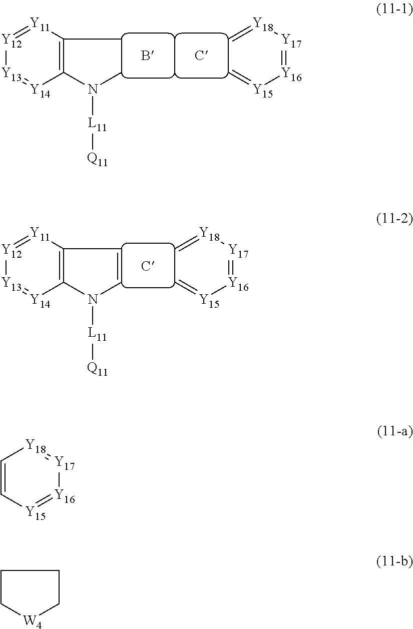

wherein in the formula (11-1) or (11-1),

the ring B′ is a ring represented by the formula (11-a) that is fused to adjacent rings;

the ring C′ is a ring represented by the formula (11-b) that is fused to adjacent rings;

W₄ is NR₂₁, CR₂₂R₂₃, SiR₂₂R₂₃ or an oxygen atom;

R₂₁ to R₂₃ are independently a hydrogen atom, a substituted or unsubstituted alkyl group including 1 to 20 carbon atoms, a substituted or unsubstituted cycloalkyl group including 3 to 20 carbon atoms, a substituted or unsubstituted haloalkyl group including 1 to 20 carbon atoms, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms;

Y₁₁ to Y₁₈ are independently a carbon atom that is bonded to the following R₂₄, or a nitrogen atom, provided that if adjacent two atoms are carbon atoms, a ring including the adjacent carbon atoms may be formed with the adjacent carbon atoms being not bonded to R₂₄;

R₂₄ is independently a hydrogen atom, a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms (excluding a substituted or unsubstituted carbazolyl group);

L₁₁ is a single bond, a substituted or unsubstituted arylene group including 6 to 30 ring carbon atoms or a substituted or unsubstituted heteroarylene group including 5 to 30 ring atoms;

Q₁₁ is a group represented by the following formula (11-c), (11-d), (11-e) or (11-f):

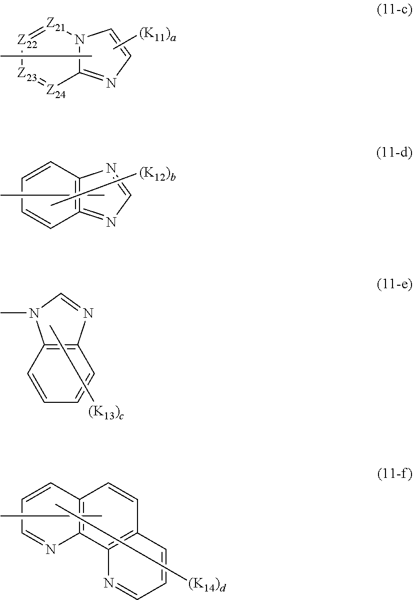

wherein in the formulas (11-c), (11-d), (11-e) and (11-f),

Z₂₁ to Z₂₄ are independently a carbon atom that is bonded to L₁₁, or a carbon atom that is bonded to the following R₂₅, or a nitrogen atom, provided that if the adjacent two atoms are carbon atoms, a ring including the adjacent carbon atoms may be formed with the adjacent two carbon atoms being not bonded to R₂₅;

R₂₅ and K₁₁ to K₁₄ are independently a hydrogen atom, a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms.

15. The nitrogen-containing aromatic heterocyclic derivative according to according to claim 14 that is represented by the following formula (12-1) or (12-2):

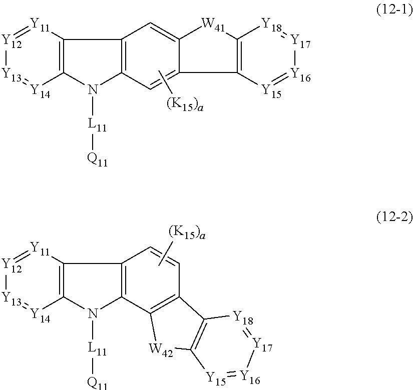

wherein in the formula (12-1) or (12-2),

L₁₁, Y₁₁ to Y₁₈ and Q₁₁ are independently a group similar to L₁₁, Y₁₁ to Y₁₈ and Q₁₁ in the above formula (11-1);

W₄₁ is CR₂₂R₂₃, SiR₂₂R₂₃ or an oxygen atom;

W₄₂ is NR₂₁, CR₂₂R₂₃, SiR₂₂R₂₃ or an oxygen atom;

R₂₁ to R₂₃ are independently a group similar to R₂₁ to R₂₃ in the formula (11-b);

K₁₅ is a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atom; and

a is an integer of 0 to 2.

16. The nitrogen-containing aromatic heterocyclic derivative according to 14 which is represented by the following formula (13-1), (13-2) or (13-3):

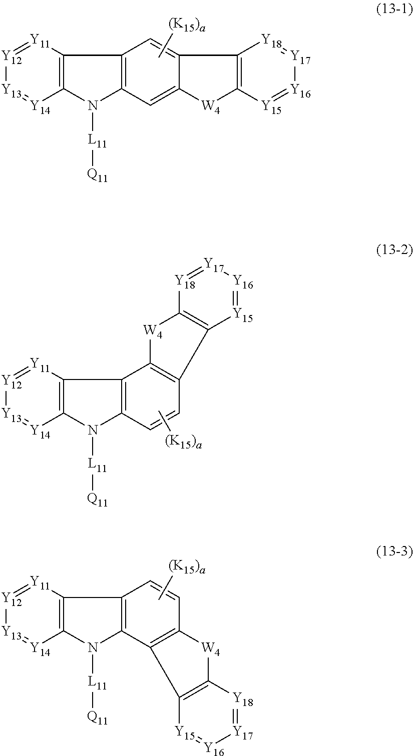

wherein in the formulas (13-1) to (13-3),

W₄, L₁₁, Y₁₁ to Y₁₈ and Q₁₁ are independently a group similar to W₄, L₁₁, Y₁₁ to Y₁₈ and Q₁₁ in the above formula (11-1);

K₁₅ is a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atom; and

a is an integer of 0 to 2.

17. The nitrogen-containing aromatic heterocyclic derivative according to 14 which is represented by the following formula (14-1):

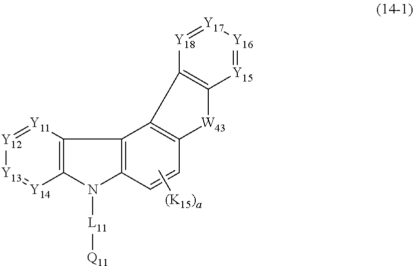

wherein in the formula (14-1),

L₁₁, Y₁₁ to Y₁₈ and Q₁₁ are independently a group similar to L₁₁, Y₁₁ to Y₁₈ and Q₁₁ in the above formula (11-1);

W₄₃ is CR₂₂R₂₃, SiR₂₂R₂₃ or an oxygen atom;

R₂₂ and R₂₃ are independently a group similar to R₂₂ and R₂₃ in the above formula (11-b);

K₁₅ is a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms; and

a is an integer of 0 to 2.

18. The nitrogen-containing aromatic heterocyclic derivative according to 14 which is represented by the following formula (15-1):

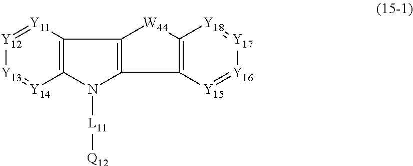

wherein in the formula (15-1),

L₁₁ and Y₁₁ to Y₁₈ are a group similar to L₁₁ and Y₁₁ to Y₁₈ in the above formula (11-1);

W₄₄ is CR₂₂R₂₃ or SiR₂₂R₂₃;

R₂₂ and R₂₃ are independently a group similar to R₂₂ and R₂₃ in the above formula (11-b); and

Q₁₂ is a group represented by the above formula (11-c), (11-d) or (11-e).

19. The nitrogen-containing aromatic heterocyclic derivative according to any of 14 to 18, which is a material for an organic electroluminescence device.
20. The nitrogen-containing aromatic heterocyclic derivative according to any of 14 to 18, which is an electron-transporting material for an organic electroluminescence device.

According to the invention, an organic EL device having a long life and a high luminous efficiency can be provided.

### BRIEF DESCRIPTION OF THE DRAWINGS

FIG. 1 is a schematic view showing the layer configuration of an organic EL device according to one embodiment of the invention;

FIG. 2 is a schematic cross-sectional view showing an example of an organic EL emitting apparatus using an organic EL device 1;

FIG. 3 is a schematic cross-sectional view showing the layer configuration of an organic EL device according to another embodiment of the invention; and

FIG. 4 is a schematic cross-sectional view showing the layer configuration of an organic EL device according to another embodiment of the invention.

### MODE FOR CARRYING OUT THE INVENTION

The organic EL device of the invention comprises, between an anode and a cathode being opposed, a first organic thin film layer and a second organic thin film layer in this sequence from the anode side. The first organic thin film layer comprises an aromatic heterocyclic derivative A represented by the following formula (1-1) and a phosphorescent emitting material, and the second organic thin film layer comprises an aromatic heterocyclic derivative B represented by the following formula (2-1).

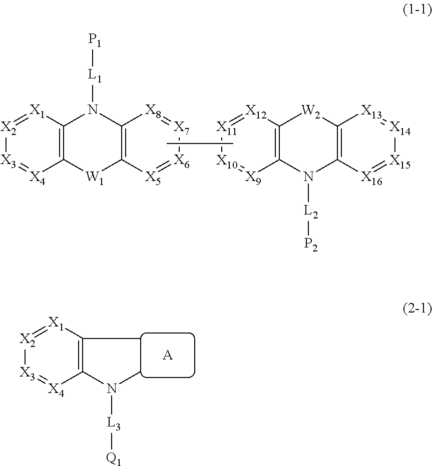

In the invention, by forming the first organic thin film layer and the second organic thin film layer in combination, the organic EL device can have a long life and a high luminous efficiency.

The first organic thin film layer can function as an emitting layer that emits phosphorescent light. The aromatic heterocyclic derivative A as the main component (host material) of the first organic thin film layer has a configuration in which two nitrogen-containing aromatic heterocyclic rings are directly bonded through a carbon-carbon bond. By introducing a nitrogen-containing heterocyclic group such as a group represented by the formula (1-a), (1-b) or (1-c) into this structure, this structure becomes a compound having a significantly high hole-transporting property and a uniquely low ionization potential (5.7 eV or less) as compared with a common carbazole derivative.

In the aromatic heterocyclic derivative A, since two cross-linked arylamine skeletons are directly bonded with each other through a carbon-carbon bond, the intermolecular electron density is increased and basicity of amines is significantly improved. As a result, the ionization potential is significantly lowered, and as a result, it exhibits a very high hole-injecting/transporting property as compared with a common cross-linked arylamine skeleton. Further, by bonding a nitrogen-containing heterocyclic group such as a group represented by the formula (1-a), (1-b) or (1-c) mentioned later as an electron-injecting/transporting site, this derivative also has electron-injecting/transporting property, whereby it functions as a host compound.

On the other hand, the aromatic heterocyclic derivative B that constitutes the second organic thin film layer is a compound having a large triplet energy (T1) (2.50 eV or more) and a high ionization potential (5.8 eV or more).

The aromatic heterocyclic derivative B has a structure in which an aromatic ring is further fused to a carbazole skeleton or an indole skeleton. In this skeleton, the intermolecular electron density is not significantly increased unlike the case of the aromatic heterocyclic derivative A, and a lowering in ionization potential does not occur. Therefore, by stacking the aromatic heterocyclic derivative A and the aromatic heterocyclic derivative B, a hole-injection barrier can be formed at the interface.

Due to a triplet energy of 2.50 eV or more, diffusion of the triplet energy from the first organic thin film layer can be prevented. That is, the second organic thin film layer functions as an exciton barrier layer.

Further, the aromatic heterocyclic derivative B has bipolarity and has high resistance to holes. In addition, the aromatic heterocyclic derivative B has a high capability of withdrawing electrons from the layers on the cathode side, and is excellent in electron-transporting property, and hence, it also functions as an electron-transporting layer. Therefore, since electrons are supplied to the first organic thin film layer efficiently, if the first organic thin film layer is an emitting layer, re-combination of holes and electrons is promoted, leading to improvement in luminous efficiency.

In the above formula (1-1), W₁ and W₂ are independently a single bond, CR₁R₂ or SiR₁R₂.

As compared with the case where W₁ and W₂ are a single bond, when W₁ and W₂ are CR₁R₂ or SiR₁R₂, basicity of amines of the compound is increased, whereby hole-transporting property is improved.

R₁ and R₂ are independently a hydrogen atom, a substituted or unsubstituted alkyl group including 1 to 20 carbon atoms, a substituted or unsubstituted cycloalkyl group including 3 to 20 carbon atoms, a substituted or unsubstituted haloalkyl group including 1 to 20 carbon atoms, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms.

L₁ and L₂ are independently a single bond, a substituted or unsubstituted arylene group including 6 to 30 ring carbon atoms or a substituted or unsubstituted heteroarylene group including 5 to 30 ring atoms.

Among X₁ to X₁₆, one of X₅ to X₈ and one of X₉ to X₁₂ are independently a carbon atom that is bonded with each other, the remainder of X₁ to X₁₆ are a carbon atom that is bonded to the following R₃, or a nitrogen atom, provided that, among X₁ to X₁₆, if adjacent two atoms are carbon atoms, a ring including the adjacent carbon atoms may be formed with the adjacent carbon atoms not being bonded to R₃.

R₃ is independently a hydrogen atom, a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atom or a substituted or unsubstituted heteroaryl group including 5 to 30 ring atoms.

P₁ and P₂ are independently a substituted or unsubstituted aryl group including 6 to 30 ring carbon atoms or a substituted or unsubstituted heteroaryl group including 5 to 30 ring atoms.

At least one of P₁ and P₂ are a group represented by the following formula (1-a), (1-b) or (1-c).

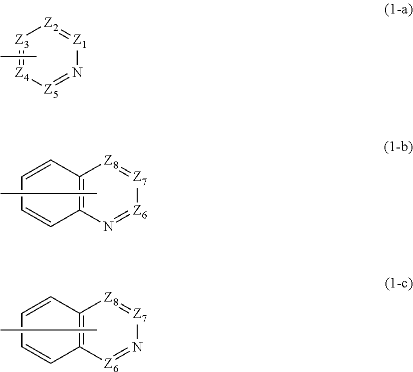

In the formulas (1-a), (1-b) and (1-c), Z₁ to Z₈ are independently a carbon atom that is bonded to L₁ or L₂ or a carbon atom that is bonded to the following R₄, or a nitrogen atom. If adjacent two atoms are carbon atoms, a ring including the adjacent carbon atoms may be formed with the adjacent carbon atoms not being bonded to R₄.

R₄ is independently a hydrogen atom, a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms.

In respect of resistance of a compound, of the compounds represented by the above formula (I-1), a compound represented by the following formula (1-2) is preferable.

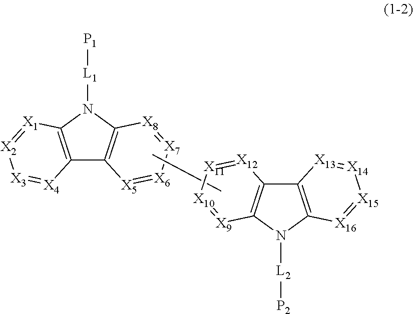

wherein X₁ to X₁₆, L₁, L₂, P₁ and P₂ are independently a group similar to X₁ to X₁₆, L₁, L₂, P₁ and P₂ in the formula (1-1).

A compound represented by the following formula (1-3), (1-4) or (1-5) is more preferable.

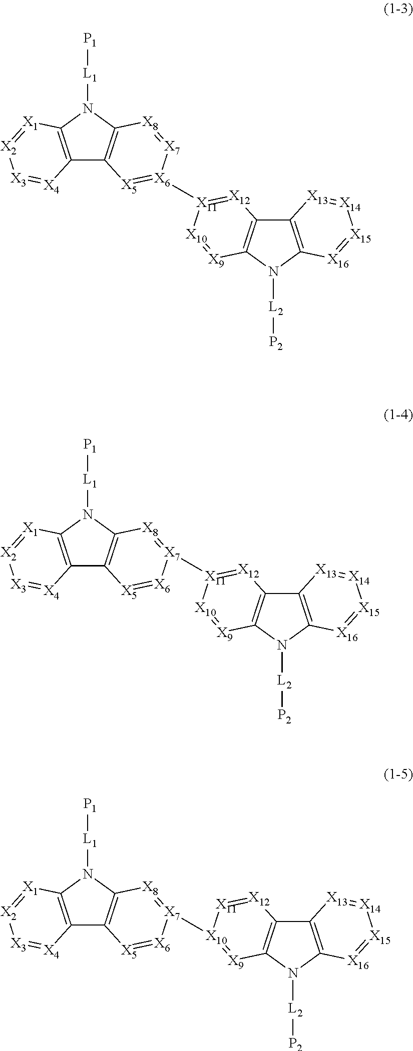

wherein X₁ to X₁₆, L₁, L₂, P₁ and P₂ are independently a group similar to X₁ to X₁₆, L₁, L₂, P₁ and P₂ in the formula (1-1).

In the formula (2-1), the ring A is a substituted or unsubstituted aromatic ring that is fused to an adjacent ring. As the aromatic ring, a ring including 6 to 30 ring carbon atoms or a heterocyclic ring including 5 to 30 ring atoms can be given.

Y₁ to Y₄ are independently a carbon atom that is bonded to the following R₅, or a nitrogen atom, provided that if adjacent two atoms are carbon atoms, a ring including the adjacent carbon atoms may be formed with the adjacent carbon atoms being not bonded to R₅.

R₅ is independently a hydrogen atom, a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms (excluding a substituted or unsubstituted carbazolyl group).

L₃ is a single bond, a substituted or unsubstituted arylene group including 6 to 30 ring carbon atoms or a substituted or unsubstituted heteroarylene group including 5 to 30 ring atoms.

Q₁ is a group represented by the above formula (1-a), (1-b) or (1-c) in the formula (1) given above or the following formula (2-c), (2-d), (2-e) or (2-f).

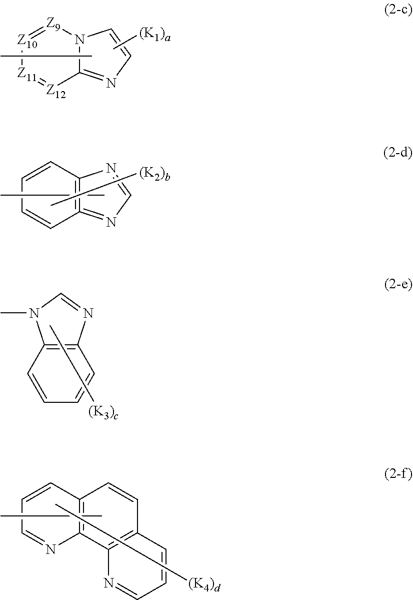

In the formulas (2-c), (2-d), (2-e) and (2-f), Z₉ to Z₁₂ are independently a carbon atom that is bonded to L₃ or a carbon atom that is bonded to the following R₆ or a nitrogen atom, provided that if adjacent two atoms are carbon atoms, a ring including the adjacent carbon atoms may be formed with the adjacent carbon atoms being not bonded to R₆.

R₆ and K₁ to K₄ are independently a hydrogen atom, a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms.

a is an integer of 0 to 2.

b is an integer of 0 to 4.

c is an integer of 0 to 5.

d is an integer of 0 to 7.

K₁ to K₄ may be bonded to the nitrogen atom.

In the invention, among the compounds represented by the above formula (2-1), a compound represented by any of the following formulas (2-2) to (2-4) is preferable.

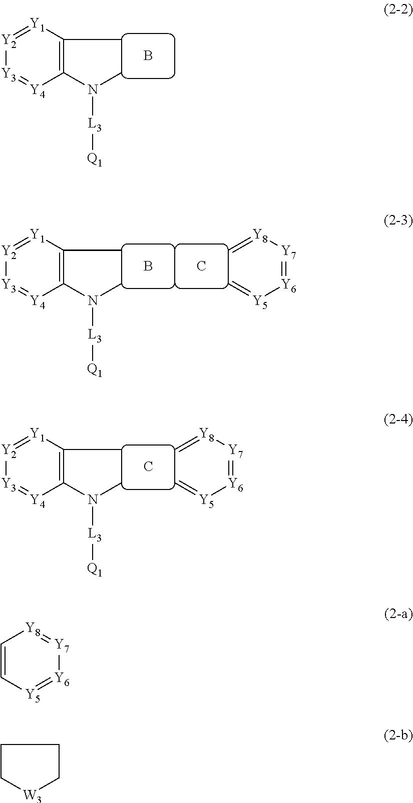

In the formula (2-2), (2-3) or (2-4), the ring B is a ring represented by the formula (2-a) that is fused to an adjacent ring(s) and the ring C is a ring represented by the formula (2-b) that is fused to adjacent rings.

W₃ is NR₇, CR₈R₉, SiR₈R₉, an oxygen atom or a sulfur atom.

R₇ to R₉ are independently a hydrogen atom, a substituted or unsubstituted alkyl group including 1 to 20 carbon atoms, a substituted or unsubstituted cycloalkyl group including 3 to 20 carbon atoms, a substituted or unsubstituted haloalkyl group including 1 to 20 carbon atoms, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms.

Y₁ to Y₈ are independently a carbon atom that is bonded to the following R₁₀, or a nitrogen atom, provided that if adjacent two atoms are carbon atoms, a ring including the two adjacent carbon atoms may be formed with the adjacent carbon atoms being not bonded to R₁₀.

R₁₀ is independently a hydrogen atom, a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms (excluding a substituted or unsubstituted carbazolyl group).

L₃ is a single bond, a substituted or unsubstituted arylene group including 6 to 30 ring carbon atoms or a substituted or unsubstituted heteroarylene group including 5 to 30 ring atoms.

Q₁ is a group represented by the above formula (1-a), (1-b), (1-c), (2-c), (2-d), (2-e) or (2-f).

In particular, as the aromatic heterocyclic derivative B, a compound represented by the following formula (3-1), (4-1), (4-2), (5-1), (5-2), (5-3), (6-1) or (7-1) is preferable.

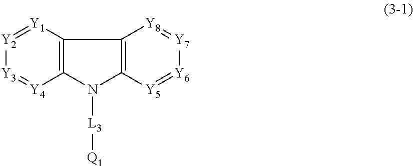

In the formula, L₃, Y₁ to Y₈ and Q₁ are independently a group similar to L₃, Y₁ to Y₄ and Q₁ in the formula (2-1).

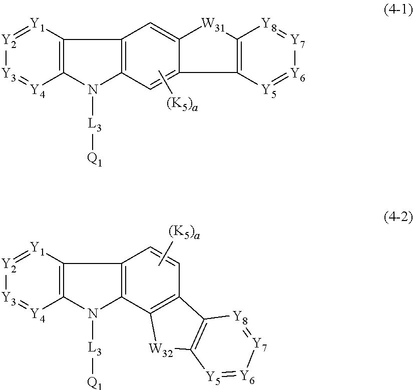

In the formula (4-1) or (4-2),

L₃, Y₁ to Y₈ and Q₁ are independently a group similar to L₃, Y₁ to Y₈ and Q₁ in the above formulas (2-3) and (2-a).

K₅ is a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms.

a is an integer of 0 to 2.

W₃₁ is CR₈R₉, SiR₈R₉, an oxygen atom or a sulfur atom.

W₃₂ is NR₇, CR₈R₉, SiR₈R₉, an oxygen atom or a sulfur atom.

R₇ to R₉ are independently a group similar to R₇ to R₉ in W₃ in the formula (2-b).

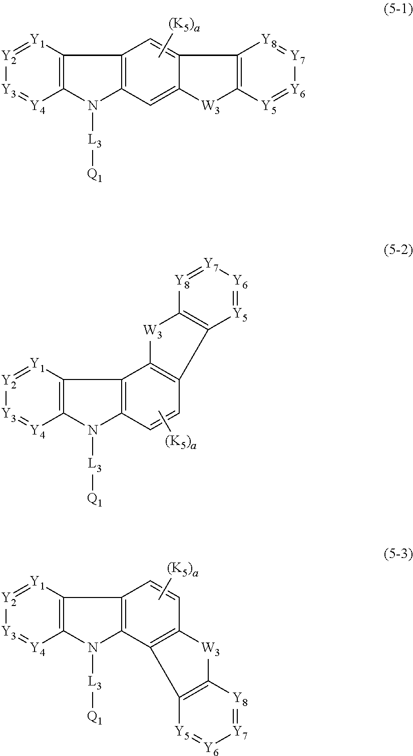

In the formula (5-1), (5-2) or (5-3),

W₃, L₃, Y₁ to Y₈ and Q₁ are independently a group similar to W₃, L₃, Y₁ to Y₈ and Q₁ in the formula (2-3).

K₅ is a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms. a is an integer of 0 to 2.

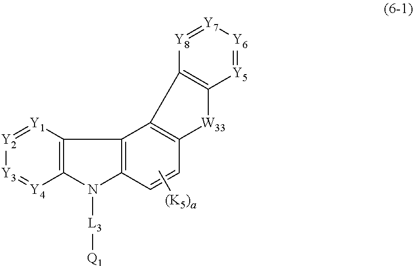

In the formula (6-1),

L₃, Y₁ to Y₈ and Q₁ are independently a group similar to L₃, Y₁ to Y₈ and Q₁ in the formula (2-3).

K₅ is a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms.

a is an integer of 0 to 2.

W₃₃ is CR₈R₉, SiR₈R₉, an oxygen atom or a sulfur atom.

R₇ to R₉ are independently a group similar to R₇ to R₉ in W₃ in the formula (2-b).

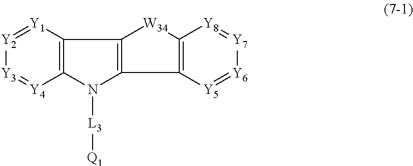

In the formula (7-1),

L₃, Y₁ to Y₈ and Q₁ are independently a group similar to L₃, Y₁ to Y₈ and Q₁ in the formula (2-3).

W₃₄ is CR₈R₉ or SiR₈R₉.

R₈ and R₉ are independently a group similar to R₈ and R₉ in W₃ in the formula (2-b).

Among the aromatic heterocyclic derivative B represented by the above formula (2-1), a nitrogen-containing aromatic heterocyclic derivative represented by the following formula (11-1) or (11-2) is a novel substance.

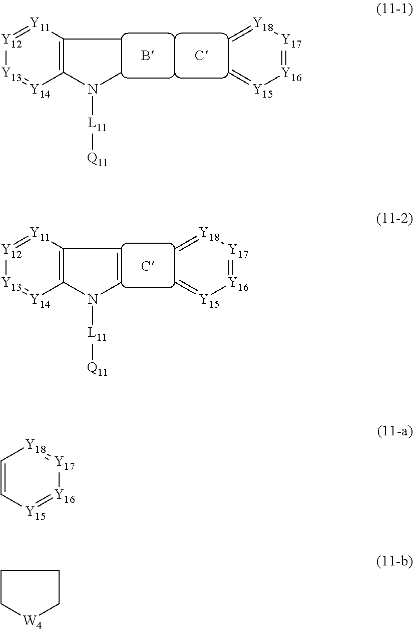

In the formula (11-1) or (11-1),

the ring B′ is a ring represented by the formula (11-a) that is fused to adjacent rings. The ring C′ is a ring represented by the formula (11-b) that is fused to adjacent rings.

W₄ is NR₂₁, CR₂₂R₂₃, SiR₂₂R₂₃ or an oxygen atom.

R₂₁ to R₂₃ are independently a hydrogen atom, a substituted or unsubstituted alkyl group including 1 to 20 carbon atoms, a substituted or unsubstituted cycloalkyl group including 3 to 20 carbon atoms, a substituted or unsubstituted haloalkyl group including 1 to 20 carbon atoms, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms.

Y₁₁ to Y₁₈ are independently a carbon atom that is bonded to the following R₂₄ or a nitrogen atom, provided that if adjacent two atoms are carbon atoms, a ring including the adjacent carbon atoms may be formed with the adjacent carbon atoms not being bonded to R₂₄.

R₂₄ is independently a hydrogen atom, a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms (excluding a substituted or unsubstituted carbazolyl group).

L₁₁ is a single bond, a substituted or unsubstituted arylene group including 6 to 30 ring carbon atoms or a substituted or unsubstituted heteroarylene group including 5 to 30 ring atoms.

Q₁₁ is a group represented by the following formula (11-c), (11-d), (11-e) or (11-f):

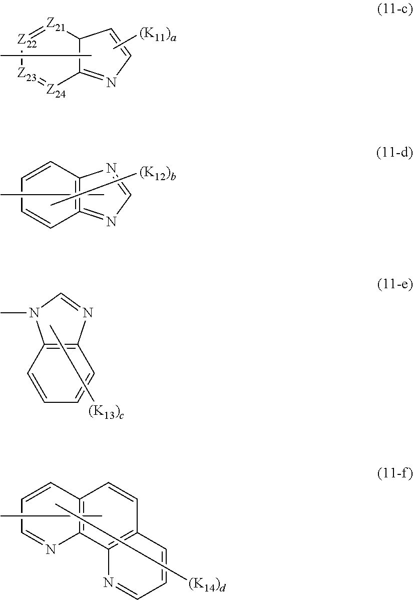

In the formula (11-c), (11-d), (11-e) or (11-f),

Z₂₁ to Z₂₄ are independently a carbon atom that is bonded to L₁₁, or a carbon atom that is bonded to the following R₂₅, or a nitrogen atom, provided that if the adjacent two atoms are carbon atoms, a ring including the adjacent carbon atoms may be formed with the adjacent carbon atoms being not bonded to R₂₅.

R₂₅ and K₁₁ to K₁₄ are independently a hydrogen atom, a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms.

Among the nitrogen-containing aromatic heterocyclic derivatives represented by the following formula (11-1) or (11-2), a derivative represented by the following formula (12-1), (12-2), (13-1), (13-2), (13-3), (14-1) or (15-1) is preferable.

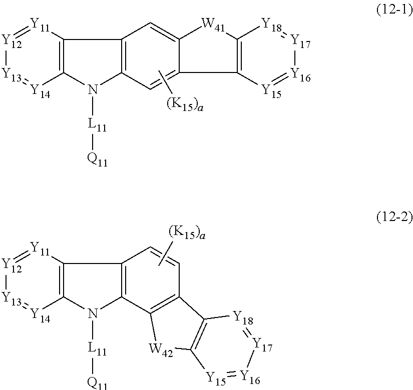

In the formula (12-1) or (12-2),

L₁₁, Y₁₁ to Y₁₈ and Q₁₁ are independently a group similar to L₁₁, Y₁₁ to Y₁₈ and Q₁₁ in the above formula (11-1).

W₄₁ is CR₂₂R₂₃, SiR₂₂R₂₃ or an oxygen atom.

W₄₂ is NR₂₁, CR₂₂R₂₃, SiR₂₂R₂₃ or an oxygen atom.

R₂₁ to R₂₃ are independently a group similar to R₂₁ to R₂₃ in the formula (11-b).

K₁₅ is a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms.

a is an integer of 0 to 2.

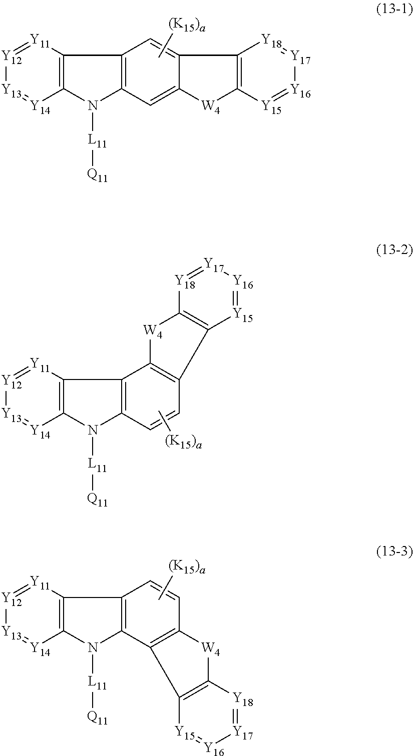

In the formulas (13-1) to (13-3),

W₄, L₁₁, Y₁₁ to Y₁₈ and Q₁₁ are independently a group similar to W₄, L₁₁, Y₁₁ to Y₁₈ and Q₁₁ in the above formula (11-1).

K₁₅ is a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms.

a is an integer of 0 to 2.

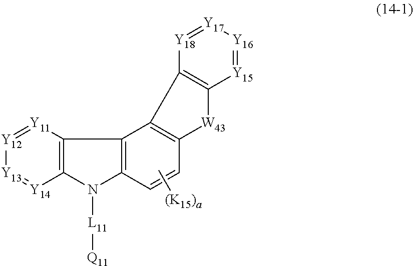

In the formula (14-1),

L₁₁, Y₁₁ to Y₁₈ and Q₁₁ are independently a group similar to L₁₁, Y₁₁ to Y₁₈ and Q₁₁ in the above formula (11-1).

W₄₃ is CR₂₂R₂₃, SiR₂₂R₂₃ or an oxygen atom.

R₂₂ and R₂₃ are independently a group similar to R₂₂ and R₂₃ in the above formula (11-b).

K₁₅ is a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms.

a is an integer of 0 to 2.

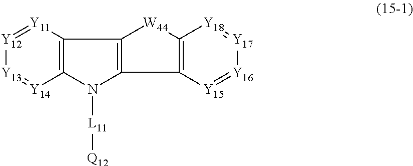

In the formula (15-1),

L₁₁ and Y₁₁ to Y₁₈ are a group similar to L₁₁ and Y₁₁ to Y₁₈ in the above formula (11-1).

W₄₄ is CR₂₂R₂₃ or SiR₂₂R₂₃.

R₂₂ and R₂₃ are independently a group similar to R₂₂ and R₂₃ in the above formula (11-b).

Q₁₂ is a group represented by the above formula (11-c), (11-d) or (11-e).

The above-mentioned nitrogen-containing heterocyclic derivative is preferable as a material for an organic EL device, in particular as an electron-transporting material.

Hereinbelow, an explanation will be made on examples of each group in the aromatic heterocyclic derivative A and the aromatic heterocyclic derivative B used in the invention.

The “ring carbon atoms” means carbon atoms that form a saturated ring, an unsaturated ring or an aromatic ring. The “ring atoms” means carbon atoms or hetero atoms that form a hetero ring (including a saturated ring, an unsaturated ring and an aromatic ring).

As the alkyl group including 1 to 20 carbon atoms, a linear or branched alkyl group can be given. Specific examples thereof include a methyl group, an ethyl group, a propyl group, an isopropyl group, an n-butyl group, an isobutyl group, a sec-butyl group, a tert-butyl group, an n-pentyl group, an n-hexyl group, an n-heptyl group, and an n-octyl group. Of these, a methyl group, an ethyl group, a propyl group, an isopropyl group, an n-butyl group, an isobutyl group, a sec-butyl group and a tert-butyl group can preferably be given. A methyl group, an ethyl group, a propyl group, an isopropyl group, an n-butyl group, a sec-butyl group, a tert-butyl group are preferable.

As the cycloalkyl group including 3 to 20 carbon atoms, a cyclopropyl group, a cyclobutyl group, a cyclopentyl group, a cyclohexyl group, a 1-adamantyl group, a 2-adamantyl group, a 1-norbornyl group, a 2-norbornyl group, or the like can be given. A cyclopentyl group and a cyclohexyl group are preferable.

As the haloalkyl group including 1 to 20 carbon atoms, a group in which the above-mentioned alkyl group including 1 to 20 carbon atoms is substituted by one or more halogen atoms (a fluorine atom, a chlorine atom and a bromine atom are preferable, with a fluorine atom being preferable) can be given. Specifically, a fluoromethyl group, a difluoromethyl group, a trifluoromethyl group, a fluoroethyl group, a trifluoromethylmethyl group, a pentafluoroethyl group or the like can be given. A trifluoromethyl group and a pentafluoroethyl group are preferable.

The aryl group including 6 to 30 ring carbon atoms is preferably an aryl group including 6 to 20 ring carbon atoms, more preferably an aryl group including 6 to 12 ring carbon atoms.

Specific examples of the aryl group include a phenyl group, a naphthyl group, an anthryl group, a phenanthryl group, a naphthacenyl group, a pyrenyl group, a chrysenyl group, a benzo[c]phenanthryl group, a benzo[g]chrysenyl group, a triphenylenyl group, a fluorenyl group, a 9,9-dimethylfluorenyl group, a benzofluorenyl group, a dibenzofluorenyl group, a biphenylyl group, a terphenyl group and a fluoranthenyl group. A phenyl group, a biphenyl group, a tolyl group, a xylyl group and a naphthyl group are preferable.

The aralkyl group including 7 to 30 carbon atoms is represented by —Y—Z. As examples of Y, examples of alkylene corresponding to the above-mentioned examples of the alkyl can be given. As examples of Z, the above-mentioned examples of the aryl can be given. The aryl part of the aralkyl group has preferably 6 to 20 carbon atoms, particularly preferably 6 to 12 carbon atoms. The alkyl part has preferably 1 to 10 carbon atoms, with 1 to 6 carbon atoms being particularly preferable. For example, a benzyl group, a phenylethyl group and a 2-phenylpropane-2-yl group can be given, for example.

As the heteroaryl group or the heteroarylene group including 5 to 30 ring atoms, a heteroaryl group including 5 to 20 ring atoms, more preferably a heteroaryl group including 5 to 14 ring atoms can be given.

As the specific examples of the heteroaryl group, a pyrrolyl group, a pyrazinyl group, a pyridinyl group, an indolyl group, an isoindolyl group, an imidazolyl group, a furyl group, a benzofuranyl group, an isobenzofuranyl group, a dibenzofuranyl group, a dibenzothiophenyl group, a quinolyl group, an isoquinolyl group, a quinoxalinyl group, a carbazolyl group, a phenanthridinyl group, an acridinyl group, a phenanthrolinyl group, a phenazinyl group, a phenothiazinyl group, a phenoxazinyl group, an oxazolyl group, an oxadiazolyl group, a furazanyl group, a thienyl group, a benzothiophenyl group or the like can be given. Of these, a dibenzofuranyl group, a dibenzothiophenyl group or a carbazolyl group can preferably be given.

As specific examples of the arylene group including 6 to 30 (preferably 6 to 20, more preferably 6 to 12) ring carbon atoms and the heteroarylene group including 5 to 30 (preferably 5 to 20, more preferably 5 to 14) ring atoms, a divalent group corresponding to the specific examples of the aryl group including 6 to 30 ring carbon atoms and the heteroaryl group including 5 to 30 ring atoms can be given. Preferably, a divalent group such as a phenyl group, a fluorenyl group, a 9,9-dimethylfluorenyl group, a naphthyl group, a phenanthryl group, a biphenylyl group, a terphenylyl group, a dibenzofluorenyl group, a pyridinyl group, an isoquinolyl group or the like can be given.

Similarly, as the ring including 6 to 30 ring carbon atoms represented by the ring A in the formula (2-1) or the heterocyclic ring including 5 to 30 ring atoms, a ring corresponding to the specific examples of the aryl group including 6 to 30 ring carbon atoms and the heteroaryl group including 5 to 30 ring atoms can be given.

The alkoxy group including 1 to 20 carbon atoms is represented by —OY, and as examples of Y, examples of the above-mentioned alkyl group can be given. The alkoxy group is a methoxy group and an ethoxy group, for example.

As the haloalkoxy group including 1 to 20 carbon atoms, a group in which the above-mentioned alkoxy group is substituted by one or more halogen atoms (a fluorine atom, a chlorine atom and a bromine atom can be given, with a fluorine atom being preferable). A trifluoromethoxy group is preferable.

As the substituted or unsubstituted silyl group, a silyl group, an alkylsilyl group including 1 to 10 (preferably 1 to 6) carbon atoms, an arylsilyl group including 6 to 30 (preferably 6 to 20, more preferably 6 to 10) carbon atoms or the like can be given.

Specific examples of the alkylsilyl group include a trimethylsilyl group, a triethylsilyl group, a t-butyldimethylsilyl group, a vinyldimethylsilyl group, a propyldimethylsilyl group or the like.

Specific examples of the arylsilyl group include a triphenylsilyl group, a phenyldimethylsilyl group, a t-butyldiphenylsilyl group, a tritolylsilyl group, a trixylylsilyl group, a trinaphthylsilyl group or the like.

In each formula, as the ring including the adjacent carbon atoms when the adjacent carbon atoms are not bonded to R, an aromatic ring such as a benzene ring, a cycloalkyl ring such as cyclohexane, a cycloalkene such as cyclohexene or the like can be given.

As the substituent of each group in the aromatic heterocyclic derivative A and the aromatic heterocyclic derivative B expressed by the “substituted or unsubstituted.”, the above-mentioned alkyl group, a substituted silyl group, an aryl group, a cycloalkyl group, a heteroaryl group, an alkoxy group, an aralkyl group, a haloalkyl group or the like can be given. In addition, a halogen atom (a fluorine atom, a chlorine atom, a bromine atom, an iodine atom, or the like can be given, with a fluorine atom being preferable), a silyl group, a hydroxyl group, a nitro group, a cyano group, a carboxy group, an aryloxy group or the like can be given.

The aryloxy group is represented by —OZ. As examples of Z, the above-mentioned aryl group can be given. The aryloxy group is a phenoxy group, for example.

The “unsubstituted” in the “substituted or unsubstituted” means a state that a hydrogen atom is substituted by a substituent.

In the invention, a hydrogen atom includes an isomer differing in number of neutrons. That is, a hydrogen atom includes protium, deuterium and tritium.

Specific examples of the aromatic heterocyclic derivative A are shown below.

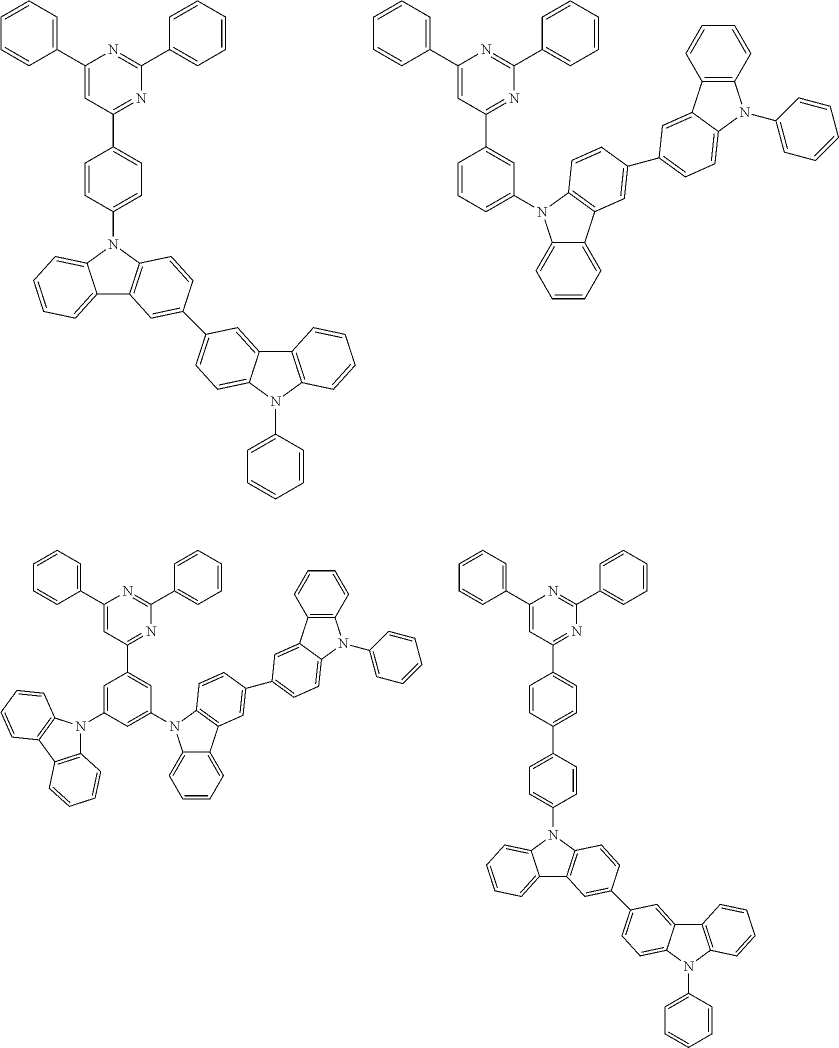 [SMILES: c1ccc(-c2cc(-c3ccc(-n4c5ccccc5c5cc(-c6ccc7c(c6)c6ccccc6n7-c6ccccc6)ccc54)cc3)nc(-c3ccccc3)n2)cc1 ; c1ccc(-c2cc(-c3cccc(-n4c5ccccc5c5cc(-c6ccc7c(c6)c6ccccc6n7-c6ccccc6)ccc54)c3)nc(-c3ccccc3)n2)cc1 ; c1ccc(-c2cc(-c3cc(-n4c5ccccc5c5ccccc54)cc(-n4c5ccccc5c5cc(-c6ccc7c(c6)c6ccccc6n7-c6ccccc6)ccc54)c3)nc(-c3ccccc3)n2)cc1 ; c1ccc(-c2cc(-c3ccc(-c4ccc(-n5c6ccccc6c6cc(-c7ccc8c(c7)c7ccccc7n8-c7ccccc7)ccc65)cc4)cc3)nc(-c3ccccc3)n2)cc1]

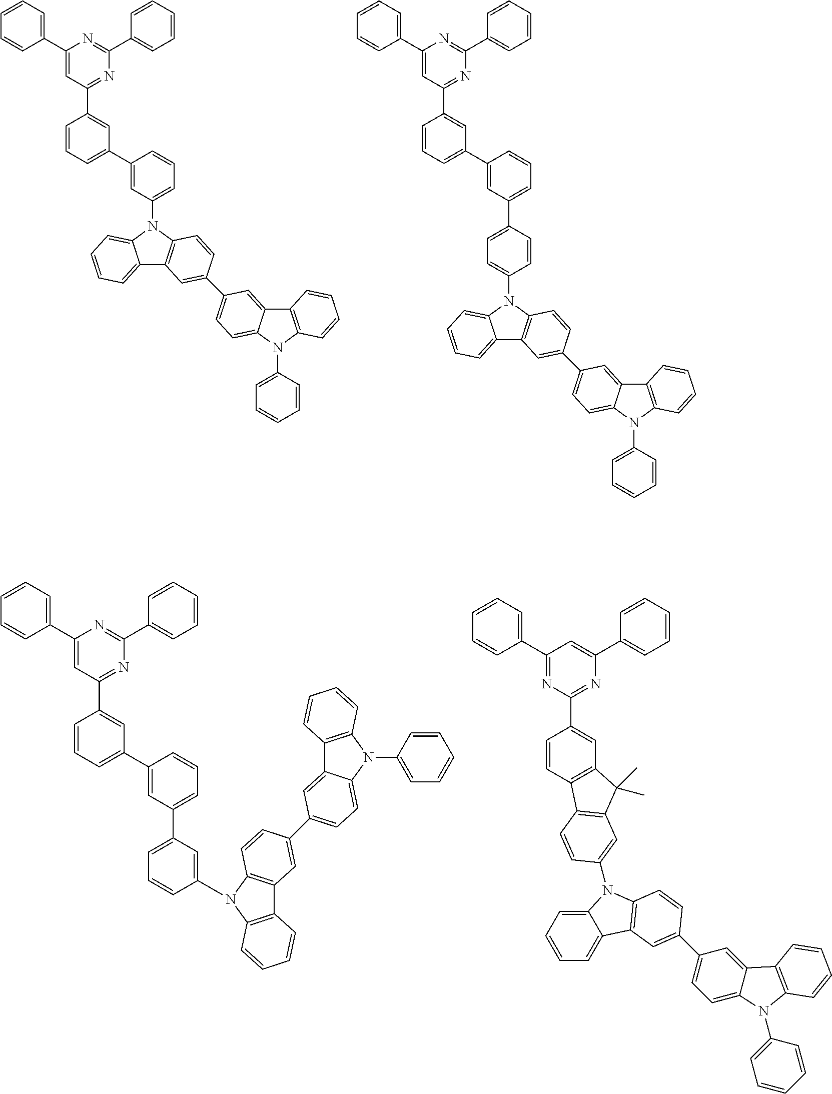 [SMILES: c1ccc(-c2cc(-c3cccc(-c4cccc(-n5c6ccccc6c6cc(-c7ccc8c(c7)c7ccccc7n8-c7ccccc7)ccc65)c4)c3)nc(-c3ccccc3)n2)cc1 ; c1ccc(-c2cc(-c3cccc(-c4cccc(-c5ccc(-n6c7ccccc7c7cc(-c8ccc9c(c8)c8ccccc8n9-c8ccccc8)ccc76)cc5)c4)c3)nc(-c3ccccc3)n2)cc1 ; c1ccc(-c2cc(-c3cccc(-c4cccc(-c5cccc(-n6c7ccccc7c7cc(-c8ccc9c(c8)c8ccccc8n9-c8ccccc8)ccc76)c5)c4)c3)nc(-c3ccccc3)n2)cc1 ; CC1(C)c2cc(-c3nc(-c4ccccc4)cc(-c4ccccc4)n3)ccc2-c2ccc(-n3c4ccccc4c4cc(-c5ccc6c(c5)c5ccccc5n6-c5ccccc5)ccc43)cc21]

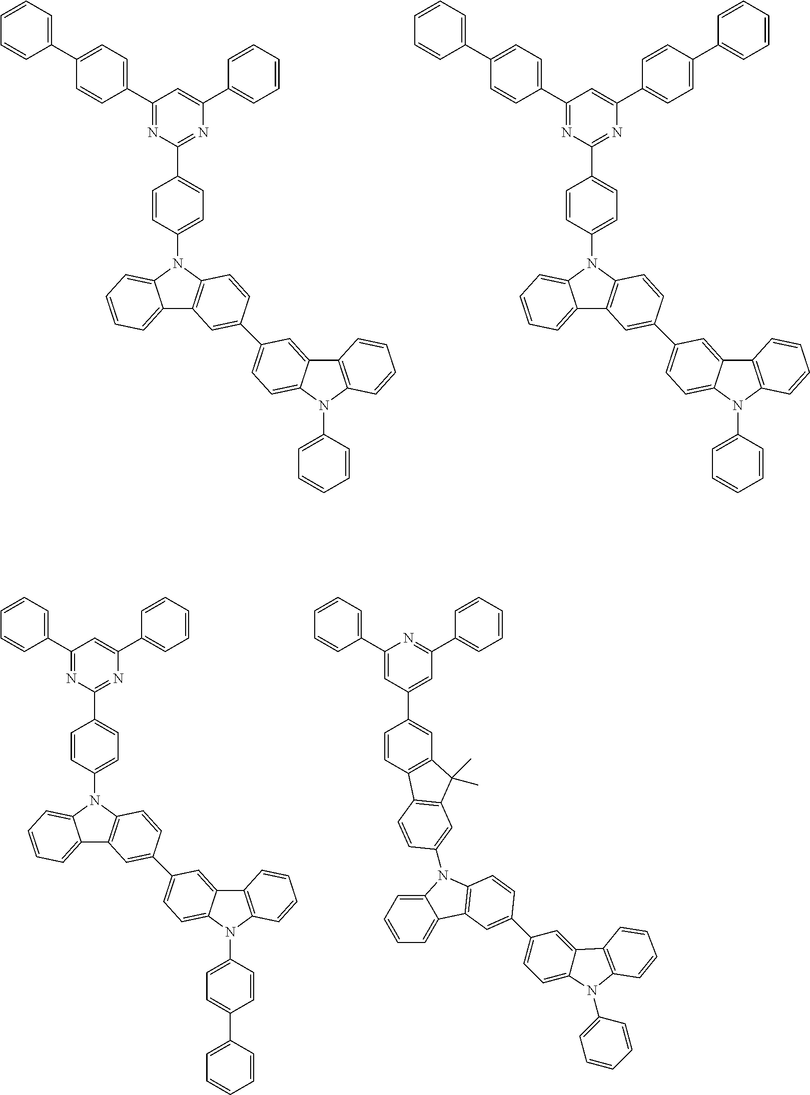 [SMILES: c1ccc(-c2ccc(-c3cc(-c4ccccc4)nc(-c4ccc(-n5c6ccccc6c6cc(-c7ccc8c(c7)c7ccccc7n8-c7ccccc7)ccc65)cc4)n3)cc2)cc1 ; c1ccc(-c2ccc(-c3cc(-c4ccc(-c5ccccc5)cc4)nc(-c4ccc(-n5c6ccccc6c6cc(-c7ccc8c(c7)c7ccccc7n8-c7ccccc7)ccc65)cc4)n3)cc2)cc1 ; c1ccc(-c2ccc(-n3c4ccccc4c4cc(-c5ccc6c(c5)c5ccccc5n6-c5ccc(-c6nc(-c7ccccc7)cc(-c7ccccc7)n6)cc5)ccc43)cc2)cc1 ; CC1(C)c2cc(-c3cc(-c4ccccc4)nc(-c4ccccc4)c3)ccc2-c2ccc(-n3c4ccccc4c4cc(-c5ccc6c(c5)c5ccccc5n6-c5ccccc5)ccc43)cc21]

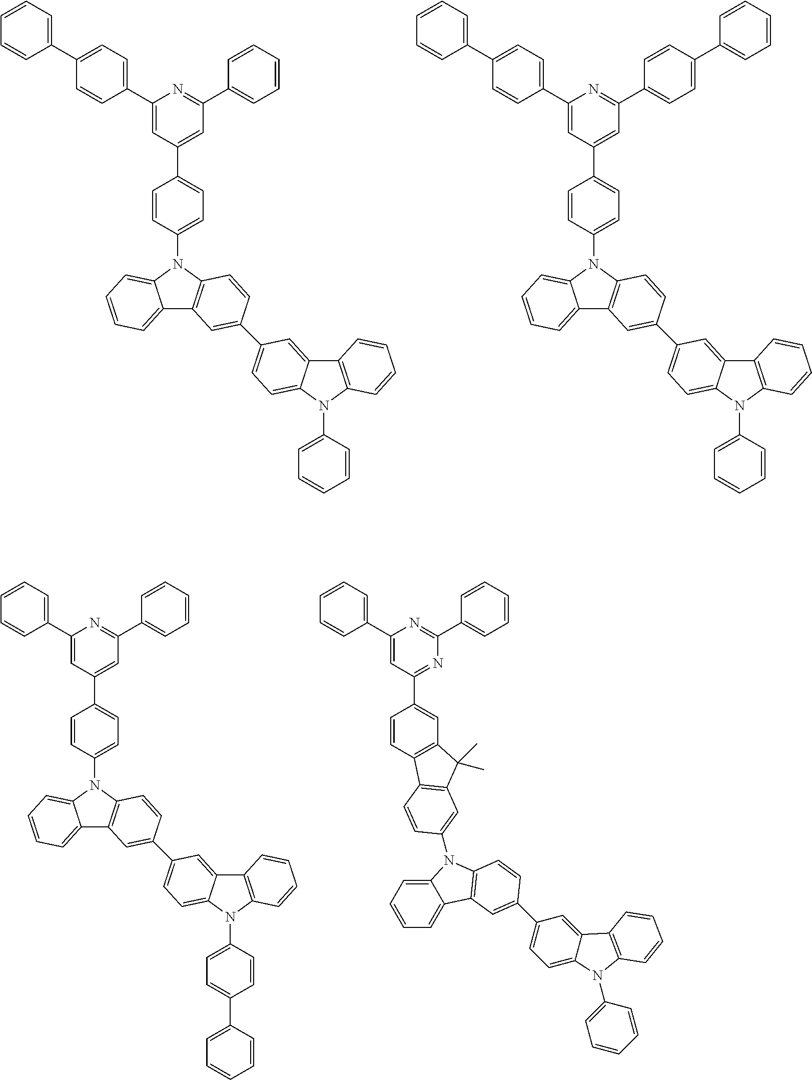 [SMILES: c1ccc(-c2ccc(-c3cc(-c4ccc(-n5c6ccccc6c6cc(-c7ccc8c(c7)c7ccccc7n8-c7ccccc7)ccc65)cc4)cc(-c4ccccc4)n3)cc2)cc1 ; c1ccc(-c2ccc(-c3cc(-c4ccc(-n5c6ccccc6c6cc(-c7ccc8c(c7)c7ccccc7n8-c7ccccc7)ccc65)cc4)cc(-c4ccc(-c5ccccc5)cc4)n3)cc2)cc1 ; c1ccc(-c2ccc(-n3c4ccccc4c4cc(-c5ccc6c(c5)c5ccccc5n6-c5ccc(-c6cc(-c7ccccc7)nc(-c7ccccc7)c6)cc5)ccc43)cc2)cc1 ; CC1(C)c2cc(-c3cc(-c4ccccc4)nc(-c4ccccc4)n3)ccc2-c2ccc(-n3c4ccccc4c4cc(-c5ccc6c(c5)c5ccccc5n6-c5ccccc5)ccc43)cc21]

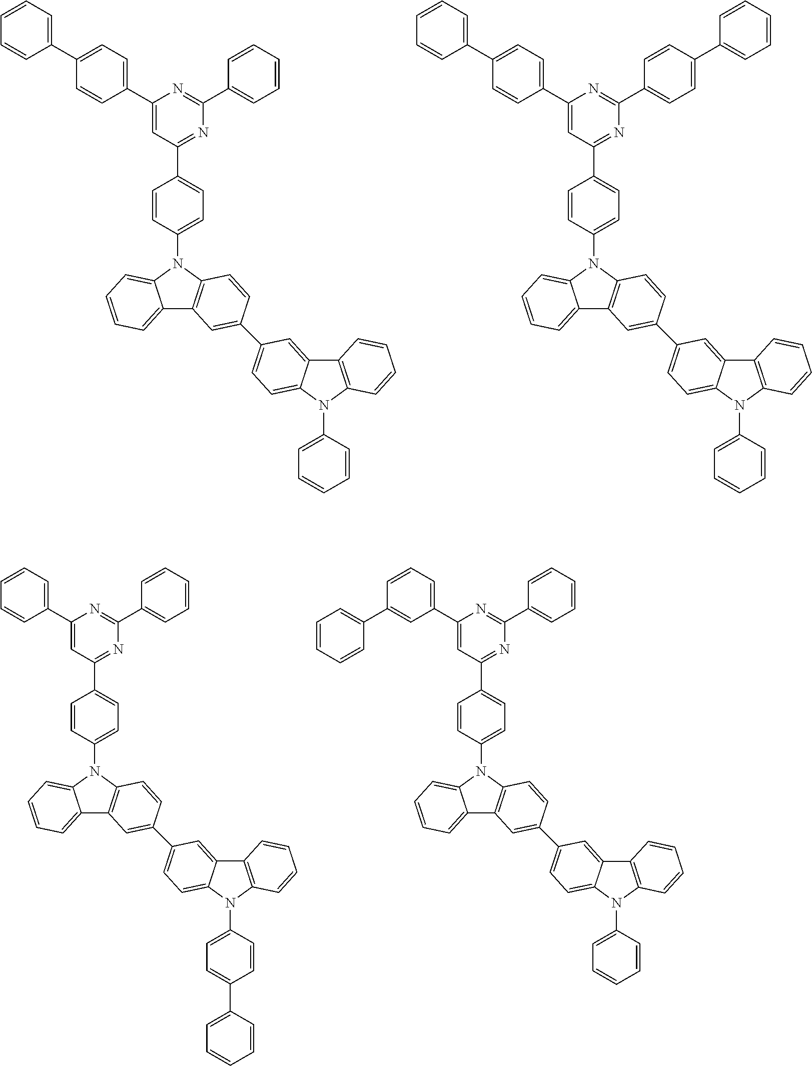 [SMILES: c1ccc(-c2ccc(-c3cc(-c4ccc(-n5c6ccccc6c6cc(-c7ccc8c(c7)c7ccccc7n8-c7ccccc7)ccc65)cc4)nc(-c4ccccc4)n3)cc2)cc1 ; c1ccc(-c2ccc(-c3cc(-c4ccc(-n5c6ccccc6c6cc(-c7ccc8c(c7)c7ccccc7n8-c7ccccc7)ccc65)cc4)nc(-c4ccc(-c5ccccc5)cc4)n3)cc2)cc1 ; c1ccc(-c2ccc(-n3c4ccccc4c4cc(-c5ccc6c(c5)c5ccccc5n6-c5ccc(-c6cc(-c7ccccc7)nc(-c7ccccc7)n6)cc5)ccc43)cc2)cc1 ; c1ccc(-c2cccc(-c3cc(-c4ccc(-n5c6ccccc6c6cc(-c7ccc8c(c7)c7ccccc7n8-c7ccccc7)ccc65)cc4)nc(-c4ccccc4)n3)c2)cc1]

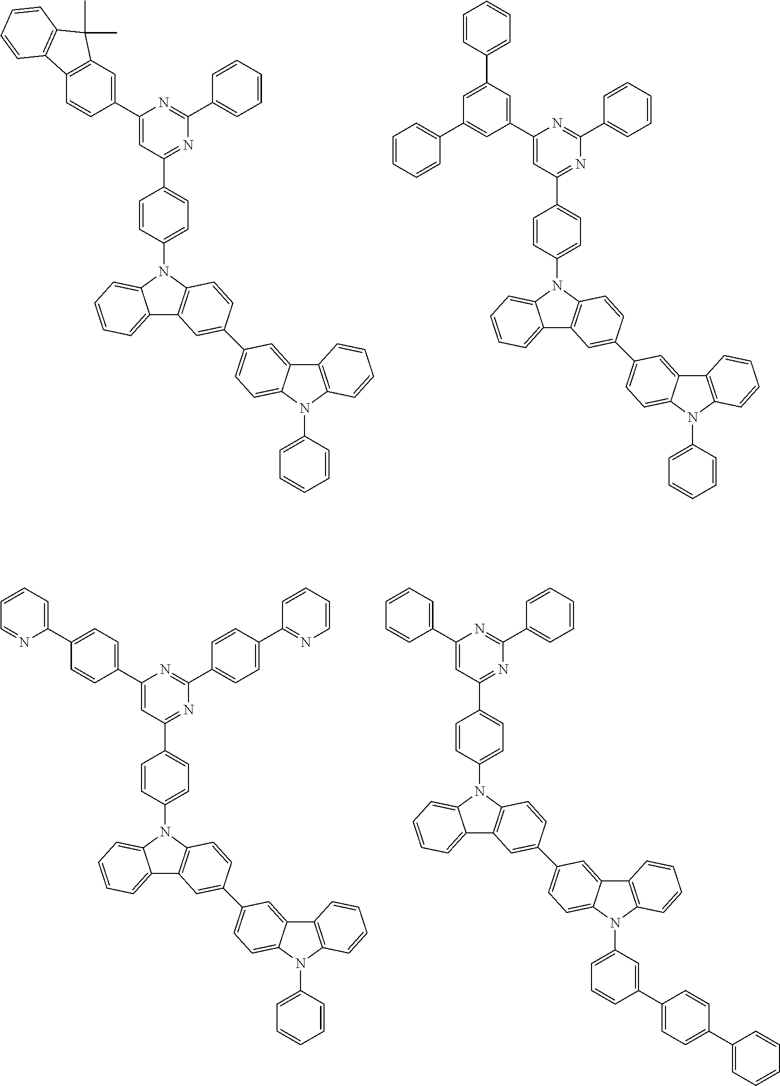 [SMILES: CC1(C)c2ccccc2-c2ccc(-c3cc(-c4ccc(-n5c6ccccc6c6cc(-c7ccc8c(c7)c7ccccc7n8-c7ccccc7)ccc65)cc4)nc(-c4ccccc4)n3)cc21 ; c1ccc(-c2cc(-c3ccccc3)cc(-c3cc(-c4ccc(-n5c6ccccc6c6cc(-c7ccc8c(c7)c7ccccc7n8-c7ccccc7)ccc65)cc4)nc(-c4ccccc4)n3)c2)cc1 ; c1ccc(-n2c3ccccc3c3cc(-c4ccc5c(c4)c4ccccc4n5-c4ccc(-c5cc(-c6ccc(-c7ccccn7)cc6)nc(-c6ccc(-c7ccccn7)cc6)n5)cc4)ccc32)cc1 ; c1ccc(-c2ccc(-c3cccc(-n4c5ccccc5c5cc(-c6ccc7c(c6)c6ccccc6n7-c6ccc(-c7cc(-c8ccccc8)nc(-c8ccccc8)n7)cc6)ccc54)c3)cc2)cc1]

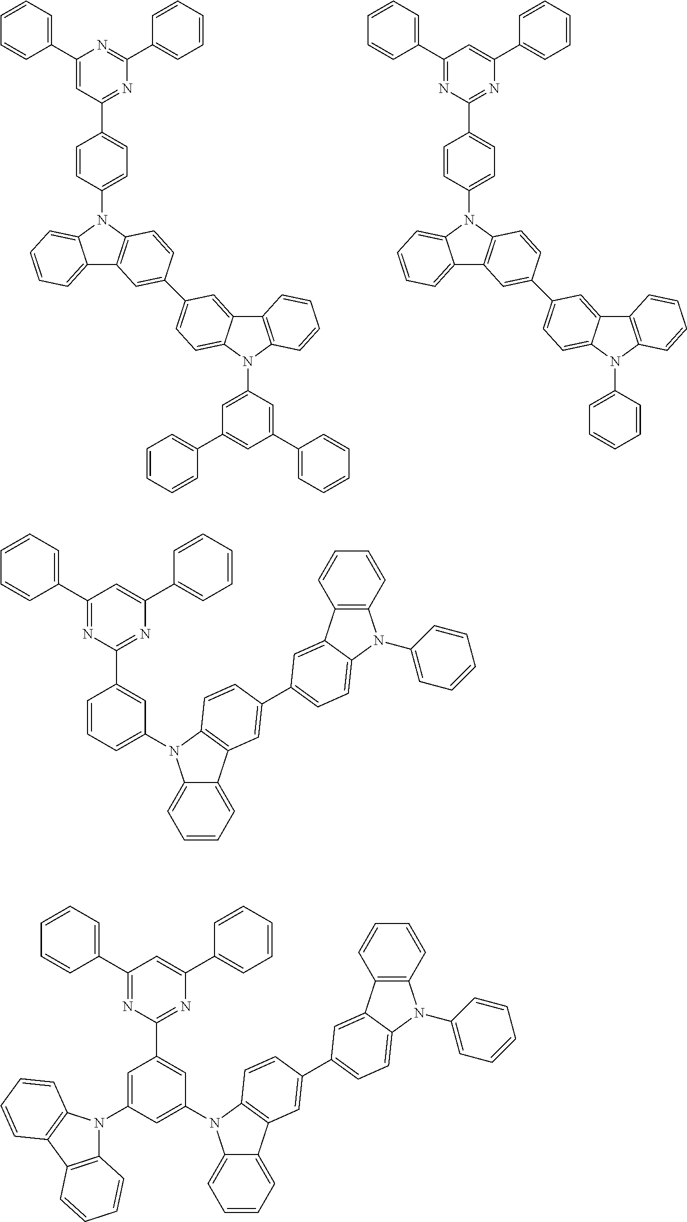 [SMILES: c1ccc(-c2cc(-c3ccccc3)cc(-n3c4ccccc4c4cc(-c5ccc6c(c5)c5ccccc5n6-c5ccc(-c6cc(-c7ccccc7)nc(-c7ccccc7)n6)cc5)ccc43)c2)cc1 ; c1ccc(-c2cc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2cc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2cc(-c3ccccc3)nc(-c3cc(-n4c5ccccc5c5ccccc54)cc(-n4c5ccccc5c5cc(-c6ccc7c(c6)c6ccccc6n7-c6ccccc6)ccc54)c3)n2)cc1]

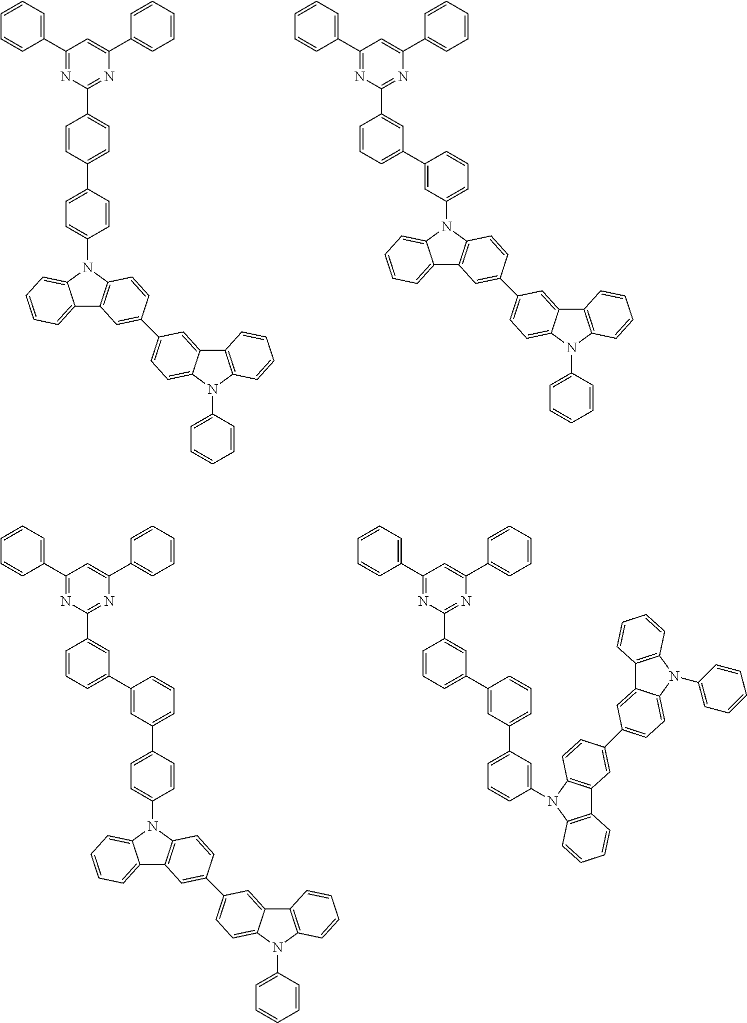 [SMILES: c1ccc(-c2cc(-c3ccccc3)nc(-c3ccc(-c4ccc(-n5c6ccccc6c6cc(-c7ccc8c(c7)c7ccccc7n8-c7ccccc7)ccc65)cc4)cc3)n2)cc1 ; c1ccc(-c2cc(-c3ccccc3)nc(-c3cccc(-c4cccc(-n5c6ccccc6c6cc(-c7ccc8c(c7)c7ccccc7n8-c7ccccc7)ccc65)c4)c3)n2)cc1 ; c1ccc(-c2cc(-c3ccccc3)nc(-c3cccc(-c4cccc(-c5ccc(-n6c7ccccc7c7cc(-c8ccc9c(c8)c8ccccc8n9-c8ccccc8)ccc76)cc5)c4)c3)n2)cc1 ; c1ccc(-c2cc(-c3ccccc3)nc(-c3cccc(-c4cccc(-c5cccc(-n6c7ccccc7c7cc(-c8ccc9c(c8)c8ccccc8n9-c8ccccc8)ccc76)c5)c4)c3)n2)cc1]

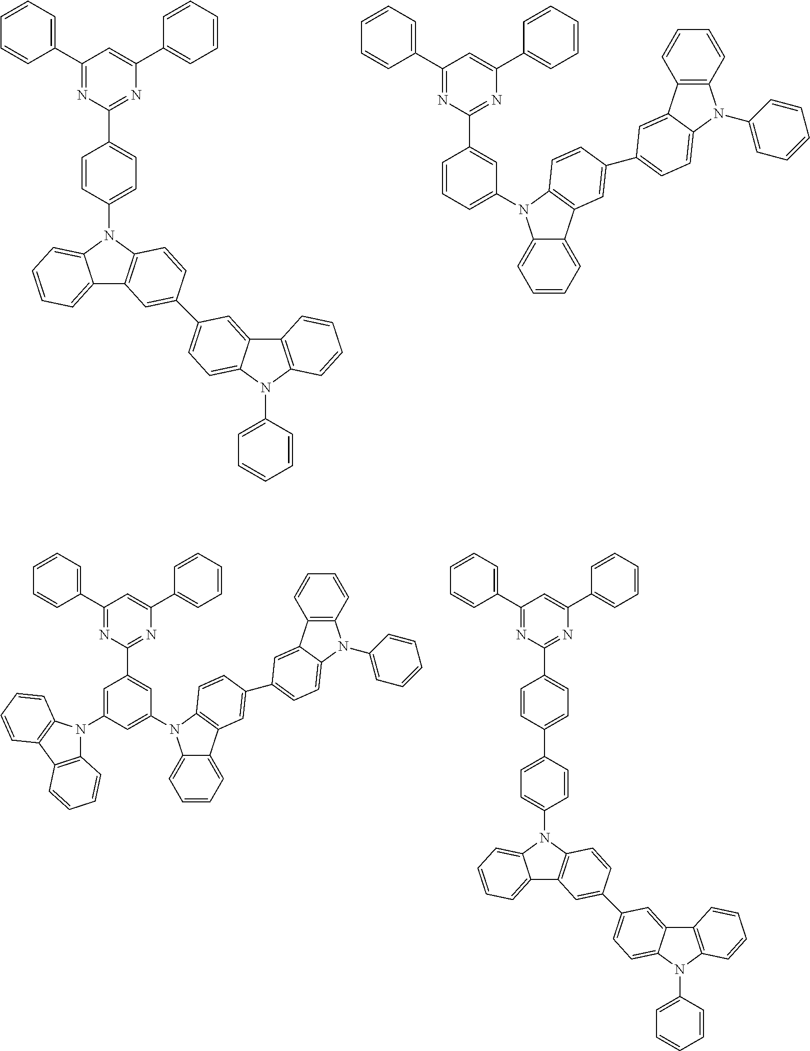 [SMILES: c1ccc(-c2cc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2cc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2cc(-c3ccccc3)nc(-c3cc(-n4c5ccccc5c5ccccc54)cc(-n4c5ccccc5c5cc(-c6ccc7c(c6)c6ccccc6n7-c6ccccc6)ccc54)c3)n2)cc1 ; c1ccc(-c2cc(-c3ccccc3)nc(-c3ccc(-c4ccc(-n5c6ccccc6c6cc(-c7ccc8c(c7)c7ccccc7n8-c7ccccc7)ccc65)cc4)cc3)n2)cc1]

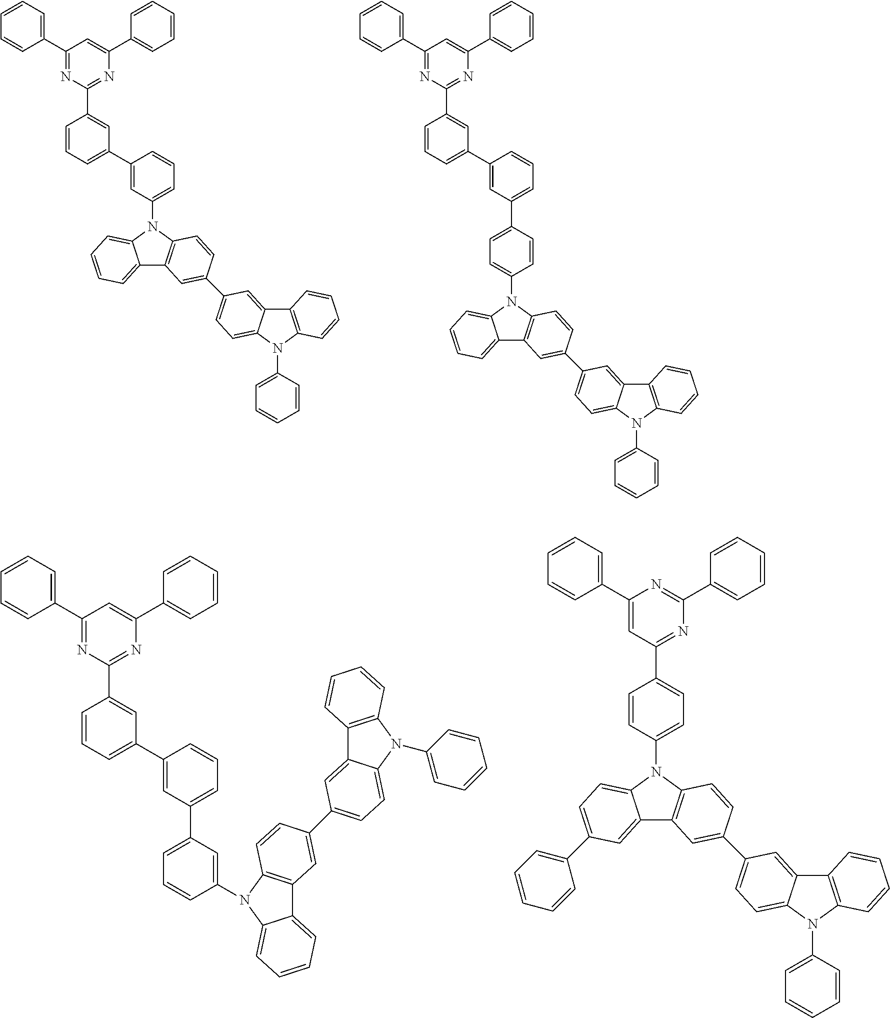 [SMILES: c1ccc(-c2cc(-c3ccccc3)nc(-c3cccc(-c4cccc(-n5c6ccccc6c6cc(-c7ccc8c(c7)c7ccccc7n8-c7ccccc7)ccc65)c4)c3)n2)cc1 ; c1ccc(-c2cc(-c3ccccc3)nc(-c3cccc(-c4cccc(-c5ccc(-n6c7ccccc7c7cc(-c8ccc9c(c8)c8ccccc8n9-c8ccccc8)ccc76)cc5)c4)c3)n2)cc1 ; c1ccc(-c2cc(-c3ccccc3)nc(-c3cccc(-c4cccc(-c5cccc(-n6c7ccccc7c7cc(-c8ccc9c(c8)c8ccccc8n9-c8ccccc8)ccc76)c5)c4)c3)n2)cc1 ; c1ccc(-c2ccc3c(c2)c2cc(-c4ccc5c(c4)c4ccccc4n5-c4ccccc4)ccc2n3-c2ccc(-c3cc(-c4ccccc4)nc(-c4ccccc4)n3)cc2)cc1]

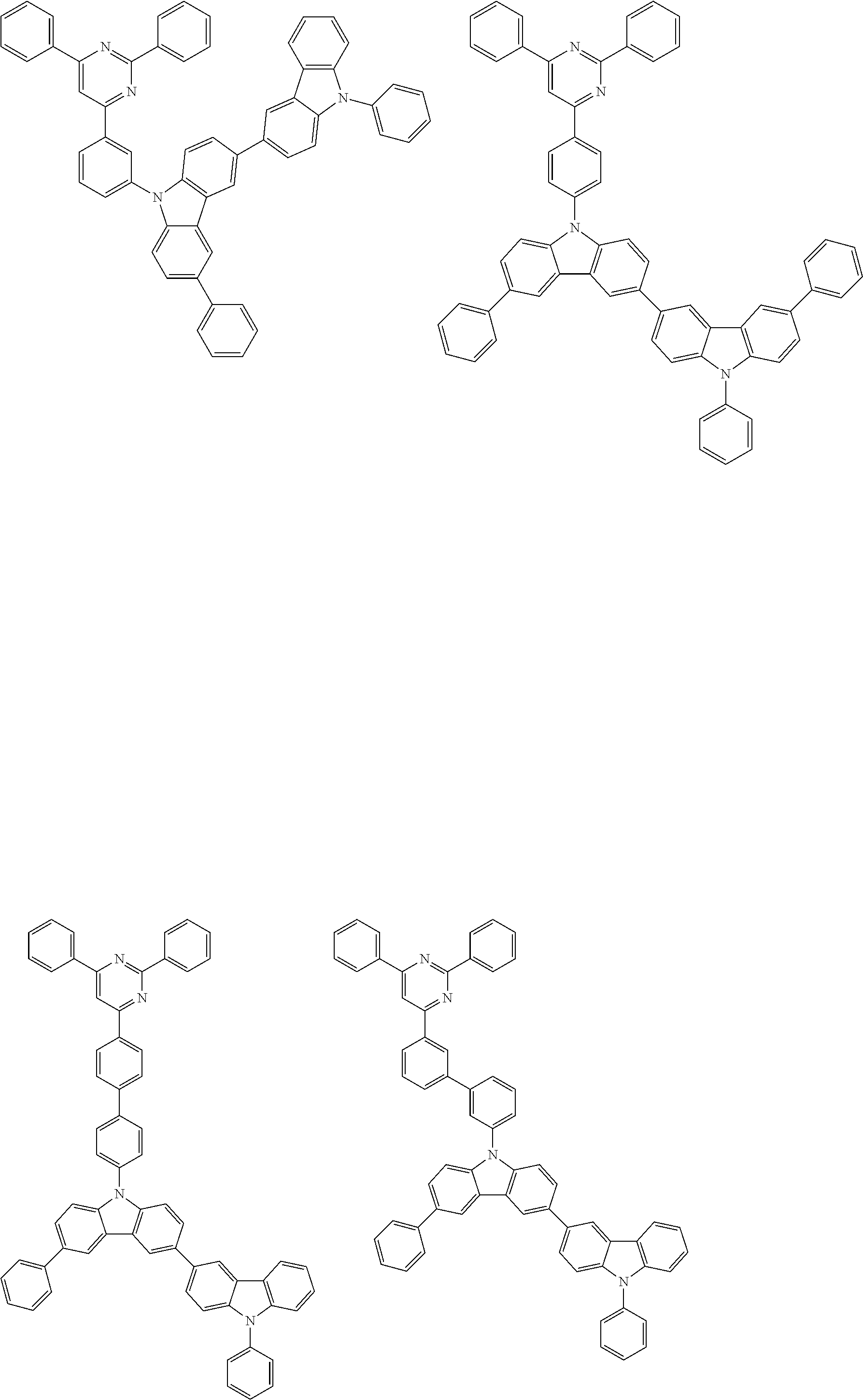 [SMILES: c1ccc(-c2ccc3c(c2)c2cc(-c4ccc5c(c4)c4ccccc4n5-c4ccccc4)ccc2n3-c2cccc(-c3cc(-c4ccccc4)nc(-c4ccccc4)n3)c2)cc1 ; c1ccc(-c2ccc3c(c2)c2cc(-c4ccc5c(c4)c4cc(-c6ccccc6)ccc4n5-c4ccc(-c5cc(-c6ccccc6)nc(-c6ccccc6)n5)cc4)ccc2n3-c2ccccc2)cc1 ; c1ccc(-c2ccc3c(c2)c2cc(-c4ccc5c(c4)c4ccccc4n5-c4ccccc4)ccc2n3-c2ccc(-c3ccc(-c4cc(-c5ccccc5)nc(-c5ccccc5)n4)cc3)cc2)cc1 ; c1ccc(-c2ccc3c(c2)c2cc(-c4ccc5c(c4)c4ccccc4n5-c4ccccc4)ccc2n3-c2cccc(-c3cccc(-c4cc(-c5ccccc5)nc(-c5ccccc5)n4)c3)c2)cc1]

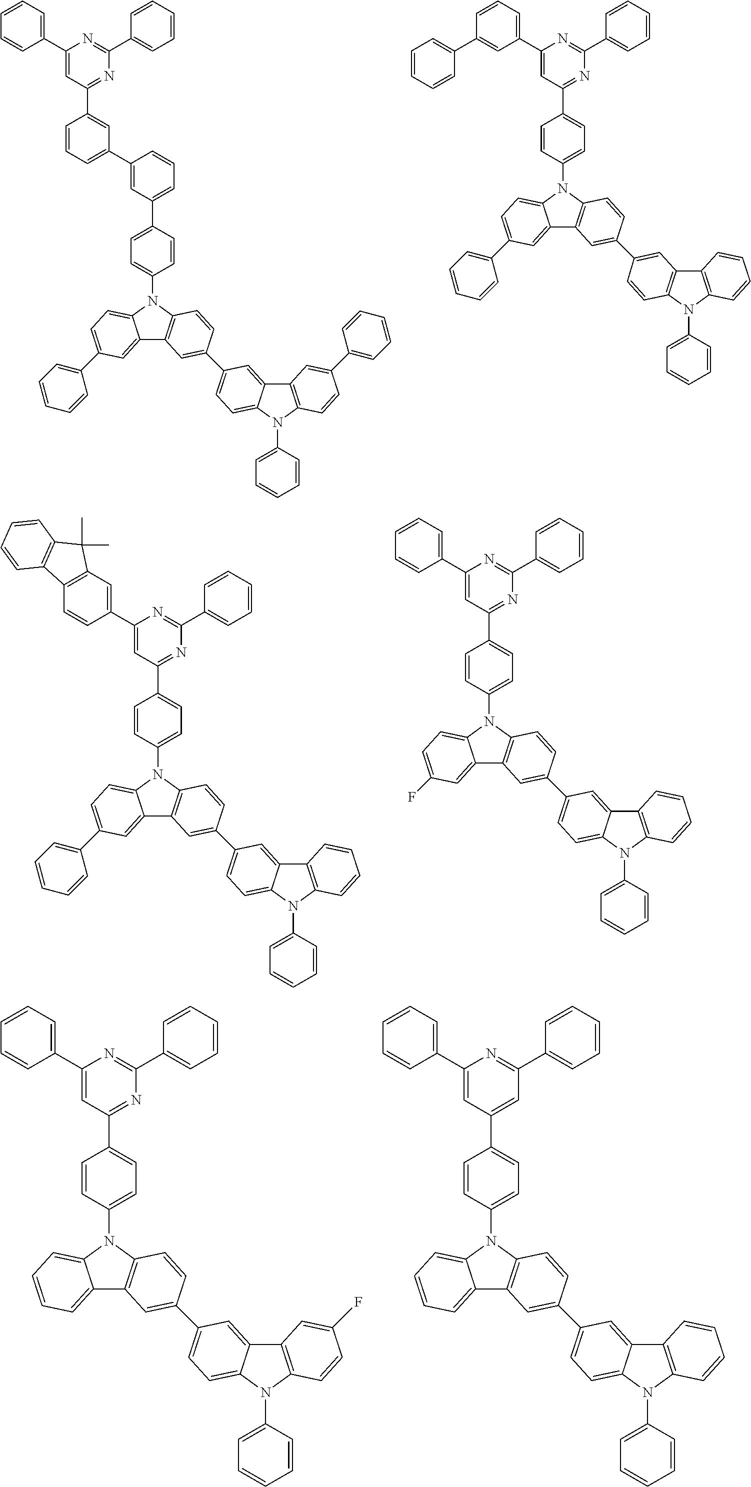

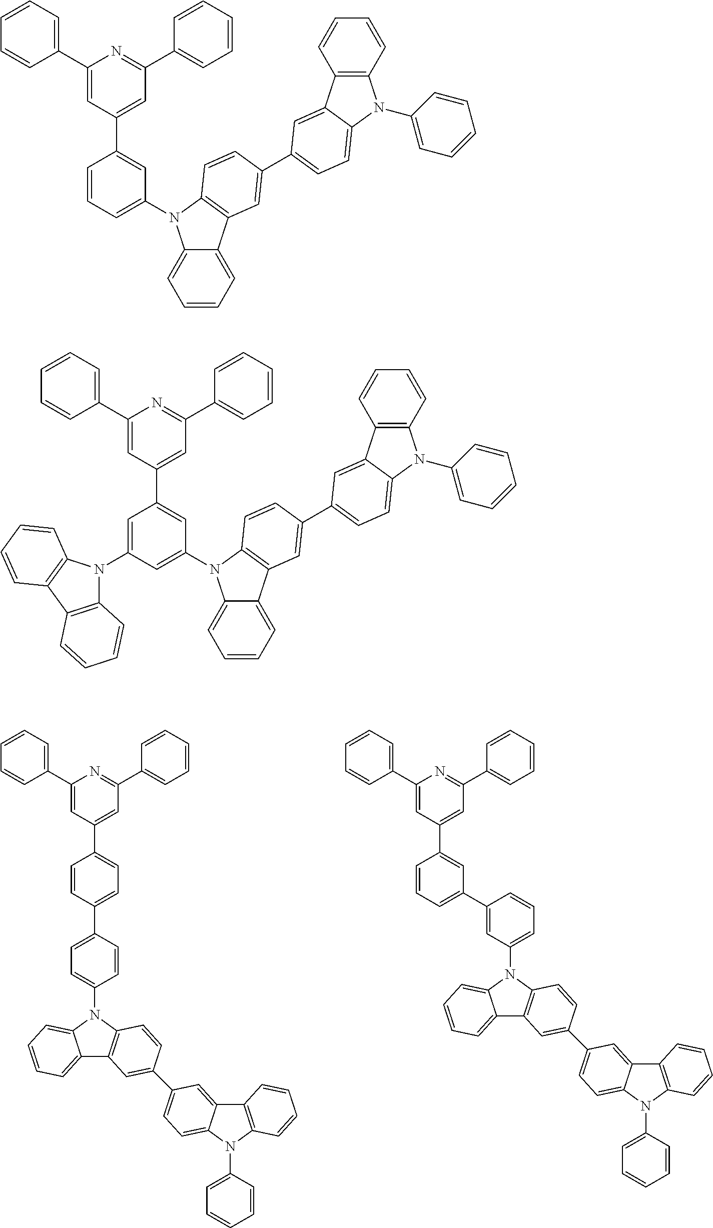 [SMILES: c1ccc(-c2cc(-c3cccc(-n4c5ccccc5c5cc(-c6ccc7c(c6)c6ccccc6n7-c6ccccc6)ccc54)c3)cc(-c3ccccc3)n2)cc1 ; c1ccc(-c2cc(-c3cc(-n4c5ccccc5c5ccccc54)cc(-n4c5ccccc5c5cc(-c6ccc7c(c6)c6ccccc6n7-c6ccccc6)ccc54)c3)cc(-c3ccccc3)n2)cc1 ; c1ccc(-c2cc(-c3ccc(-c4ccc(-n5c6ccccc6c6cc(-c7ccc8c(c7)c7ccccc7n8-c7ccccc7)ccc65)cc4)cc3)cc(-c3ccccc3)n2)cc1 ; c1ccc(-c2cc(-c3cccc(-c4cccc(-n5c6ccccc6c6cc(-c7ccc8c(c7)c7ccccc7n8-c7ccccc7)ccc65)c4)c3)cc(-c3ccccc3)n2)cc1]

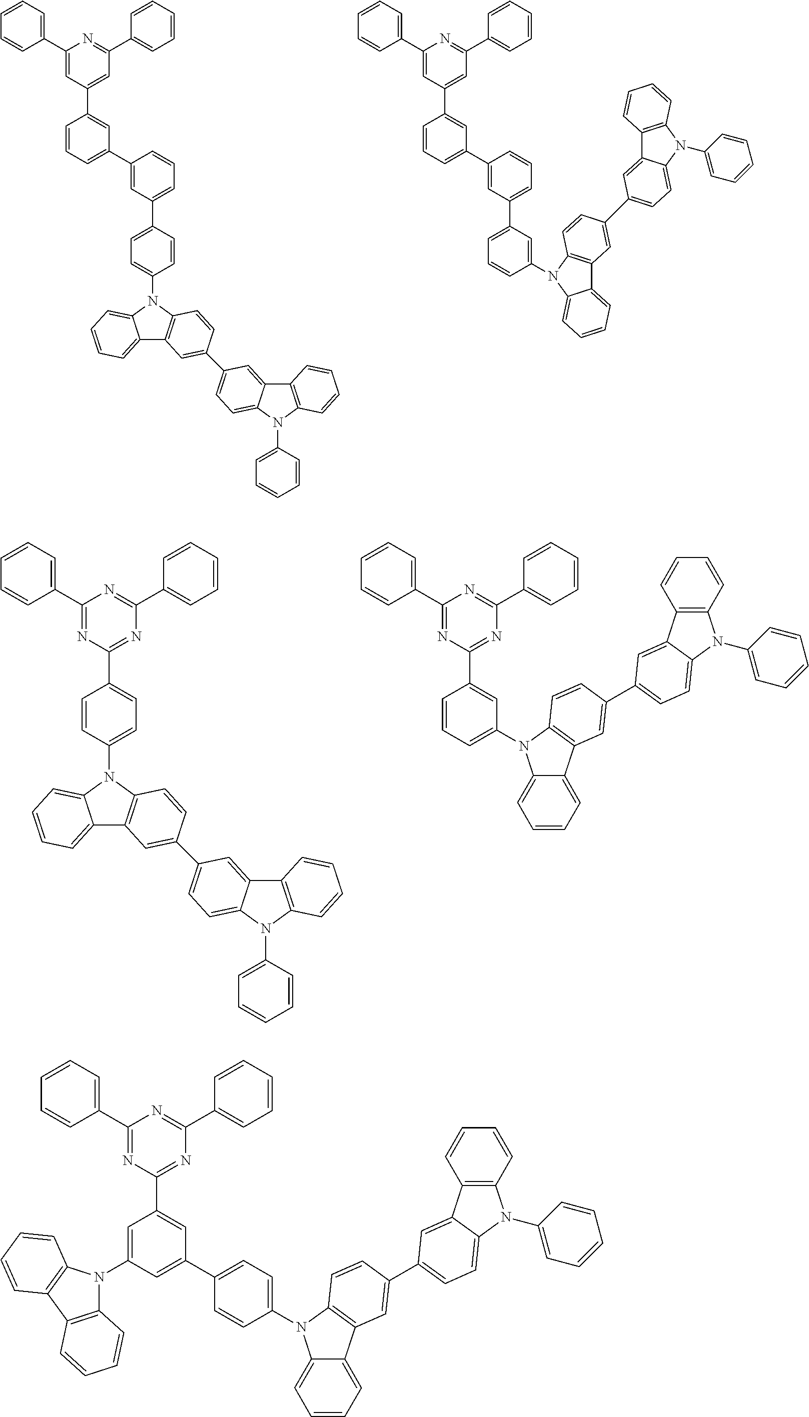

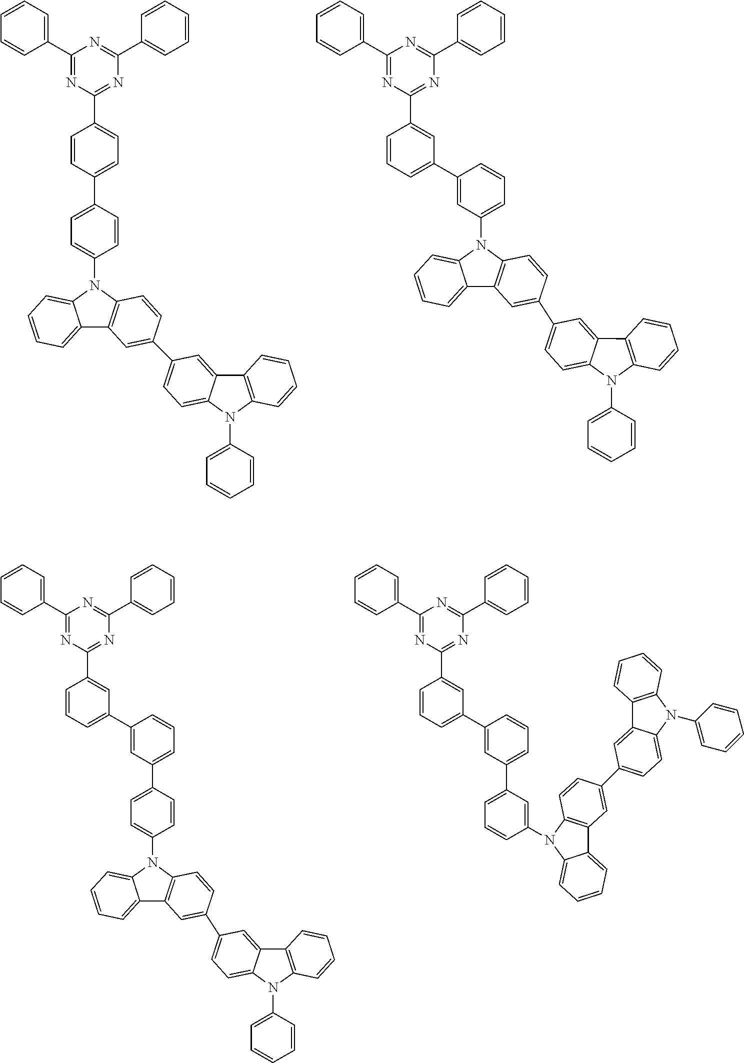 [SMILES: c1ccc(-c2nc(-c3ccccc3)nc(-c3ccc(-c4ccc(-n5c6ccccc6c6cc(-c7ccc8c(c7)c7ccccc7n8-c7ccccc7)ccc65)cc4)cc3)n2)cc1 ; c1ccc(-c2nc(-c3ccccc3)nc(-c3cccc(-c4cccc(-n5c6ccccc6c6cc(-c7ccc8c(c7)c7ccccc7n8-c7ccccc7)ccc65)c4)c3)n2)cc1 ; c1ccc(-c2nc(-c3ccccc3)nc(-c3cccc(-c4cccc(-c5ccc(-n6c7ccccc7c7cc(-c8ccc9c(c8)c8ccccc8n9-c8ccccc8)ccc76)cc5)c4)c3)n2)cc1 ; c1ccc(-c2nc(-c3ccccc3)nc(-c3cccc(-c4cccc(-c5cccc(-n6c7ccccc7c7cc(-c8ccc9c(c8)c8ccccc8n9-c8ccccc8)ccc76)c5)c4)c3)n2)cc1]

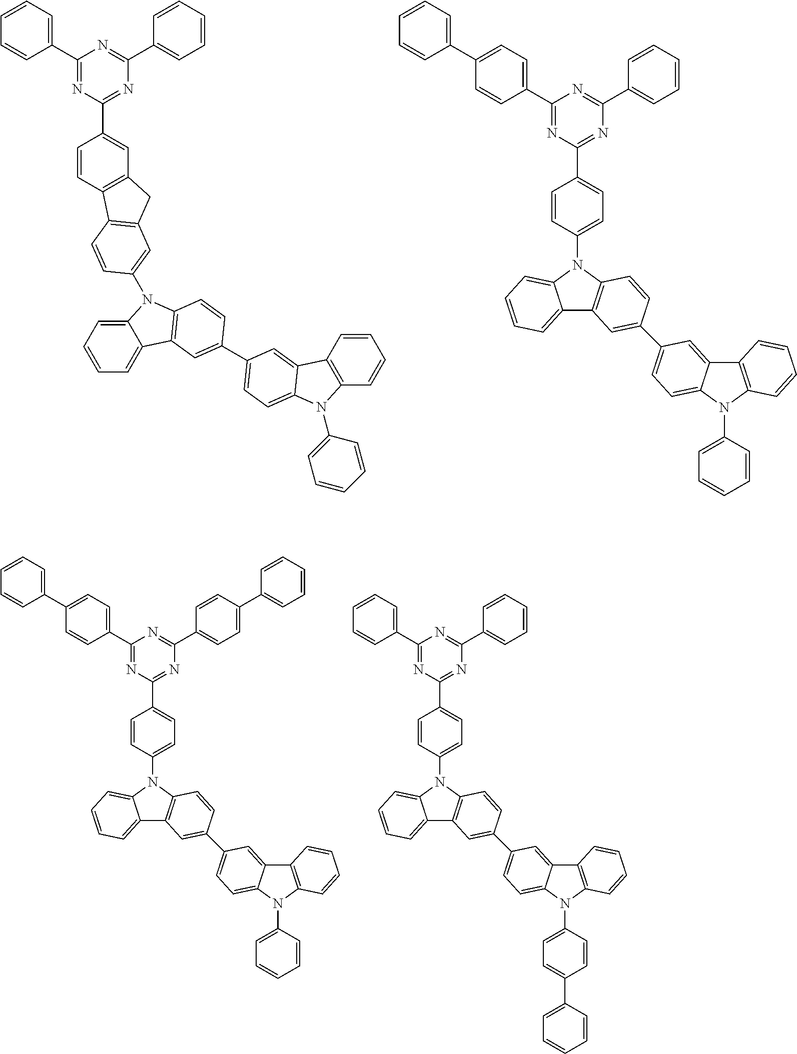 [SMILES: c1ccc(-c2nc(-c3ccccc3)nc(-c3ccc4c(c3)Cc3cc(-n5c6ccccc6c6cc(-c7ccc8c(c7)c7ccccc7n8-c7ccccc7)ccc65)ccc3-4)n2)cc1 ; c1ccc(-c2ccc(-c3nc(-c4ccccc4)nc(-c4ccc(-n5c6ccccc6c6cc(-c7ccc8c(c7)c7ccccc7n8-c7ccccc7)ccc65)cc4)n3)cc2)cc1 ; c1ccc(-c2ccc(-c3nc(-c4ccc(-c5ccccc5)cc4)nc(-c4ccc(-n5c6ccccc6c6cc(-c7ccc8c(c7)c7ccccc7n8-c7ccccc7)ccc65)cc4)n3)cc2)cc1 ; c1ccc(-c2ccc(-n3c4ccccc4c4cc(-c5ccc6c(c5)c5ccccc5n6-c5ccc(-c6nc(-c7ccccc7)nc(-c7ccccc7)n6)cc5)ccc43)cc2)cc1]

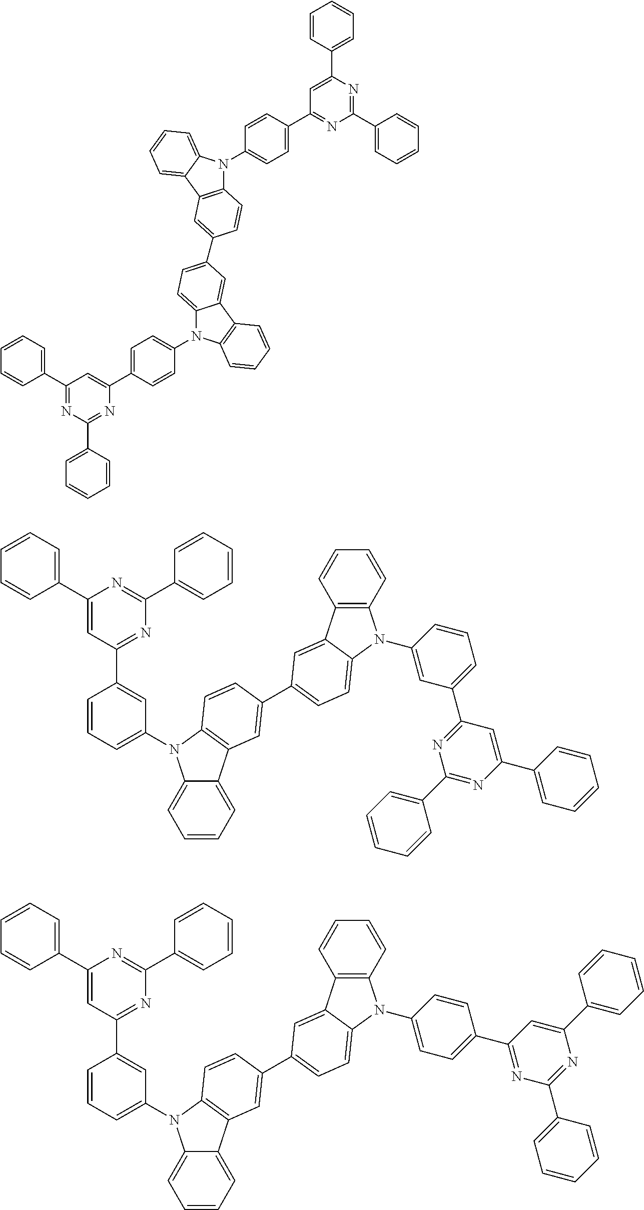 [SMILES: c1ccc(-c2cc(-c3ccc(-n4c5ccccc5c5cc(-c6ccc7c(c6)c6ccccc6n7-c6ccc(-c7cc(-c8ccccc8)nc(-c8ccccc8)n7)cc6)ccc54)cc3)nc(-c3ccccc3)n2)cc1 ; c1ccc(-c2cc(-c3cccc(-n4c5ccccc5c5cc(-c6ccc7c(c6)c6ccccc6n7-c6cccc(-c7cc(-c8ccccc8)nc(-c8ccccc8)n7)c6)ccc54)c3)nc(-c3ccccc3)n2)cc1 ; c1ccc(-c2cc(-c3ccc(-n4c5ccccc5c5cc(-c6ccc7c(c6)c6ccccc6n7-c6cccc(-c7cc(-c8ccccc8)nc(-c8ccccc8)n7)c6)ccc54)cc3)nc(-c3ccccc3)n2)cc1]

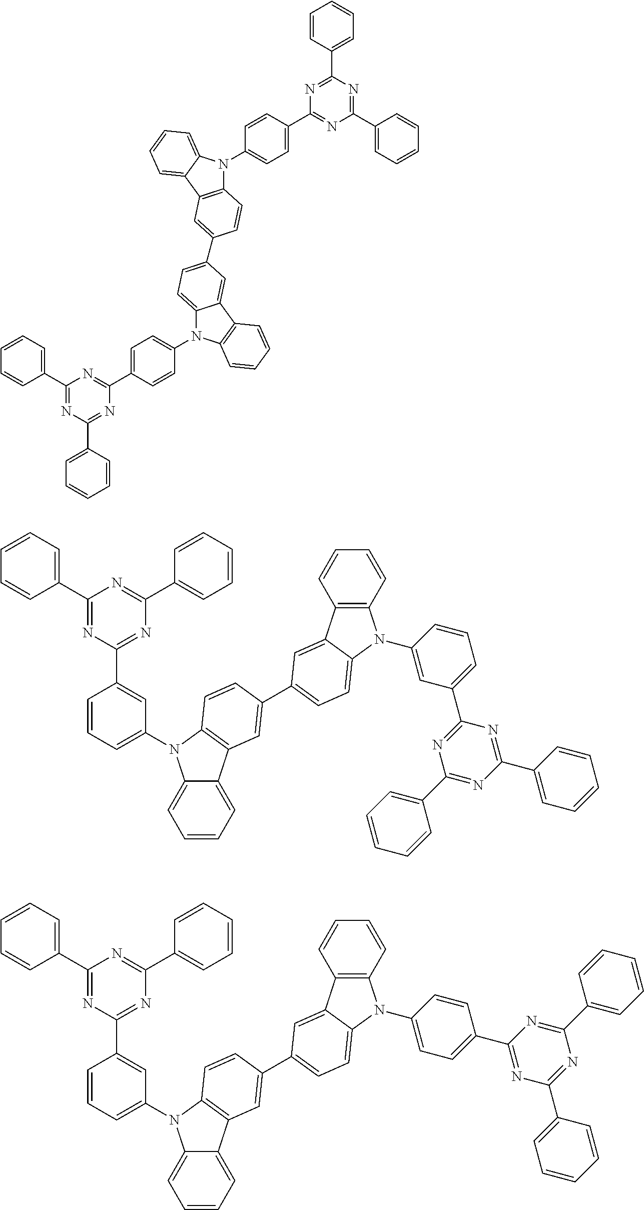 [SMILES: c1ccc(-c2nc(-c3ccccc3)nc(-c3ccc(-n4c5ccccc5c5cc(-c6ccc7c(c6)c6ccccc6n7-c6ccc(-c7nc(-c8ccccc8)nc(-c8ccccc8)n7)cc6)ccc54)cc3)n2)cc1 ; c1ccc(-c2nc(-c3ccccc3)nc(-c3cccc(-n4c5ccccc5c5cc(-c6ccc7c(c6)c6ccccc6n7-c6cccc(-c7nc(-c8ccccc8)nc(-c8ccccc8)n7)c6)ccc54)c3)n2)cc1 ; c1ccc(-c2nc(-c3ccccc3)nc(-c3ccc(-n4c5ccccc5c5cc(-c6ccc7c(c6)c6ccccc6n7-c6cccc(-c7nc(-c8ccccc8)nc(-c8ccccc8)n7)c6)ccc54)cc3)n2)cc1]

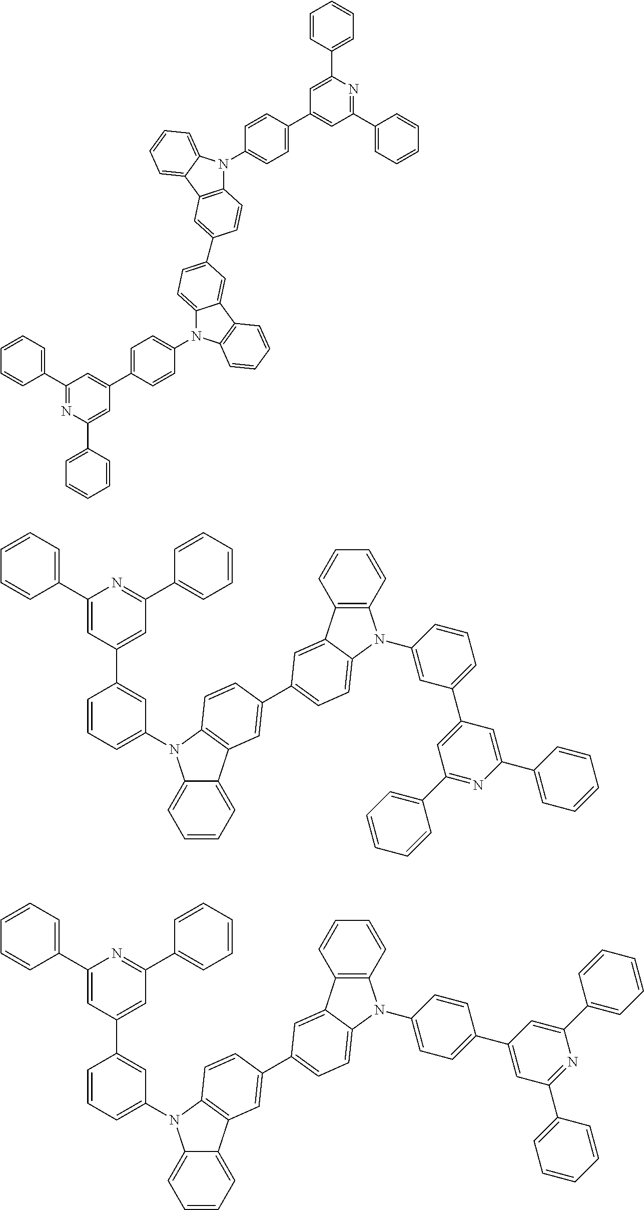 [SMILES: c1ccc(-c2cc(-c3ccc(-n4c5ccccc5c5cc(-c6ccc7c(c6)c6ccccc6n7-c6ccc(-c7cc(-c8ccccc8)nc(-c8ccccc8)c7)cc6)ccc54)cc3)cc(-c3ccccc3)n2)cc1 ; c1ccc(-c2cc(-c3cccc(-n4c5ccccc5c5cc(-c6ccc7c(c6)c6ccccc6n7-c6cccc(-c7cc(-c8ccccc8)nc(-c8ccccc8)c7)c6)ccc54)c3)cc(-c3ccccc3)n2)cc1 ; c1ccc(-c2cc(-c3ccc(-n4c5ccccc5c5cc(-c6ccc7c(c6)c6ccccc6n7-c6cccc(-c7cc(-c8ccccc8)nc(-c8ccccc8)c7)c6)ccc54)cc3)cc(-c3ccccc3)n2)cc1]

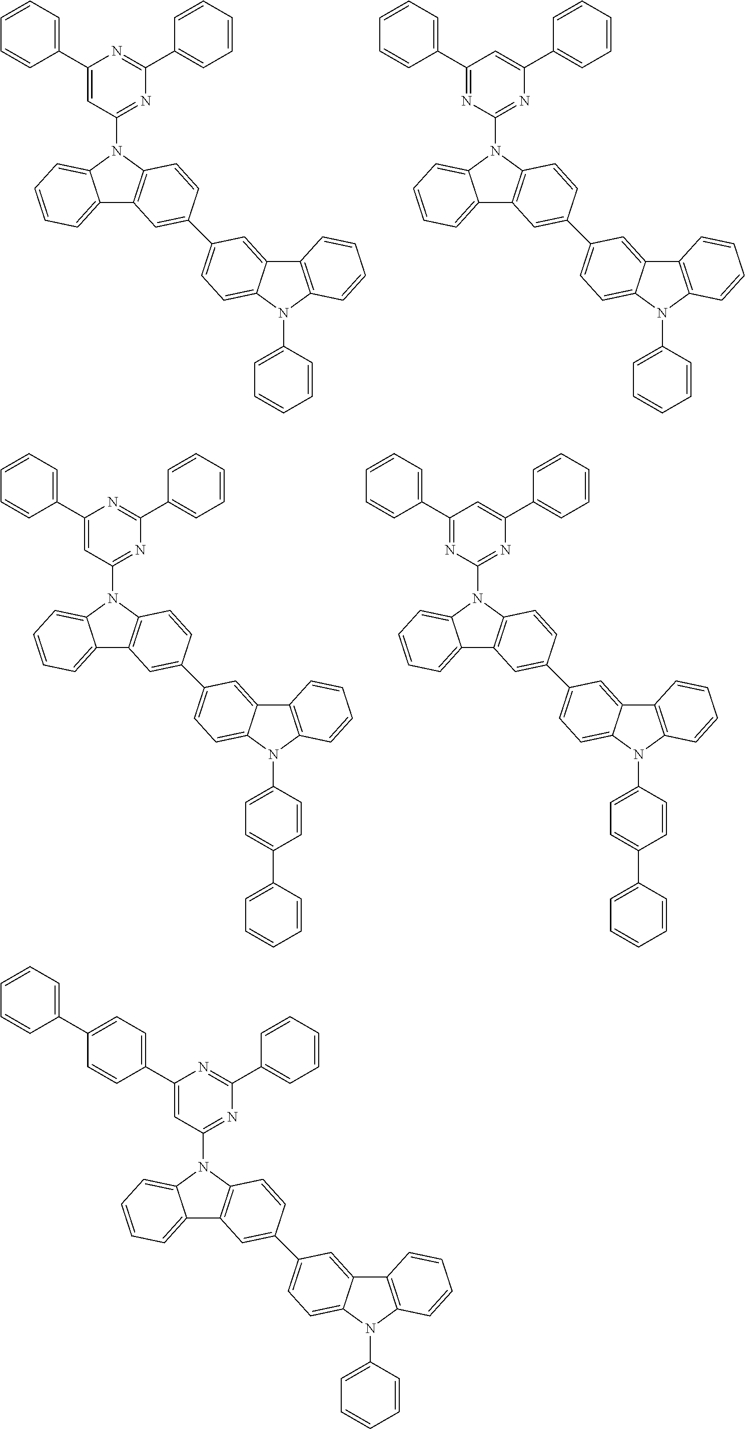 [SMILES: c1ccc(-c2cc(-n3c4ccccc4c4cc(-c5ccc6c(c5)c5ccccc5n6-c5ccccc5)ccc43)nc(-c3ccccc3)n2)cc1 ; c1ccc(-c2cc(-c3ccccc3)nc(-n3c4ccccc4c4cc(-c5ccc6c(c5)c5ccccc5n6-c5ccccc5)ccc43)n2)cc1 ; c1ccc(-c2ccc(-n3c4ccccc4c4cc(-c5ccc6c(c5)c5ccccc5n6-c5cc(-c6ccccc6)nc(-c6ccccc6)n5)ccc43)cc2)cc1 ; c1ccc(-c2ccc(-n3c4ccccc4c4cc(-c5ccc6c(c5)c5ccccc5n6-c5nc(-c6ccccc6)cc(-c6ccccc6)n5)ccc43)cc2)cc1 ; c1ccc(-c2ccc(-c3cc(-n4c5ccccc5c5cc(-c6ccc7c(c6)c6ccccc6n7-c6ccccc6)ccc54)nc(-c4ccccc4)n3)cc2)cc1]

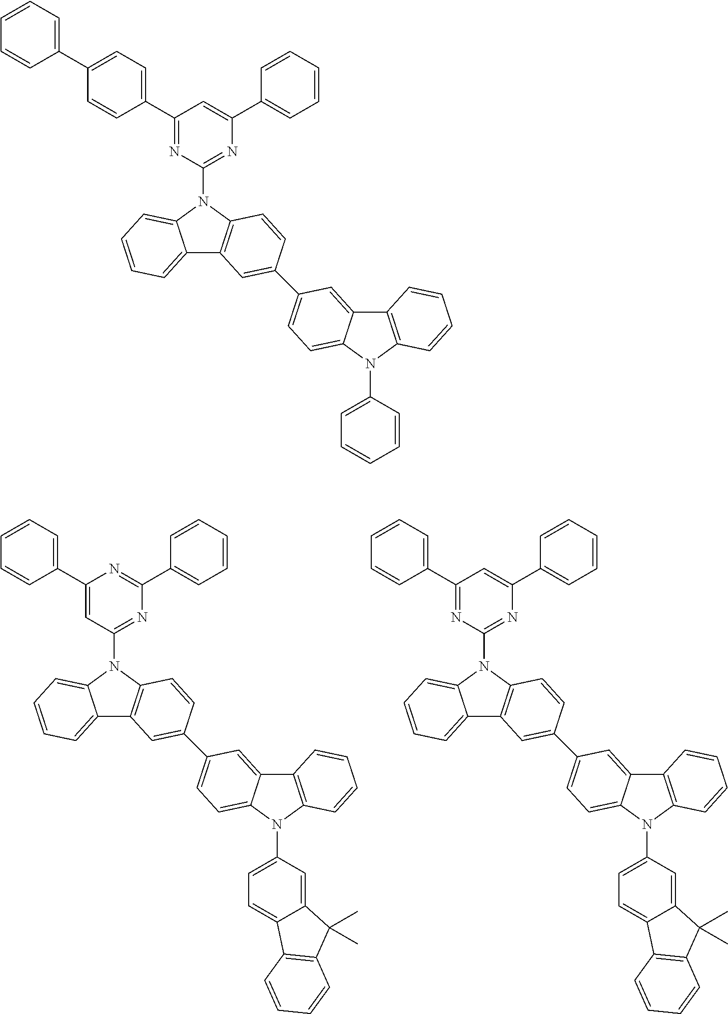 [SMILES: c1ccc(-c2ccc(-c3cc(-c4ccccc4)nc(-n4c5ccccc5c5cc(-c6ccc7c(c6)c6ccccc6n7-c6ccccc6)ccc54)n3)cc2)cc1 ; CC1(C)c2ccccc2-c2ccc(-n3c4ccccc4c4cc(-c5ccc6c(c5)c5ccccc5n6-c5cc(-c6ccccc6)nc(-c6ccccc6)n5)ccc43)cc21 ; CC1(C)c2ccccc2-c2ccc(-n3c4ccccc4c4cc(-c5ccc6c(c5)c5ccccc5n6-c5nc(-c6ccccc6)cc(-c6ccccc6)n5)ccc43)cc21]

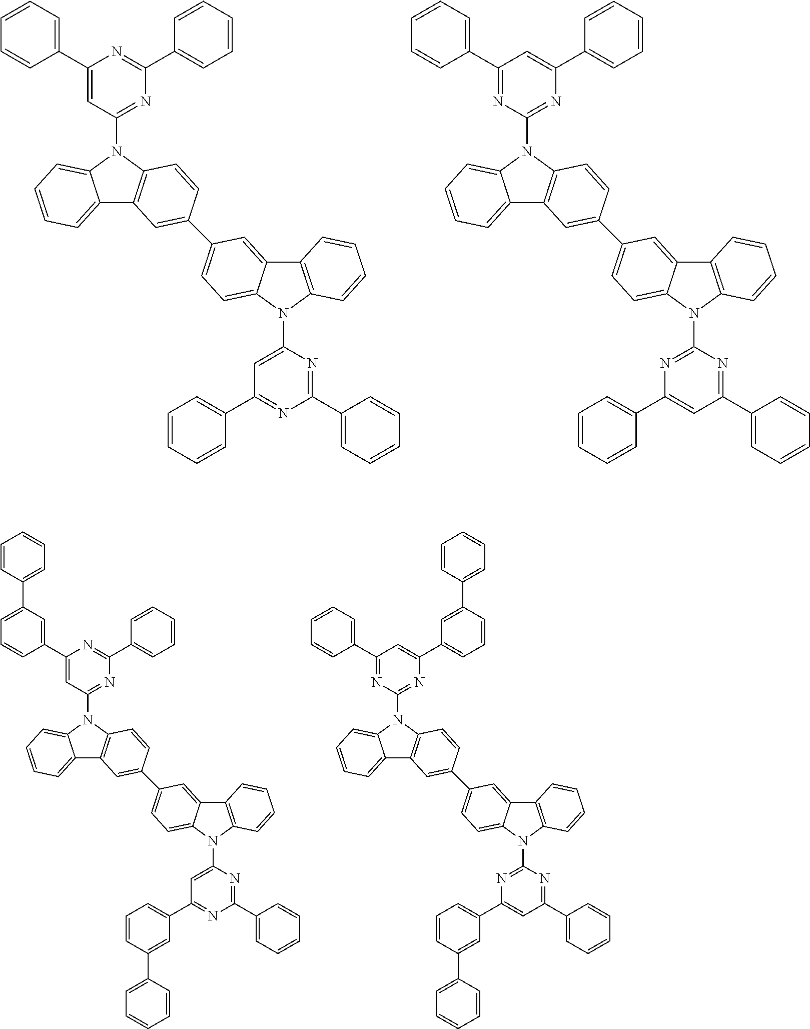 [SMILES: c1ccc(-c2cc(-n3c4ccccc4c4cc(-c5ccc6c(c5)c5ccccc5n6-c5cc(-c6ccccc6)nc(-c6ccccc6)n5)ccc43)nc(-c3ccccc3)n2)cc1 ; c1ccc(-c2cc(-c3ccccc3)nc(-n3c4ccccc4c4cc(-c5ccc6c(c5)c5ccccc5n6-c5nc(-c6ccccc6)cc(-c6ccccc6)n5)ccc43)n2)cc1 ; c1ccc(-c2cccc(-c3cc(-n4c5ccccc5c5cc(-c6ccc7c(c6)c6ccccc6n7-c6cc(-c7cccc(-c8ccccc8)c7)nc(-c7ccccc7)n6)ccc54)nc(-c4ccccc4)n3)c2)cc1 ; c1ccc(-c2cccc(-c3cc(-c4ccccc4)nc(-n4c5ccccc5c5cc(-c6ccc7c(c6)c6ccccc6n7-c6nc(-c7ccccc7)cc(-c7cccc(-c8ccccc8)c7)n6)ccc54)n3)c2)cc1]

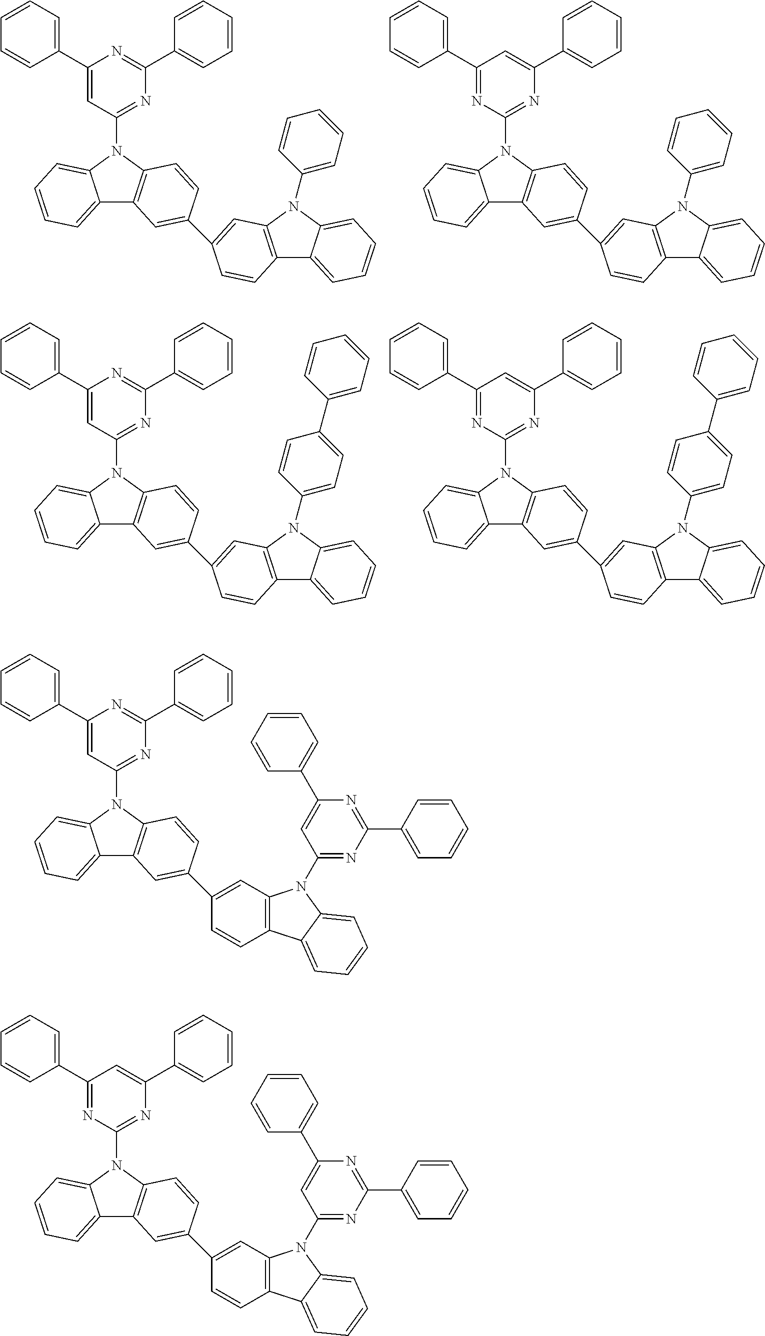

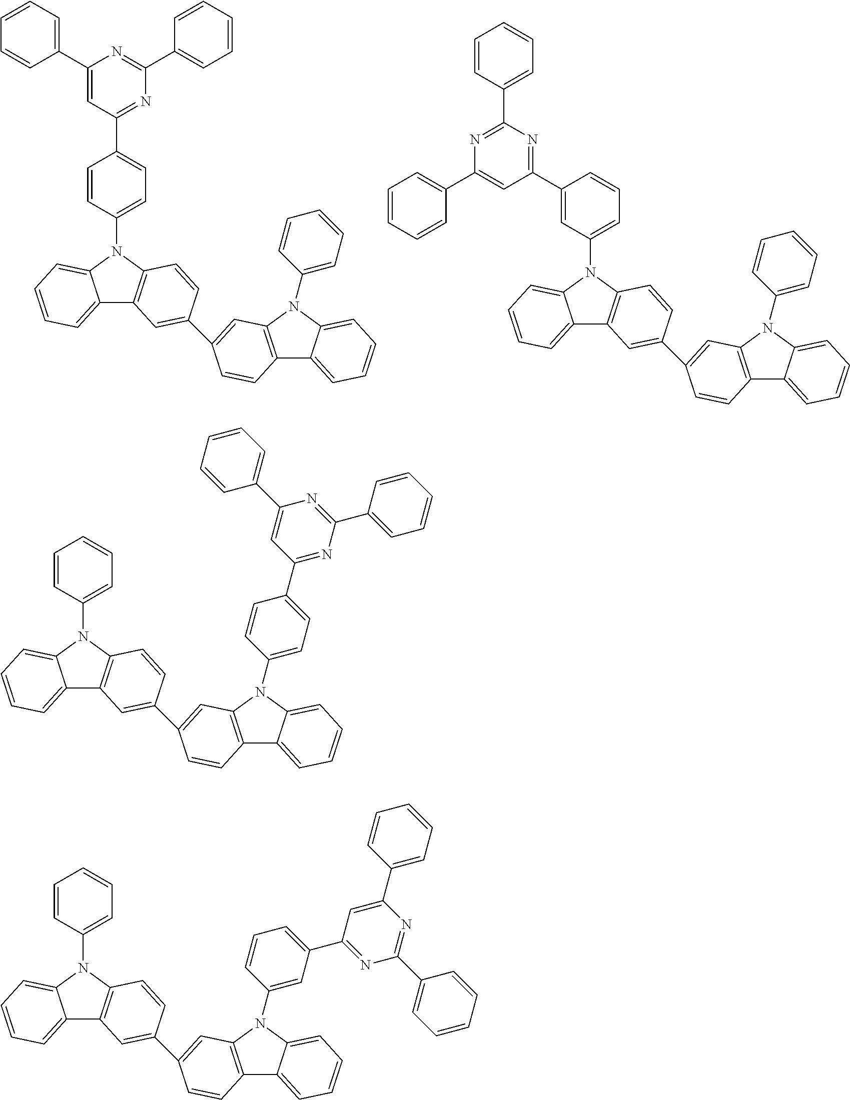

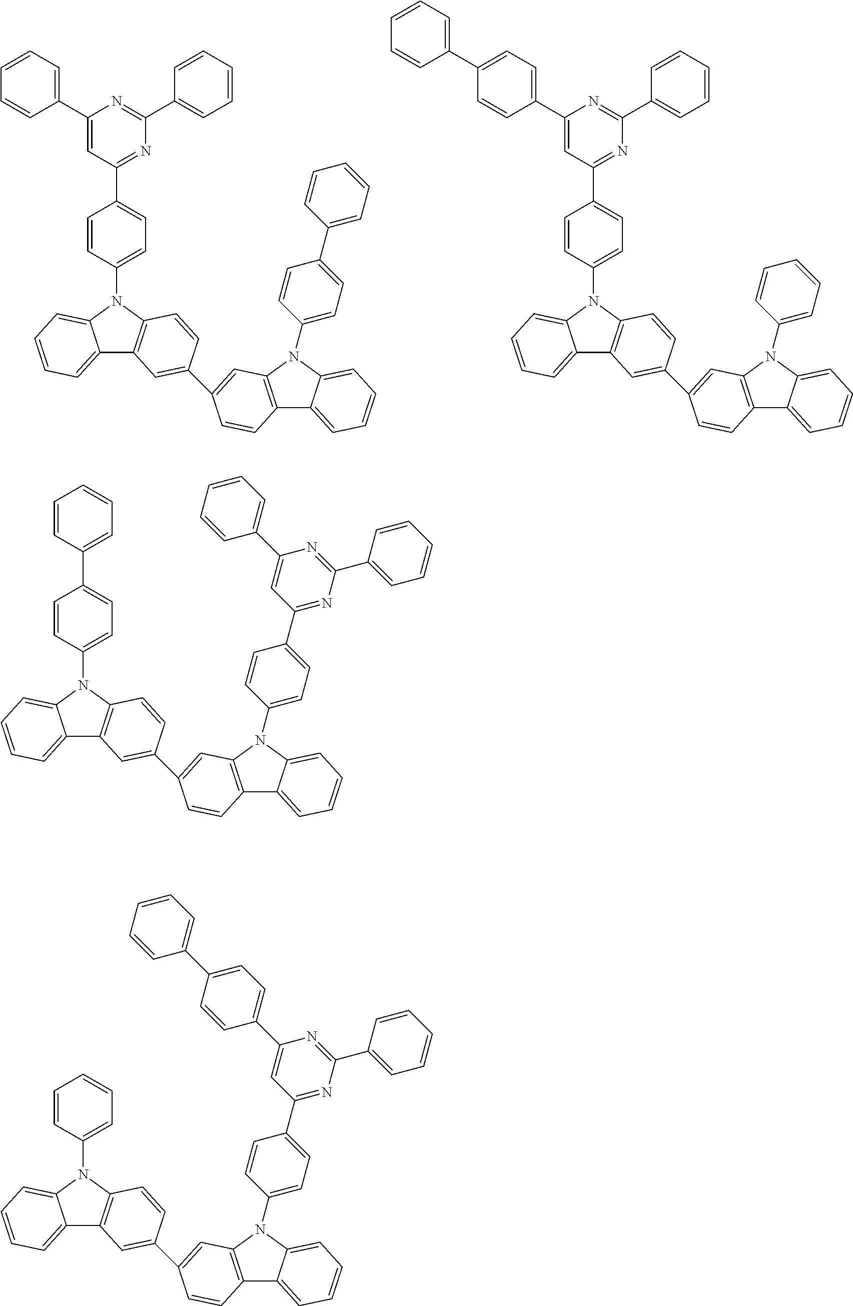

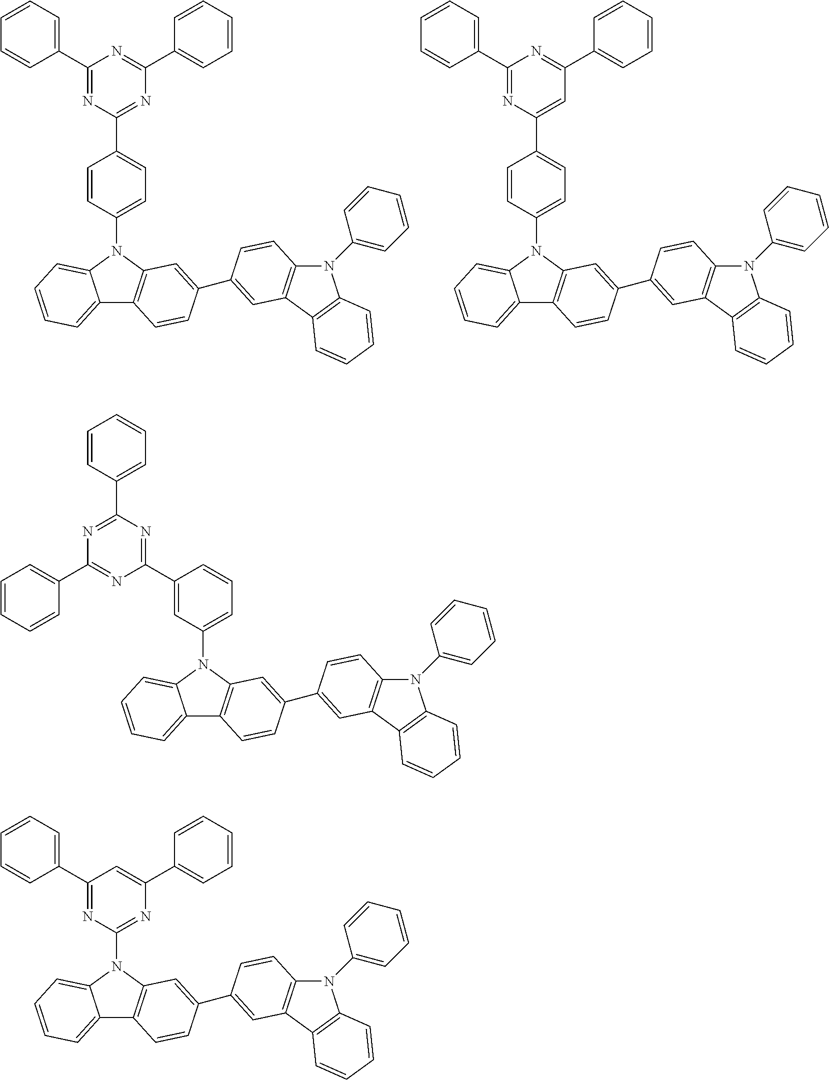 [SMILES: c1ccc(-c2nc(-c3ccccc3)nc(-c3ccc(-n4c5ccccc5c5ccc(-c6ccc7c(c6)c6ccccc6n7-c6ccccc6)cc54)cc3)n2)cc1 ; c1ccc(-c2cc(-c3ccc(-n4c5ccccc5c5ccc(-c6ccc7c(c6)c6ccccc6n7-c6ccccc6)cc54)cc3)nc(-c3ccccc3)n2)cc1 ; c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1 ; c1ccc(-c2cc(-c3ccccc3)nc(-n3c4ccccc4c4ccc(-c5ccc6c(c5)c5ccccc5n6-c5ccccc5)cc43)n2)cc1]

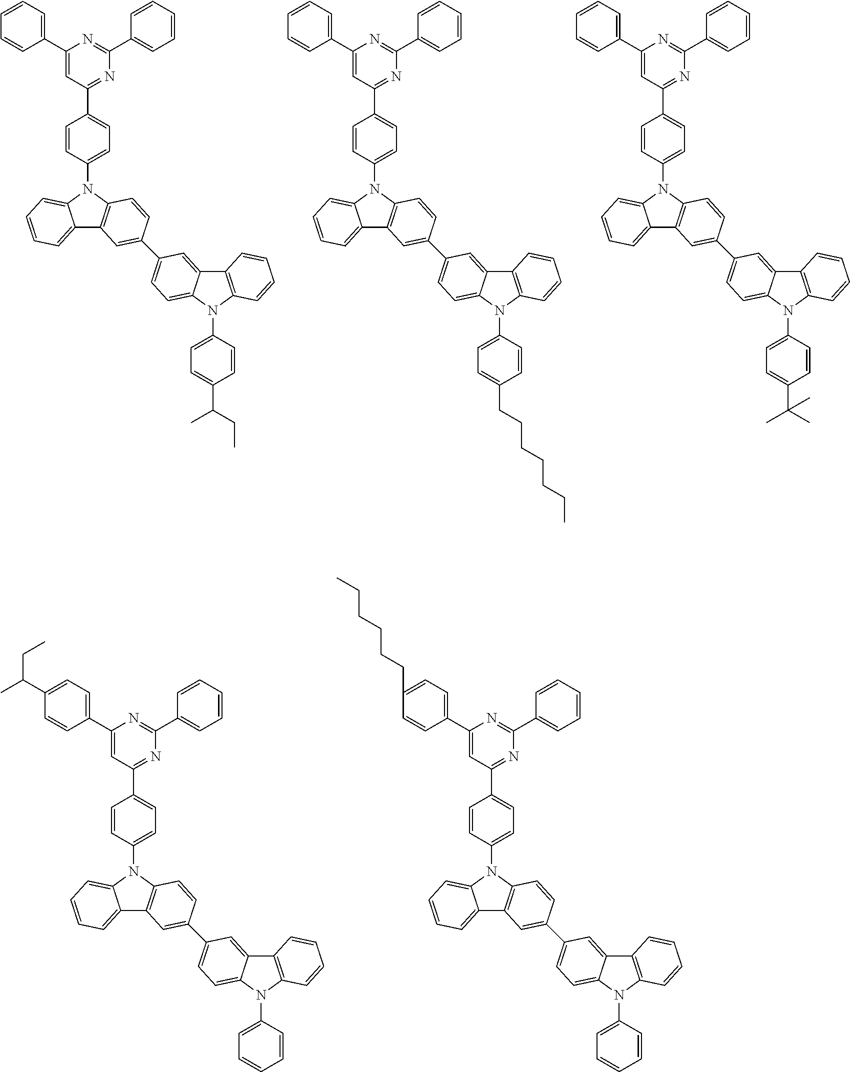

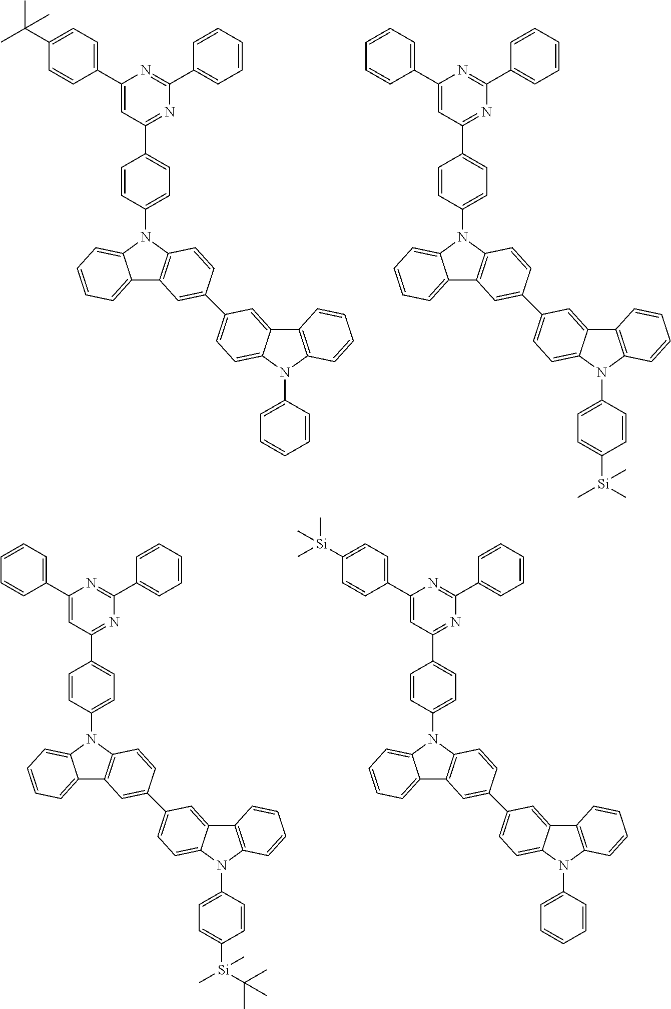 [SMILES: CC(C)(C)c1ccc(-c2cc(-c3ccc(-n4c5ccccc5c5cc(-c6ccc7c(c6)c6ccccc6n7-c6ccccc6)ccc54)cc3)nc(-c3ccccc3)n2)cc1 ; C[Si](C)(C)c1ccc(-n2c3ccccc3c3cc(-c4ccc5c(c4)c4ccccc4n5-c4ccc(-c5cc(-c6ccccc6)nc(-c6ccccc6)n5)cc4)ccc32)cc1 ; CC(C)(C)[Si](C)(C)c1ccc(-n2c3ccccc3c3cc(-c4ccc5c(c4)c4ccccc4n5-c4ccc(-c5cc(-c6ccccc6)nc(-c6ccccc6)n5)cc4)ccc32)cc1 ; C[Si](C)(C)c1ccc(-c2cc(-c3ccc(-n4c5ccccc5c5cc(-c6ccc7c(c6)c6ccccc6n7-c6ccccc6)ccc54)cc3)nc(-c3ccccc3)n2)cc1]

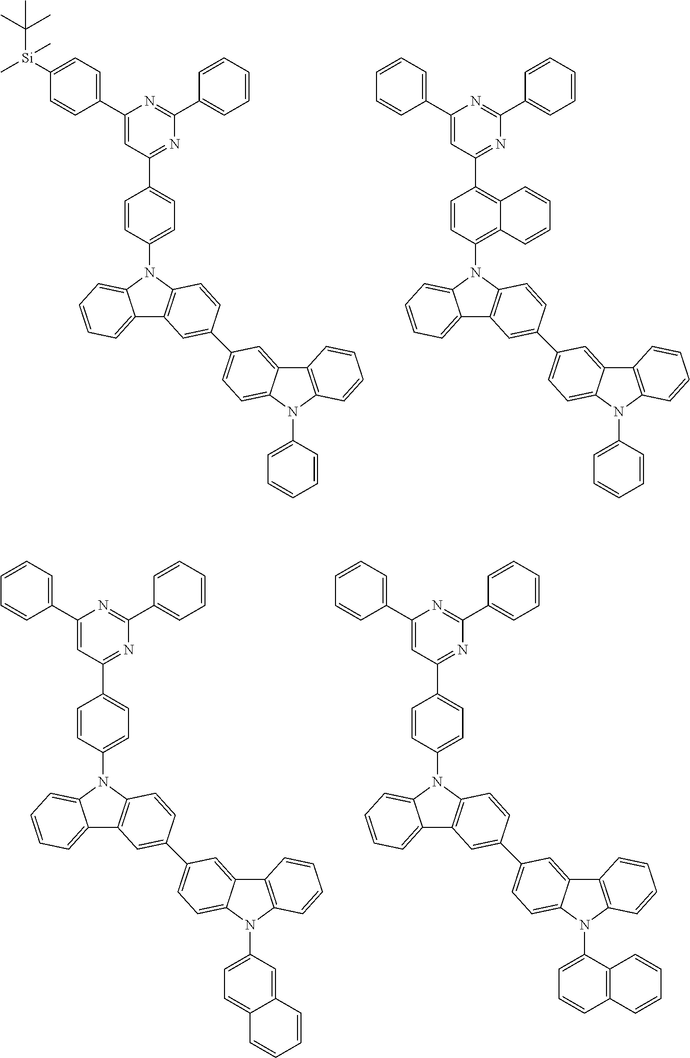 [SMILES: CC(C)(C)[Si](C)(C)c1ccc(-c2cc(-c3ccc(-n4c5ccccc5c5cc(-c6ccc7c(c6)c6ccccc6n7-c6ccccc6)ccc54)cc3)nc(-c3ccccc3)n2)cc1 ; c1ccc(-c2cc(-c3ccc(-n4c5ccccc5c5cc(-c6ccc7c(c6)c6ccccc6n7-c6ccccc6)ccc54)c4ccccc34)nc(-c3ccccc3)n2)cc1 ; c1ccc(-c2cc(-c3ccc(-n4c5ccccc5c5cc(-c6ccc7c(c6)c6ccccc6n7-c6ccc7ccccc7c6)ccc54)cc3)nc(-c3ccccc3)n2)cc1 ; c1ccc(-c2cc(-c3ccc(-n4c5ccccc5c5cc(-c6ccc7c(c6)c6ccccc6n7-c6cccc7ccccc67)ccc54)cc3)nc(-c3ccccc3)n2)cc1]

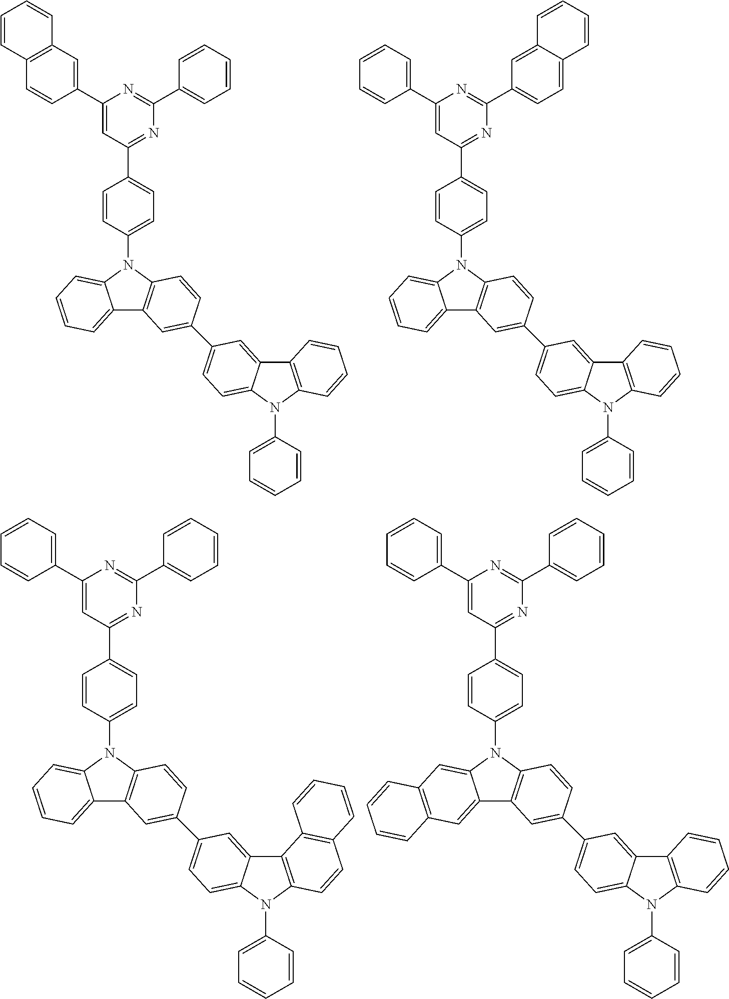

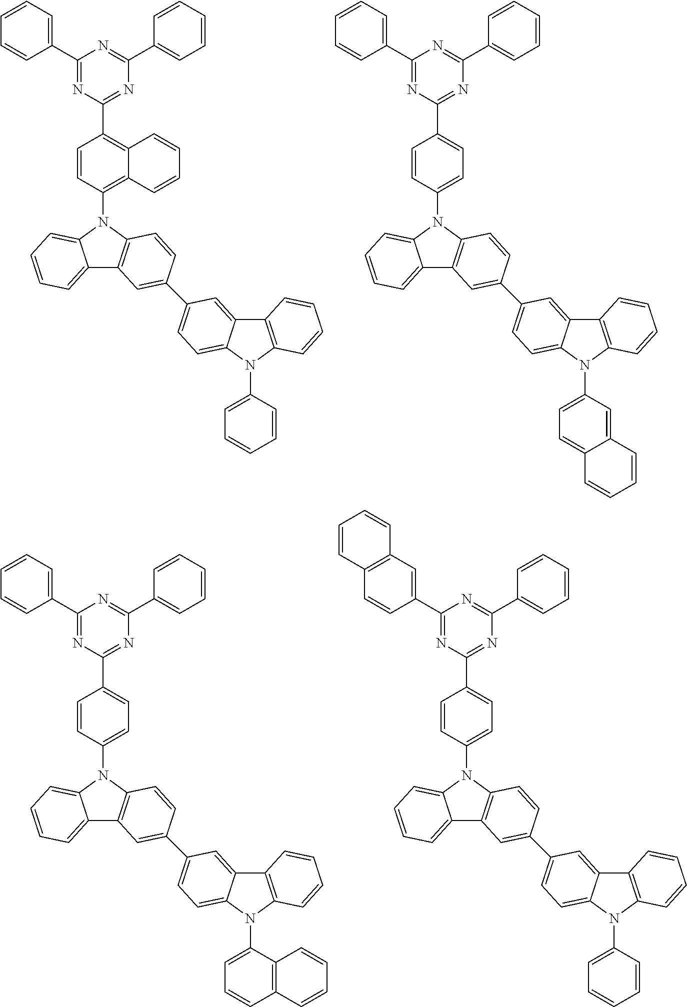 [SMILES: c1ccc(-c2nc(-c3ccccc3)nc(-c3ccc(-n4c5ccccc5c5cc(-c6ccc7c(c6)c6ccccc6n7-c6ccccc6)ccc54)c4ccccc34)n2)cc1 ; c1ccc(-c2nc(-c3ccccc3)nc(-c3ccc(-n4c5ccccc5c5cc(-c6ccc7c(c6)c6ccccc6n7-c6ccc7ccccc7c6)ccc54)cc3)n2)cc1 ; c1ccc(-c2nc(-c3ccccc3)nc(-c3ccc(-n4c5ccccc5c5cc(-c6ccc7c(c6)c6ccccc6n7-c6cccc7ccccc67)ccc54)cc3)n2)cc1 ; c1ccc(-c2nc(-c3ccc(-n4c5ccccc5c5cc(-c6ccc7c(c6)c6ccccc6n7-c6ccccc6)ccc54)cc3)nc(-c3ccc4ccccc4c3)n2)cc1]

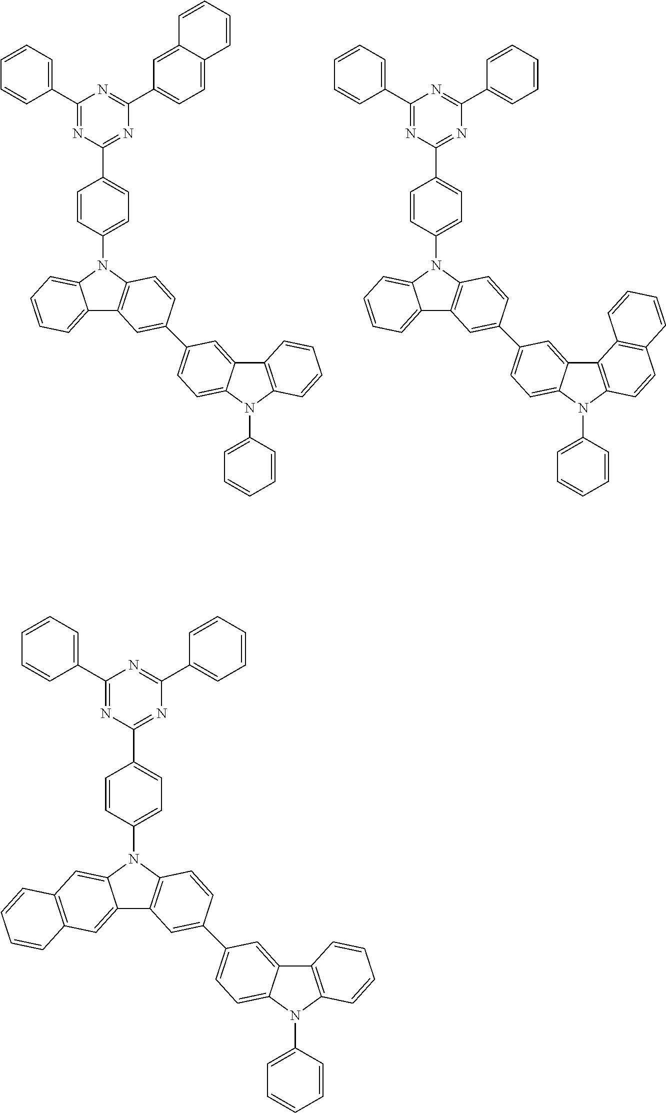 [SMILES: c1ccc(-c2nc(-c3ccc(-n4c5ccccc5c5cc(-c6ccc7c(c6)c6ccccc6n7-c6ccccc6)ccc54)cc3)nc(-c3ccc4ccccc4c3)n2)cc1 ; c1ccc(-c2nc(-c3ccccc3)nc(-c3ccc(-n4c5ccccc5c5cc(-c6ccc7c(c6)c6c8ccccc8ccc6n7-c6ccccc6)ccc54)cc3)n2)cc1 ; c1ccc(-c2nc(-c3ccccc3)nc(-c3ccc(-n4c5ccc(-c6ccc7c(c6)c6ccccc6n7-c6ccccc6)cc5c5cc6ccccc6cc54)cc3)n2)cc1]

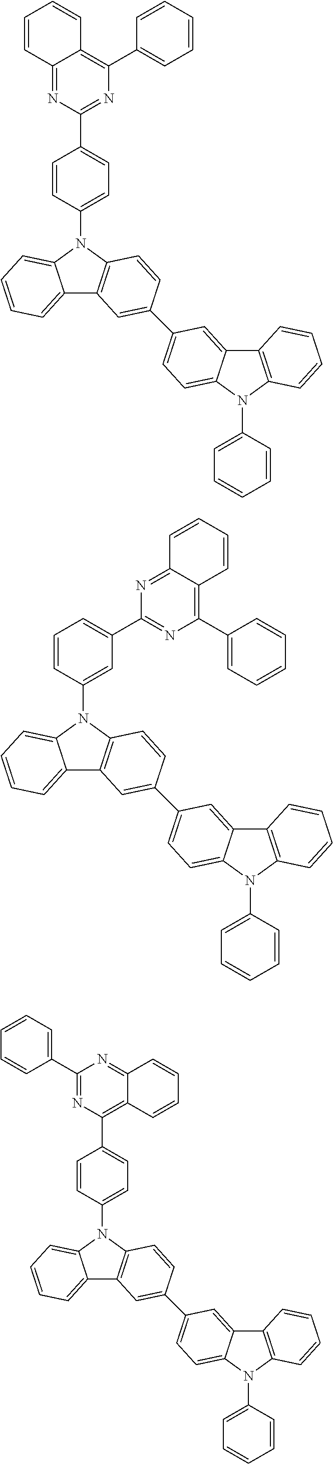

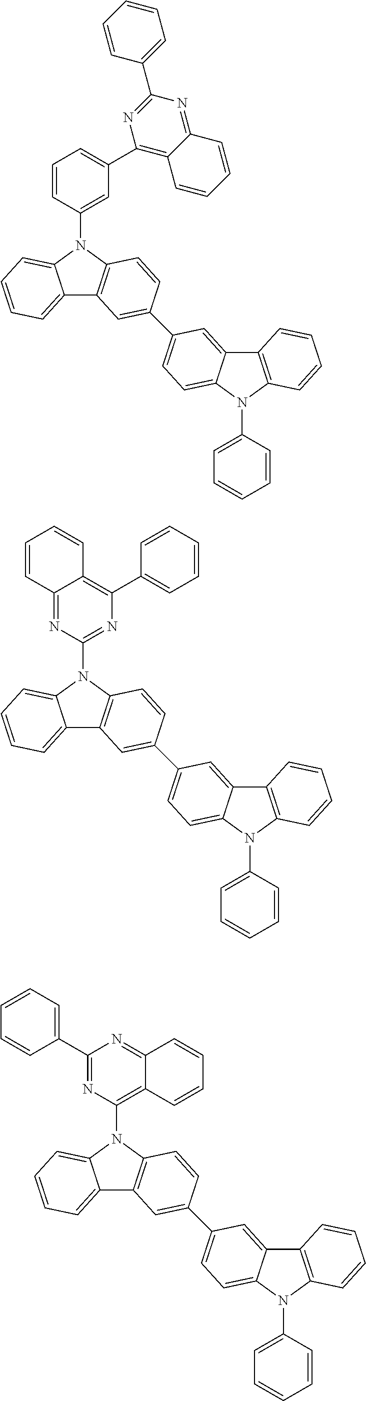 [SMILES: c1ccc(-c2nc(-c3cccc(-n4c5ccccc5c5cc(-c6ccc7c(c6)c6ccccc6n7-c6ccccc6)ccc54)c3)c3ccccc3n2)cc1 ; c1ccc(-c2nc(-n3c4ccccc4c4cc(-c5ccc6c(c5)c5ccccc5n6-c5ccccc5)ccc43)nc3ccccc23)cc1 ; c1ccc(-c2nc(-n3c4ccccc4c4cc(-c5ccc6c(c5)c5ccccc5n6-c5ccccc5)ccc43)c3ccccc3n2)cc1]

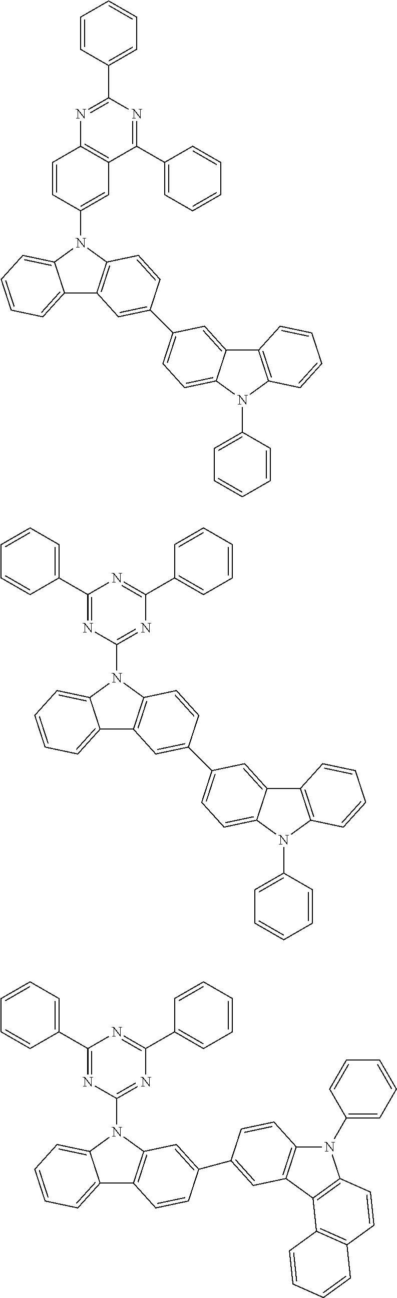 [SMILES: c1ccc(-c2nc(-c3ccccc3)c3cc(-n4c5ccccc5c5cc(-c6ccc7c(c6)c6ccccc6n7-c6ccccc6)ccc54)ccc3n2)cc1 ; c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-n3c4ccccc4c4ccc(-c5ccc6c(c5)c5c7ccccc7ccc5n6-c5ccccc5)cc43)n2)cc1]

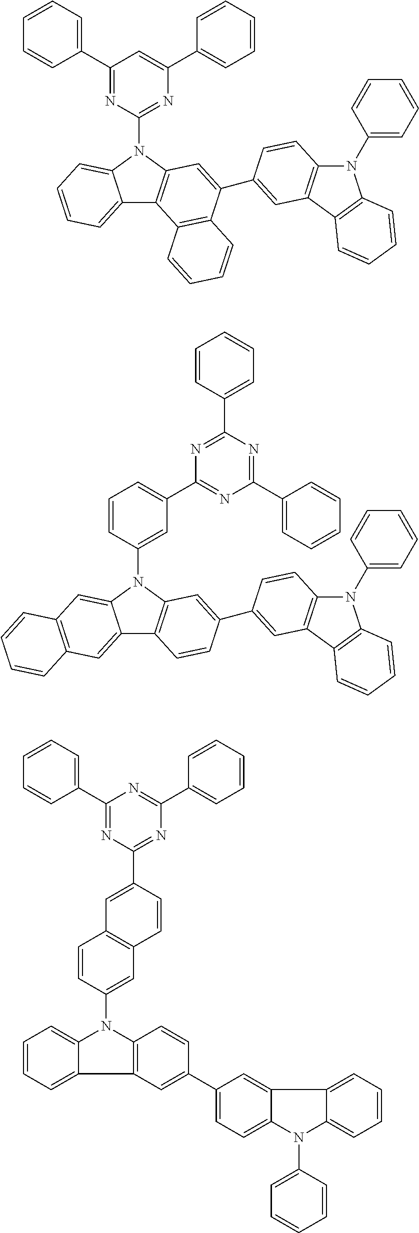 [SMILES: c1ccc(-c2cc(-c3ccccc3)nc(-n3c4ccccc4c4c5ccccc5c(-c5ccc6c(c5)c5ccccc5n6-c5ccccc5)cc43)n2)cc1 ; c1ccc(-c2nc(-c3ccccc3)nc(-c3cccc(-n4c5cc(-c6ccc7c(c6)c6ccccc6n7-c6ccccc6)ccc5c5cc6ccccc6cc54)c3)n2)cc1 ; c1ccc(-c2nc(-c3ccccc3)nc(-c3ccc4cc(-n5c6ccccc6c6cc(-c7ccc8c(c7)c7ccccc7n8-c7ccccc7)ccc65)ccc4c3)n2)cc1]

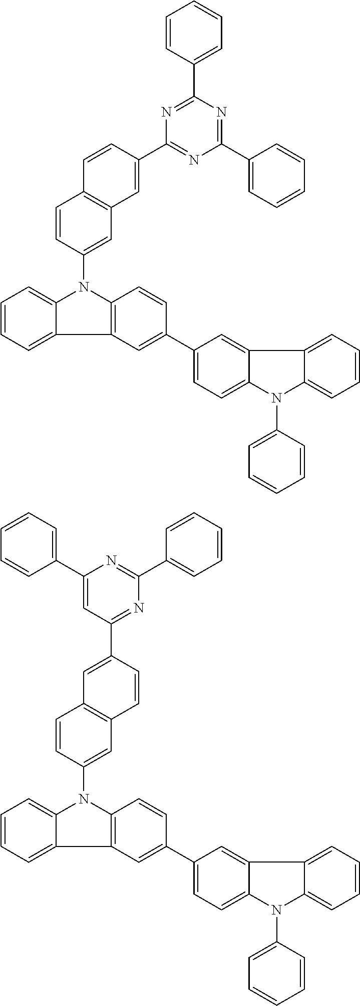 [SMILES: c1ccc(-c2nc(-c3ccccc3)nc(-c3ccc4ccc(-n5c6ccccc6c6cc(-c7ccc8c(c7)c7ccccc7n8-c7ccccc7)ccc65)cc4c3)n2)cc1 ; c1ccc(-c2cc(-c3ccc4cc(-n5c6ccccc6c6cc(-c7ccc8c(c7)c7ccccc7n8-c7ccccc7)ccc65)ccc4c3)nc(-c3ccccc3)n2)cc1]

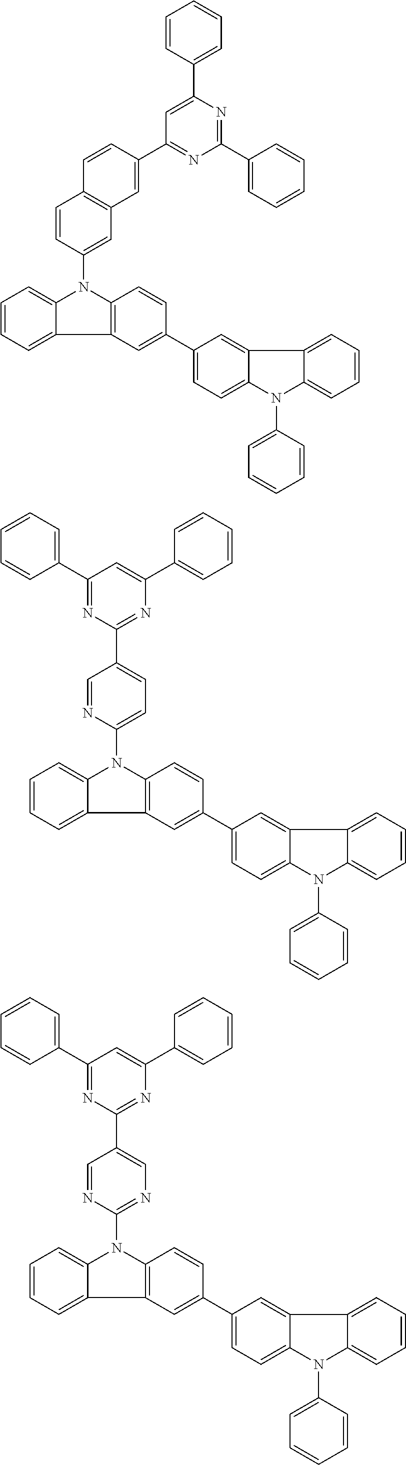 [SMILES: c1ccc(-c2cc(-c3ccc4ccc(-n5c6ccccc6c6cc(-c7ccc8c(c7)c7ccccc7n8-c7ccccc7)ccc65)cc4c3)nc(-c3ccccc3)n2)cc1 ; c1ccc(-c2cc(-c3ccccc3)nc(-c3ccc(-n4c5ccccc5c5cc(-c6ccc7c(c6)c6ccccc6n7-c6ccccc6)ccc54)nc3)n2)cc1 ; c1ccc(-c2cc(-c3ccccc3)nc(-c3cnc(-n4c5ccccc5c5cc(-c6ccc7c(c6)c6ccccc6n7-c6ccccc6)ccc54)nc3)n2)cc1]

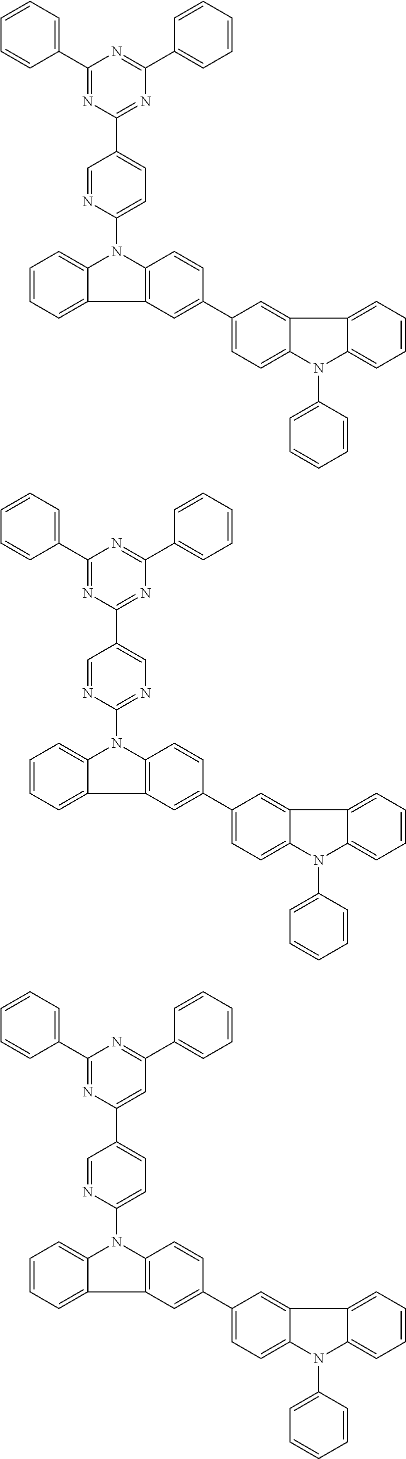 [SMILES: c1ccc(-c2nc(-c3ccccc3)nc(-c3ccc(-n4c5ccccc5c5cc(-c6ccc7c(c6)c6ccccc6n7-c6ccccc6)ccc54)nc3)n2)cc1 ; c1ccc(-c2nc(-c3ccccc3)nc(-c3cnc(-n4c5ccccc5c5cc(-c6ccc7c(c6)c6ccccc6n7-c6ccccc6)ccc54)nc3)n2)cc1 ; c1ccc(-c2cc(-c3ccc(-n4c5ccccc5c5cc(-c6ccc7c(c6)c6ccccc6n7-c6ccccc6)ccc54)nc3)nc(-c3ccccc3)n2)cc1]

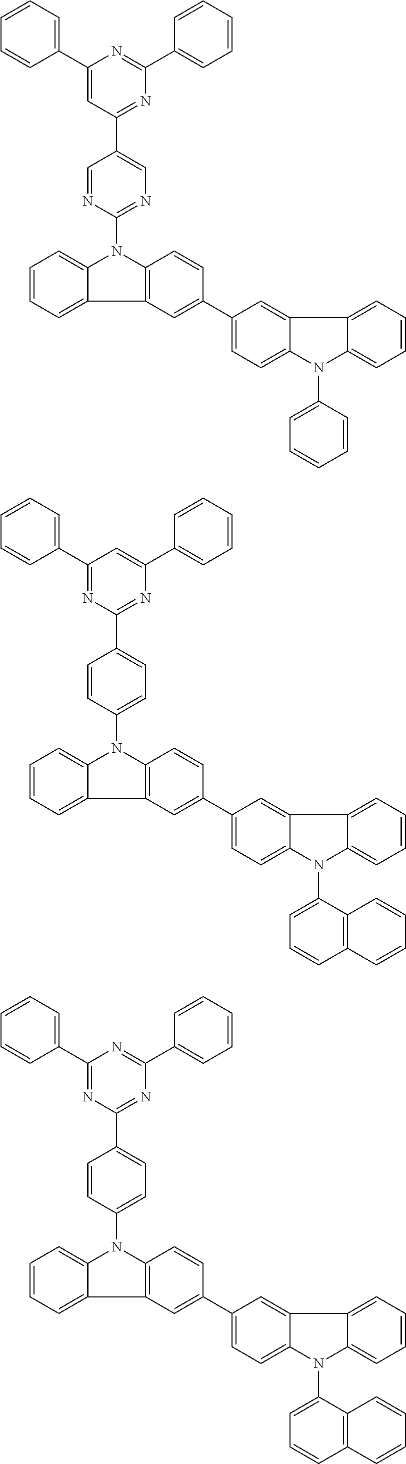 [SMILES: c1ccc(-c2cc(-c3cnc(-n4c5ccccc5c5cc(-c6ccc7c(c6)c6ccccc6n7-c6ccccc6)ccc54)nc3)nc(-c3ccccc3)n2)cc1 ; c1ccc(-c2cc(-c3ccccc3)nc(-c3ccc(-n4c5ccccc5c5cc(-c6ccc7c(c6)c6ccccc6n7-c6cccc7ccccc67)ccc54)cc3)n2)cc1 ; c1ccc(-c2nc(-c3ccccc3)nc(-c3ccc(-n4c5ccccc5c5cc(-c6ccc7c(c6)c6ccccc6n7-c6cccc7ccccc67)ccc54)cc3)n2)cc1]

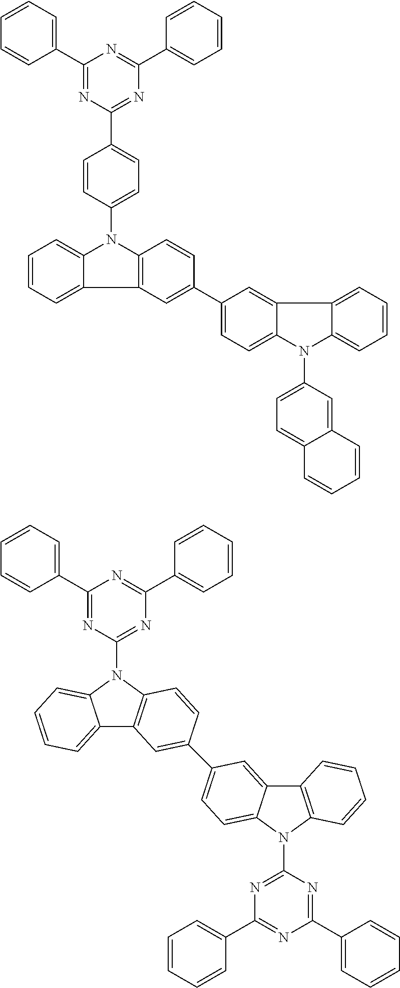 [SMILES: c1ccc(-c2nc(-c3ccccc3)nc(-c3ccc(-n4c5ccccc5c5cc(-c6ccc7c(c6)c6ccccc6n7-c6ccc7ccccc7c6)ccc54)cc3)n2)cc1 ; c1ccc(-c2nc(-c3ccccc3)nc(-n3c4ccccc4c4cc(-c5ccc6c(c5)c5ccccc5n6-c5nc(-c6ccccc6)nc(-c6ccccc6)n5)ccc43)n2)cc1]

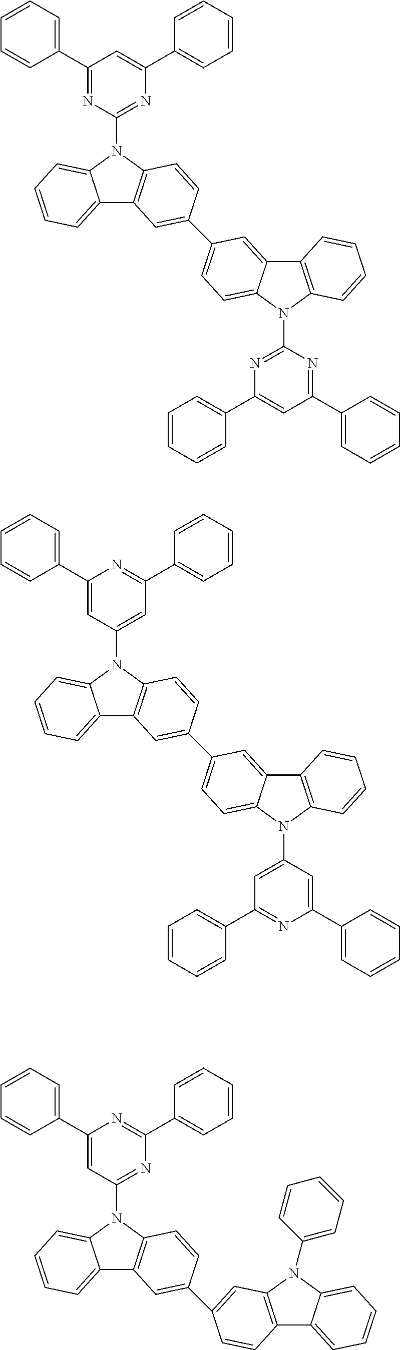 [SMILES: c1ccc(-c2cc(-c3ccccc3)nc(-n3c4ccccc4c4cc(-c5ccc6c(c5)c5ccccc5n6-c5nc(-c6ccccc6)cc(-c6ccccc6)n5)ccc43)n2)cc1 ; c1ccc(-c2cc(-n3c4ccccc4c4cc(-c5ccc6c(c5)c5ccccc5n6-c5cc(-c6ccccc6)nc(-c6ccccc6)c5)ccc43)cc(-c3ccccc3)n2)cc1 ; c1ccc(-c2cc(-n3c4ccccc4c4cc(-c5ccc6c7ccccc7n(-c7ccccc7)c6c5)ccc43)nc(-c3ccccc3)n2)cc1]

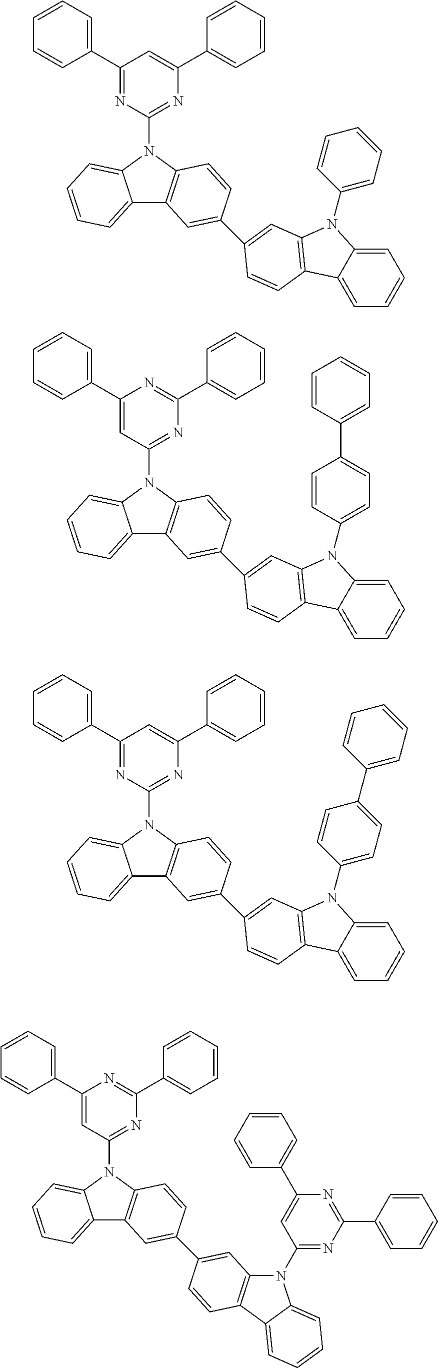 [SMILES: c1ccc(-c2cc(-c3ccccc3)nc(-n3c4ccccc4c4cc(-c5ccc6c7ccccc7n(-c7ccccc7)c6c5)ccc43)n2)cc1 ; c1ccc(-c2ccc(-n3c4ccccc4c4ccc(-c5ccc6c(c5)c5ccccc5n6-c5cc(-c6ccccc6)nc(-c6ccccc6)n5)cc43)cc2)cc1 ; c1ccc(-c2ccc(-n3c4ccccc4c4ccc(-c5ccc6c(c5)c5ccccc5n6-c5nc(-c6ccccc6)cc(-c6ccccc6)n5)cc43)cc2)cc1 ; c1ccc(-c2cc(-n3c4ccccc4c4cc(-c5ccc6c7ccccc7n(-c7cc(-c8ccccc8)nc(-c8ccccc8)n7)c6c5)ccc43)nc(-c3ccccc3)n2)cc1]

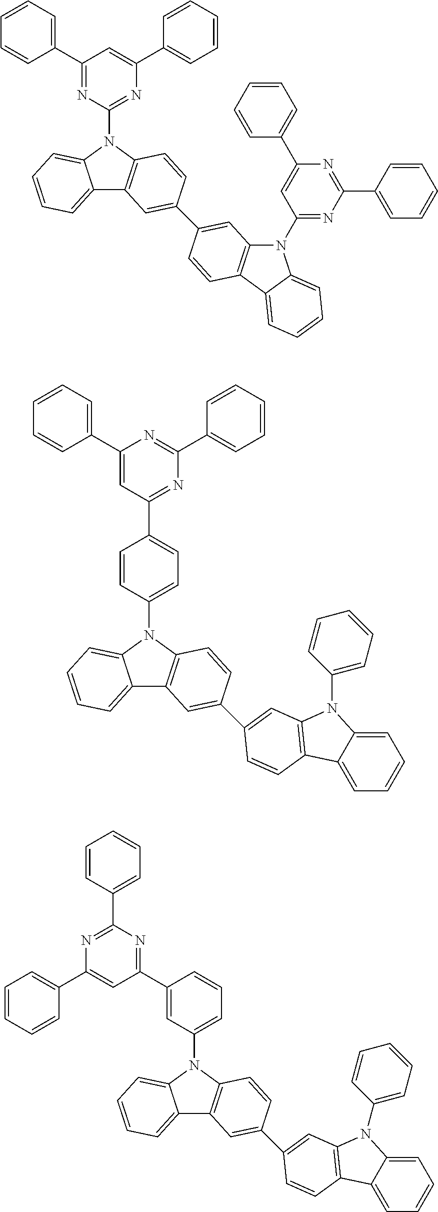 [SMILES: c1ccc(-c2cc(-n3c4ccccc4c4ccc(-c5ccc6c(c5)c5ccccc5n6-c5nc(-c6ccccc6)cc(-c6ccccc6)n5)cc43)nc(-c3ccccc3)n2)cc1 ; c1ccc(-c2cc(-c3ccc(-n4c5ccccc5c5cc(-c6ccc7c8ccccc8n(-c8ccccc8)c7c6)ccc54)cc3)nc(-c3ccccc3)n2)cc1 ; c1ccc(-c2cc(-c3cccc(-n4c5ccccc5c5cc(-c6ccc7c8ccccc8n(-c8ccccc8)c7c6)ccc54)c3)nc(-c3ccccc3)n2)cc1]

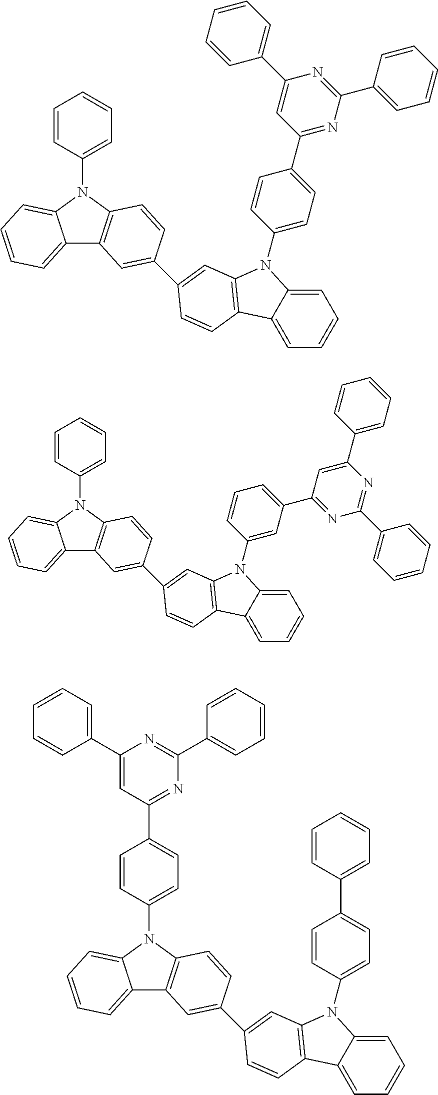

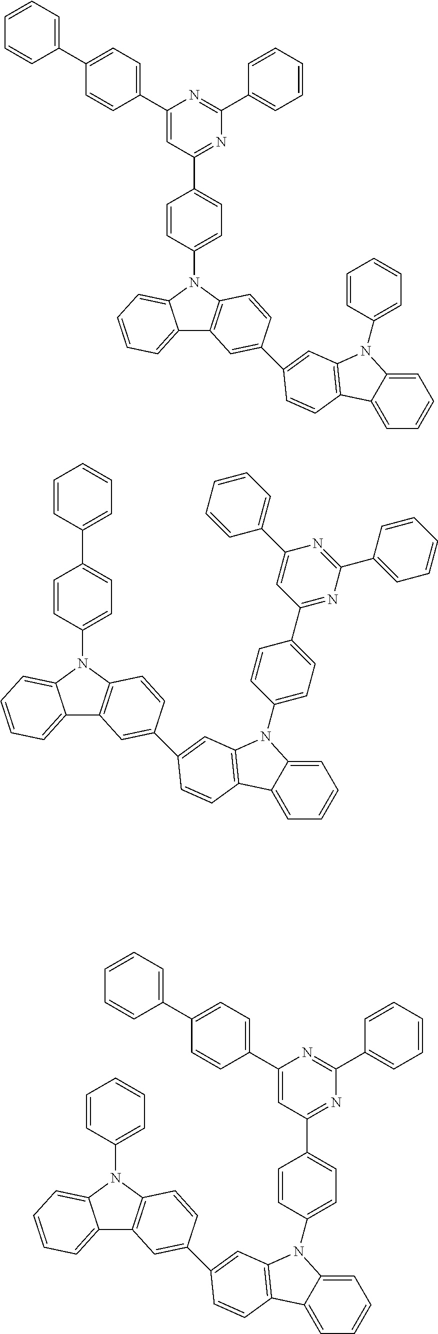 [SMILES: c1ccc(-c2ccc(-c3cc(-c4ccc(-n5c6ccccc6c6cc(-c7ccc8c9ccccc9n(-c9ccccc9)c8c7)ccc65)cc4)nc(-c4ccccc4)n3)cc2)cc1 ; c1ccc(-c2ccc(-n3c4ccccc4c4cc(-c5ccc6c7ccccc7n(-c7ccc(-c8cc(-c9ccccc9)nc(-c9ccccc9)n8)cc7)c6c5)ccc43)cc2)cc1 ; c1ccc(-c2ccc(-c3cc(-c4ccc(-n5c6ccccc6c6ccc(-c7ccc8c(c7)c7ccccc7n8-c7ccccc7)cc65)cc4)nc(-c4ccccc4)n3)cc2)cc1]

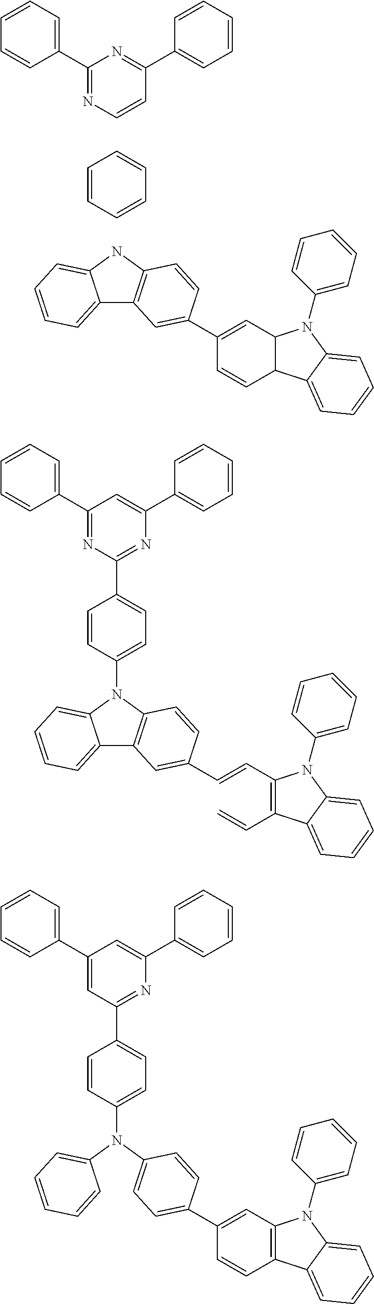

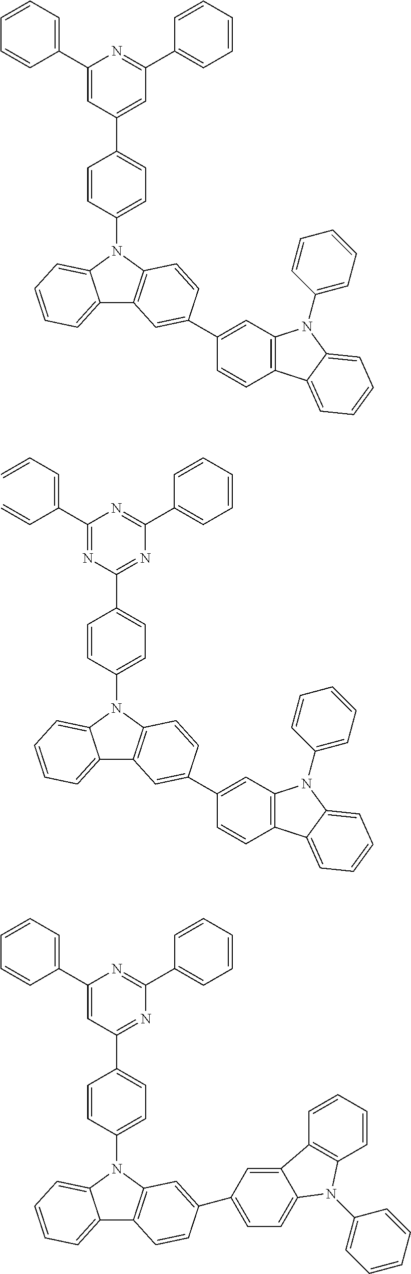 [SMILES: c1ccc(-c2cc(-c3ccc(-n4c5ccccc5c5cc(-c6ccc7c8ccccc8n(-c8ccccc8)c7c6)ccc54)cc3)cc(-c3ccccc3)n2)cc1 ; C=C/C=C(\C=C)c1nc(-c2ccccc2)nc(-c2ccc(-n3c4ccccc4c4cc(-c5ccc6c7ccccc7n(-c7ccccc7)c6c5)ccc43)cc2)n1 ; c1ccc(-c2cc(-c3ccc(-n4c5ccccc5c5ccc(-c6ccc7c(c6)c6ccccc6n7-c6ccccc6)cc54)cc3)nc(-c3ccccc3)n2)cc1]

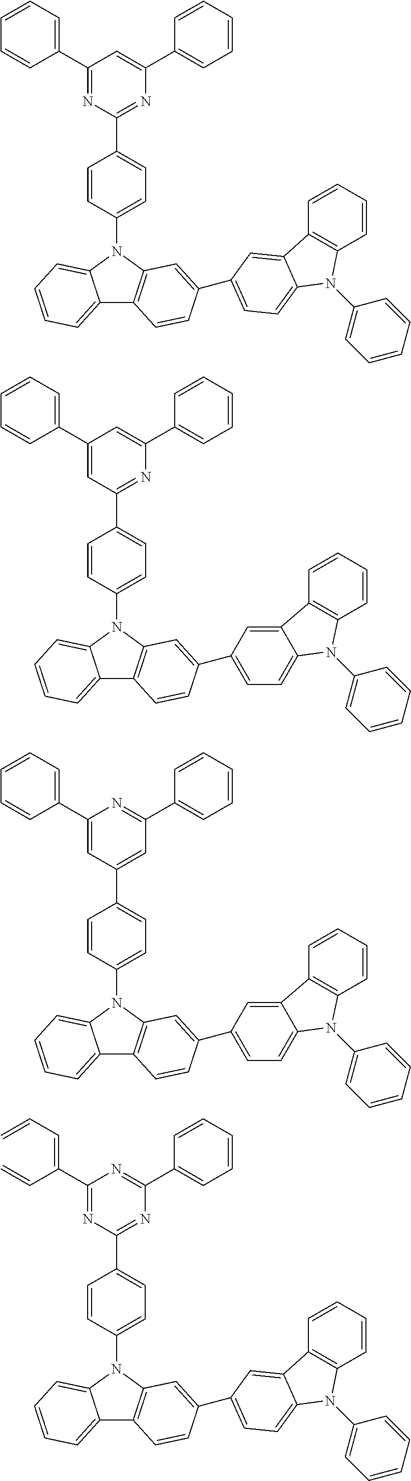 [SMILES: c1ccc(-c2cc(-c3ccccc3)nc(-c3ccc(-n4c5ccccc5c5ccc(-c6ccc7c(c6)c6ccccc6n7-c6ccccc6)cc54)cc3)n2)cc1 ; c1ccc(-c2cc(-c3ccccc3)nc(-c3ccc(-n4c5ccccc5c5ccc(-c6ccc7c(c6)c6ccccc6n7-c6ccccc6)cc54)cc3)c2)cc1 ; c1ccc(-c2cc(-c3ccc(-n4c5ccccc5c5ccc(-c6ccc7c(c6)c6ccccc6n7-c6ccccc6)cc54)cc3)cc(-c3ccccc3)n2)cc1 ; C=C/C=C(\C=C)c1nc(-c2ccccc2)nc(-c2ccc(-n3c4ccccc4c4ccc(-c5ccc6c(c5)c5ccccc5n6-c5ccccc5)cc43)cc2)n1]

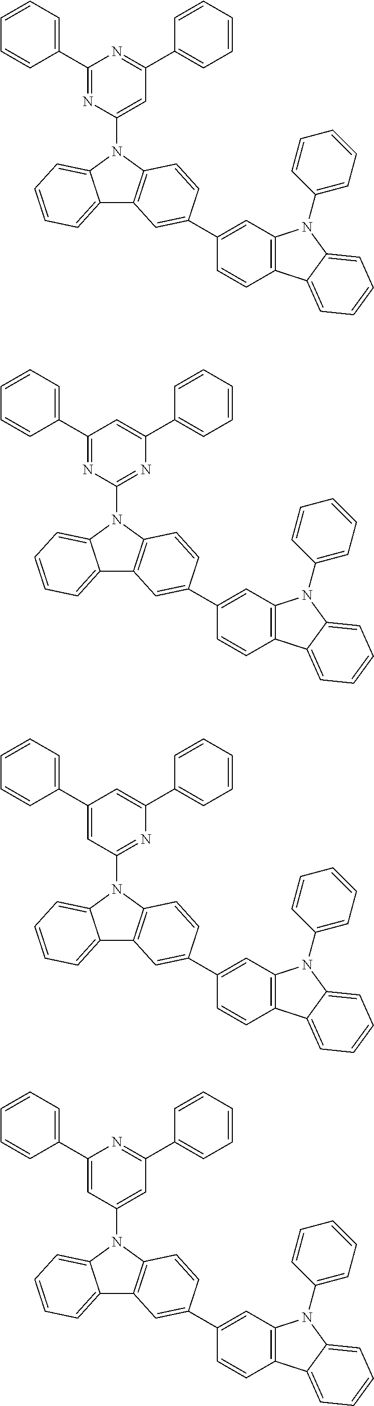 [SMILES: c1ccc(-c2cc(-n3c4ccccc4c4cc(-c5ccc6c7ccccc7n(-c7ccccc7)c6c5)ccc43)nc(-c3ccccc3)n2)cc1 ; c1ccc(-c2cc(-c3ccccc3)nc(-n3c4ccccc4c4cc(-c5ccc6c7ccccc7n(-c7ccccc7)c6c5)ccc43)n2)cc1 ; c1ccc(-c2cc(-c3ccccc3)nc(-n3c4ccccc4c4cc(-c5ccc6c7ccccc7n(-c7ccccc7)c6c5)ccc43)c2)cc1 ; c1ccc(-c2cc(-n3c4ccccc4c4cc(-c5ccc6c7ccccc7n(-c7ccccc7)c6c5)ccc43)cc(-c3ccccc3)n2)cc1]

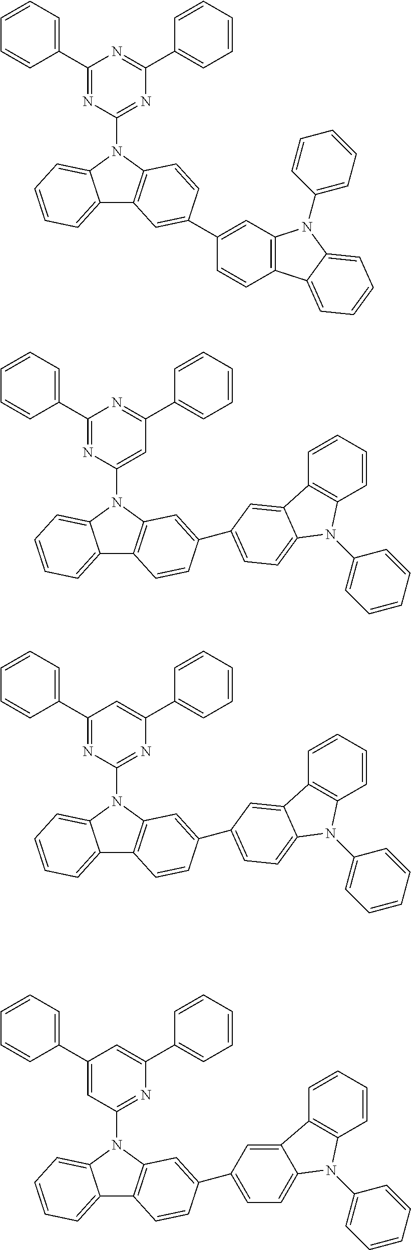 [SMILES: c1ccc(-c2nc(-c3ccccc3)nc(-n3c4ccccc4c4cc(-c5ccc6c7ccccc7n(-c7ccccc7)c6c5)ccc43)n2)cc1 ; c1ccc(-c2cc(-n3c4ccccc4c4ccc(-c5ccc6c(c5)c5ccccc5n6-c5ccccc5)cc43)nc(-c3ccccc3)n2)cc1 ; c1ccc(-c2cc(-c3ccccc3)nc(-n3c4ccccc4c4ccc(-c5ccc6c(c5)c5ccccc5n6-c5ccccc5)cc43)n2)cc1 ; c1ccc(-c2cc(-c3ccccc3)nc(-n3c4ccccc4c4ccc(-c5ccc6c(c5)c5ccccc5n6-c5ccccc5)cc43)c2)cc1]

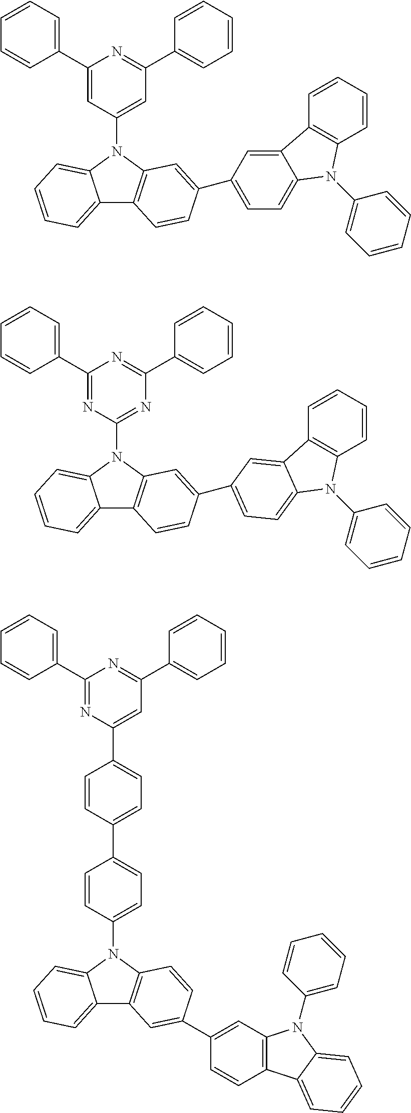 [SMILES: c1ccc(-c2cc(-n3c4ccccc4c4ccc(-c5ccc6c(c5)c5ccccc5n6-c5ccccc5)cc43)cc(-c3ccccc3)n2)cc1 ; c1ccc(-c2nc(-c3ccccc3)nc(-n3c4ccccc4c4ccc(-c5ccc6c(c5)c5ccccc5n6-c5ccccc5)cc43)n2)cc1 ; c1ccc(-c2cc(-c3ccc(-c4ccc(-n5c6ccccc6c6cc(-c7ccc8c9ccccc9n(-c9ccccc9)c8c7)ccc65)cc4)cc3)nc(-c3ccccc3)n2)cc1]

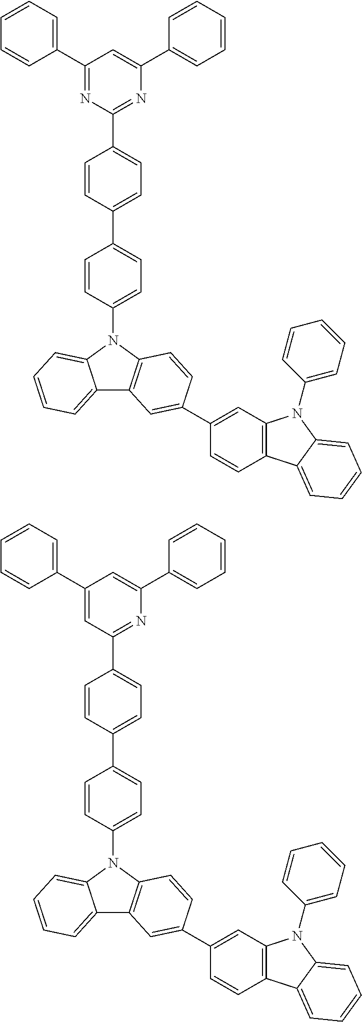 [SMILES: c1ccc(-c2cc(-c3ccccc3)nc(-c3ccc(-c4ccc(-n5c6ccccc6c6cc(-c7ccc8c9ccccc9n(-c9ccccc9)c8c7)ccc65)cc4)cc3)n2)cc1 ; c1ccc(-c2cc(-c3ccccc3)nc(-c3ccc(-c4ccc(-n5c6ccccc6c6cc(-c7ccc8c9ccccc9n(-c9ccccc9)c8c7)ccc65)cc4)cc3)c2)cc1]

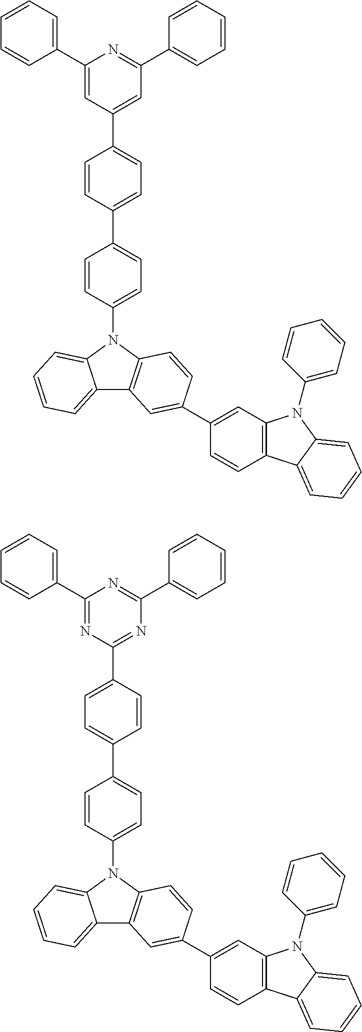 [SMILES: c1ccc(-c2cc(-c3ccc(-c4ccc(-n5c6ccccc6c6cc(-c7ccc8c9ccccc9n(-c9ccccc9)c8c7)ccc65)cc4)cc3)cc(-c3ccccc3)n2)cc1 ; c1ccc(-c2nc(-c3ccccc3)nc(-c3ccc(-c4ccc(-n5c6ccccc6c6cc(-c7ccc8c9ccccc9n(-c9ccccc9)c8c7)ccc65)cc4)cc3)n2)cc1]

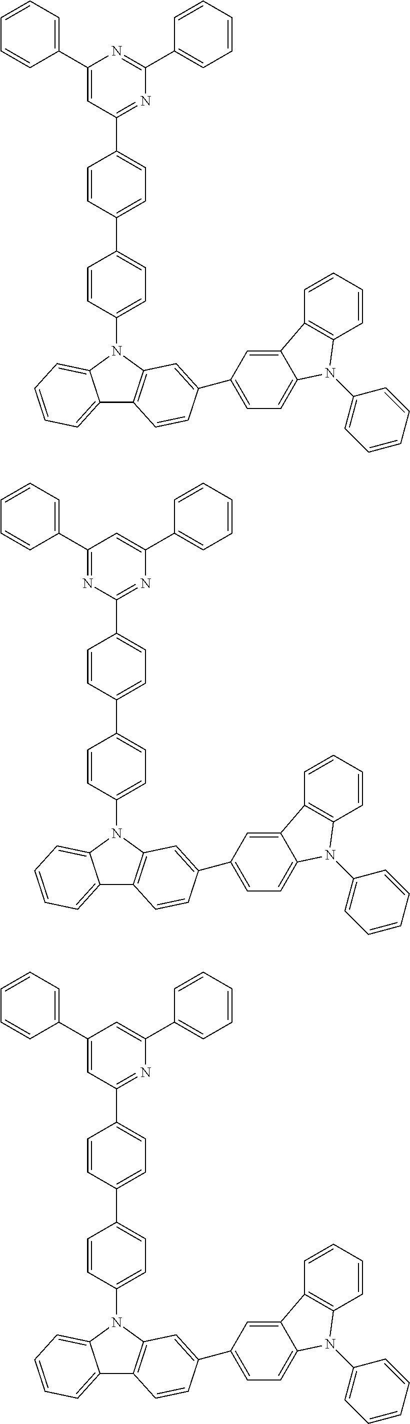 [SMILES: c1ccc(-c2cc(-c3ccc(-c4ccc(-n5c6ccccc6c6ccc(-c7ccc8c(c7)c7ccccc7n8-c7ccccc7)cc65)cc4)cc3)nc(-c3ccccc3)n2)cc1 ; c1ccc(-c2cc(-c3ccccc3)nc(-c3ccc(-c4ccc(-n5c6ccccc6c6ccc(-c7ccc8c(c7)c7ccccc7n8-c7ccccc7)cc65)cc4)cc3)n2)cc1 ; c1ccc(-c2cc(-c3ccccc3)nc(-c3ccc(-c4ccc(-n5c6ccccc6c6ccc(-c7ccc8c(c7)c7ccccc7n8-c7ccccc7)cc65)cc4)cc3)c2)cc1]

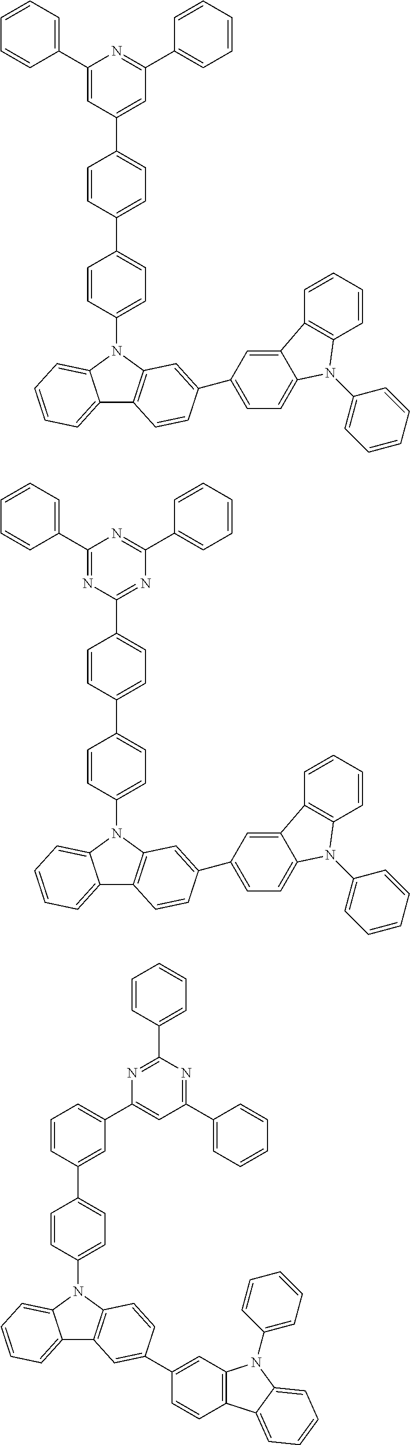 [SMILES: c1ccc(-c2cc(-c3ccc(-c4ccc(-n5c6ccccc6c6ccc(-c7ccc8c(c7)c7ccccc7n8-c7ccccc7)cc65)cc4)cc3)cc(-c3ccccc3)n2)cc1 ; c1ccc(-c2nc(-c3ccccc3)nc(-c3ccc(-c4ccc(-n5c6ccccc6c6ccc(-c7ccc8c(c7)c7ccccc7n8-c7ccccc7)cc65)cc4)cc3)n2)cc1 ; c1ccc(-c2cc(-c3cccc(-c4ccc(-n5c6ccccc6c6cc(-c7ccc8c9ccccc9n(-c9ccccc9)c8c7)ccc65)cc4)c3)nc(-c3ccccc3)n2)cc1]

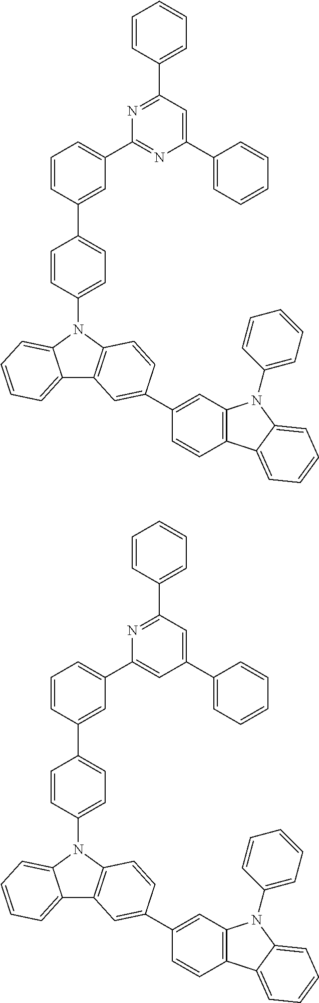 [SMILES: c1ccc(-c2cc(-c3ccccc3)nc(-c3cccc(-c4ccc(-n5c6ccccc6c6cc(-c7ccc8c9ccccc9n(-c9ccccc9)c8c7)ccc65)cc4)c3)n2)cc1 ; c1ccc(-c2cc(-c3ccccc3)nc(-c3cccc(-c4ccc(-n5c6ccccc6c6cc(-c7ccc8c9ccccc9n(-c9ccccc9)c8c7)ccc65)cc4)c3)c2)cc1]

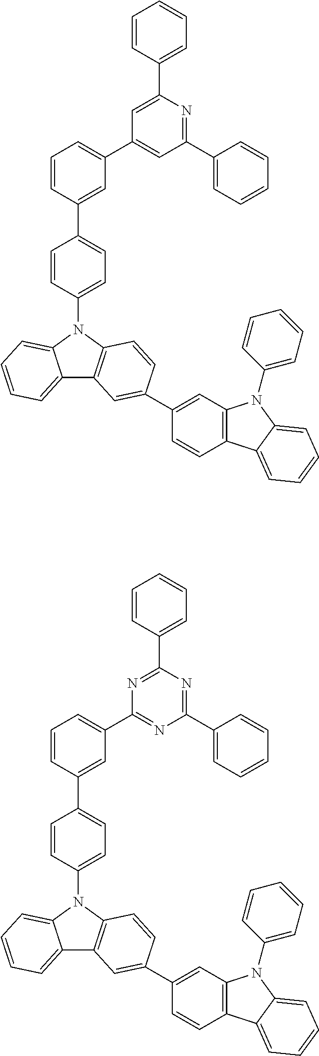 [SMILES: c1ccc(-c2cc(-c3cccc(-c4ccc(-n5c6ccccc6c6cc(-c7ccc8c9ccccc9n(-c9ccccc9)c8c7)ccc65)cc4)c3)cc(-c3ccccc3)n2)cc1 ; c1ccc(-c2nc(-c3ccccc3)nc(-c3cccc(-c4ccc(-n5c6ccccc6c6cc(-c7ccc8c9ccccc9n(-c9ccccc9)c8c7)ccc65)cc4)c3)n2)cc1]

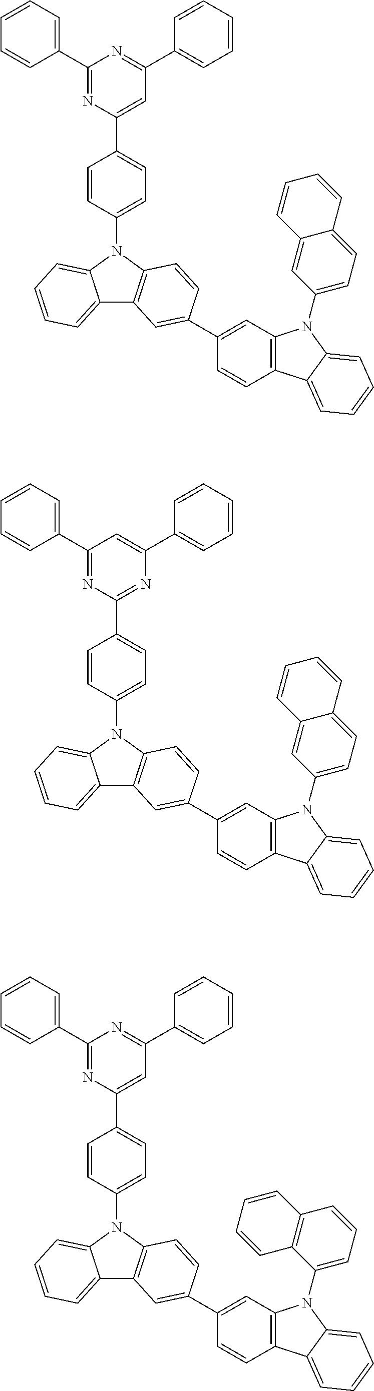 [SMILES: c1ccc(-c2cc(-c3ccc(-n4c5ccccc5c5cc(-c6ccc7c8ccccc8n(-c8ccc9ccccc9c8)c7c6)ccc54)cc3)nc(-c3ccccc3)n2)cc1 ; c1ccc(-c2cc(-c3ccccc3)nc(-c3ccc(-n4c5ccccc5c5cc(-c6ccc7c8ccccc8n(-c8ccc9ccccc9c8)c7c6)ccc54)cc3)n2)cc1 ; c1ccc(-c2cc(-c3ccc(-n4c5ccccc5c5cc(-c6ccc7c8ccccc8n(-c8cccc9ccccc89)c7c6)ccc54)cc3)nc(-c3ccccc3)n2)cc1]

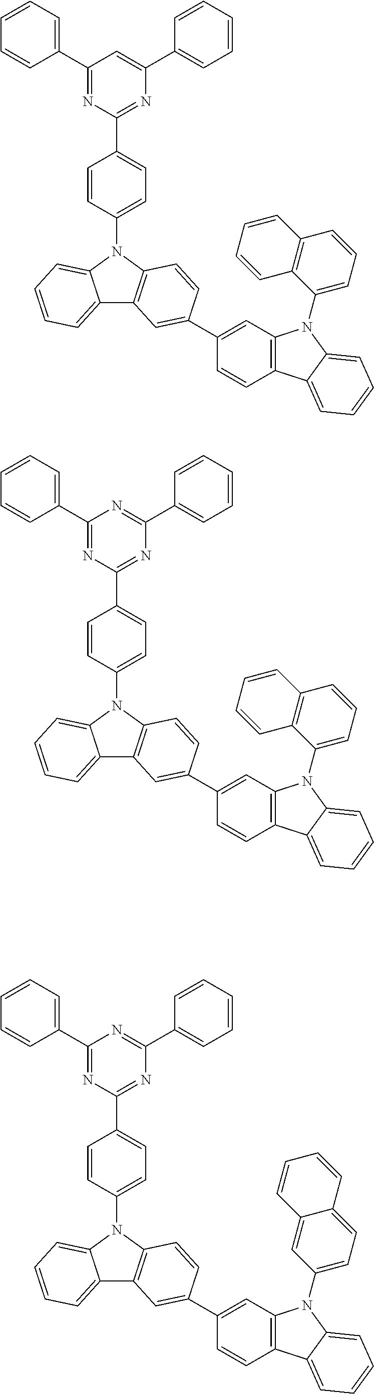 [SMILES: c1ccc(-c2cc(-c3ccccc3)nc(-c3ccc(-n4c5ccccc5c5cc(-c6ccc7c8ccccc8n(-c8cccc9ccccc89)c7c6)ccc54)cc3)n2)cc1 ; c1ccc(-c2nc(-c3ccccc3)nc(-c3ccc(-n4c5ccccc5c5cc(-c6ccc7c8ccccc8n(-c8cccc9ccccc89)c7c6)ccc54)cc3)n2)cc1 ; c1ccc(-c2nc(-c3ccccc3)nc(-c3ccc(-n4c5ccccc5c5cc(-c6ccc7c8ccccc8n(-c8ccc9ccccc9c8)c7c6)ccc54)cc3)n2)cc1]

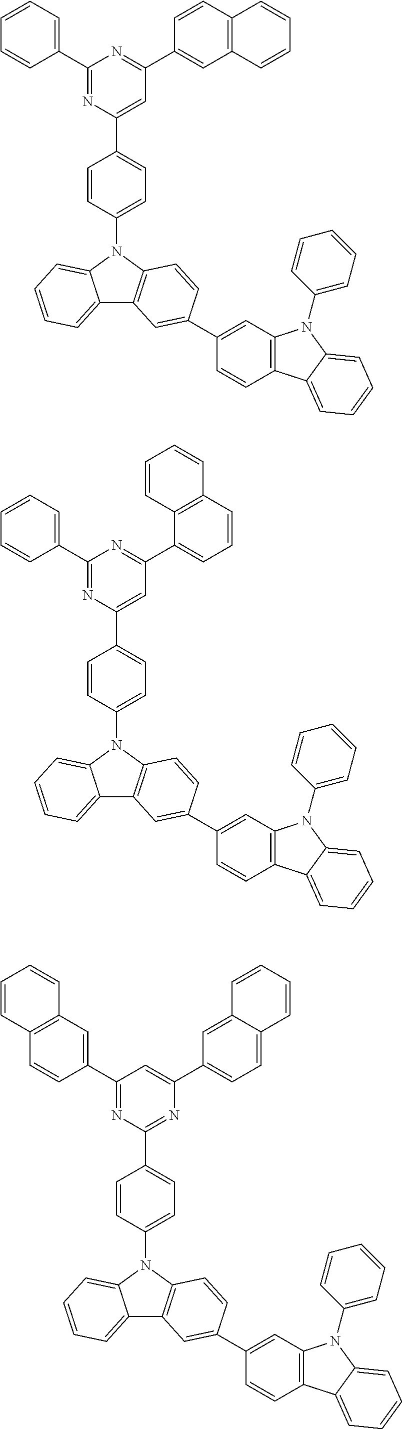 [SMILES: c1ccc(-c2nc(-c3ccc(-n4c5ccccc5c5cc(-c6ccc7c8ccccc8n(-c8ccccc8)c7c6)ccc54)cc3)cc(-c3ccc4ccccc4c3)n2)cc1 ; c1ccc(-c2nc(-c3ccc(-n4c5ccccc5c5cc(-c6ccc7c8ccccc8n(-c8ccccc8)c7c6)ccc54)cc3)cc(-c3cccc4ccccc34)n2)cc1 ; c1ccc(-n2c3ccccc3c3ccc(-c4ccc5c(c4)c4ccccc4n5-c4ccc(-c5nc(-c6ccc7ccccc7c6)cc(-c6ccc7ccccc7c6)n5)cc4)cc32)cc1]

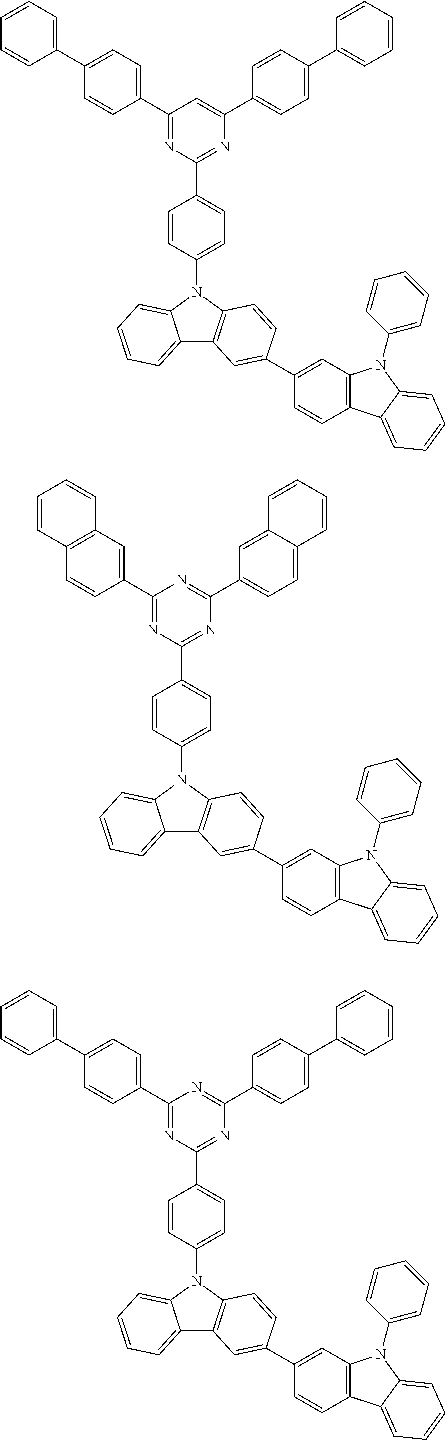 [SMILES: c1ccc(-c2ccc(-c3cc(-c4ccc(-c5ccccc5)cc4)nc(-c4ccc(-n5c6ccccc6c6cc(-c7ccc8c9ccccc9n(-c9ccccc9)c8c7)ccc65)cc4)n3)cc2)cc1 ; c1ccc(-n2c3ccccc3c3ccc(-c4ccc5c(c4)c4ccccc4n5-c4ccc(-c5nc(-c6ccc7ccccc7c6)nc(-c6ccc7ccccc7c6)n5)cc4)cc32)cc1 ; c1ccc(-c2ccc(-c3nc(-c4ccc(-c5ccccc5)cc4)nc(-c4ccc(-n5c6ccccc6c6cc(-c7ccc8c9ccccc9n(-c9ccccc9)c8c7)ccc65)cc4)n3)cc2)cc1]

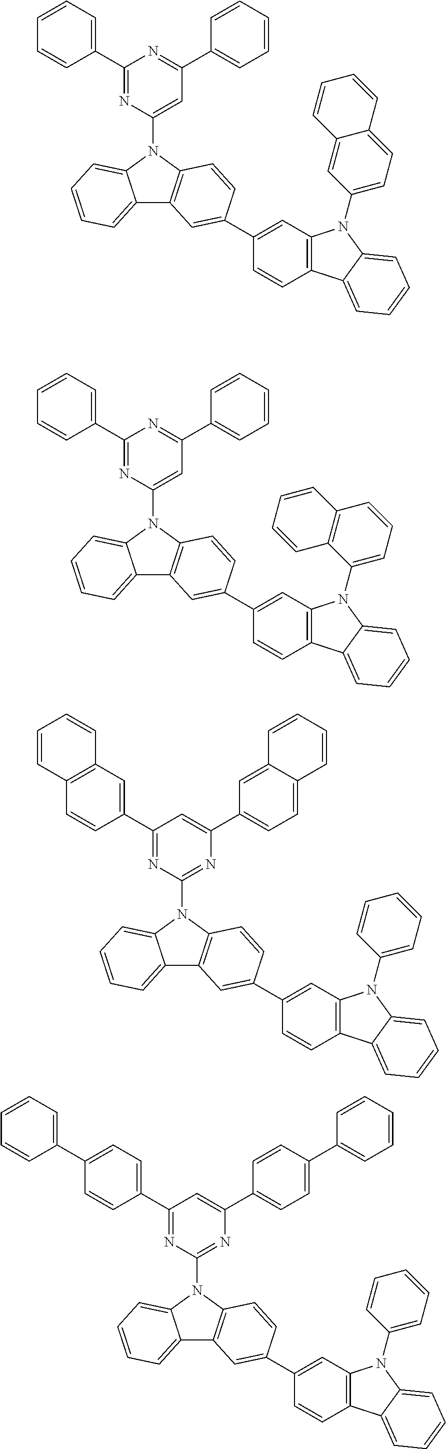

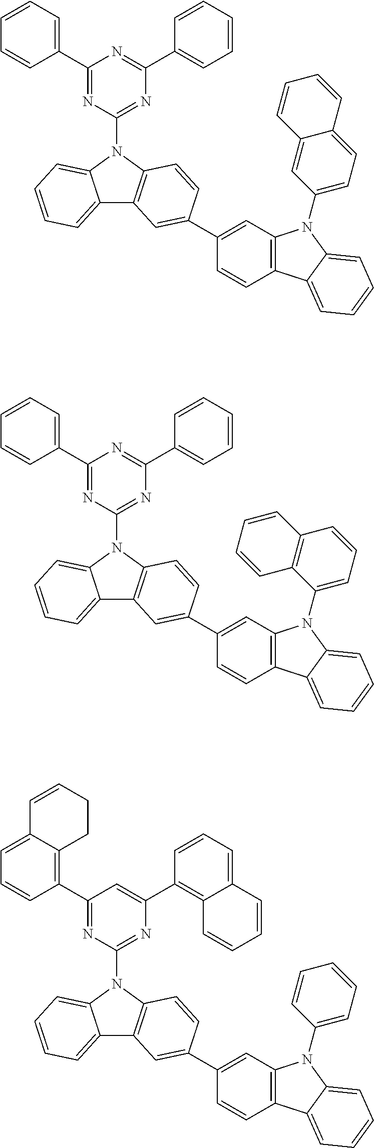 [SMILES: c1ccc(-c2nc(-c3ccccc3)nc(-n3c4ccccc4c4cc(-c5ccc6c7ccccc7n(-c7ccc8ccccc8c7)c6c5)ccc43)n2)cc1 ; c1ccc(-c2nc(-c3ccccc3)nc(-n3c4ccccc4c4cc(-c5ccc6c7ccccc7n(-c7cccc8ccccc78)c6c5)ccc43)n2)cc1 ; C1=Cc2cccc(-c3cc(-c4cccc5ccccc45)nc(-n4c5ccccc5c5cc(-c6ccc7c8ccccc8n(-c8ccccc8)c7c6)ccc54)n3)c2CC1]

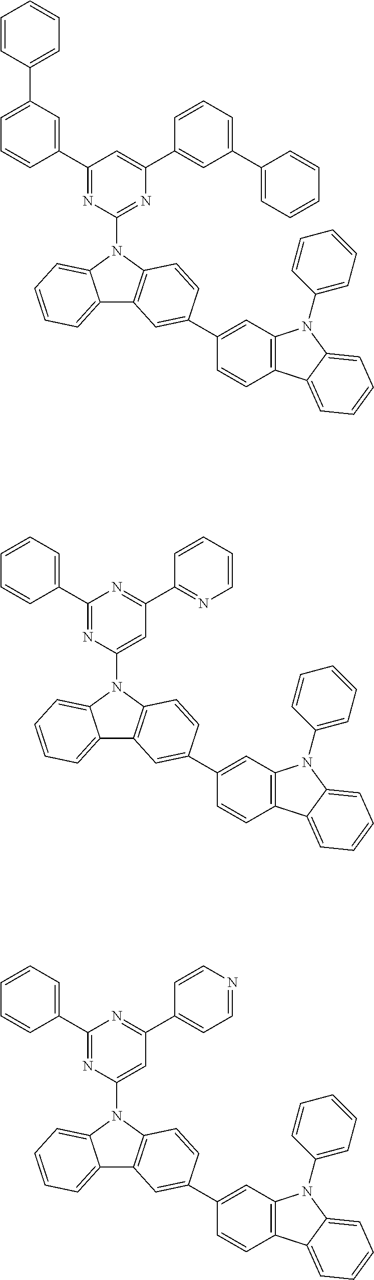 [SMILES: c1ccc(-c2cccc(-c3cc(-c4cccc(-c5ccccc5)c4)nc(-n4c5ccccc5c5cc(-c6ccc7c8ccccc8n(-c8ccccc8)c7c6)ccc54)n3)c2)cc1 ; c1ccc(-c2nc(-c3ccccn3)cc(-n3c4ccccc4c4cc(-c5ccc6c7ccccc7n(-c7ccccc7)c6c5)ccc43)n2)cc1 ; c1ccc(-c2nc(-c3ccncc3)cc(-n3c4ccccc4c4cc(-c5ccc6c7ccccc7n(-c7ccccc7)c6c5)ccc43)n2)cc1]

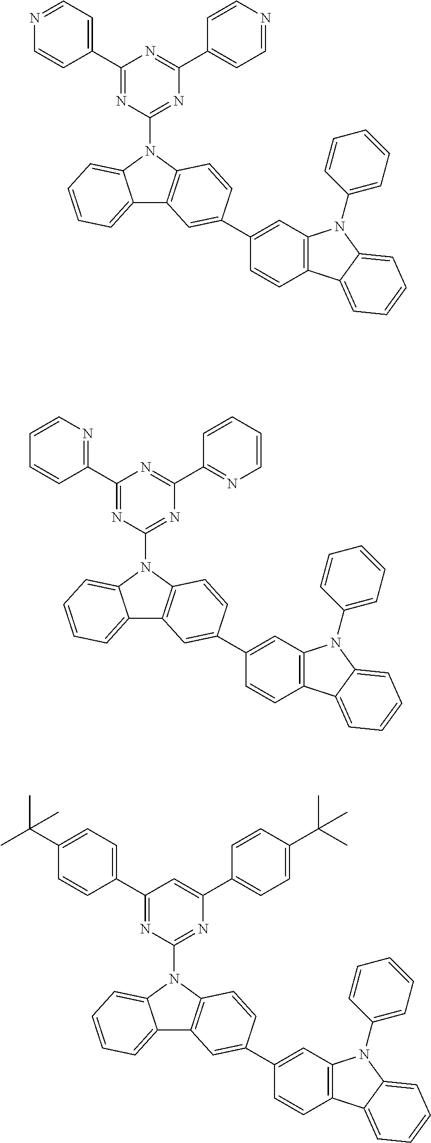 [SMILES: c1ccc(-n2c3ccccc3c3ccc(-c4ccc5c(c4)c4ccccc4n5-c4nc(-c5ccncc5)nc(-c5ccncc5)n4)cc32)cc1 ; c1ccc(-n2c3ccccc3c3ccc(-c4ccc5c(c4)c4ccccc4n5-c4nc(-c5ccccn5)nc(-c5ccccn5)n4)cc32)cc1 ; CC(C)(C)c1ccc(-c2cc(-c3ccc(C(C)(C)C)cc3)nc(-n3c4ccccc4c4cc(-c5ccc6c7ccccc7n(-c7ccccc7)c6c5)ccc43)n2)cc1]

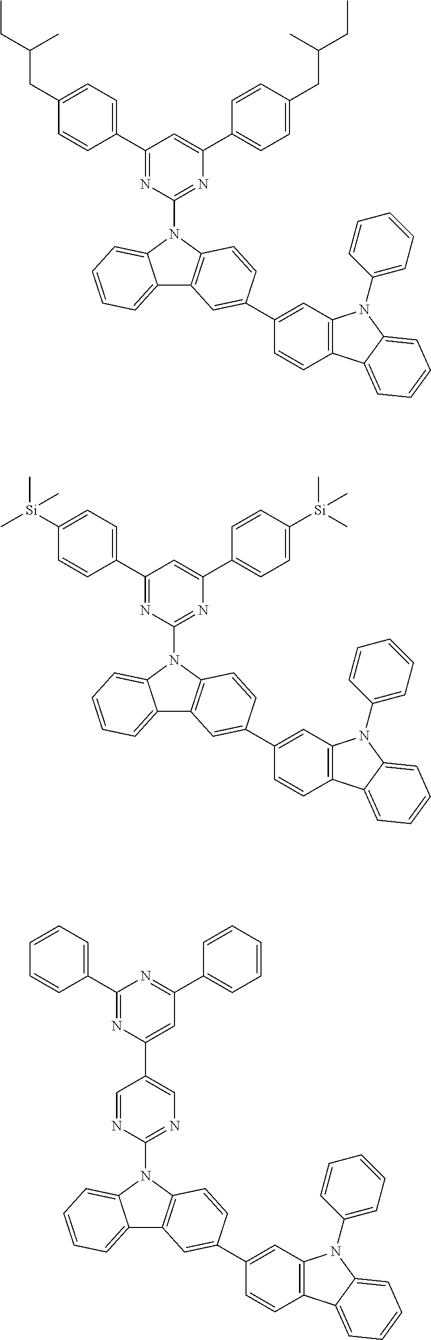 [SMILES: CCC(C)Cc1ccc(-c2cc(-c3ccc(CC(C)CC)cc3)nc(-n3c4ccccc4c4cc(-c5ccc6c7ccccc7n(-c7ccccc7)c6c5)ccc43)n2)cc1 ; C[Si](C)(C)c1ccc(-c2cc(-c3ccc([Si](C)(C)C)cc3)nc(-n3c4ccccc4c4cc(-c5ccc6c7ccccc7n(-c7ccccc7)c6c5)ccc43)n2)cc1 ; c1ccc(-c2cc(-c3cnc(-n4c5ccccc5c5cc(-c6ccc7c8ccccc8n(-c8ccccc8)c7c6)ccc54)nc3)nc(-c3ccccc3)n2)cc1]

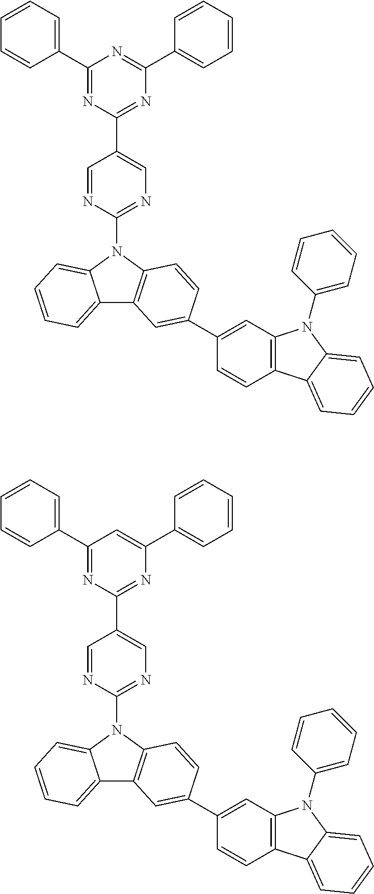 [SMILES: c1ccc(-c2nc(-c3ccccc3)nc(-c3cnc(-n4c5ccccc5c5cc(-c6ccc7c8ccccc8n(-c8ccccc8)c7c6)ccc54)nc3)n2)cc1 ; c1ccc(-c2cc(-c3ccccc3)nc(-c3cnc(-n4c5ccccc5c5cc(-c6ccc7c8ccccc8n(-c8ccccc8)c7c6)ccc54)nc3)n2)cc1]

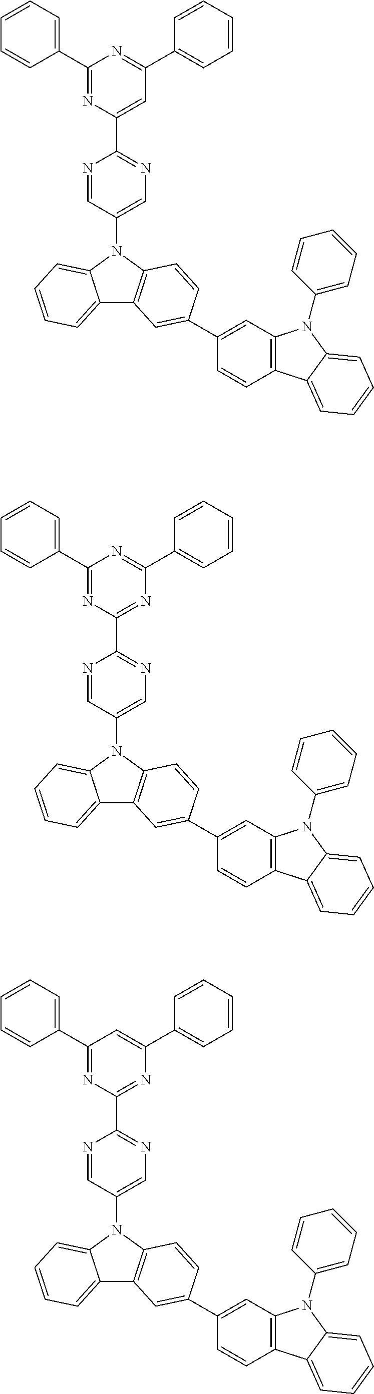 [SMILES: c1ccc(-c2cc(-c3ncc(-n4c5ccccc5c5cc(-c6ccc7c8ccccc8n(-c8ccccc8)c7c6)ccc54)cn3)nc(-c3ccccc3)n2)cc1 ; c1ccc(-c2nc(-c3ccccc3)nc(-c3ncc(-n4c5ccccc5c5cc(-c6ccc7c8ccccc8n(-c8ccccc8)c7c6)ccc54)cn3)n2)cc1 ; c1ccc(-c2cc(-c3ccccc3)nc(-c3ncc(-n4c5ccccc5c5cc(-c6ccc7c8ccccc8n(-c8ccccc8)c7c6)ccc54)cn3)n2)cc1]

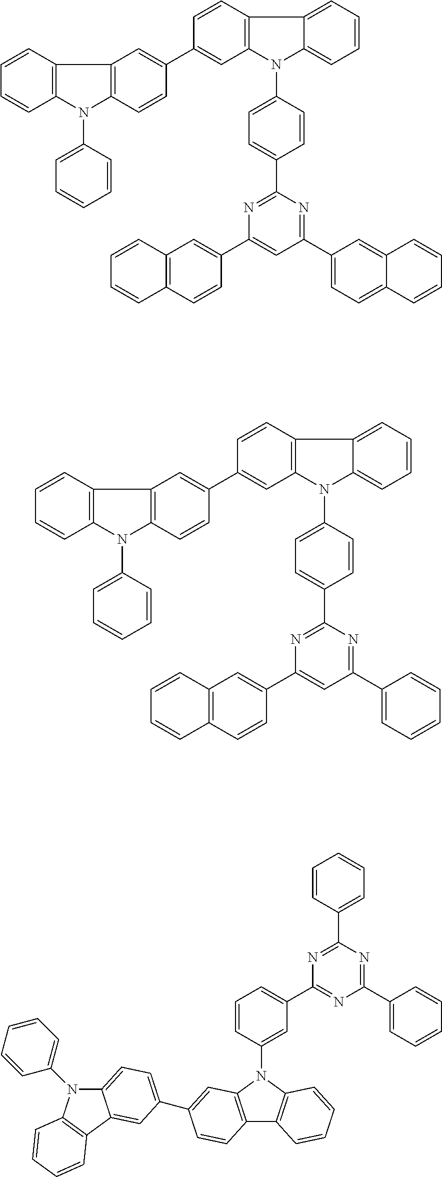 [SMILES: c1ccc(-n2c3ccccc3c3cc(-c4ccc5c6ccccc6n(-c6ccc(-c7nc(-c8ccc9ccccc9c8)cc(-c8ccc9ccccc9c8)n7)cc6)c5c4)ccc32)cc1 ; c1ccc(-c2cc(-c3ccc4ccccc4c3)nc(-c3ccc(-n4c5ccccc5c5ccc(-c6ccc7c(c6)c6ccccc6n7-c6ccccc6)cc54)cc3)n2)cc1 ; c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1]

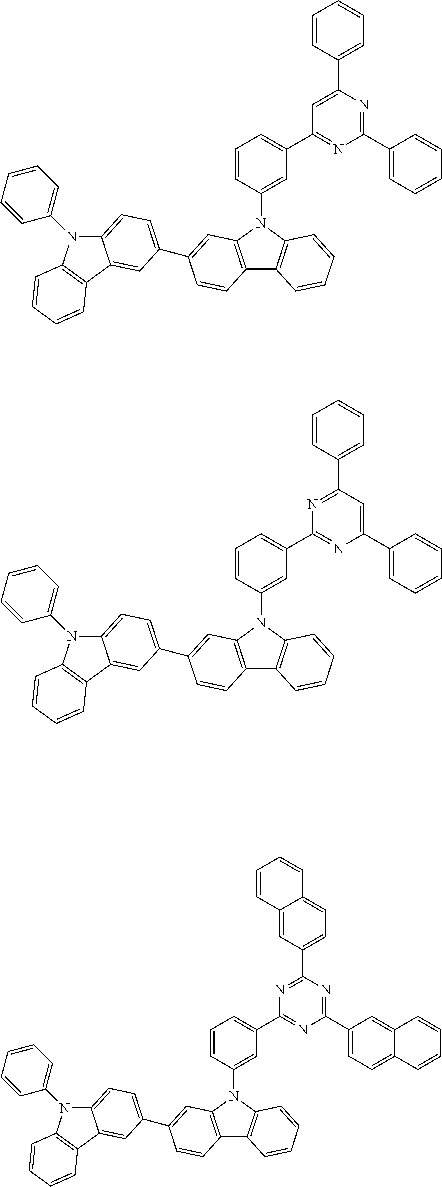 [SMILES: c1ccc(-c2cc(-c3cccc(-n4c5ccccc5c5ccc(-c6ccc7c(c6)c6ccccc6n7-c6ccccc6)cc54)c3)nc(-c3ccccc3)n2)cc1 ; c1ccc(-c2cc(-c3ccccc3)nc(-c3cccc(-n4c5ccccc5c5ccc(-c6ccc7c(c6)c6ccccc6n7-c6ccccc6)cc54)c3)n2)cc1 ; c1ccc(-n2c3ccccc3c3cc(-c4ccc5c6ccccc6n(-c6cccc(-c7nc(-c8ccc9ccccc9c8)nc(-c8ccc9ccccc9c8)n7)c6)c5c4)ccc32)cc1]

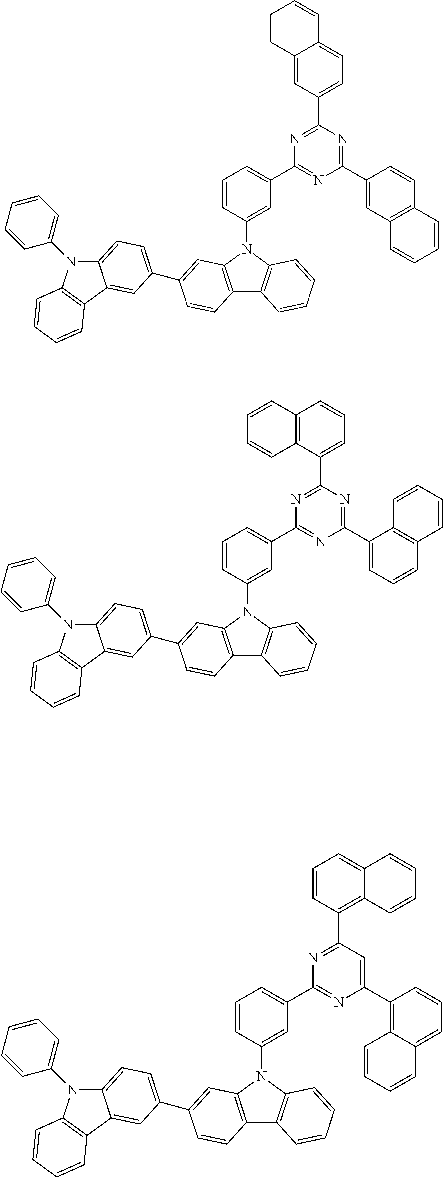 [SMILES: c1ccc(-n2c3ccccc3c3cc(-c4ccc5c6ccccc6n(-c6cccc(-c7nc(-c8ccc9ccccc9c8)nc(-c8ccc9ccccc9c8)n7)c6)c5c4)ccc32)cc1 ; c1ccc(-n2c3ccccc3c3cc(-c4ccc5c6ccccc6n(-c6cccc(-c7nc(-c8cccc9ccccc89)nc(-c8cccc9ccccc89)n7)c6)c5c4)ccc32)cc1 ; c1ccc(-n2c3ccccc3c3cc(-c4ccc5c6ccccc6n(-c6cccc(-c7nc(-c8cccc9ccccc89)cc(-c8cccc9ccccc89)n7)c6)c5c4)ccc32)cc1]

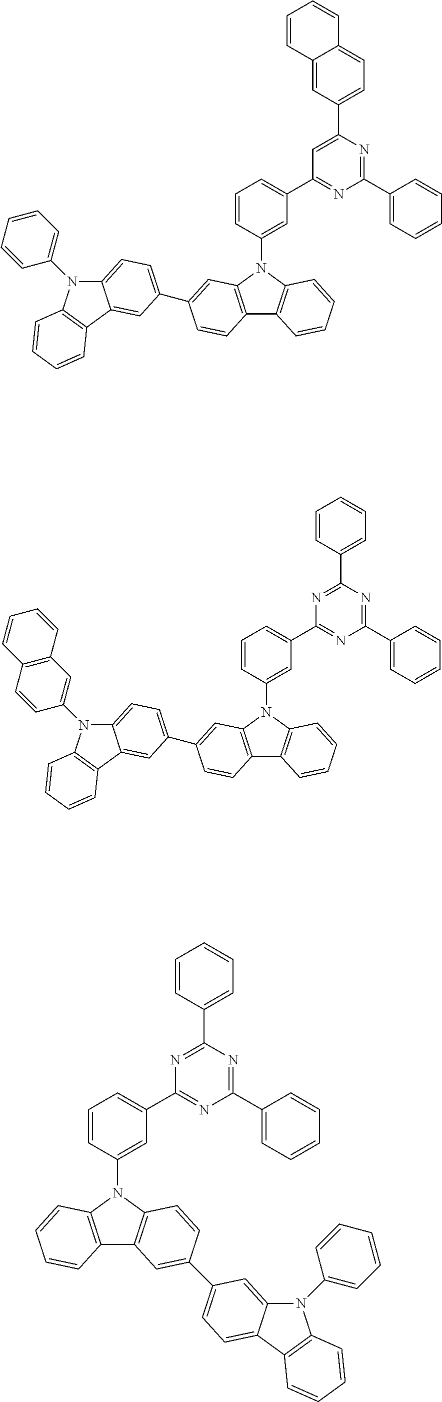 [SMILES: c1ccc(-c2nc(-c3cccc(-n4c5ccccc5c5ccc(-c6ccc7c(c6)c6ccccc6n7-c6ccccc6)cc54)c3)cc(-c3ccc4ccccc4c3)n2)cc1 ; c1ccc(-c2nc(-c3ccccc3)nc(-c3cccc(-n4c5ccccc5c5ccc(-c6ccc7c(c6)c6ccccc6n7-c6ccc7ccccc7c6)cc54)c3)n2)cc1 ; c1ccc(-c2nc(-c3ccccc3)nc(-c3cccc(-n4c5ccccc5c5cc(-c6ccc7c8ccccc8n(-c8ccccc8)c7c6)ccc54)c3)n2)cc1]

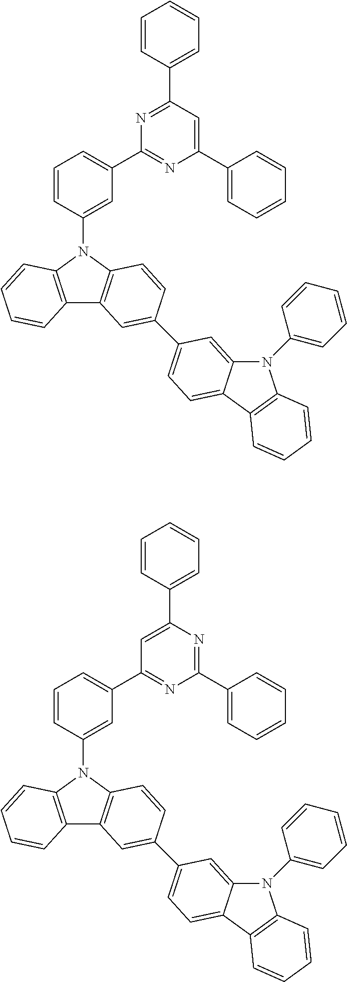 [SMILES: c1ccc(-c2cc(-c3ccccc3)nc(-c3cccc(-n4c5ccccc5c5cc(-c6ccc7c8ccccc8n(-c8ccccc8)c7c6)ccc54)c3)n2)cc1 ; c1ccc(-c2cc(-c3cccc(-n4c5ccccc5c5cc(-c6ccc7c8ccccc8n(-c8ccccc8)c7c6)ccc54)c3)nc(-c3ccccc3)n2)cc1]

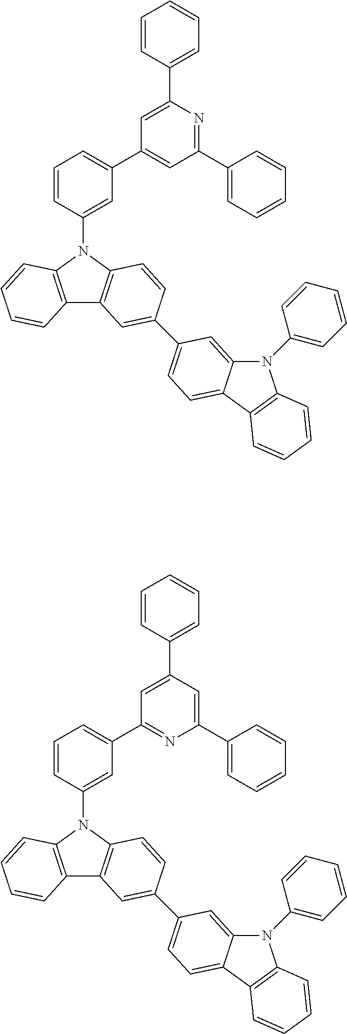 [SMILES: c1ccc(-c2cc(-c3cccc(-n4c5ccccc5c5cc(-c6ccc7c8ccccc8n(-c8ccccc8)c7c6)ccc54)c3)cc(-c3ccccc3)n2)cc1 ; c1ccc(-c2cc(-c3ccccc3)nc(-c3cccc(-n4c5ccccc5c5cc(-c6ccc7c8ccccc8n(-c8ccccc8)c7c6)ccc54)c3)c2)cc1]

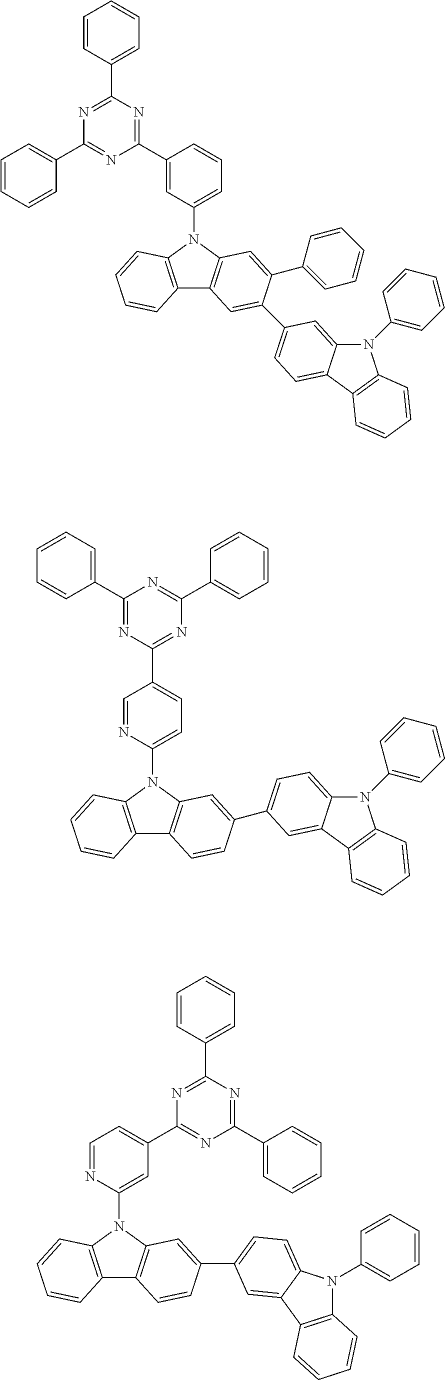 [SMILES: c1ccc(-c2nc(-c3ccccc3)nc(-c3cccc(-n4c5ccccc5c5cc(-c6ccc7c8ccccc8n(-c8ccccc8)c7c6)c(-c6ccccc6)cc54)c3)n2)cc1 ; c1ccc(-c2nc(-c3ccccc3)nc(-c3ccc(-n4c5ccccc5c5ccc(-c6ccc7c(c6)c6ccccc6n7-c6ccccc6)cc54)nc3)n2)cc1 ; c1ccc(-c2nc(-c3ccccc3)nc(-c3ccnc(-n4c5ccccc5c5ccc(-c6ccc7c(c6)c6ccccc6n7-c6ccccc6)cc54)c3)n2)cc1]

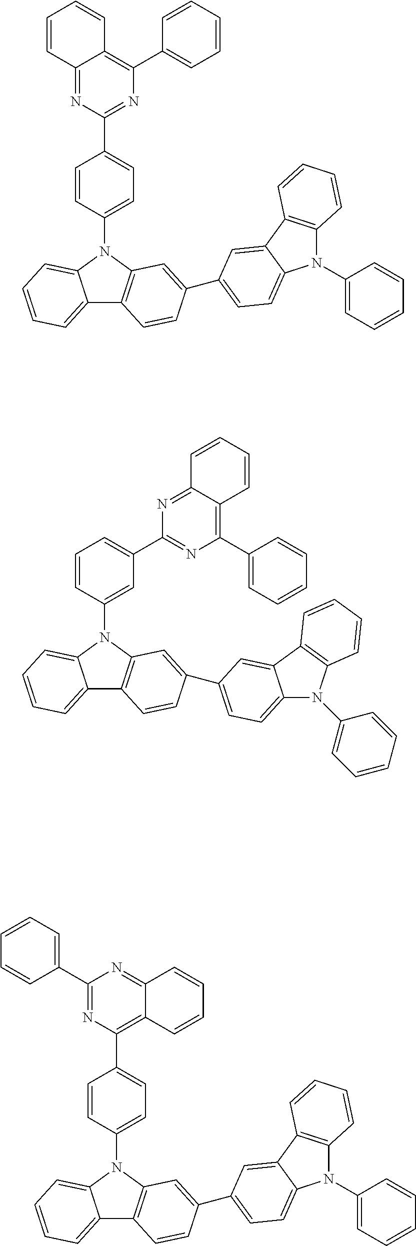 [SMILES: c1ccc(-c2nc(-c3ccc(-n4c5ccccc5c5ccc(-c6ccc7c(c6)c6ccccc6n7-c6ccccc6)cc54)cc3)nc3ccccc23)cc1 ; c1ccc(-c2nc(-c3cccc(-n4c5ccccc5c5ccc(-c6ccc7c(c6)c6ccccc6n7-c6ccccc6)cc54)c3)nc3ccccc23)cc1 ; c1ccc(-c2nc(-c3ccc(-n4c5ccccc5c5ccc(-c6ccc7c(c6)c6ccccc6n7-c6ccccc6)cc54)cc3)c3ccccc3n2)cc1]

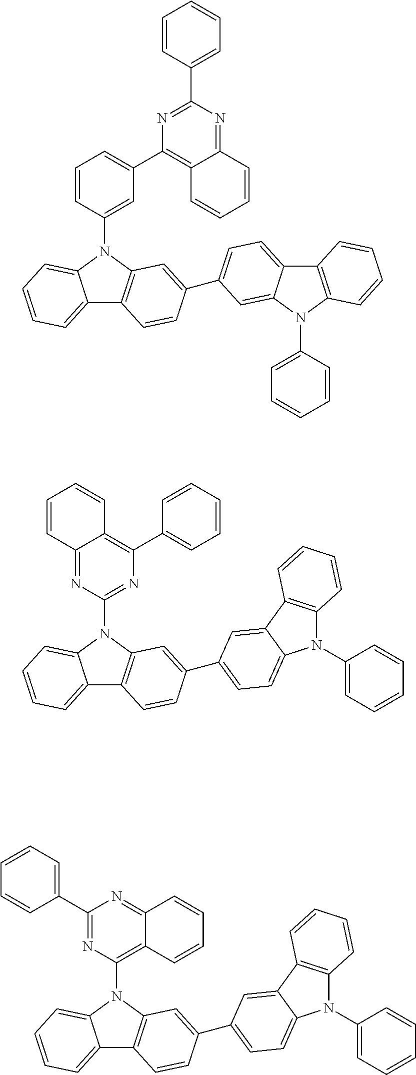 [SMILES: c1ccc(-c2nc(-c3cccc(-n4c5ccccc5c5ccc(-c6ccc7c8ccccc8n(-c8ccccc8)c7c6)cc54)c3)c3ccccc3n2)cc1 ; c1ccc(-c2nc(-n3c4ccccc4c4ccc(-c5ccc6c(c5)c5ccccc5n6-c5ccccc5)cc43)nc3ccccc23)cc1 ; c1ccc(-c2nc(-n3c4ccccc4c4ccc(-c5ccc6c(c5)c5ccccc5n6-c5ccccc5)cc43)c3ccccc3n2)cc1]

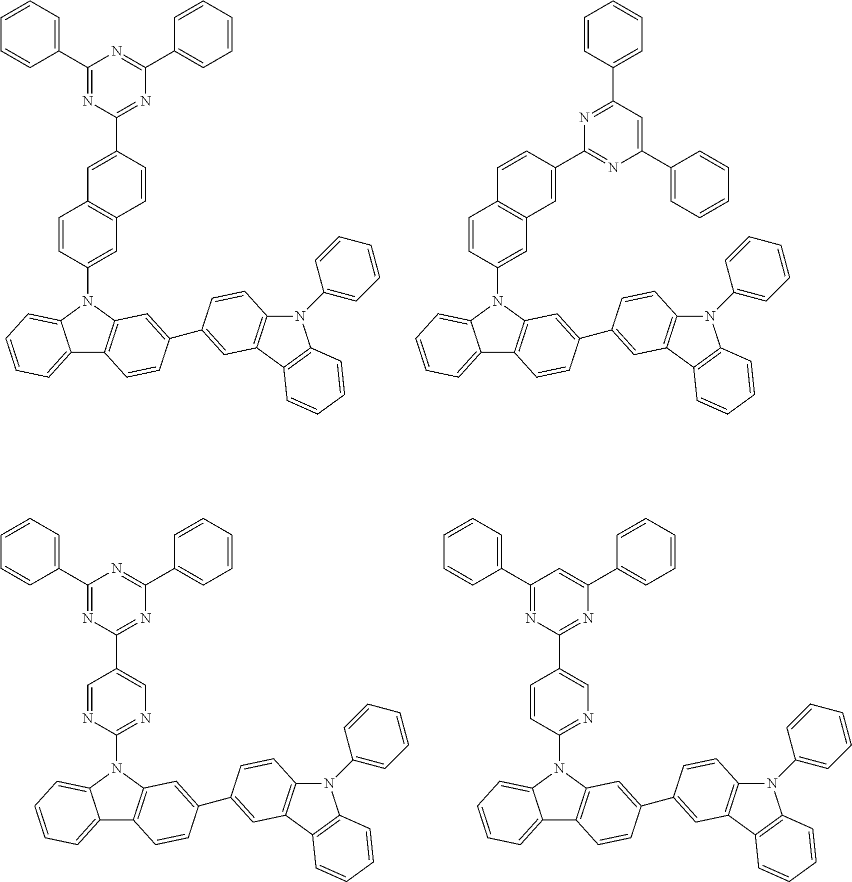 [SMILES: c1ccc(-c2nc(-c3ccccc3)nc(-c3ccc4cc(-n5c6ccccc6c6ccc(-c7ccc8c(c7)c7ccccc7n8-c7ccccc7)cc65)ccc4c3)n2)cc1 ; c1ccc(-c2cc(-c3ccccc3)nc(-c3ccc4ccc(-n5c6ccccc6c6ccc(-c7ccc8c(c7)c7ccccc7n8-c7ccccc7)cc65)cc4c3)n2)cc1 ; c1ccc(-c2nc(-c3ccccc3)nc(-c3cnc(-n4c5ccccc5c5ccc(-c6ccc7c(c6)c6ccccc6n7-c6ccccc6)cc54)nc3)n2)cc1 ; c1ccc(-c2cc(-c3ccccc3)nc(-c3ccc(-n4c5ccccc5c5ccc(-c6ccc7c(c6)c6ccccc6n7-c6ccccc6)cc54)nc3)n2)cc1]

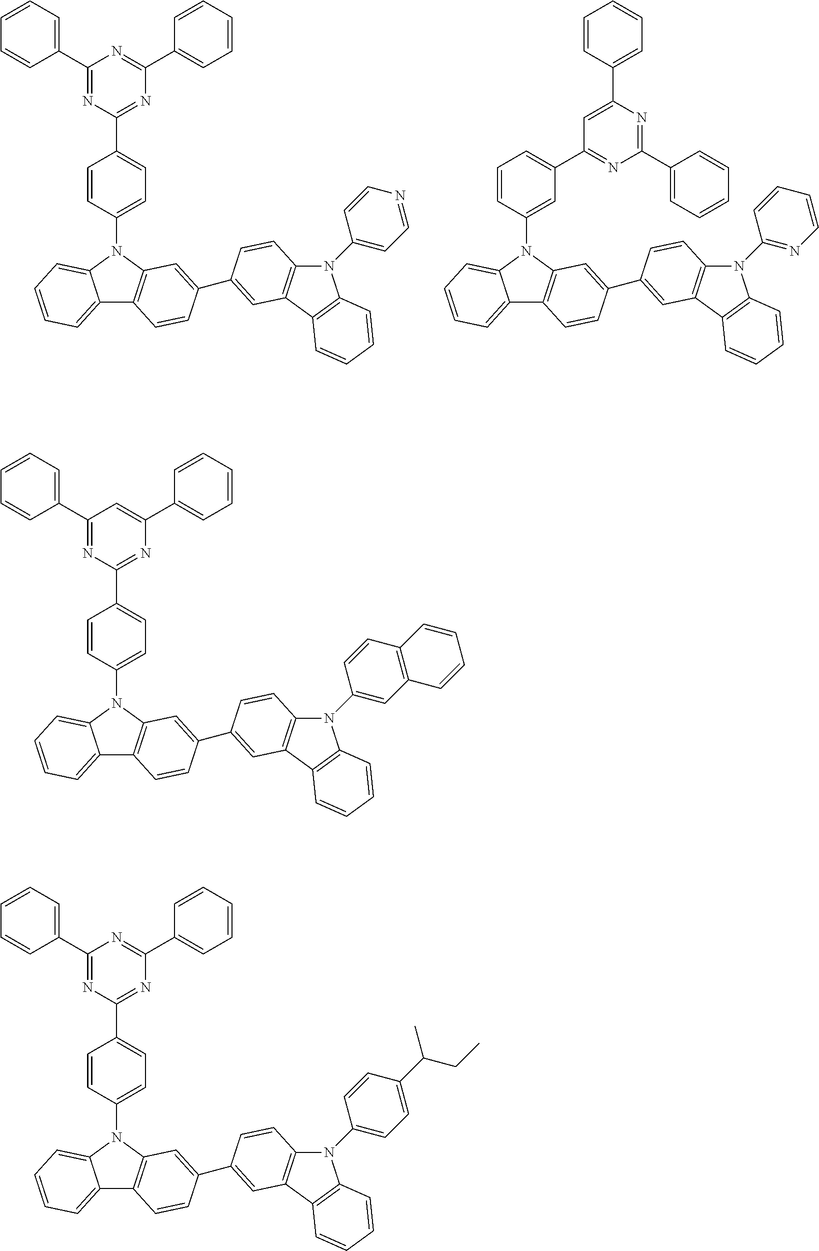 [SMILES: c1ccc(-c2nc(-c3ccccc3)nc(-c3ccc(-n4c5ccccc5c5ccc(-c6ccc7c(c6)c6ccccc6n7-c6ccncc6)cc54)cc3)n2)cc1 ; c1ccc(-c2cc(-c3cccc(-n4c5ccccc5c5ccc(-c6ccc7c(c6)c6ccccc6n7-c6ccccn6)cc54)c3)nc(-c3ccccc3)n2)cc1 ; c1ccc(-c2cc(-c3ccccc3)nc(-c3ccc(-n4c5ccccc5c5ccc(-c6ccc7c(c6)c6ccccc6n7-c6ccc7ccccc7c6)cc54)cc3)n2)cc1 ; CCC(C)c1ccc(-n2c3ccccc3c3cc(-c4ccc5c6ccccc6n(-c6ccc(-c7nc(-c8ccccc8)nc(-c8ccccc8)n7)cc6)c5c4)ccc32)cc1]

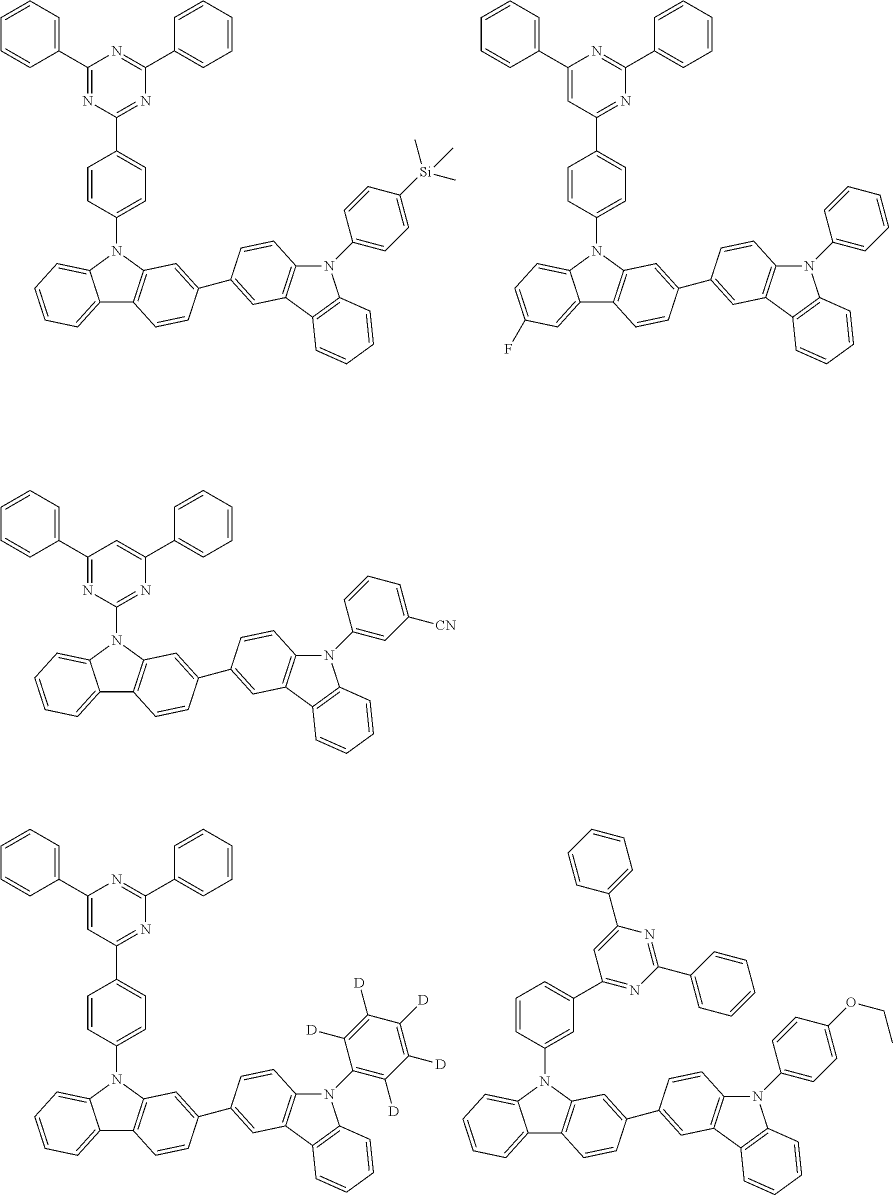

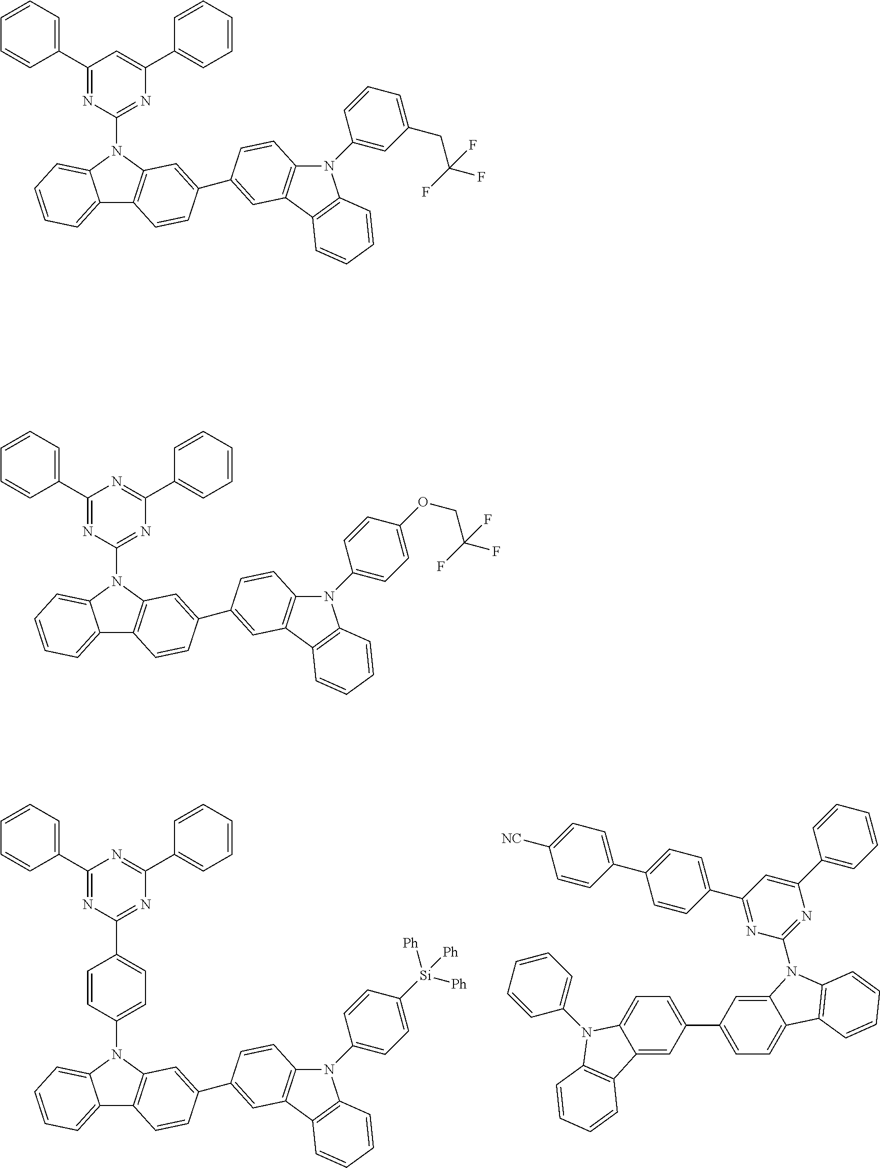 [SMILES: FC(F)(F)Cc1cccc(-n2c3ccccc3c3cc(-c4ccc5c6ccccc6n(-c6nc(-c7ccccc7)cc(-c7ccccc7)n6)c5c4)ccc32)c1 ; FC(F)(F)COc1ccc(-n2c3ccccc3c3cc(-c4ccc5c6ccccc6n(-c6nc(-c7ccccc7)nc(-c7ccccc7)n6)c5c4)ccc32)cc1 ; c1ccc(-c2nc(-c3ccccc3)nc(-c3ccc(-n4c5ccccc5c5ccc(-c6ccc7c(c6)c6ccccc6n7-c6ccc([Si](c7ccccc7)(c7ccccc7)c7ccccc7)cc6)cc54)cc3)n2)cc1 ; N#Cc1ccc(-c2ccc(-c3cc(-c4ccccc4)nc(-n4c5ccccc5c5ccc(-c6ccc7c(c6)c6ccccc6n7-c6ccccc6)cc54)n3)cc2)cc1]

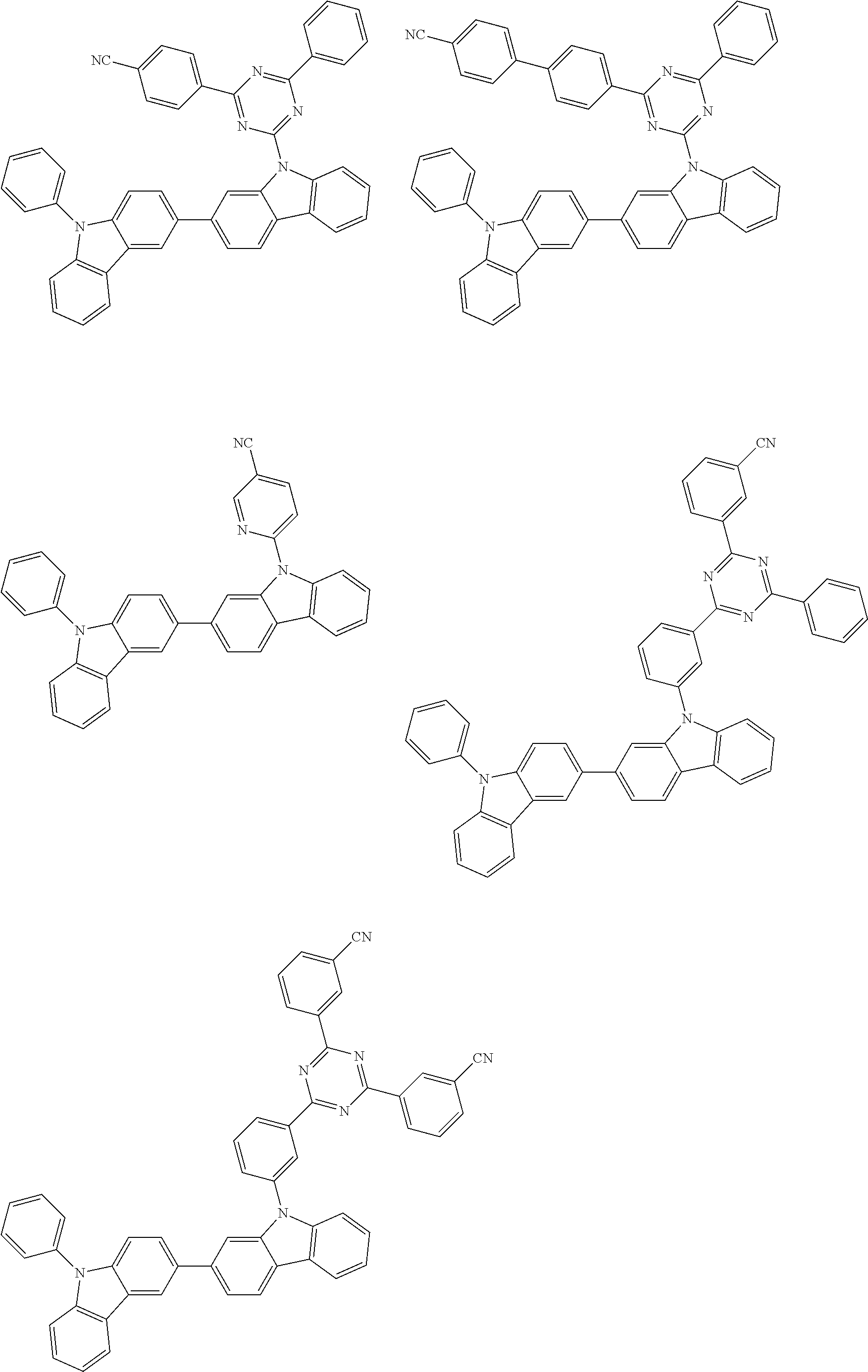

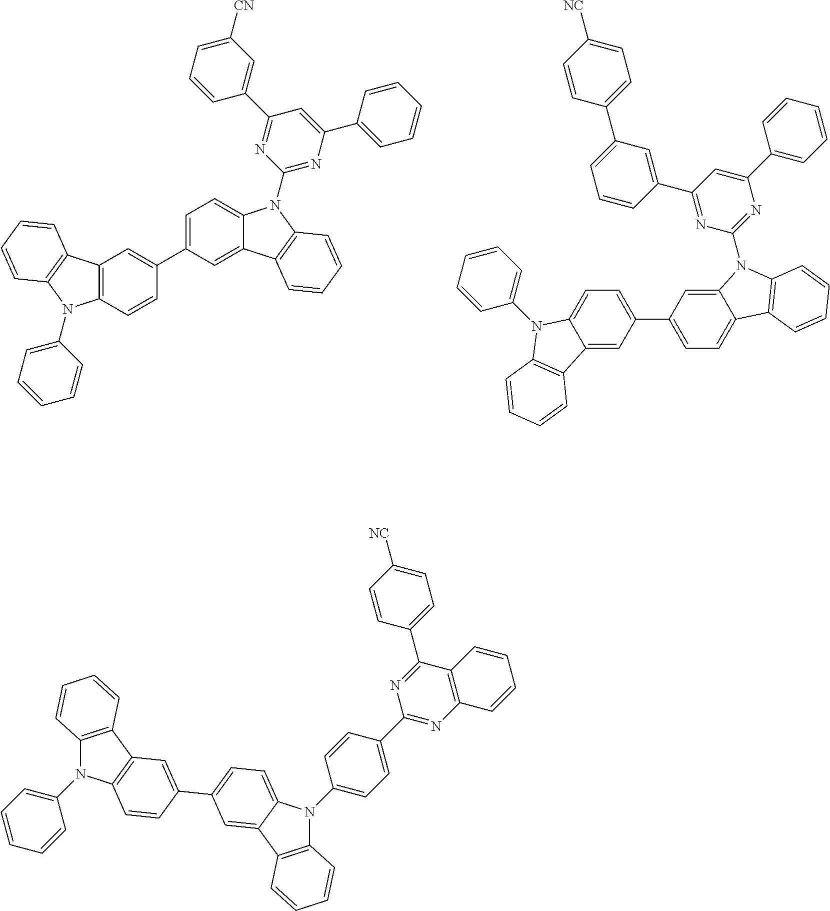 [SMILES: N#Cc1cccc(-c2cc(-c3ccccc3)nc(-n3c4ccccc4c4cc(-c5ccc6c(c5)c5ccccc5n6-c5ccccc5)ccc43)n2)c1 ; N#Cc1ccc(-c2cccc(-c3cc(-c4ccccc4)nc(-n4c5ccccc5c5ccc(-c6ccc7c(c6)c6ccccc6n7-c6ccccc6)cc54)n3)c2)cc1 ; N#Cc1ccc(-c2nc(-c3ccc(-n4c5ccccc5c5cc(-c6ccc7c(c6)c6ccccc6n7-c6ccccc6)ccc54)cc3)nc3ccccc23)cc1]

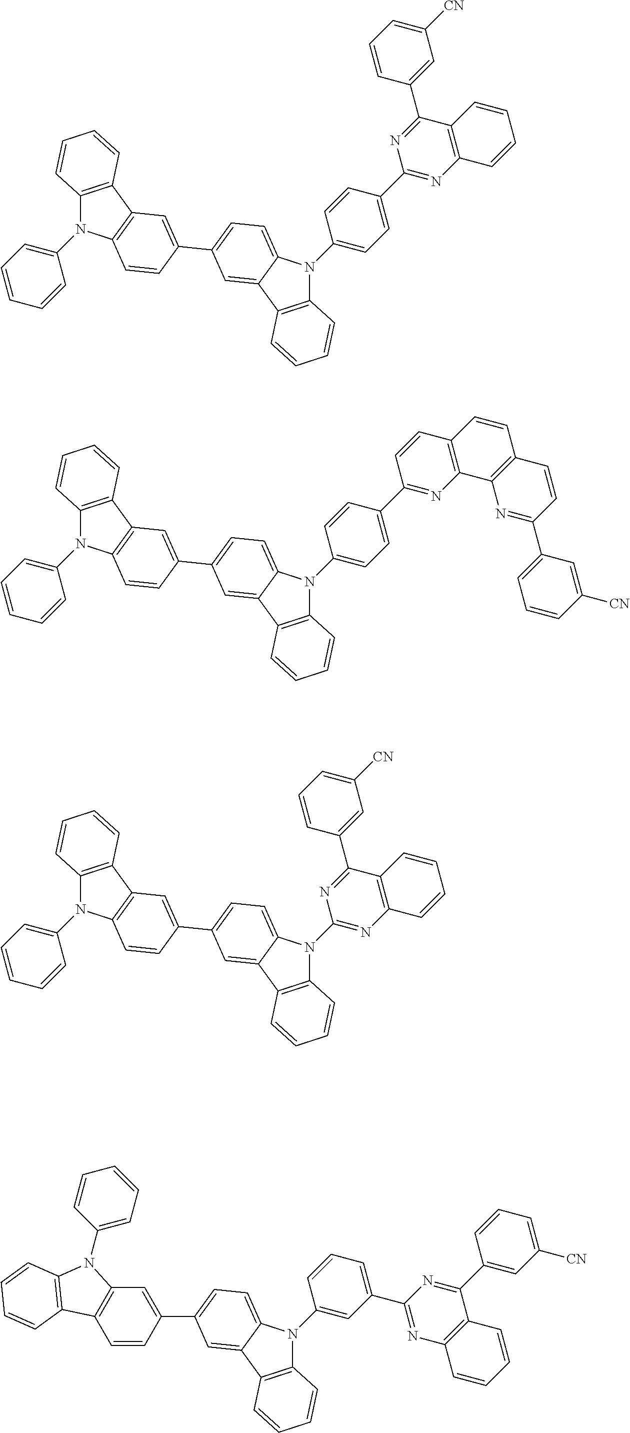 [SMILES: N#Cc1cccc(-c2nc(-c3ccc(-n4c5ccccc5c5cc(-c6ccc7c(c6)c6ccccc6n7-c6ccccc6)ccc54)cc3)nc3ccccc23)c1 ; N#Cc1cccc(-c2ccc3ccc4ccc(-c5ccc(-n6c7ccccc7c7cc(-c8ccc9c(c8)c8ccccc8n9-c8ccccc8)ccc76)cc5)nc4c3n2)c1 ; N#Cc1cccc(-c2nc(-n3c4ccccc4c4cc(-c5ccc6c(c5)c5ccccc5n6-c5ccccc5)ccc43)nc3ccccc23)c1 ; N#Cc1cccc(-c2nc(-c3cccc(-n4c5ccccc5c5cc(-c6ccc7c8ccccc8n(-c8ccccc8)c7c6)ccc54)c3)nc3ccccc23)c1]

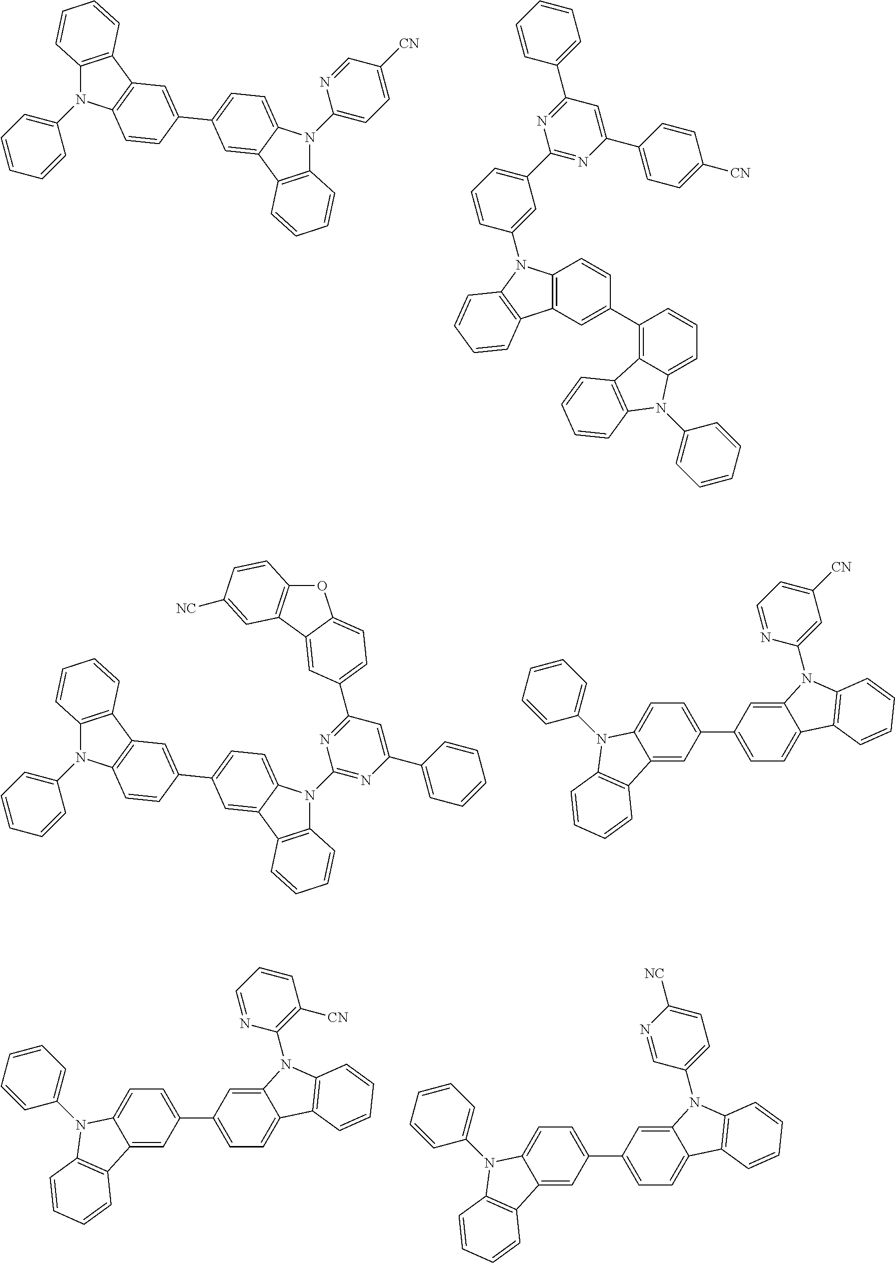

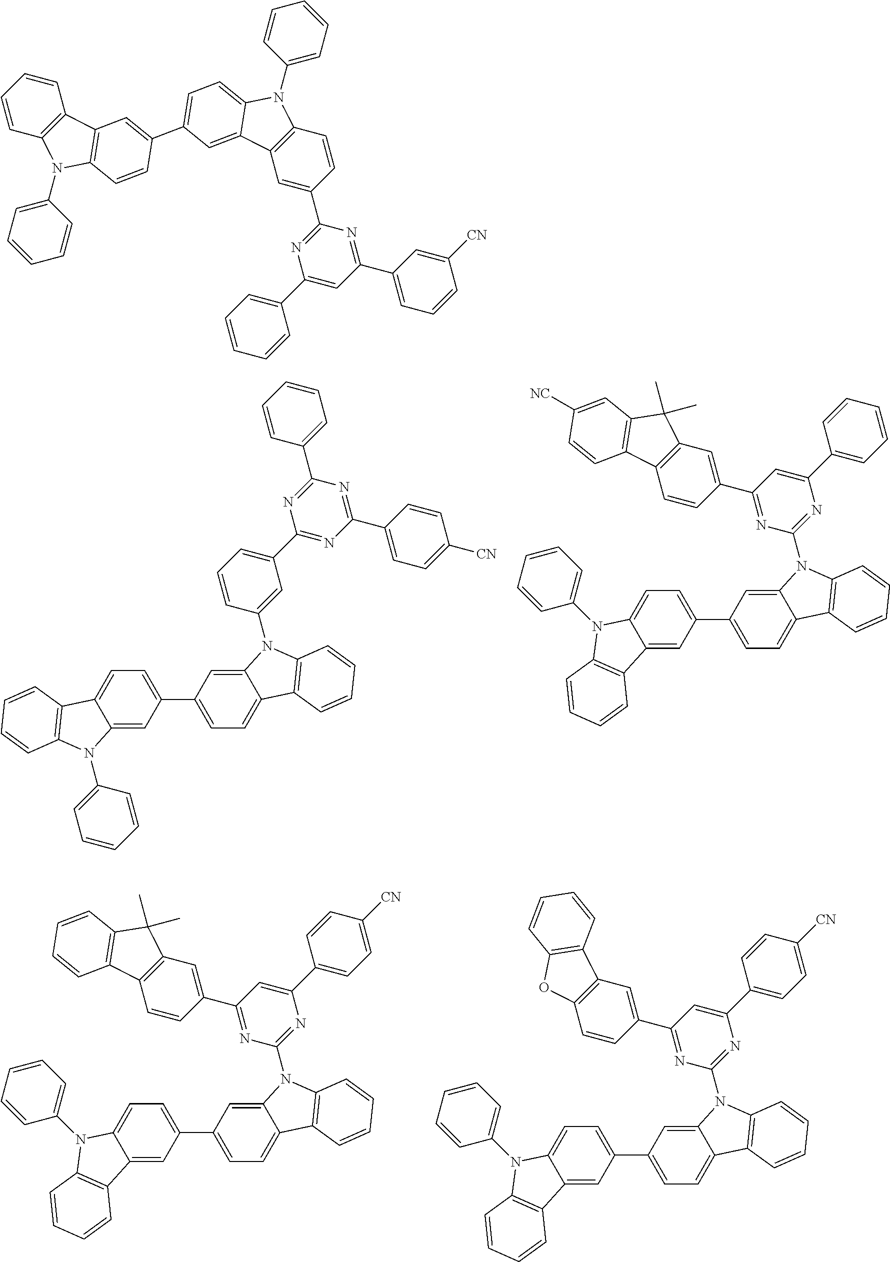

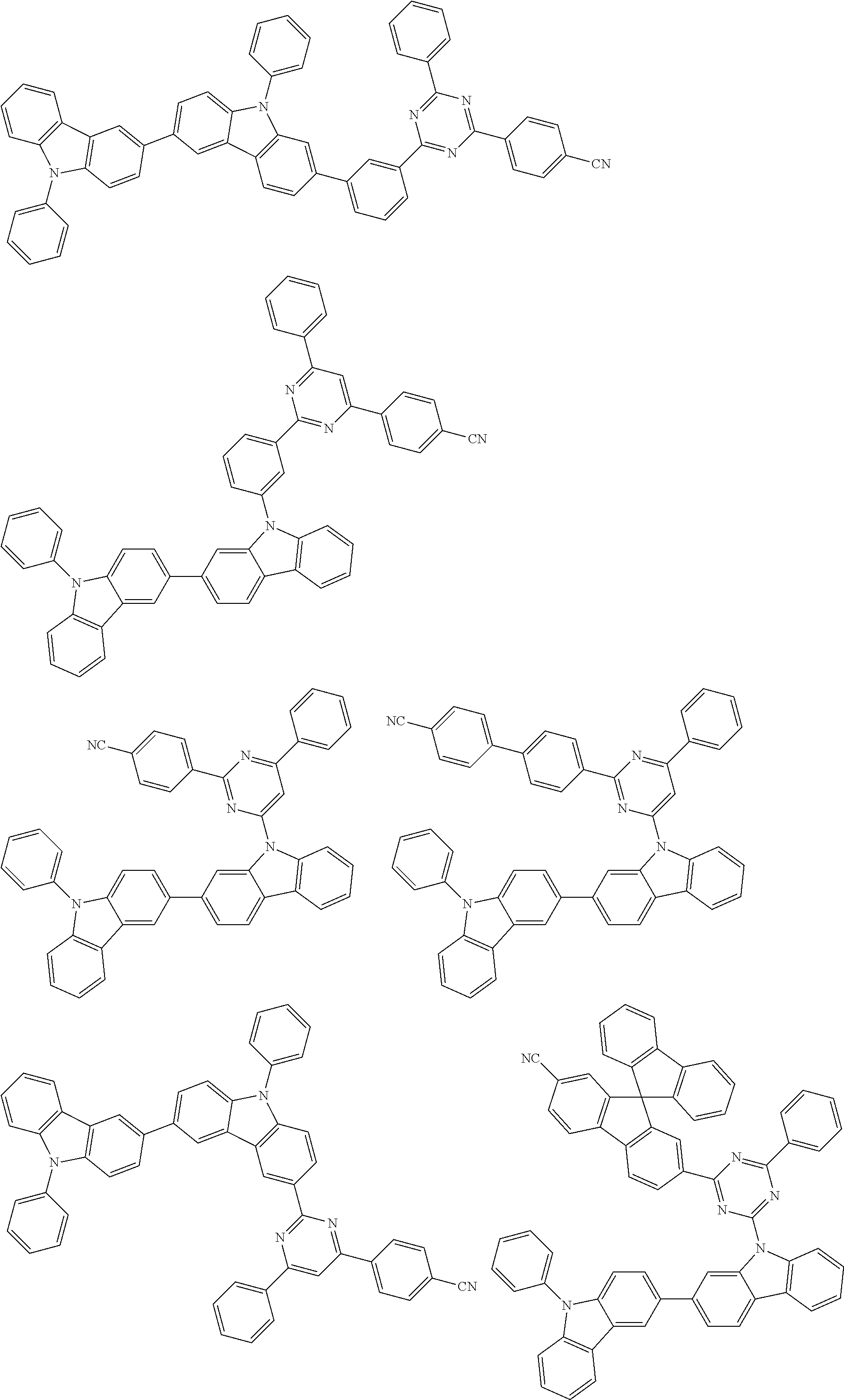

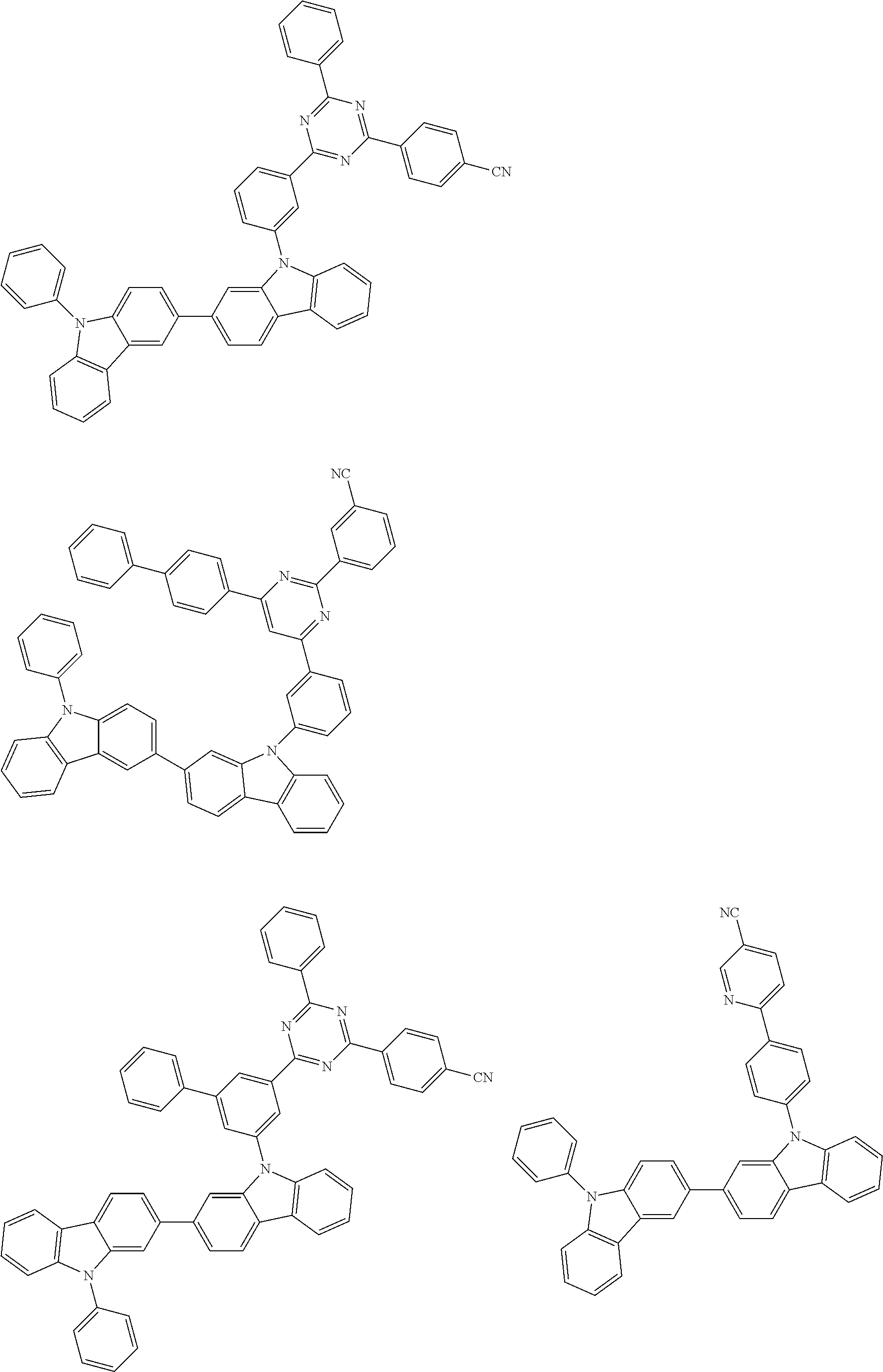 [SMILES: N#Cc1ccc(-c2nc(-c3ccccc3)nc(-c3cccc(-n4c5ccccc5c5ccc(-c6ccc7c(c6)c6ccccc6n7-c6ccccc6)cc54)c3)n2)cc1 ; N#Cc1cccc(-c2nc(-c3ccc(-c4ccccc4)cc3)cc(-c3cccc(-n4c5ccccc5c5ccc(-c6ccc7c(c6)c6ccccc6n7-c6ccccc6)cc54)c3)n2)c1 ; N#Cc1ccc(-c2nc(-c3ccccc3)nc(-c3cc(-c4ccccc4)cc(-n4c5ccccc5c5ccc(-c6ccc7c8ccccc8n(-c8ccccc8)c7c6)cc54)c3)n2)cc1 ; N#Cc1ccc(-c2ccc(-n3c4ccccc4c4ccc(-c5ccc6c(c5)c5ccccc5n6-c5ccccc5)cc43)cc2)nc1]

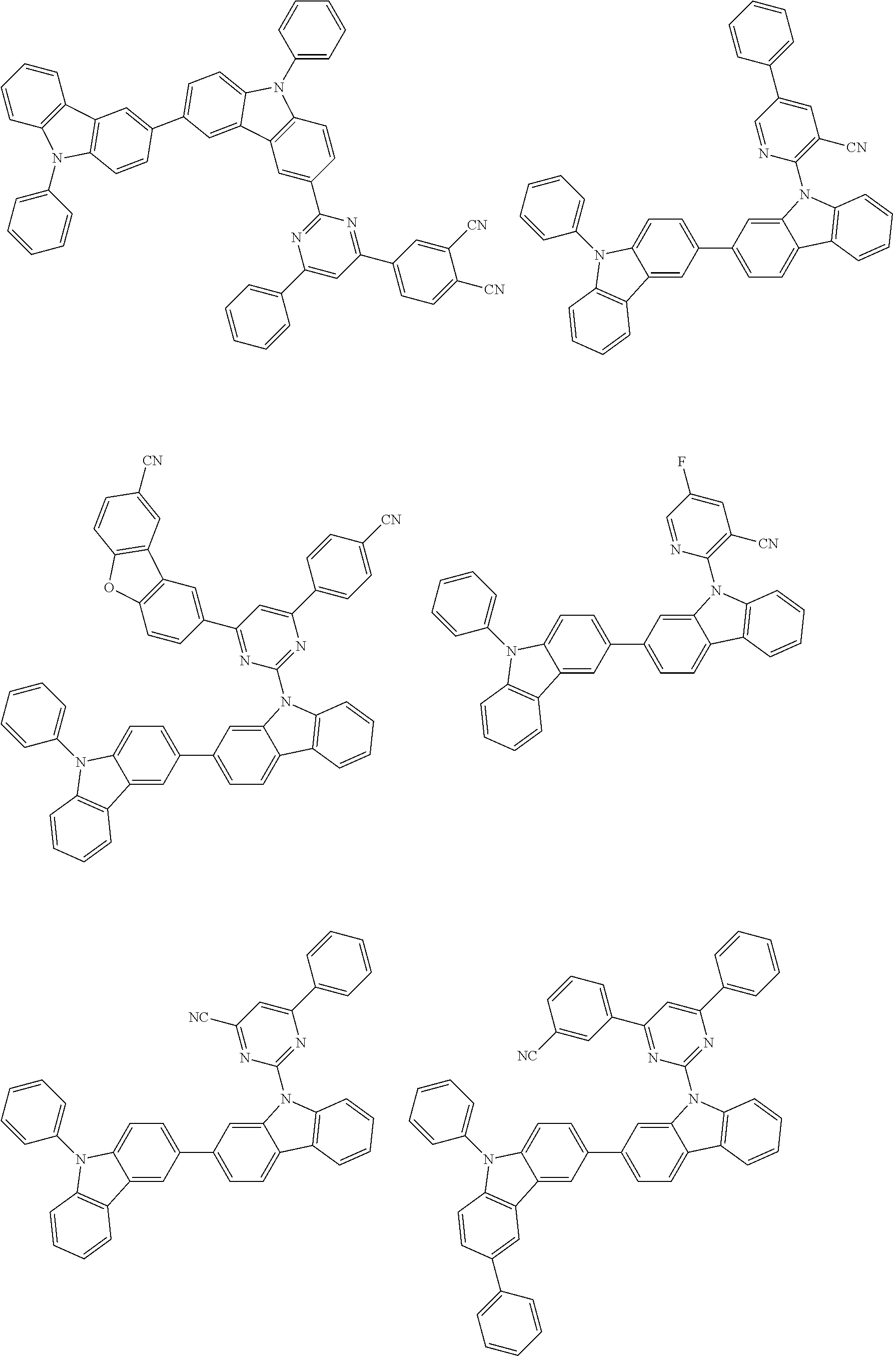

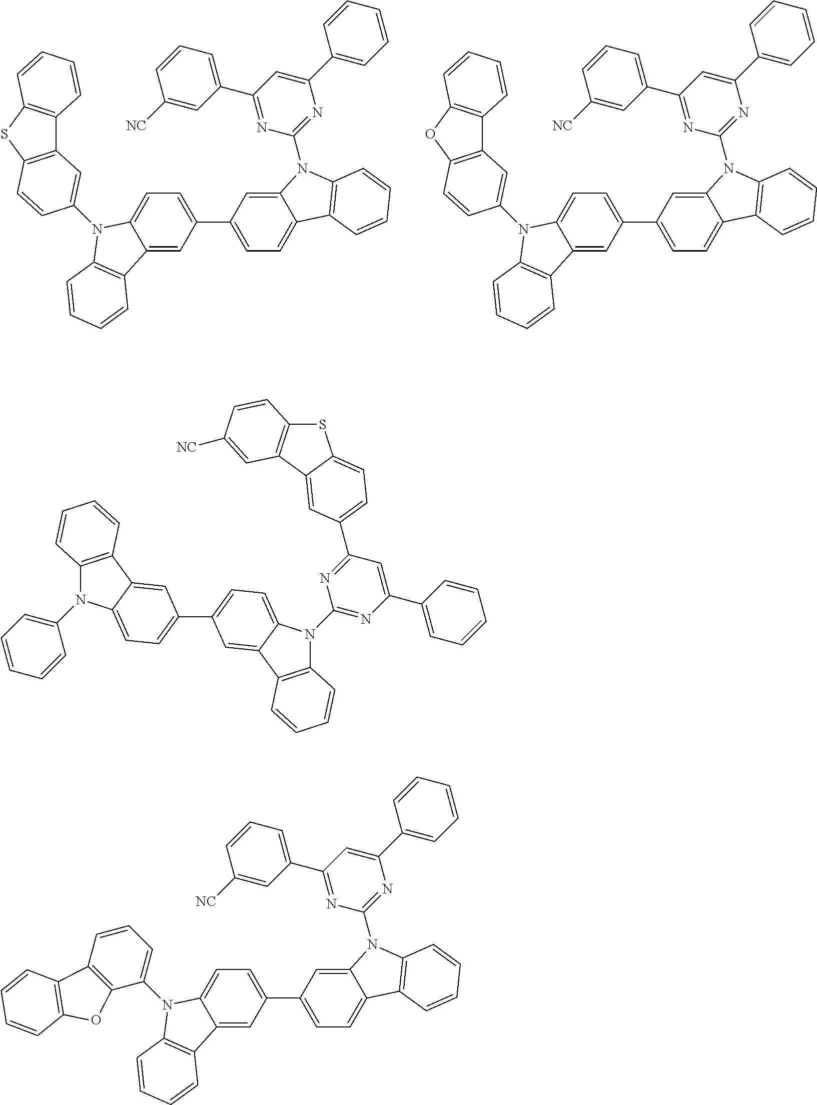 [SMILES: N#Cc1cccc(-c2cc(-c3ccccc3)nc(-n3c4ccccc4c4ccc(-c5ccc6c(c5)c5ccccc5n6-c5ccc6sc7ccccc7c6c5)cc43)n2)c1 ; N#Cc1cccc(-c2cc(-c3ccccc3)nc(-n3c4ccccc4c4ccc(-c5ccc6c(c5)c5ccccc5n6-c5ccc6oc7ccccc7c6c5)cc43)n2)c1 ; N#Cc1ccc2sc3ccc(-c4cc(-c5ccccc5)nc(-n5c6ccccc6c6cc(-c7ccc8c(c7)c7ccccc7n8-c7ccccc7)ccc65)n4)cc3c2c1 ; N#Cc1cccc(-c2cc(-c3ccccc3)nc(-n3c4ccccc4c4ccc(-c5ccc6c(c5)c5ccccc5n6-c5cccc6c5oc5ccccc56)cc43)n2)c1]

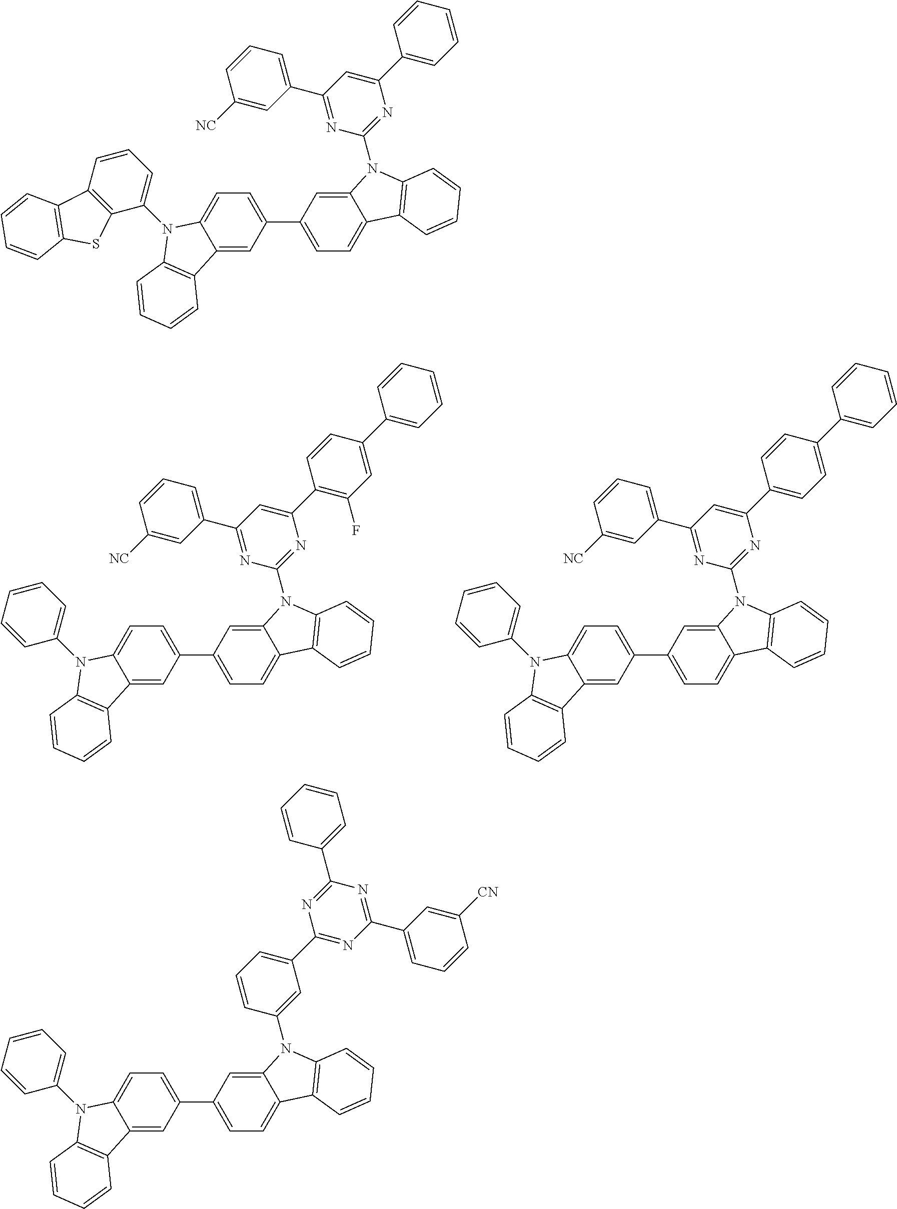 [SMILES: N#Cc1cccc(-c2cc(-c3ccccc3)nc(-n3c4ccccc4c4ccc(-c5ccc6c(c5)c5ccccc5n6-c5cccc6c5sc5ccccc56)cc43)n2)c1 ; N#Cc1cccc(-c2cc(-c3ccc(-c4ccccc4)cc3F)nc(-n3c4ccccc4c4ccc(-c5ccc6c(c5)c5ccccc5n6-c5ccccc5)cc43)n2)c1 ; N#Cc1cccc(-c2cc(-c3ccc(-c4ccccc4)cc3)nc(-n3c4ccccc4c4ccc(-c5ccc6c(c5)c5ccccc5n6-c5ccccc5)cc43)n2)c1 ; N#Cc1cccc(-c2nc(-c3ccccc3)nc(-c3cccc(-n4c5ccccc5c5ccc(-c6ccc7c(c6)c6ccccc6n7-c6ccccc6)cc54)c3)n2)c1]

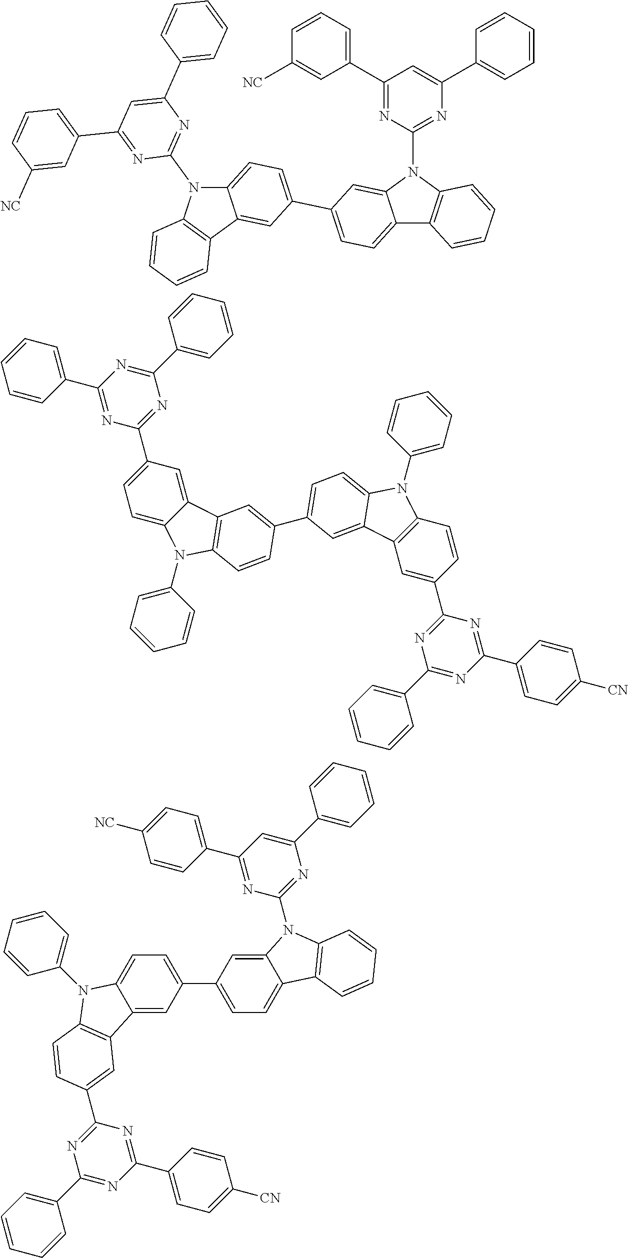

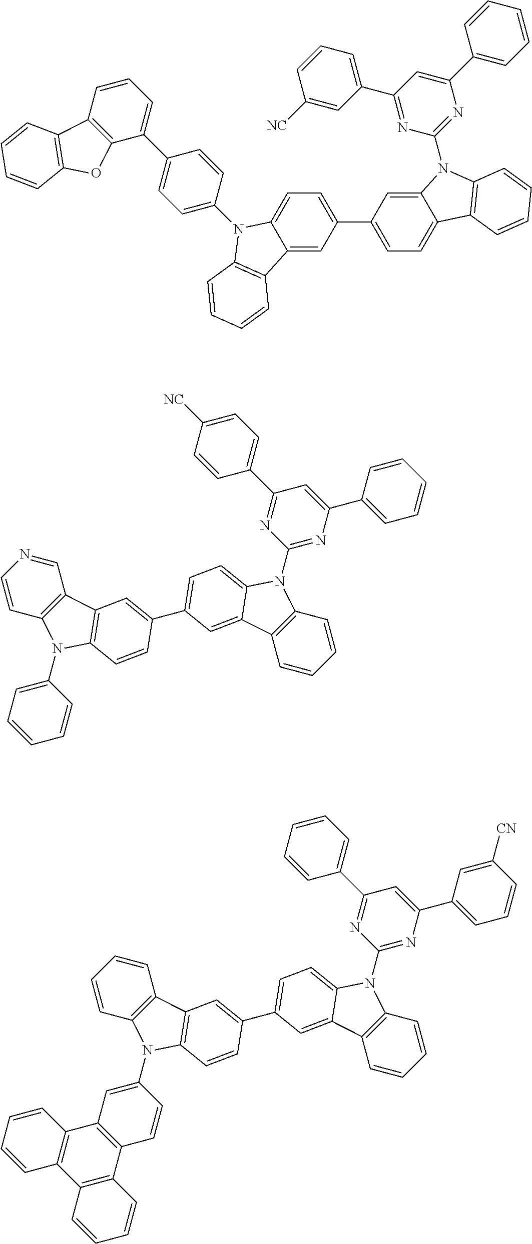 [SMILES: N#Cc1cccc(-c2cc(-c3ccccc3)nc(-n3c4ccccc4c4ccc(-c5ccc6c(c5)c5ccccc5n6-c5ccc(-c6cccc7c6oc6ccccc67)cc5)cc43)n2)c1 ; N#Cc1ccc(-c2cc(-c3ccccc3)nc(-n3c4ccccc4c4cc(-c5ccc6c(c5)c5cnccc5n6-c5ccccc5)ccc43)n2)cc1 ; N#Cc1cccc(-c2cc(-c3ccccc3)nc(-n3c4ccccc4c4cc(-c5ccc6c(c5)c5ccccc5n6-c5ccc6c7ccccc7c7ccccc7c6c5)ccc43)n2)c1]

Specific examples of the aromatic heterocyclic derivative B are shown below.

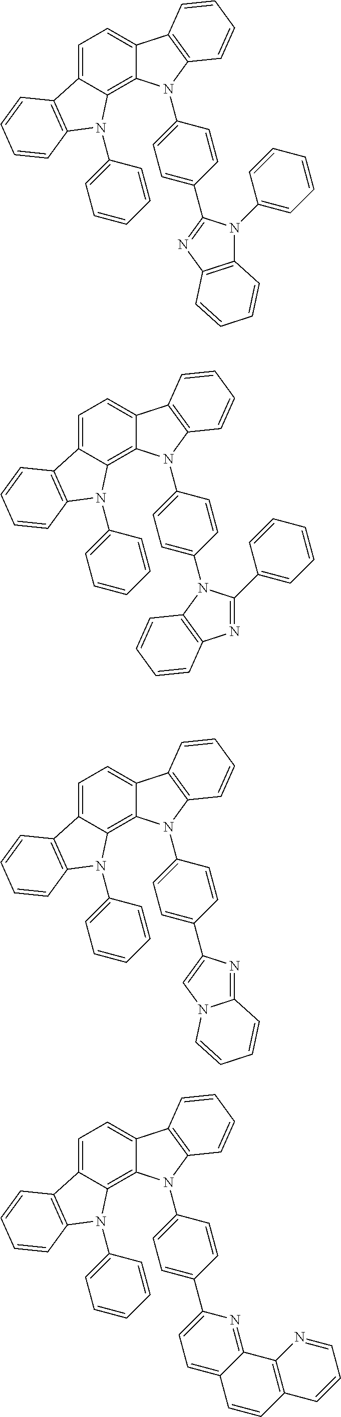

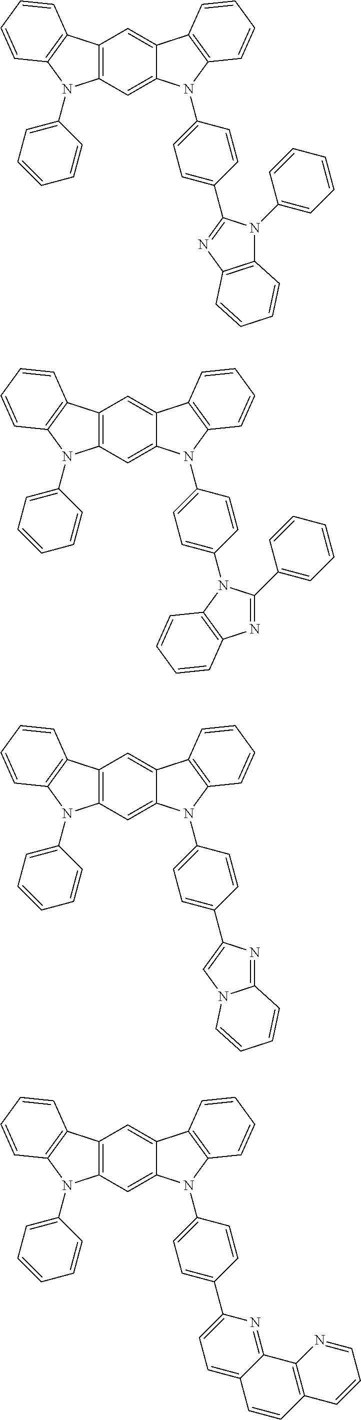

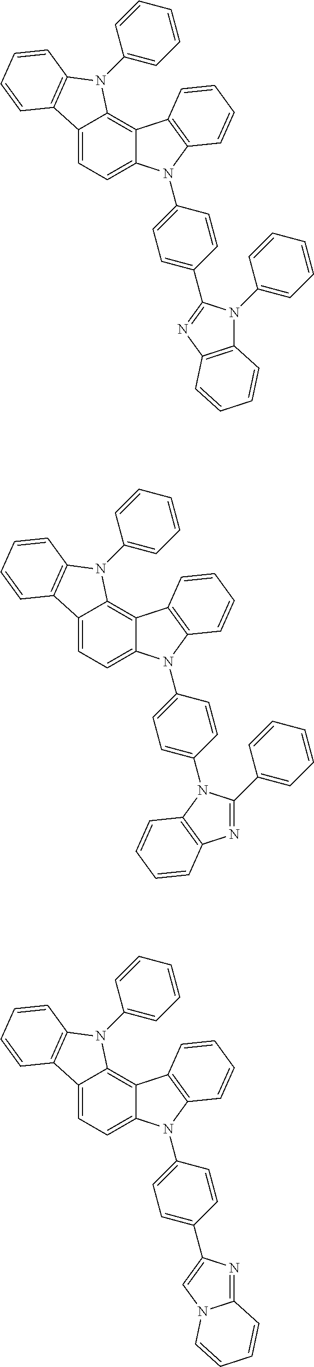 [SMILES: c1ccc(-n2c(-c3ccc(-n4c5ccccc5c5c4ccc4c6ccccc6n(-c6ccccc6)c45)cc3)nc3ccccc32)cc1 ; c1ccc(-c2nc3ccccc3n2-c2ccc(-n3c4ccccc4c4c3ccc3c5ccccc5n(-c5ccccc5)c34)cc2)cc1 ; c1ccc(-n2c3ccccc3c3ccc4c(c5ccccc5n4-c4ccc(-c5cn6ccccc6n5)cc4)c32)cc1]

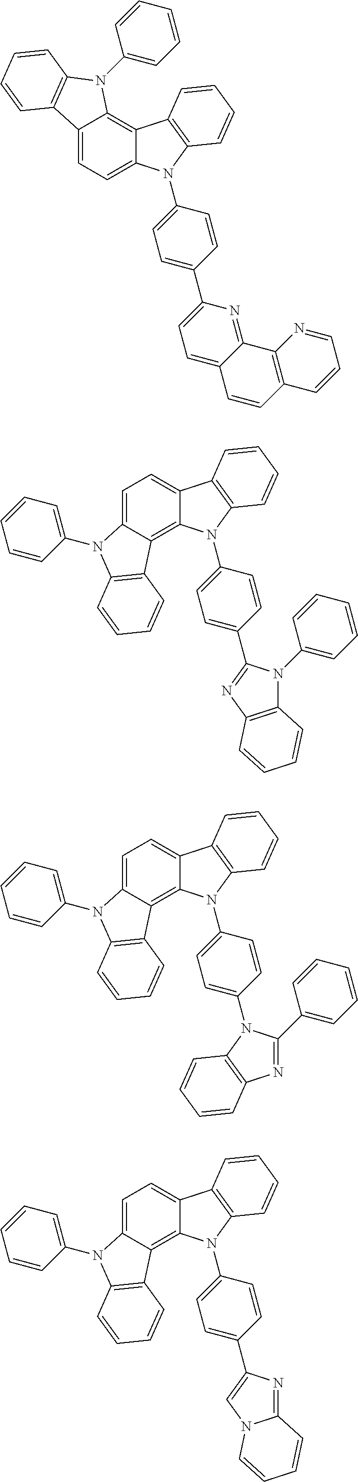

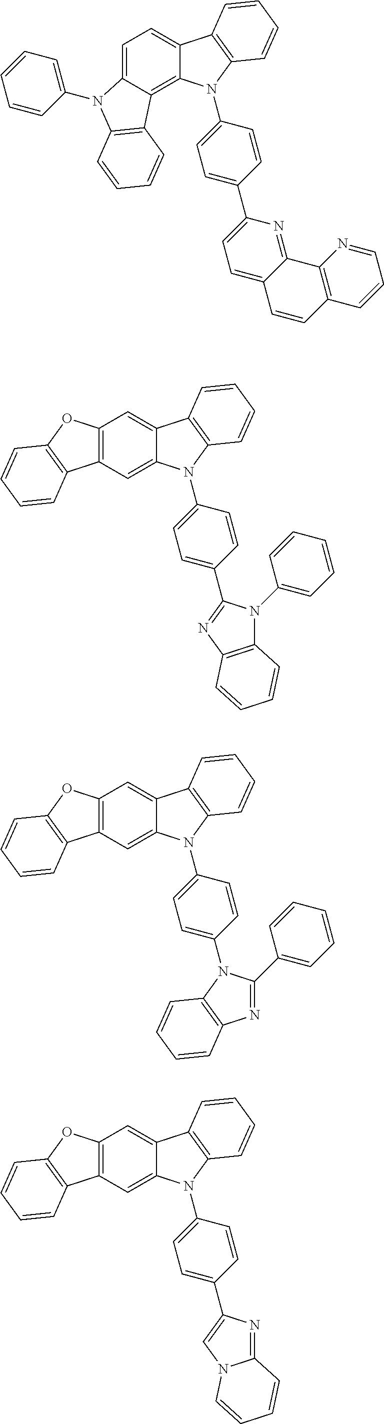

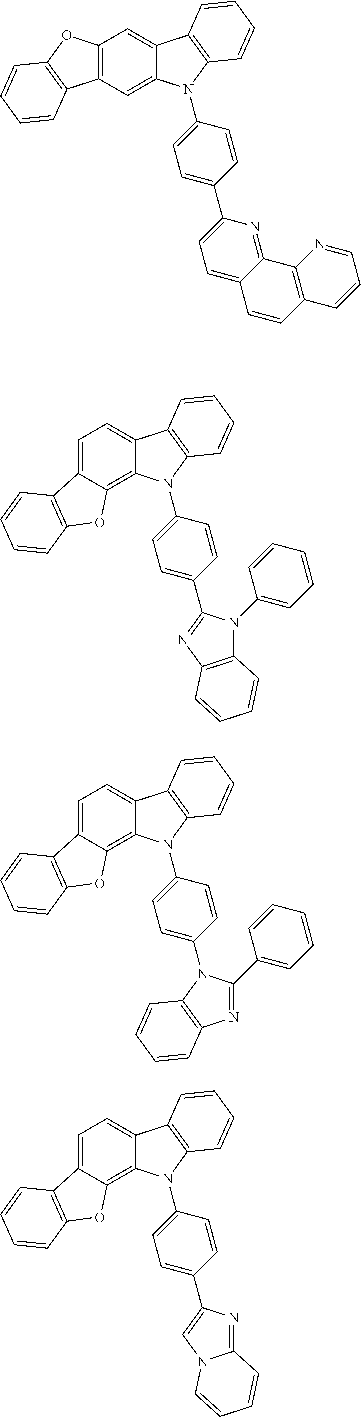

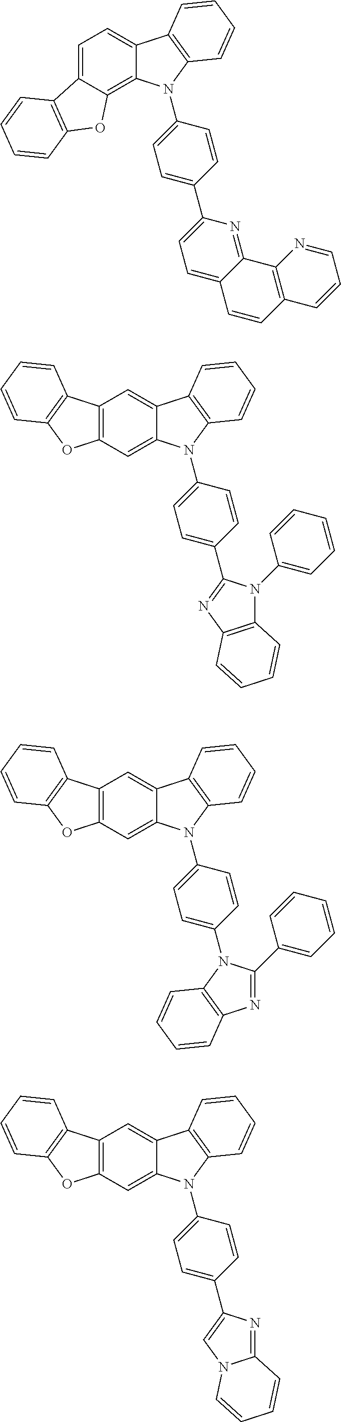 [SMILES: c1cnc2c(c1)ccc1ccc(-c3ccc(-n4c5ccccc5c5ccc6c7ccccc7oc6c54)cc3)nc12 ; c1ccc(-n2c(-c3ccc(-n4c5ccccc5c5cc6c(cc54)oc4ccccc46)cc3)nc3ccccc32)cc1 ; c1ccc(-c2nc3ccccc3n2-c2ccc(-n3c4ccccc4c4cc5c(cc43)oc3ccccc35)cc2)cc1 ; c1ccc2c(c1)oc1cc3c(cc12)c1ccccc1n3-c1ccc(-c2cn3ccccc3n2)cc1]

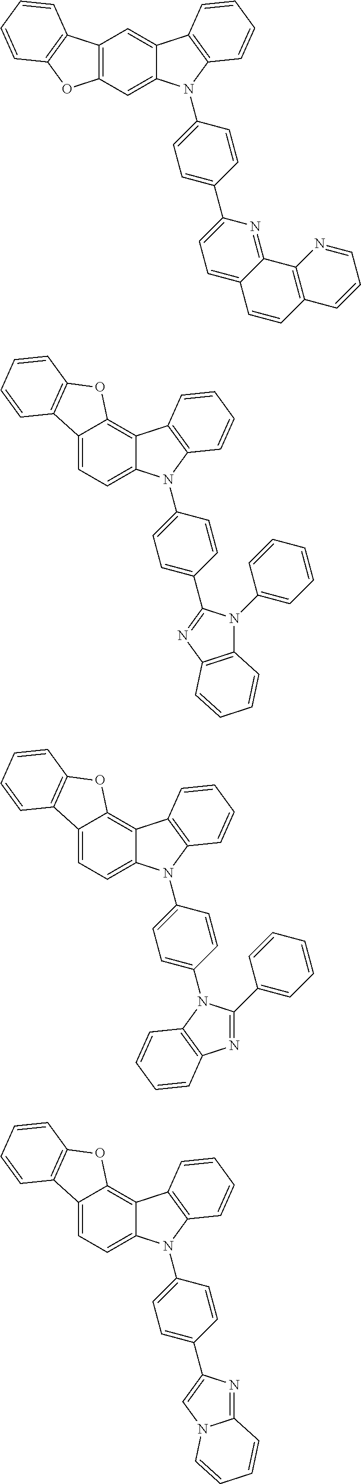 [SMILES: c1cnc2c(c1)ccc1ccc(-c3ccc(-n4c5ccccc5c5cc6c(cc54)oc4ccccc46)cc3)nc12 ; c1ccc(-n2c(-c3ccc(-n4c5ccccc5c5c6oc7ccccc7c6ccc54)cc3)nc3ccccc32)cc1 ; c1ccc(-c2nc3ccccc3n2-c2ccc(-n3c4ccccc4c4c5oc6ccccc6c5ccc43)cc2)cc1 ; c1ccc2c(c1)oc1c2ccc2c1c1ccccc1n2-c1ccc(-c2cn3ccccc3n2)cc1]

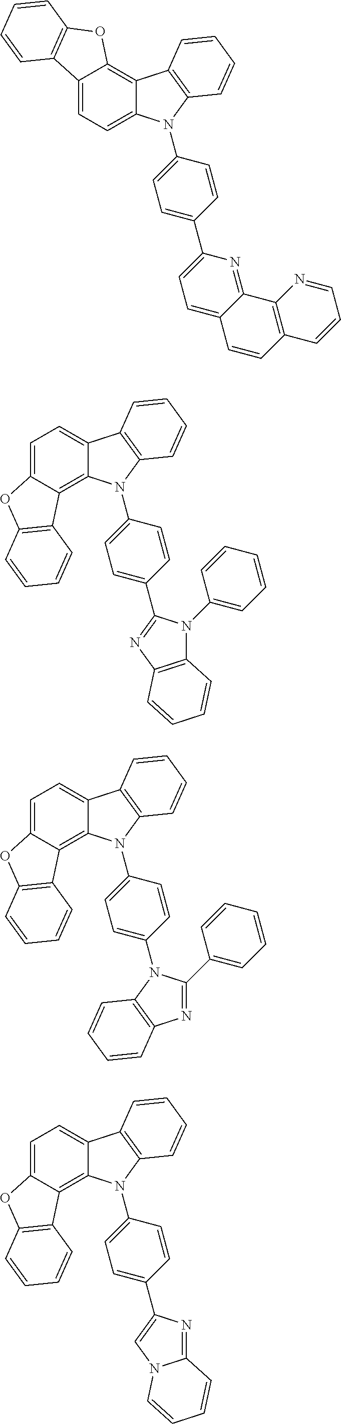

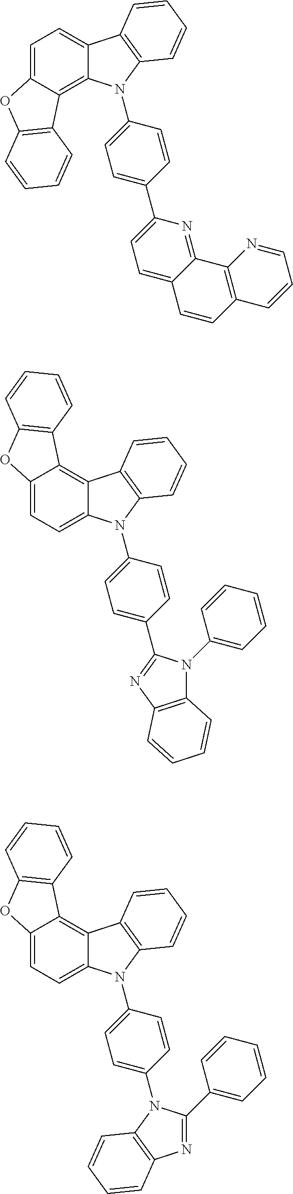 [SMILES: c1cnc2c(c1)ccc1ccc(-c3ccc(-n4c5ccccc5c5ccc6oc7ccccc7c6c54)cc3)nc12 ; c1ccc(-n2c(-c3ccc(-n4c5ccccc5c5c6c(ccc54)oc4ccccc46)cc3)nc3ccccc32)cc1 ; c1ccc(-c2nc3ccccc3n2-c2ccc(-n3c4ccccc4c4c5c(ccc43)oc3ccccc35)cc2)cc1]

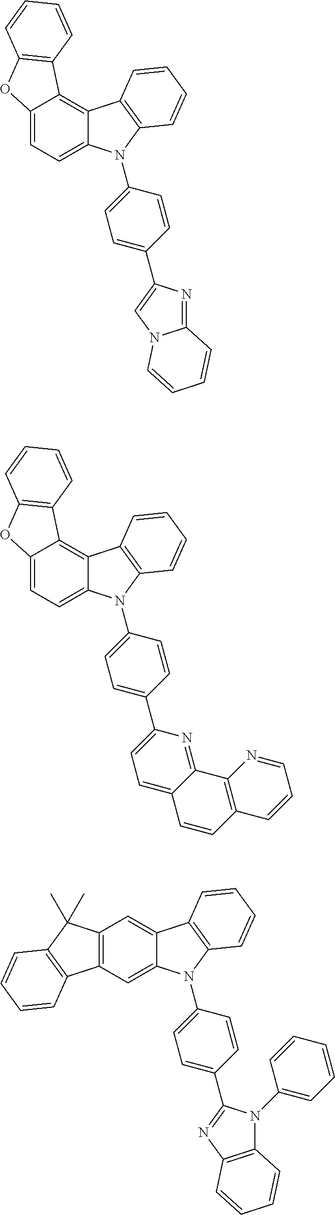 [SMILES: c1ccc2c(c1)oc1ccc3c(c4ccccc4n3-c3ccc(-c4cn5ccccc5n4)cc3)c12 ; c1cnc2c(c1)ccc1ccc(-c3ccc(-n4c5ccccc5c5c6c(ccc54)oc4ccccc46)cc3)nc12 ; CC1(C)c2ccccc2-c2cc3c(cc21)c1ccccc1n3-c1ccc(-c2nc3ccccc3n2-c2ccccc2)cc1]

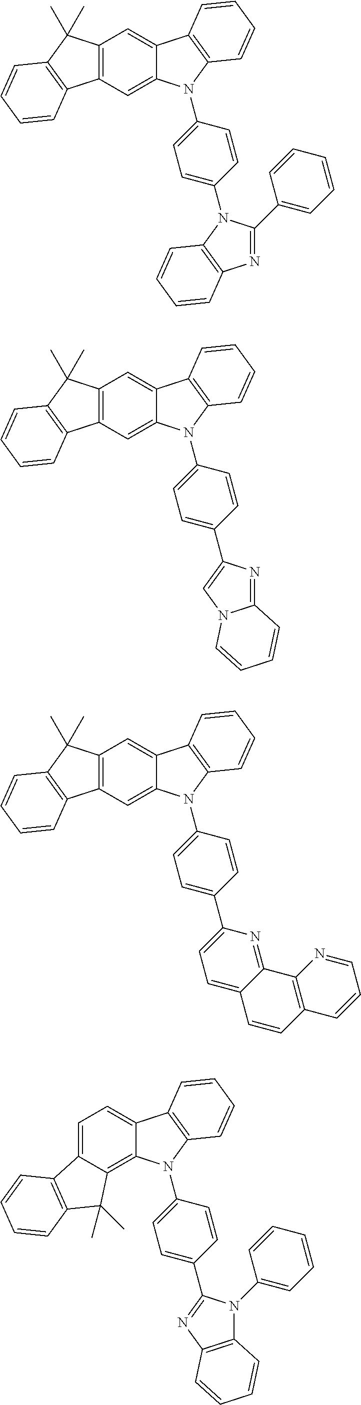

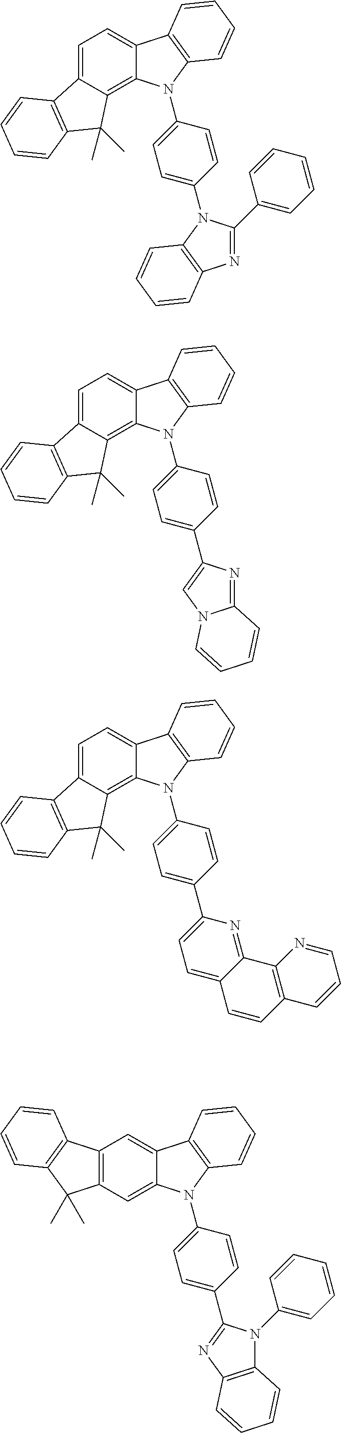

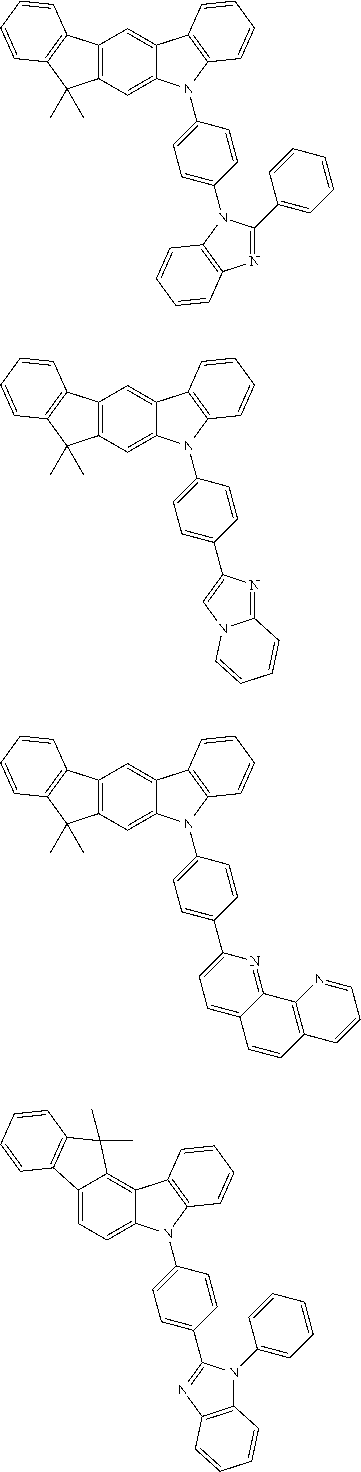 [SMILES: CC1(C)c2ccccc2-c2cc3c4ccccc4n(-c4ccc(-n5c(-c6ccccc6)nc6ccccc65)cc4)c3cc21 ; CC1(C)c2ccccc2-c2cc3c4ccccc4n(-c4ccc(-c5cn6ccccc6n5)cc4)c3cc21 ; CC1(C)c2ccccc2-c2cc3c4ccccc4n(-c4ccc(-c5ccc6ccc7cccnc7c6n5)cc4)c3cc21 ; CC1(C)c2ccccc2-c2ccc3c(c21)c1ccccc1n3-c1ccc(-c2nc3ccccc3n2-c2ccccc2)cc1]

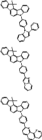 [SMILES: CC1(C)c2ccccc2-c2ccc3c(c21)c1ccccc1n3-c1ccc(-n2c(-c3ccccc3)nc3ccccc32)cc1 ; CC1(C)c2ccccc2-c2ccc3c(c21)c1ccccc1n3-c1ccc(-c2cn3ccccc3n2)cc1 ; CC1(C)c2ccccc2-c2ccc3c(c21)c1ccccc1n3-c1ccc(-c2ccc3ccc4cccnc4c3n2)cc1]

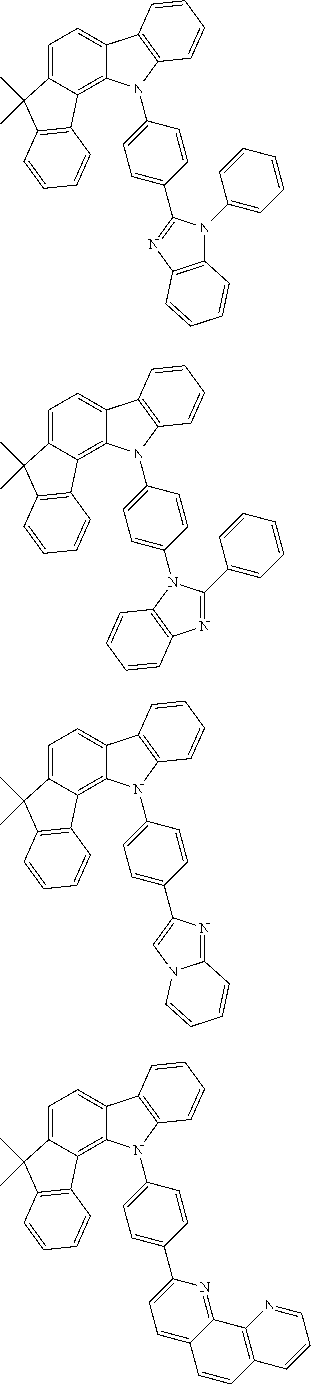

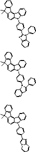 [SMILES: CC1(C)c2ccccc2-c2c1ccc1c2c2ccccc2n1-c1ccc(-c2nc3ccccc3n2-c2ccccc2)cc1 ; CC1(C)c2ccccc2-c2c1ccc1c2c2ccccc2n1-c1ccc(-n2c(-c3ccccc3)nc3ccccc32)cc1 ; CC1(C)c2ccccc2-c2c1ccc1c2c2ccccc2n1-c1ccc(-c2cn3ccccc3n2)cc1]

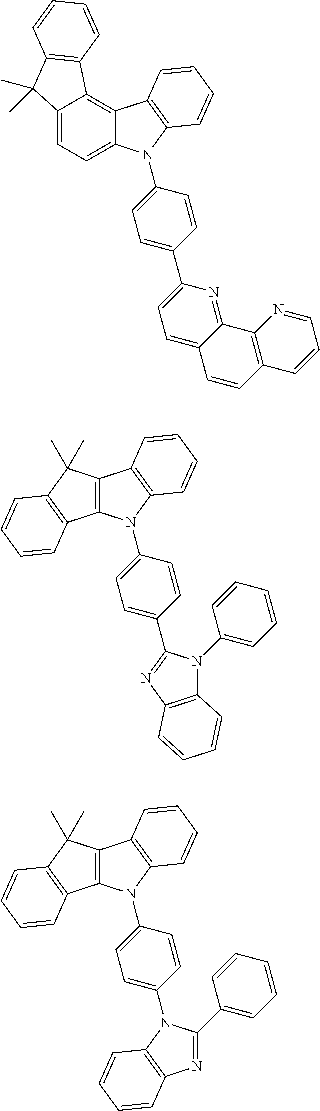

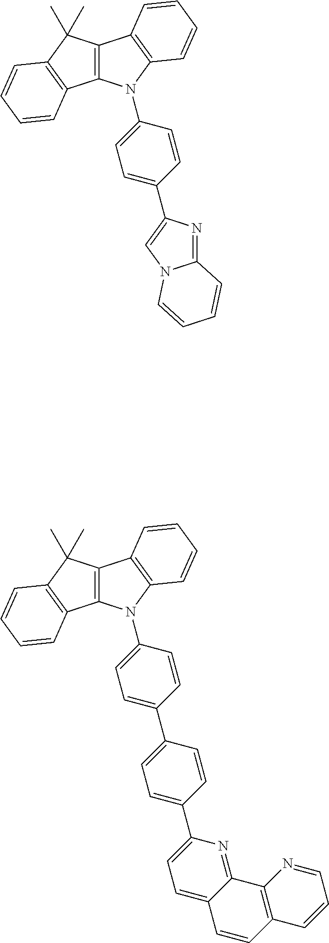 [SMILES: CC1(C)c2ccccc2-c2c1c1ccccc1n2-c1ccc(-c2cn3ccccc3n2)cc1 ; CC1(C)c2ccccc2-c2c1c1ccccc1n2-c1ccc(-c2ccc(-c3ccc4ccc5cccnc5c4n3)cc2)cc1]

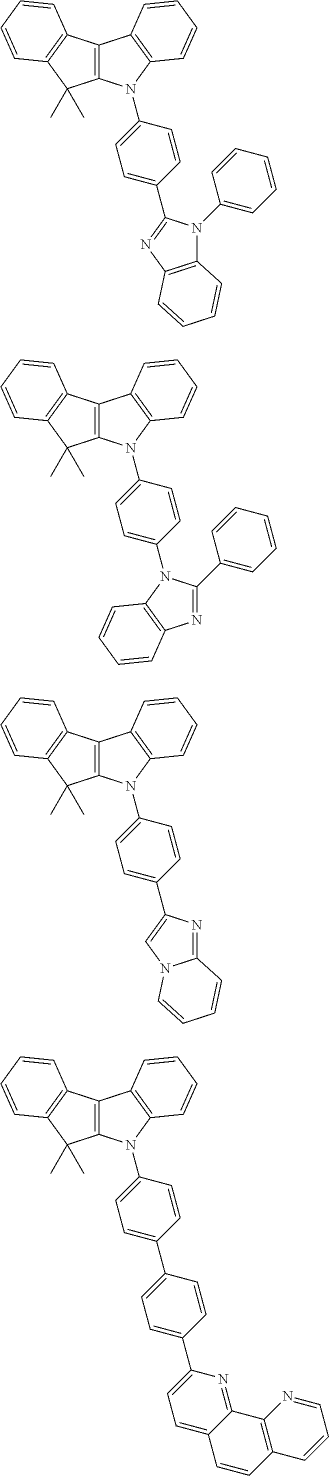

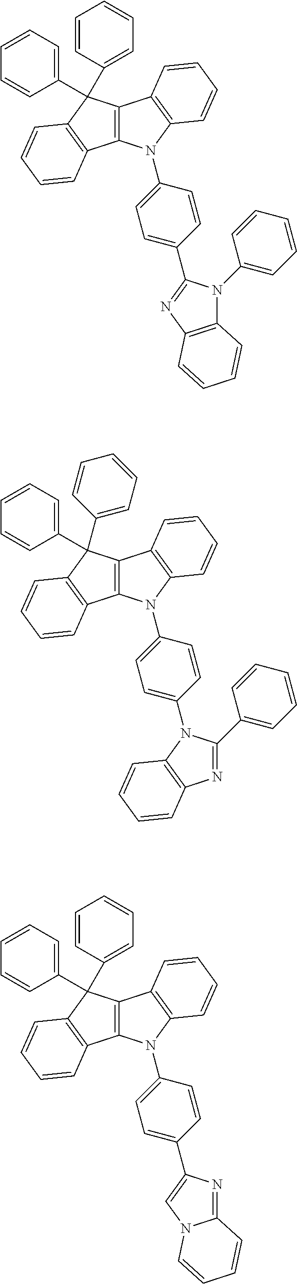 [SMILES: c1ccc(-n2c(-c3ccc(-n4c5c(c6ccccc64)C(c4ccccc4)(c4ccccc4)c4ccccc4-5)cc3)nc3ccccc32)cc1 ; c1ccc(-c2nc3ccccc3n2-c2ccc(-n3c4c(c5ccccc53)C(c3ccccc3)(c3ccccc3)c3ccccc3-4)cc2)cc1 ; c1ccc(C2(c3ccccc3)c3ccccc3-c3c2c2ccccc2n3-c2ccc(-c3cn4ccccc4n3)cc2)cc1]

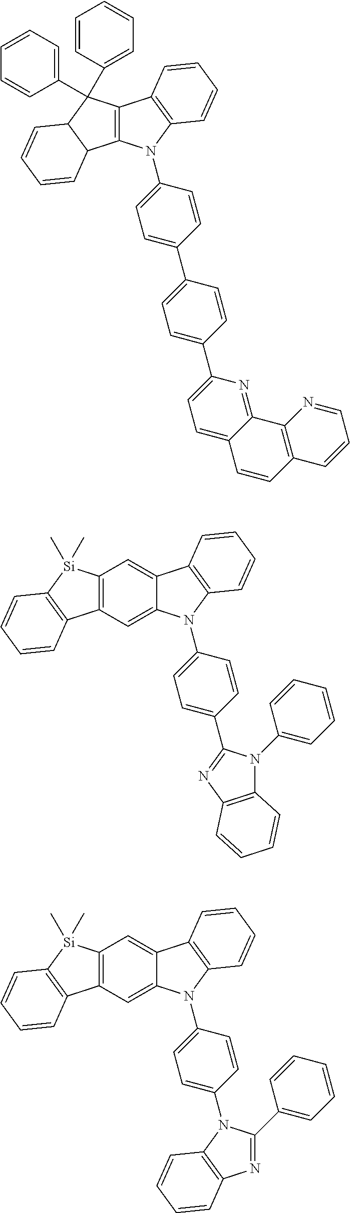 [SMILES: C1=CC2c3c(c4ccccc4n3-c3ccc(-c4ccc(-c5ccc6ccc7cccnc7c6n5)cc4)cc3)C(c3ccccc3)(c3ccccc3)C2C=C1 ; C[Si]1(C)c2ccccc2-c2cc3c(cc21)c1ccccc1n3-c1ccc(-c2nc3ccccc3n2-c2ccccc2)cc1 ; C[Si]1(C)c2ccccc2-c2cc3c(cc21)c1ccccc1n3-c1ccc(-n2c(-c3ccccc3)nc3ccccc32)cc1]

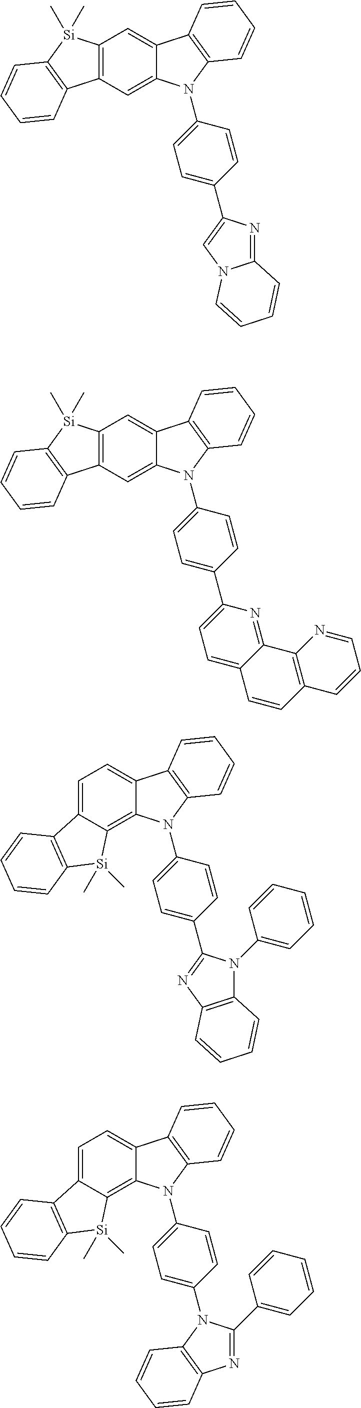

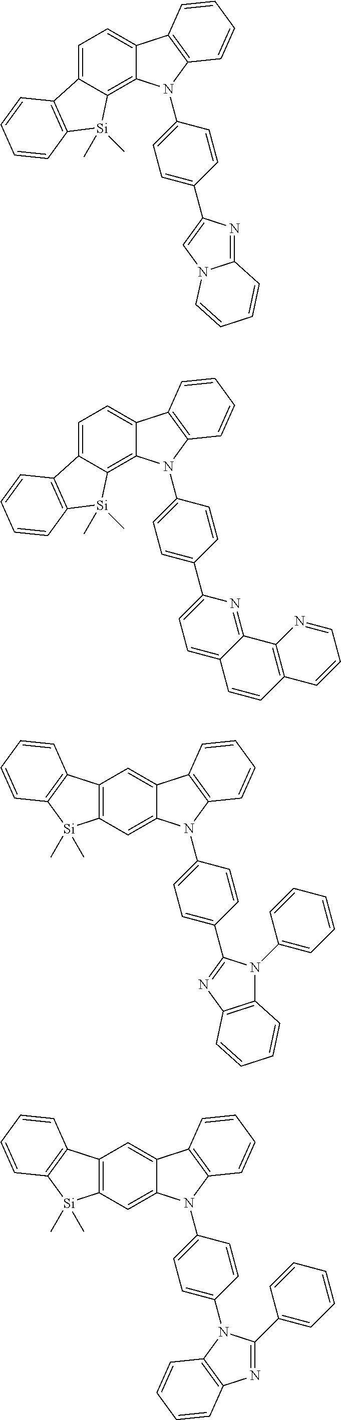 [SMILES: C[Si]1(C)c2ccccc2-c2ccc3c4ccccc4n(-c4ccc(-c5cn6ccccc6n5)cc4)c3c21 ; C[Si]1(C)c2ccccc2-c2ccc3c4ccccc4n(-c4ccc(-c5ccc6ccc7cccnc7c6n5)cc4)c3c21 ; C[Si]1(C)c2ccccc2-c2cc3c4ccccc4n(-c4ccc(-c5nc6ccccc6n5-c5ccccc5)cc4)c3cc21 ; C[Si]1(C)c2ccccc2-c2cc3c4ccccc4n(-c4ccc(-n5c(-c6ccccc6)nc6ccccc65)cc4)c3cc21]

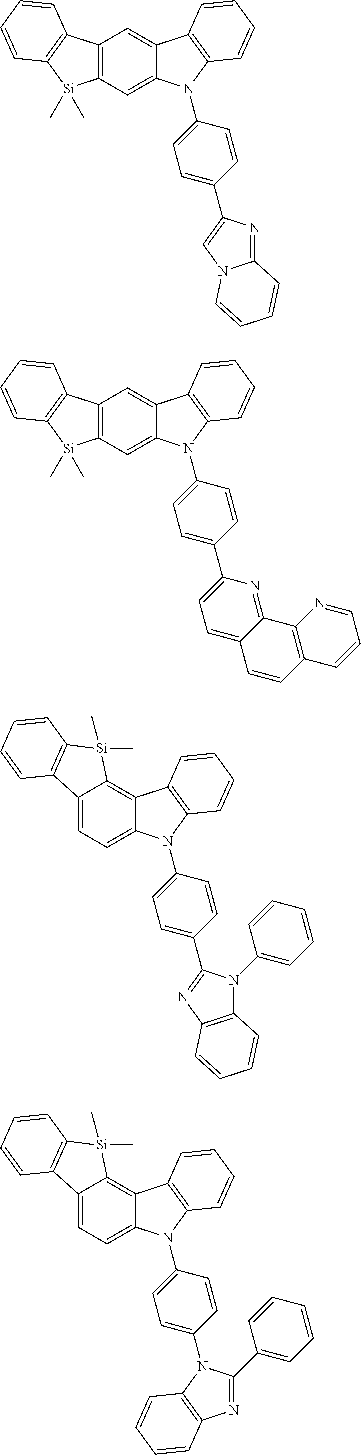

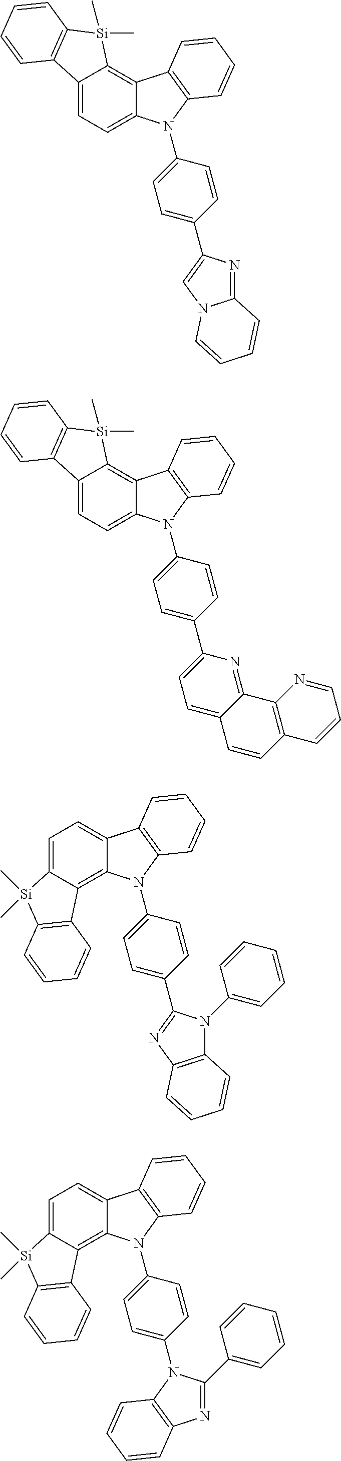

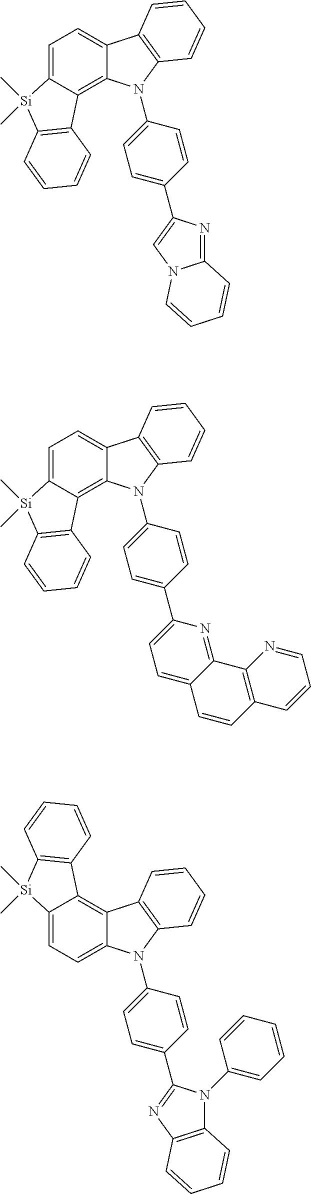 [SMILES: C[Si]1(C)c2ccccc2-c2c1ccc1c3ccccc3n(-c3ccc(-c4cn5ccccc5n4)cc3)c21 ; C[Si]1(C)c2ccccc2-c2c1ccc1c3ccccc3n(-c3ccc(-c4ccc5ccc6cccnc6c5n4)cc3)c21 ; C[Si]1(C)c2ccccc2-c2c1ccc1c2c2ccccc2n1-c1ccc(-c2nc3ccccc3n2-c2ccccc2)cc1]

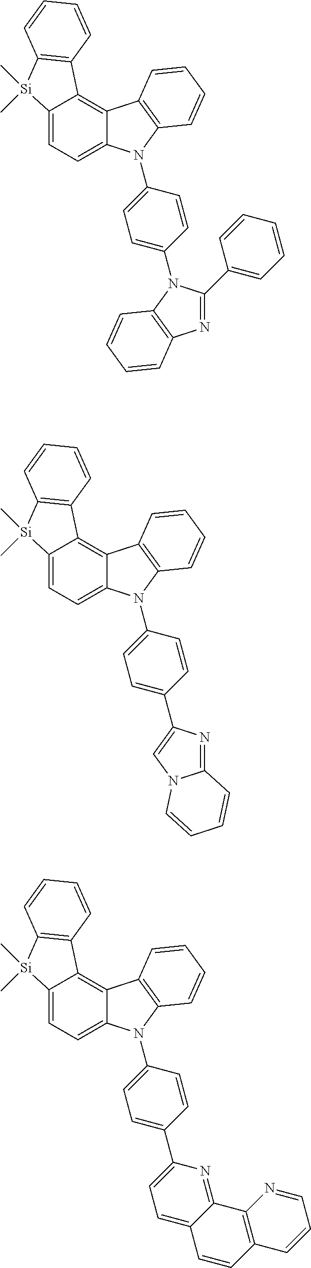 [SMILES: C[Si]1(C)c2ccccc2-c2c1ccc1c2c2ccccc2n1-c1ccc(-n2c(-c3ccccc3)nc3ccccc32)cc1 ; C[Si]1(C)c2ccccc2-c2c1ccc1c2c2ccccc2n1-c1ccc(-c2cn3ccccc3n2)cc1 ; C[Si]1(C)c2ccccc2-c2c1ccc1c2c2ccccc2n1-c1ccc(-c2ccc3ccc4cccnc4c3n2)cc1]

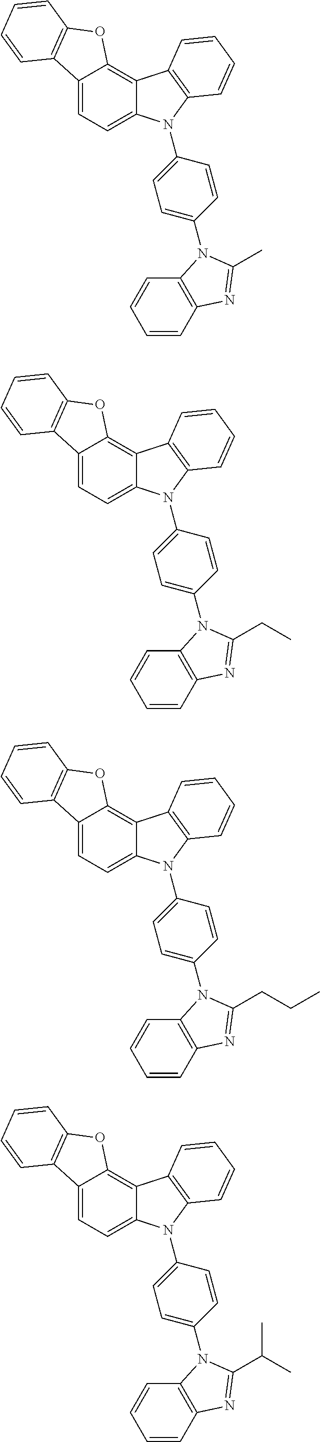 [SMILES: Cc1nc2ccccc2n1-c1ccc(-n2c3ccccc3c3c4oc5ccccc5c4ccc32)cc1 ; CCc1nc2ccccc2n1-c1ccc(-n2c3ccccc3c3c4oc5ccccc5c4ccc32)cc1 ; CCCc1nc2ccccc2n1-c1ccc(-n2c3ccccc3c3c4oc5ccccc5c4ccc32)cc1 ; CC(C)c1nc2ccccc2n1-c1ccc(-n2c3ccccc3c3c4oc5ccccc5c4ccc32)cc1]

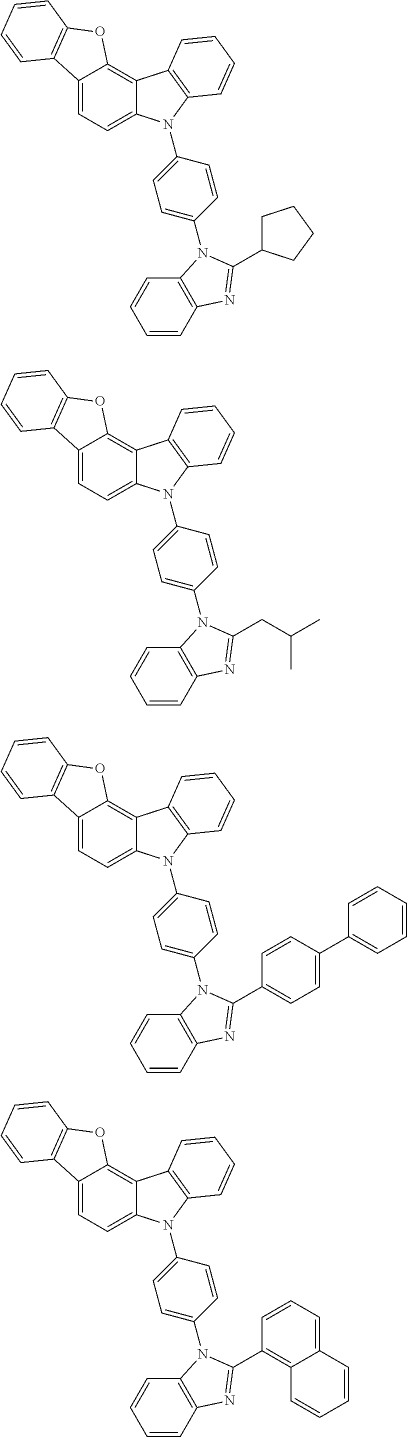 [SMILES: c1ccc2c(c1)nc(C1CCCC1)n2-c1ccc(-n2c3ccccc3c3c4oc5ccccc5c4ccc32)cc1 ; CC(C)Cc1nc2ccccc2n1-c1ccc(-n2c3ccccc3c3c4oc5ccccc5c4ccc32)cc1 ; c1ccc(-c2ccc(-c3nc4ccccc4n3-c3ccc(-n4c5ccccc5c5c6oc7ccccc7c6ccc54)cc3)cc2)cc1 ; c1ccc2c(-c3nc4ccccc4n3-c3ccc(-n4c5ccccc5c5c6oc7ccccc7c6ccc54)cc3)cccc2c1]

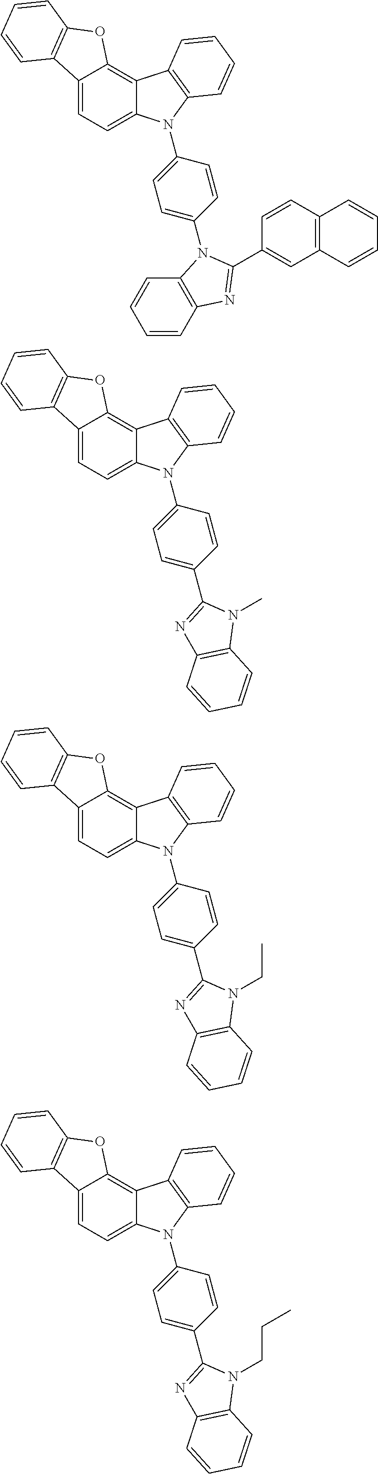 [SMILES: c1ccc2cc(-c3nc4ccccc4n3-c3ccc(-n4c5ccccc5c5c6oc7ccccc7c6ccc54)cc3)ccc2c1 ; Cn1c(-c2ccc(-n3c4ccccc4c4c5oc6ccccc6c5ccc43)cc2)nc2ccccc21 ; CCn1c(-c2ccc(-n3c4ccccc4c4c5oc6ccccc6c5ccc43)cc2)nc2ccccc21 ; CCCn1c(-c2ccc(-n3c4ccccc4c4c5oc6ccccc6c5ccc43)cc2)nc2ccccc21]

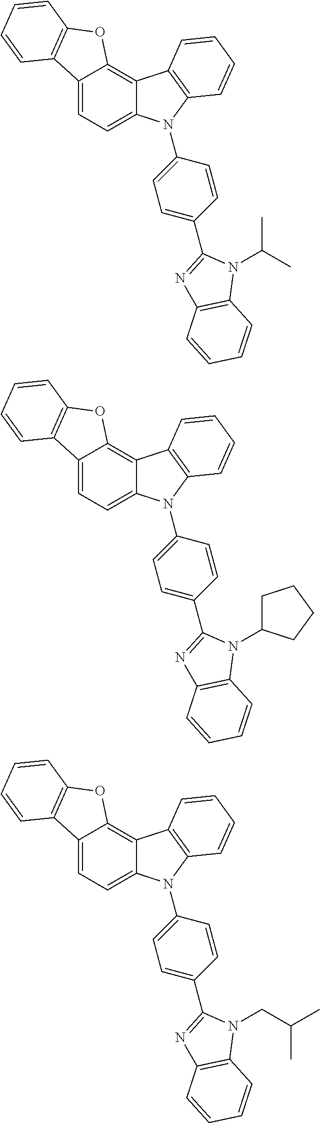 [SMILES: CC(C)n1c(-c2ccc(-n3c4ccccc4c4c5oc6ccccc6c5ccc43)cc2)nc2ccccc21 ; c1ccc2c(c1)nc(-c1ccc(-n3c4ccccc4c4c5oc6ccccc6c5ccc43)cc1)n2C1CCCC1 ; CC(C)Cn1c(-c2ccc(-n3c4ccccc4c4c5oc6ccccc6c5ccc43)cc2)nc2ccccc21]

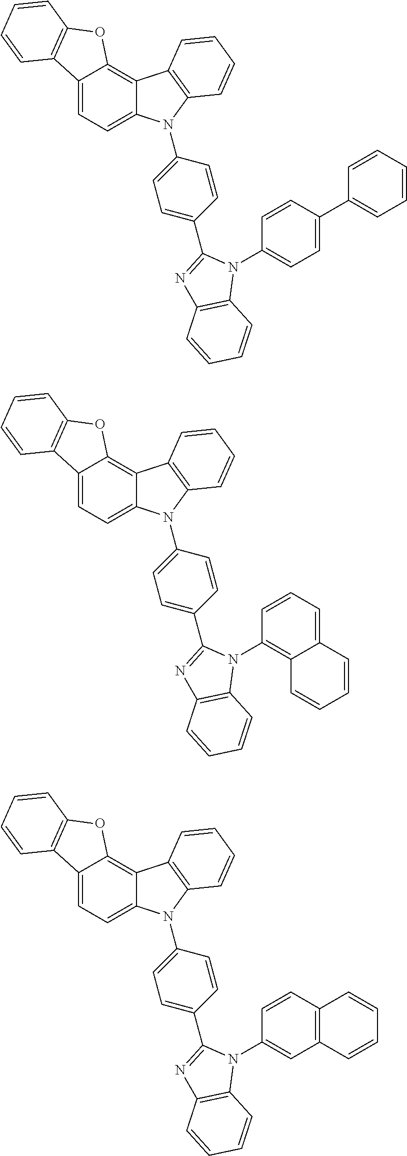 [SMILES: c1ccc(-c2ccc(-n3c(-c4ccc(-n5c6ccccc6c6c7oc8ccccc8c7ccc65)cc4)nc4ccccc43)cc2)cc1 ; c1ccc2c(-n3c(-c4ccc(-n5c6ccccc6c6c7oc8ccccc8c7ccc65)cc4)nc4ccccc43)cccc2c1 ; c1ccc2cc(-n3c(-c4ccc(-n5c6ccccc6c6c7oc8ccccc8c7ccc65)cc4)nc4ccccc43)ccc2c1]

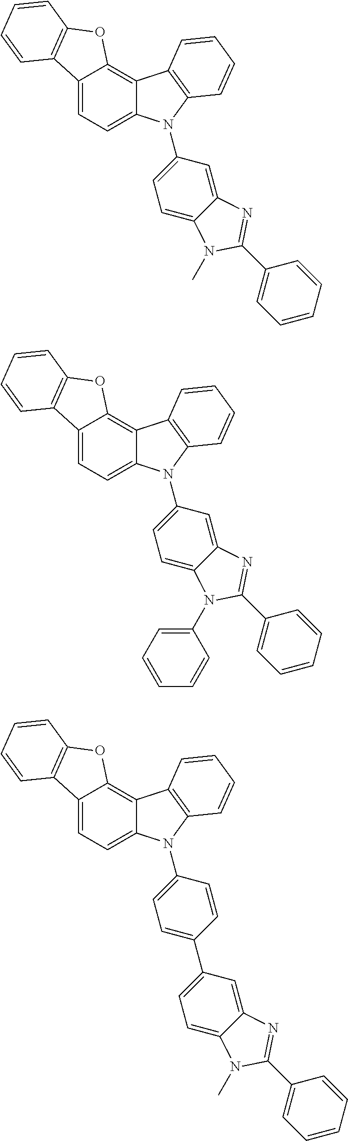 [SMILES: Cn1c(-c2ccccc2)nc2cc(-n3c4ccccc4c4c5oc6ccccc6c5ccc43)ccc21 ; c1ccc(-c2nc3cc(-n4c5ccccc5c5c6oc7ccccc7c6ccc54)ccc3n2-c2ccccc2)cc1 ; Cn1c(-c2ccccc2)nc2cc(-c3ccc(-n4c5ccccc5c5c6oc7ccccc7c6ccc54)cc3)ccc21]

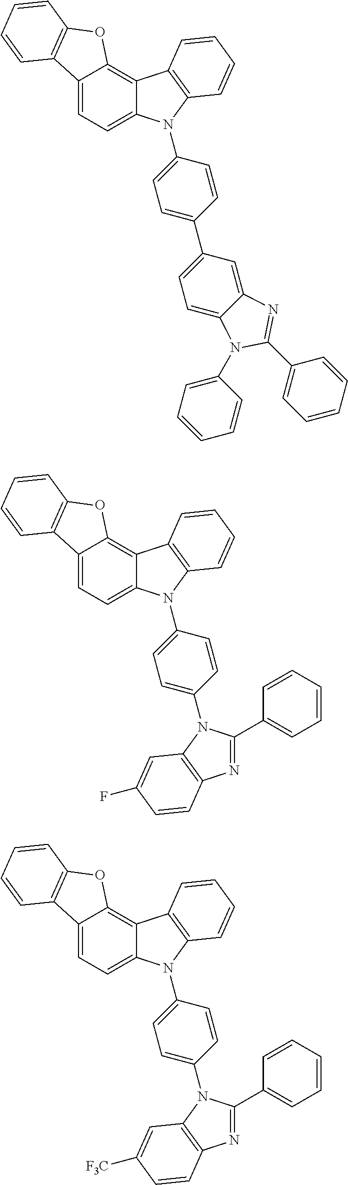 [SMILES: c1ccc(-c2nc3cc(-c4ccc(-n5c6ccccc6c6c7oc8ccccc8c7ccc65)cc4)ccc3n2-c2ccccc2)cc1 ; Fc1ccc2nc(-c3ccccc3)n(-c3ccc(-n4c5ccccc5c5c6oc7ccccc7c6ccc54)cc3)c2c1 ; FC(F)(F)c1ccc2nc(-c3ccccc3)n(-c3ccc(-n4c5ccccc5c5c6oc7ccccc7c6ccc54)cc3)c2c1]

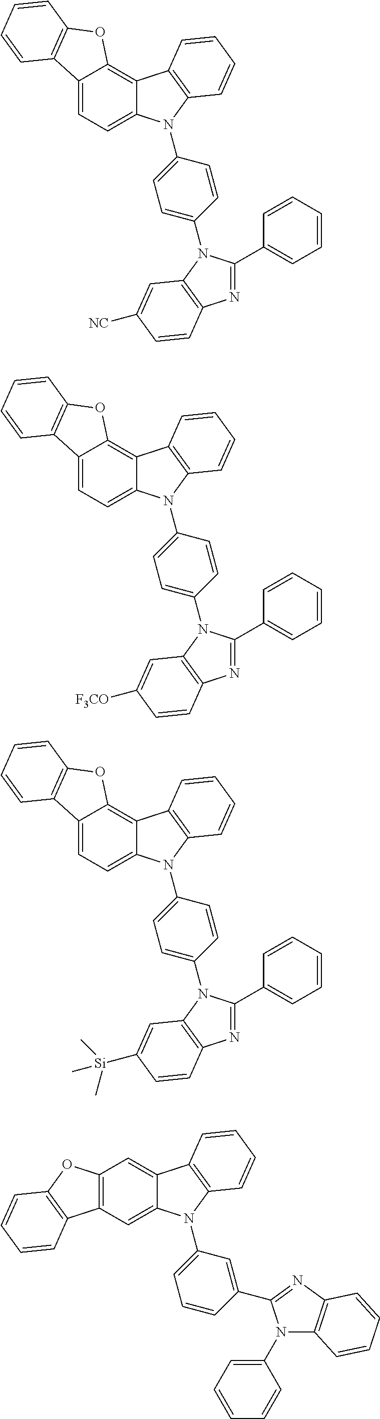 [SMILES: N#Cc1ccc2nc(-c3ccccc3)n(-c3ccc(-n4c5ccccc5c5c6oc7ccccc7c6ccc54)cc3)c2c1 ; FC(F)(F)Oc1ccc2nc(-c3ccccc3)n(-c3ccc(-n4c5ccccc5c5c6oc7ccccc7c6ccc54)cc3)c2c1 ; C[Si](C)(C)c1ccc2nc(-c3ccccc3)n(-c3ccc(-n4c5ccccc5c5c6oc7ccccc7c6ccc54)cc3)c2c1 ; c1ccc(-n2c(-c3cccc(-n4c5ccccc5c5cc6oc7ccccc7c6cc54)c3)nc3ccccc32)cc1]

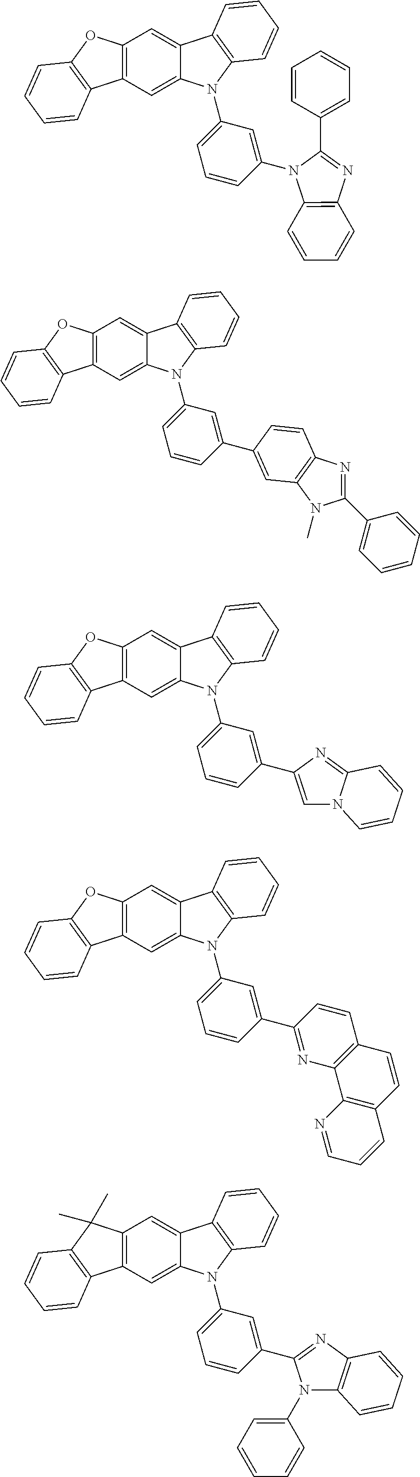 [SMILES: c1ccc(-c2nc3ccccc3n2-c2cccc(-n3c4ccccc4c4cc5oc6ccccc6c5cc43)c2)cc1 ; Cn1c(-c2ccccc2)nc2ccc(-c3cccc(-n4c5ccccc5c5cc6oc7ccccc7c6cc54)c3)cc21 ; c1cc(-c2cn3ccccc3n2)cc(-n2c3ccccc3c3cc4oc5ccccc5c4cc32)c1 ; c1cc(-c2ccc3ccc4cccnc4c3n2)cc(-n2c3ccccc3c3cc4oc5ccccc5c4cc32)c1 ; CC1(C)c2ccccc2-c2cc3c(cc21)c1ccccc1n3-c1cccc(-c2nc3ccccc3n2-c2ccccc2)c1]

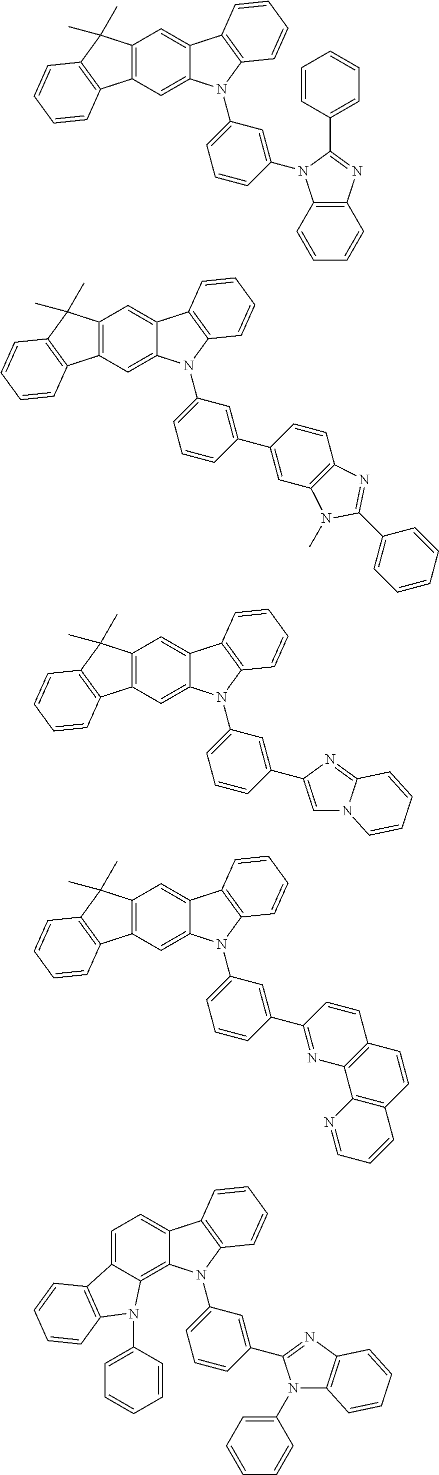 [SMILES: CC1(C)c2ccccc2-c2cc3c(cc21)c1ccccc1n3-c1cccc(-n2c(-c3ccccc3)nc3ccccc32)c1 ; Cn1c(-c2ccccc2)nc2ccc(-c3cccc(-n4c5ccccc5c5cc6c(cc54)-c4ccccc4C6(C)C)c3)cc21 ; CC1(C)c2ccccc2-c2cc3c(cc21)c1ccccc1n3-c1cccc(-c2cn3ccccc3n2)c1 ; CC1(C)c2ccccc2-c2cc3c(cc21)c1ccccc1n3-c1cccc(-c2ccc3ccc4cccnc4c3n2)c1 ; c1ccc(-n2c(-c3cccc(-n4c5ccccc5c5ccc6c7ccccc7n(-c7ccccc7)c6c54)c3)nc3ccccc32)cc1]

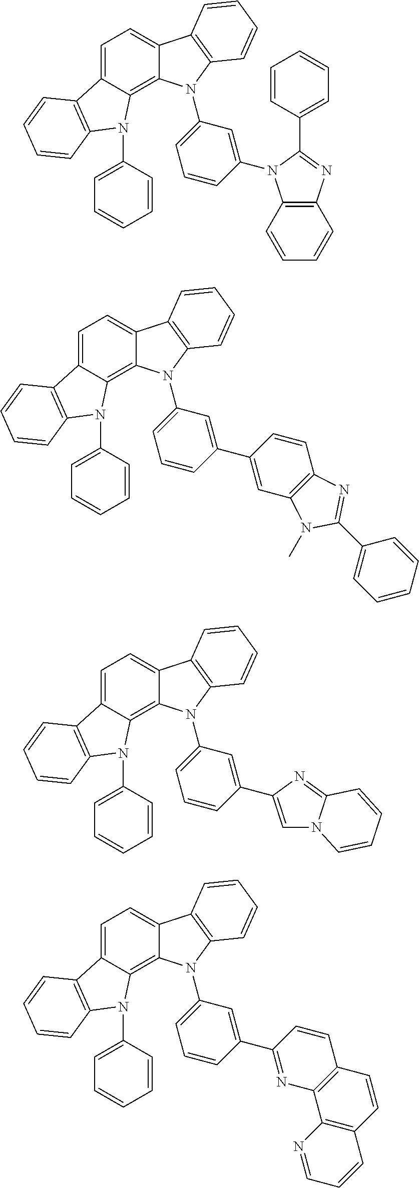 [SMILES: c1ccc(-c2nc3ccccc3n2-c2cccc(-n3c4ccccc4c4ccc5c6ccccc6n(-c6ccccc6)c5c43)c2)cc1 ; Cn1c(-c2ccccc2)nc2ccc(-c3cccc(-n4c5ccccc5c5ccc6c7ccccc7n(-c7ccccc7)c6c54)c3)cc21 ; c1ccc(-n2c3ccccc3c3ccc4c5ccccc5n(-c5cccc(-c6cn7ccccc7n6)c5)c4c32)cc1 ; c1ccc(-n2c3ccccc3c3ccc4c5ccccc5n(-c5cccc(-c6ccc7ccc8cccnc8c7n6)c5)c4c32)cc1]

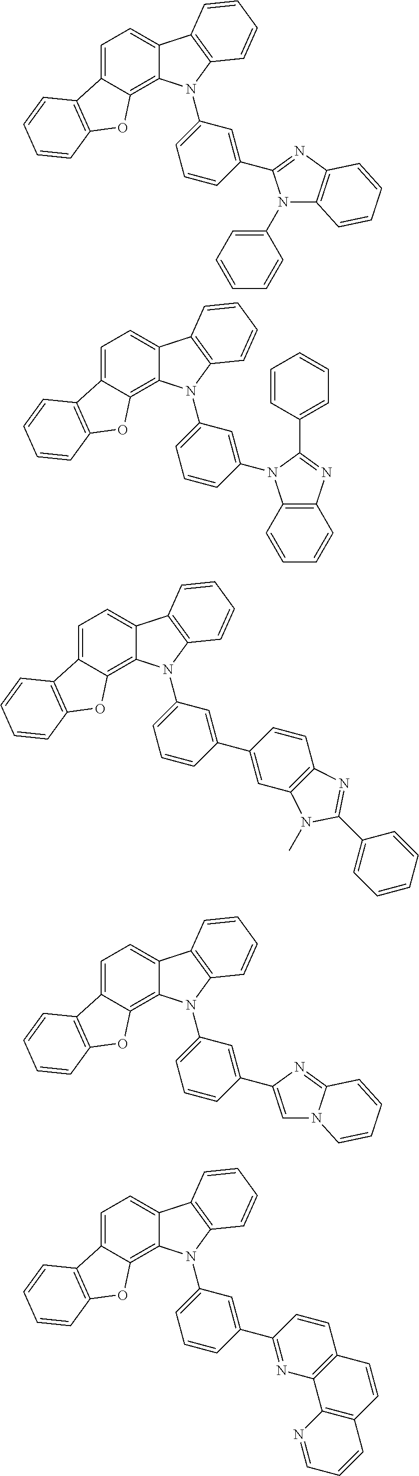

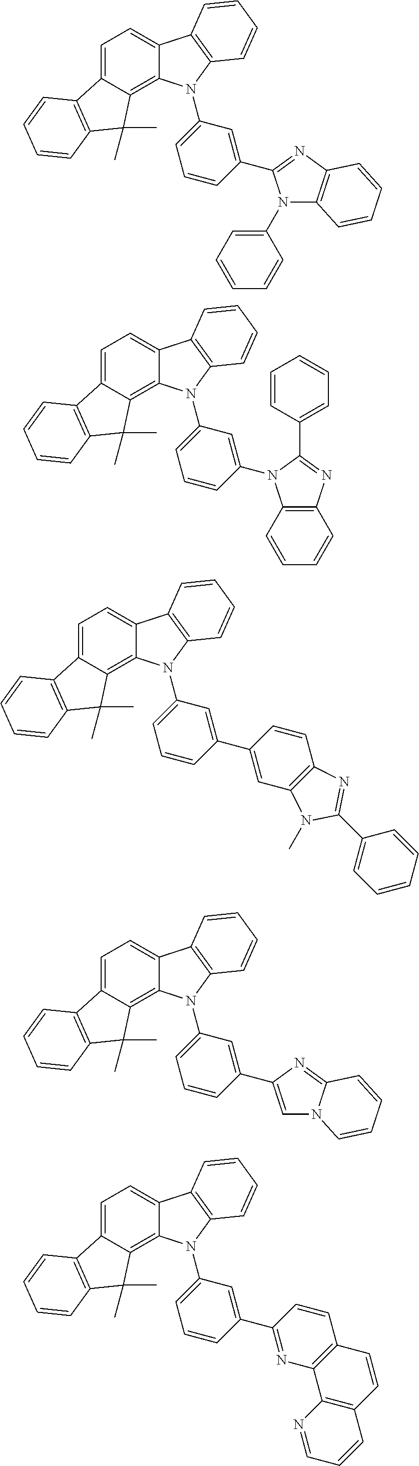

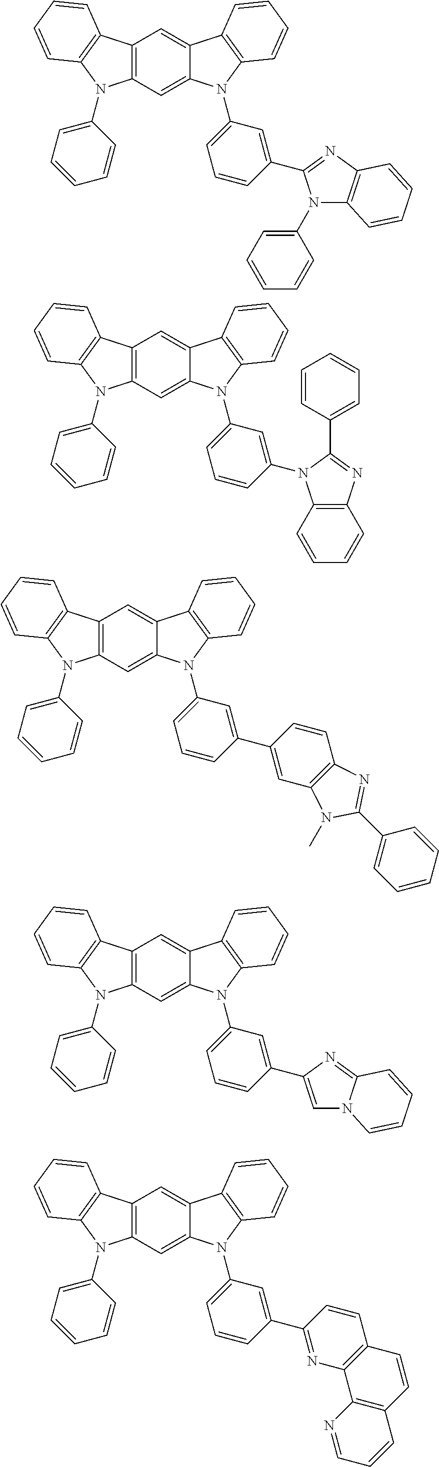

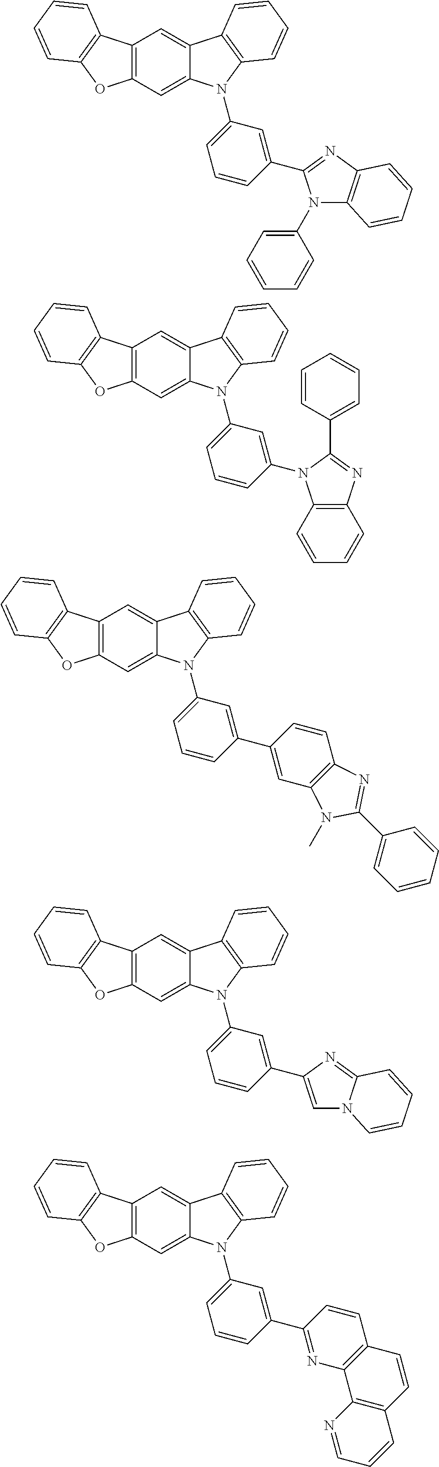

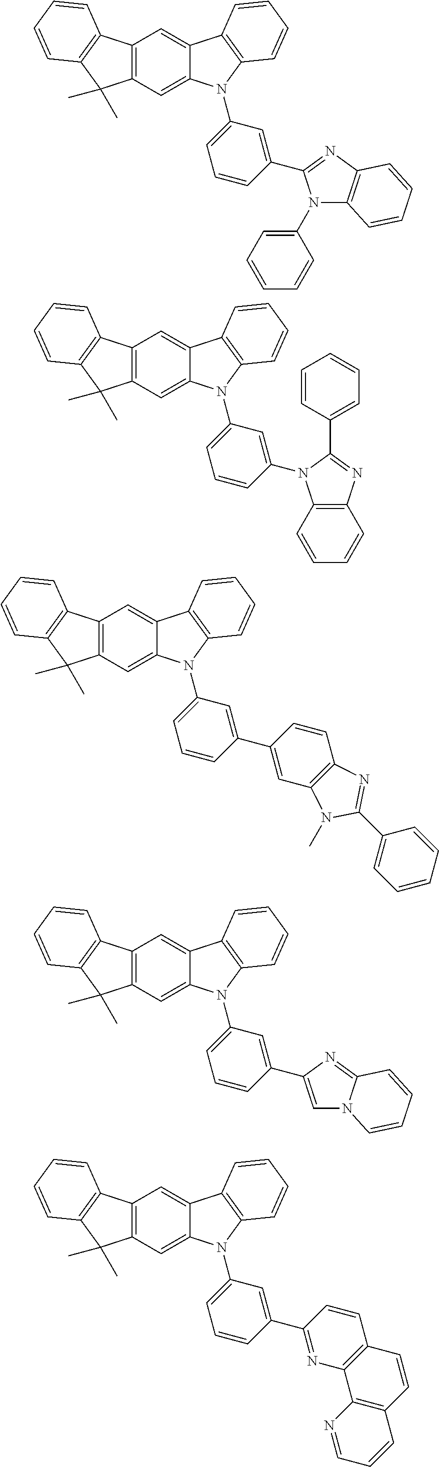

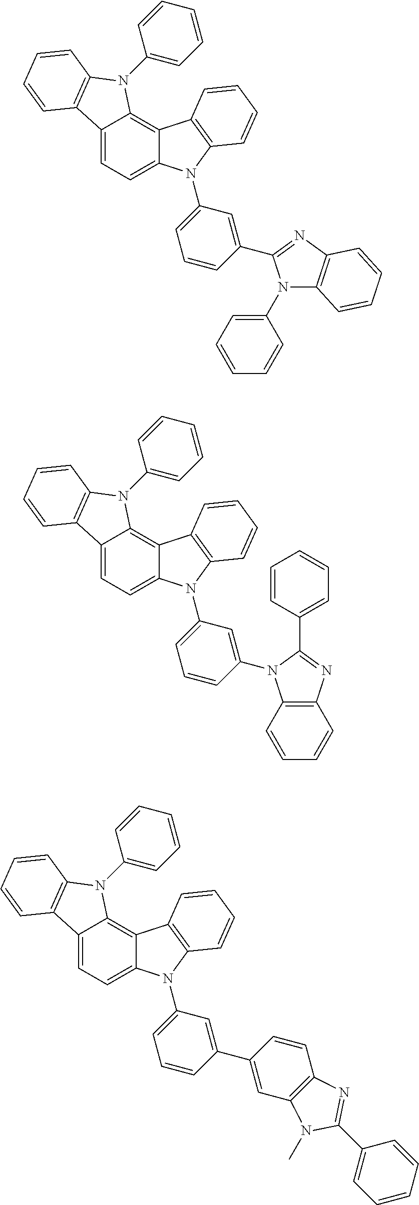 [SMILES: c1ccc(-n2c(-c3cccc(-n4c5ccccc5c5c4ccc4c6ccccc6n(-c6ccccc6)c45)c3)nc3ccccc32)cc1 ; c1ccc(-c2nc3ccccc3n2-c2cccc(-n3c4ccccc4c4c3ccc3c5ccccc5n(-c5ccccc5)c34)c2)cc1 ; Cn1c(-c2ccccc2)nc2ccc(-c3cccc(-n4c5ccccc5c5c4ccc4c6ccccc6n(-c6ccccc6)c45)c3)cc21]

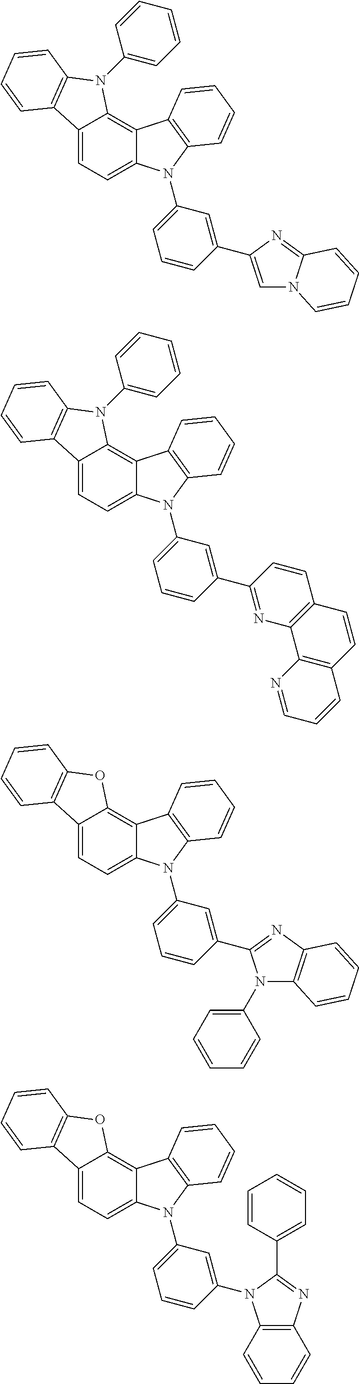 [SMILES: c1ccc(-n2c3ccccc3c3ccc4c(c5ccccc5n4-c4cccc(-c5cn6ccccc6n5)c4)c32)cc1 ; c1ccc(-n2c3ccccc3c3ccc4c(c5ccccc5n4-c4cccc(-c5ccc6ccc7cccnc7c6n5)c4)c32)cc1 ; c1ccc(-n2c(-c3cccc(-n4c5ccccc5c5c6oc7ccccc7c6ccc54)c3)nc3ccccc32)cc1 ; c1ccc(-c2nc3ccccc3n2-c2cccc(-n3c4ccccc4c4c5oc6ccccc6c5ccc43)c2)cc1]

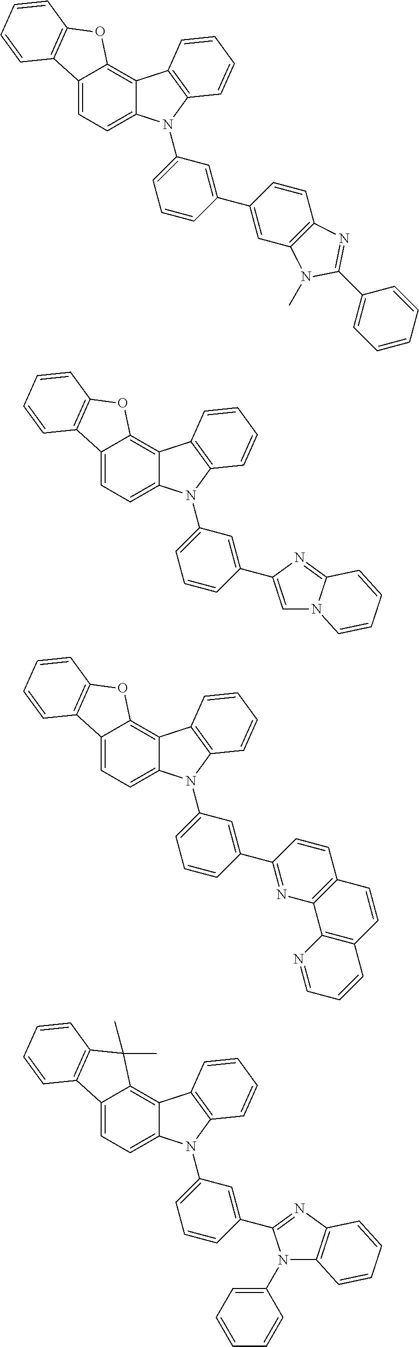 [SMILES: Cn1c(-c2ccccc2)nc2ccc(-c3cccc(-n4c5ccccc5c5c6oc7ccccc7c6ccc54)c3)cc21 ; c1cc(-c2cn3ccccc3n2)cc(-n2c3ccccc3c3c4oc5ccccc5c4ccc32)c1 ; c1cc(-c2ccc3ccc4cccnc4c3n2)cc(-n2c3ccccc3c3c4oc5ccccc5c4ccc32)c1 ; CC1(C)c2ccccc2-c2ccc3c(c21)c1ccccc1n3-c1cccc(-c2nc3ccccc3n2-c2ccccc2)c1]

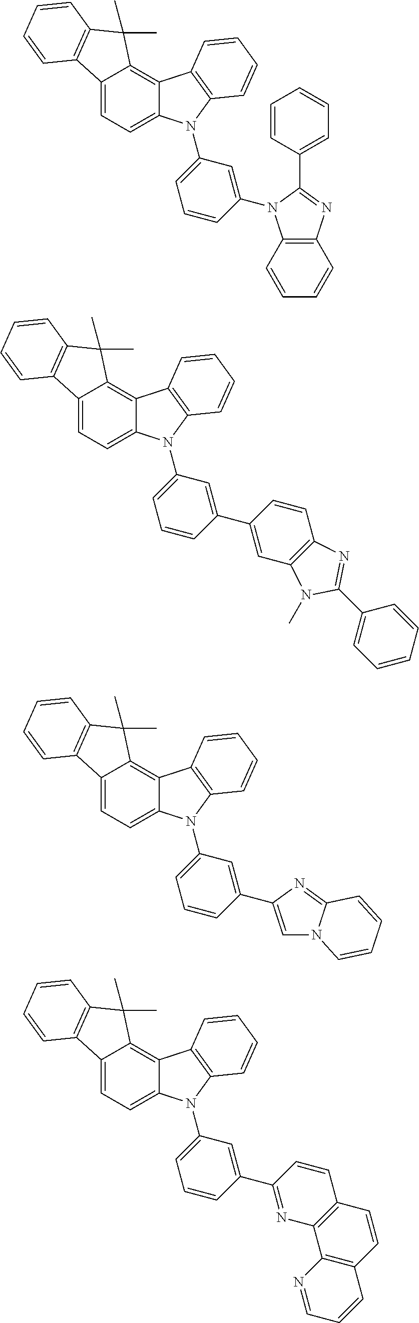 [SMILES: CC1(C)c2ccccc2-c2ccc3c(c21)c1ccccc1n3-c1cccc(-n2c(-c3ccccc3)nc3ccccc32)c1 ; Cn1c(-c2ccccc2)nc2ccc(-c3cccc(-n4c5ccccc5c5c6c(ccc54)-c4ccccc4C6(C)C)c3)cc21 ; CC1(C)c2ccccc2-c2ccc3c(c21)c1ccccc1n3-c1cccc(-c2cn3ccccc3n2)c1 ; CC1(C)c2ccccc2-c2ccc3c(c21)c1ccccc1n3-c1cccc(-c2ccc3ccc4cccnc4c3n2)c1]

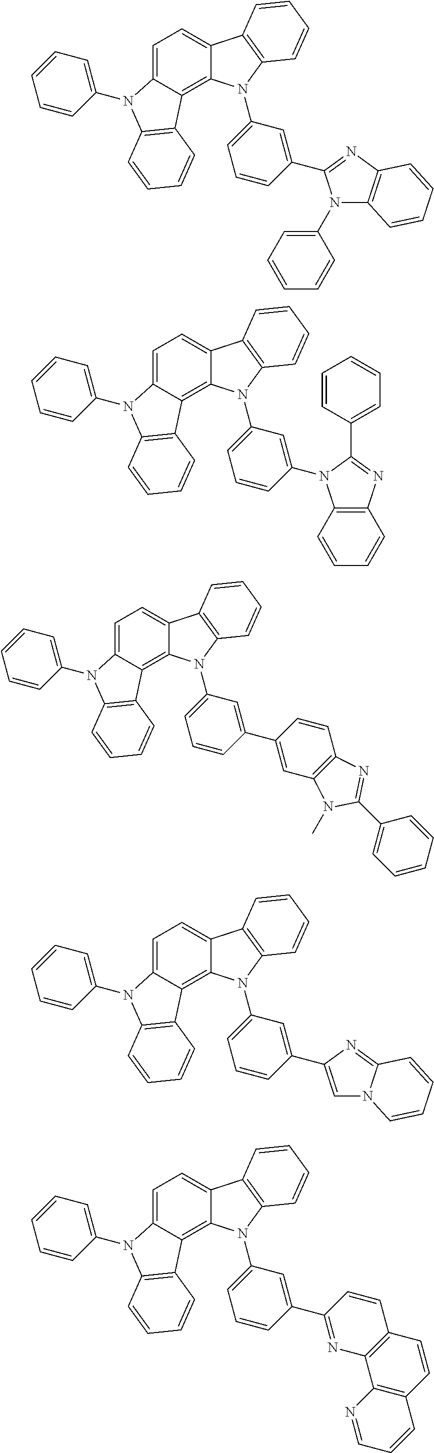

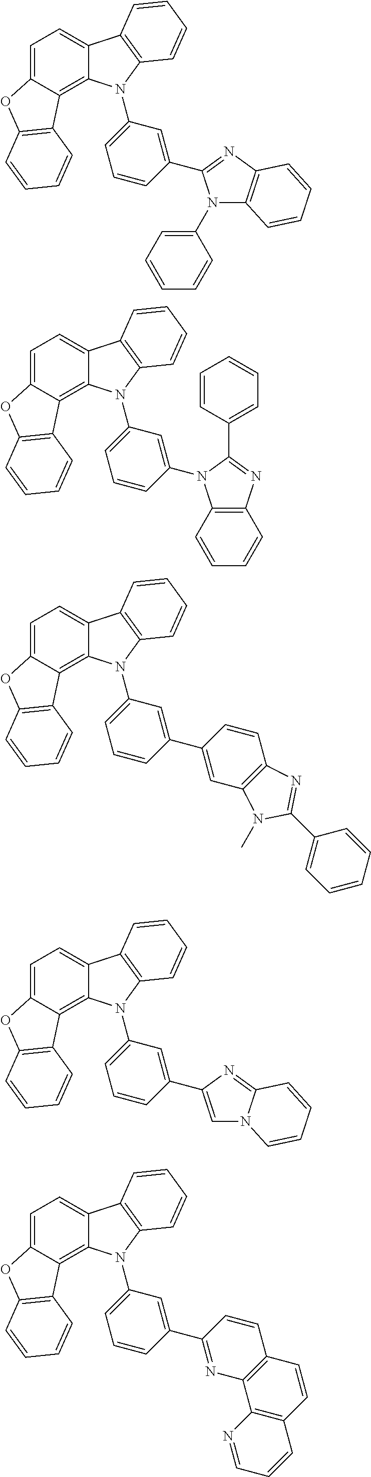

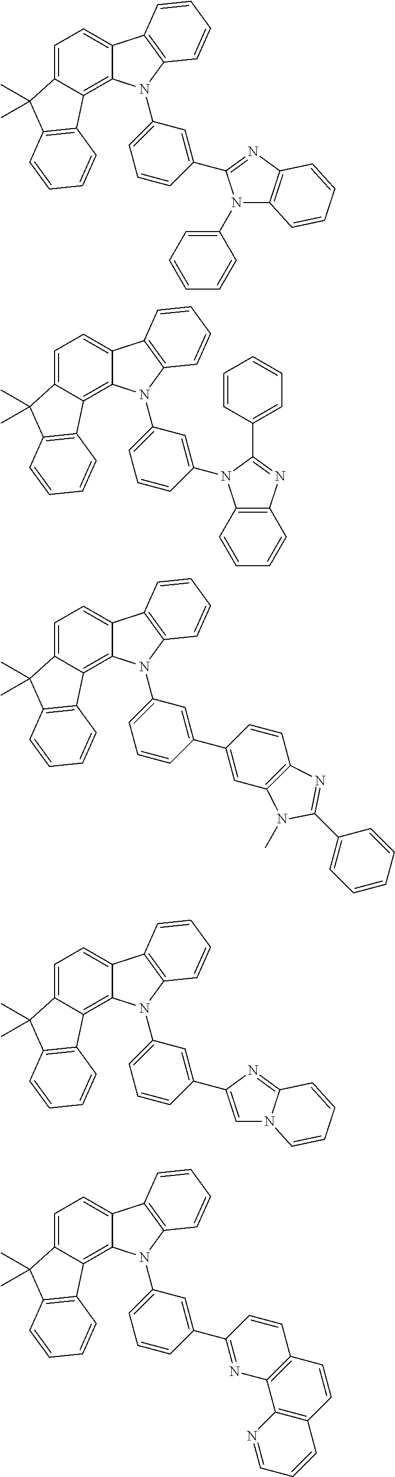

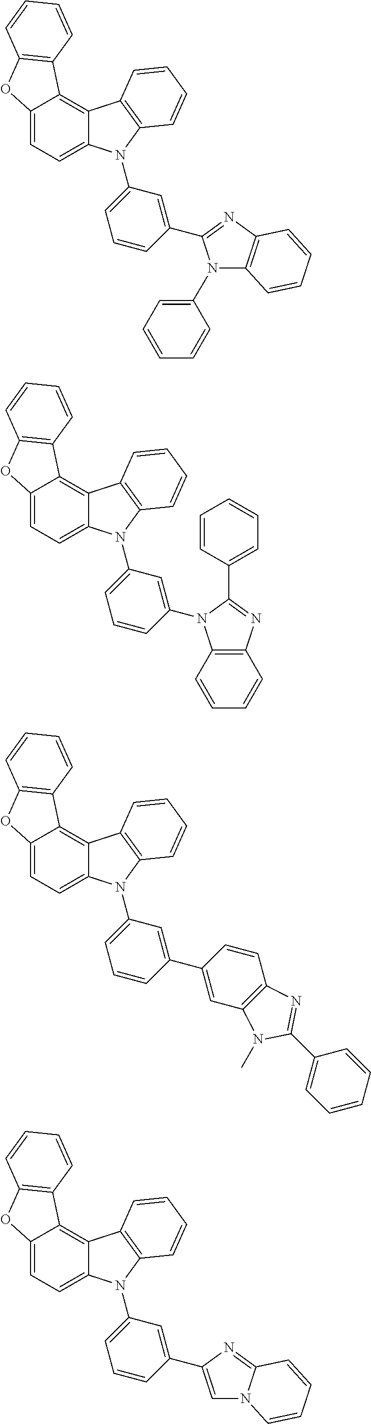 [SMILES: c1ccc(-n2c(-c3cccc(-n4c5ccccc5c5c6c(ccc54)oc4ccccc46)c3)nc3ccccc32)cc1 ; c1ccc(-c2nc3ccccc3n2-c2cccc(-n3c4ccccc4c4c5c(ccc43)oc3ccccc35)c2)cc1 ; Cn1c(-c2ccccc2)nc2ccc(-c3cccc(-n4c5ccccc5c5c6c(ccc54)oc4ccccc46)c3)cc21 ; c1cc(-c2cn3ccccc3n2)cc(-n2c3ccccc3c3c4c(ccc32)oc2ccccc24)c1]

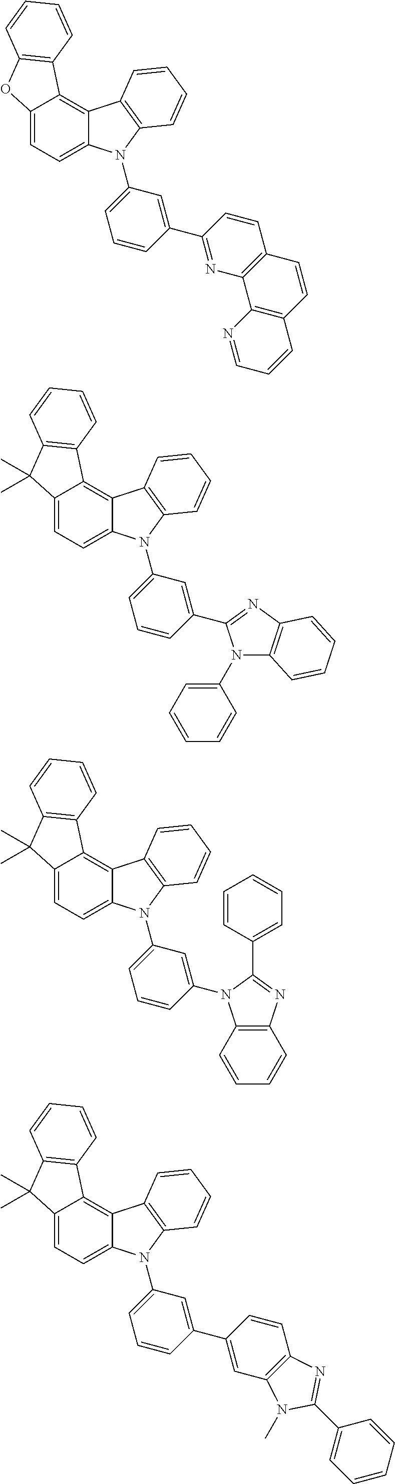 [SMILES: c1cc(-c2ccc3ccc4cccnc4c3n2)cc(-n2c3ccccc3c3c4c(ccc32)oc2ccccc24)c1 ; CC1(C)c2ccccc2-c2c1ccc1c2c2ccccc2n1-c1cccc(-c2nc3ccccc3n2-c2ccccc2)c1 ; CC1(C)c2ccccc2-c2c1ccc1c2c2ccccc2n1-c1cccc(-n2c(-c3ccccc3)nc3ccccc32)c1 ; Cn1c(-c2ccccc2)nc2ccc(-c3cccc(-n4c5ccccc5c5c6c(ccc54)C(C)(C)c4ccccc4-6)c3)cc21]

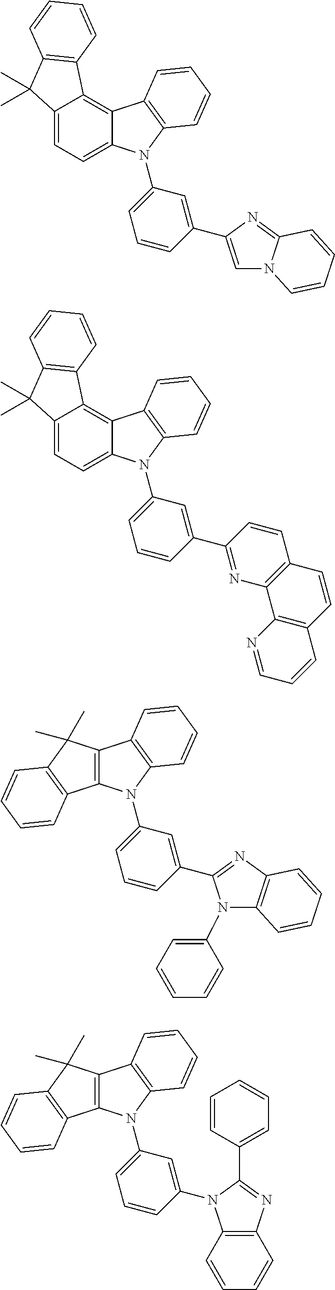

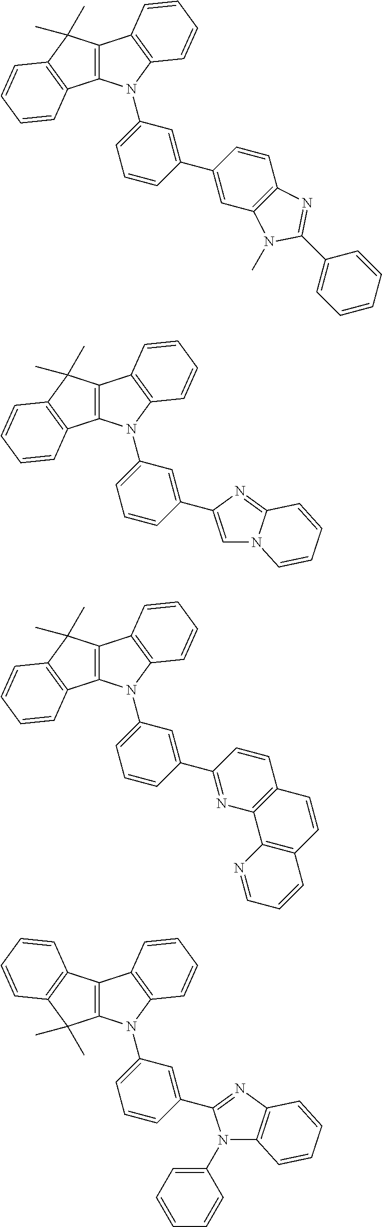 [SMILES: Cn1c(-c2ccccc2)nc2ccc(-c3cccc(-n4c5c(c6ccccc64)C(C)(C)c4ccccc4-5)c3)cc21 ; CC1(C)c2ccccc2-c2c1c1ccccc1n2-c1cccc(-c2cn3ccccc3n2)c1 ; CC1(C)c2ccccc2-c2c1c1ccccc1n2-c1cccc(-c2ccc3ccc4cccnc4c3n2)c1 ; CC1(C)c2ccccc2-c2c1n(-c1cccc(-c3nc4ccccc4n3-c3ccccc3)c1)c1ccccc21]

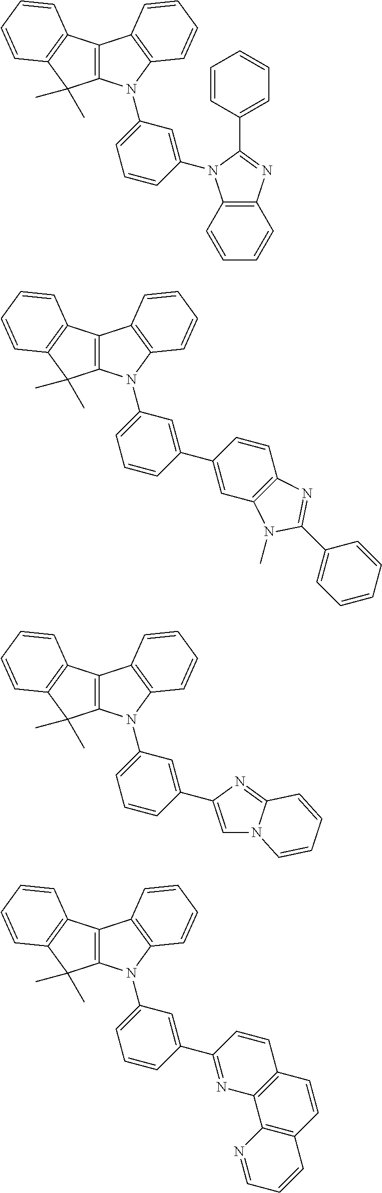 [SMILES: CC1(C)c2ccccc2-c2c1n(-c1cccc(-n3c(-c4ccccc4)nc4ccccc43)c1)c1ccccc21 ; Cn1c(-c2ccccc2)nc2ccc(-c3cccc(-n4c5c(c6ccccc64)-c4ccccc4C5(C)C)c3)cc21 ; CC1(C)c2ccccc2-c2c1n(-c1cccc(-c3cn4ccccc4n3)c1)c1ccccc21 ; CC1(C)c2ccccc2-c2c1n(-c1cccc(-c3ccc4ccc5cccnc5c4n3)c1)c1ccccc21]

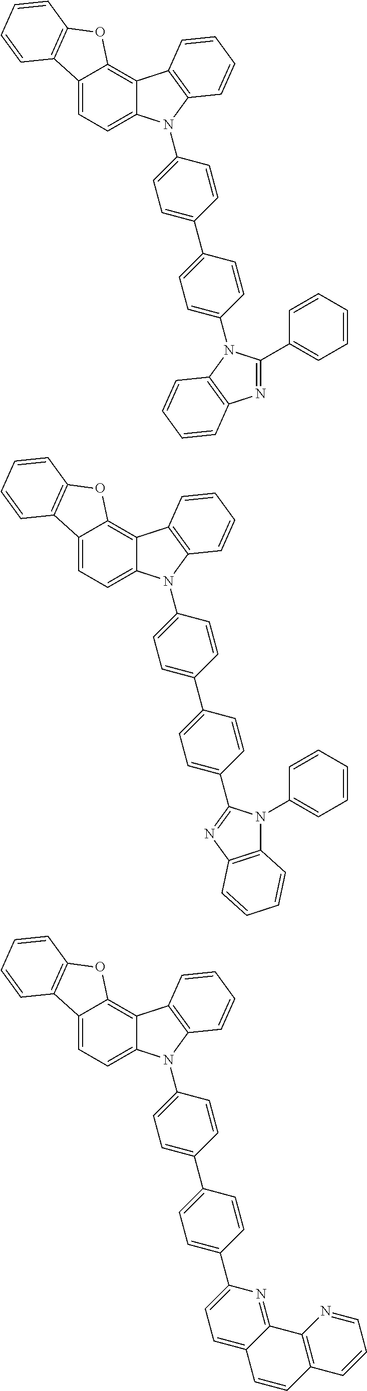 [SMILES: c1ccc(-c2nc3ccccc3n2-c2ccc(-c3ccc(-n4c5ccccc5c5c6oc7ccccc7c6ccc54)cc3)cc2)cc1 ; c1ccc(-n2c(-c3ccc(-c4ccc(-n5c6ccccc6c6c7oc8ccccc8c7ccc65)cc4)cc3)nc3ccccc32)cc1 ; c1cnc2c(c1)ccc1ccc(-c3ccc(-c4ccc(-n5c6ccccc6c6c7oc8ccccc8c7ccc65)cc4)cc3)nc12]

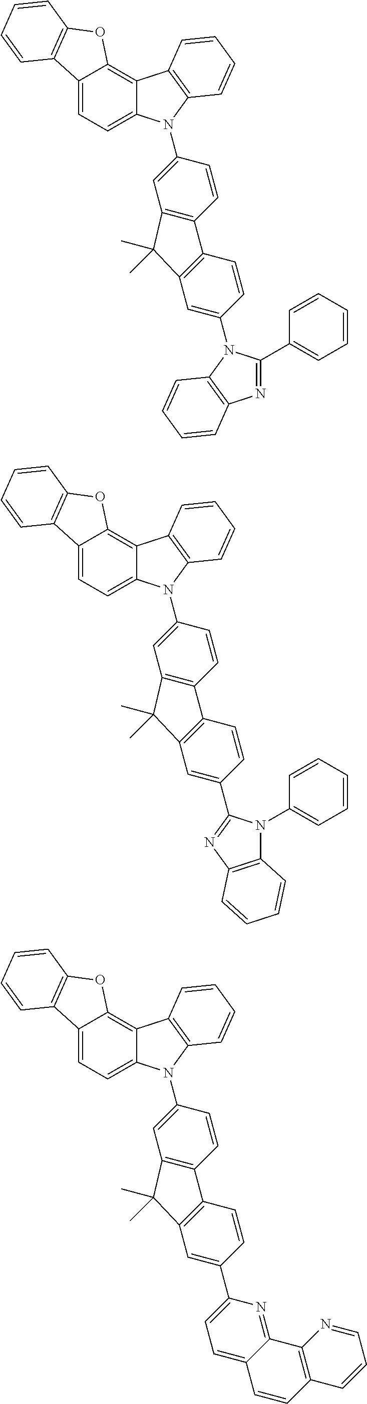 [SMILES: CC1(C)c2cc(-n3c(-c4ccccc4)nc4ccccc43)ccc2-c2ccc(-n3c4ccccc4c4c5oc6ccccc6c5ccc43)cc21 ; CC1(C)c2cc(-c3nc4ccccc4n3-c3ccccc3)ccc2-c2ccc(-n3c4ccccc4c4c5oc6ccccc6c5ccc43)cc21 ; CC1(C)c2cc(-c3ccc4ccc5cccnc5c4n3)ccc2-c2ccc(-n3c4ccccc4c4c5oc6ccccc6c5ccc43)cc21]

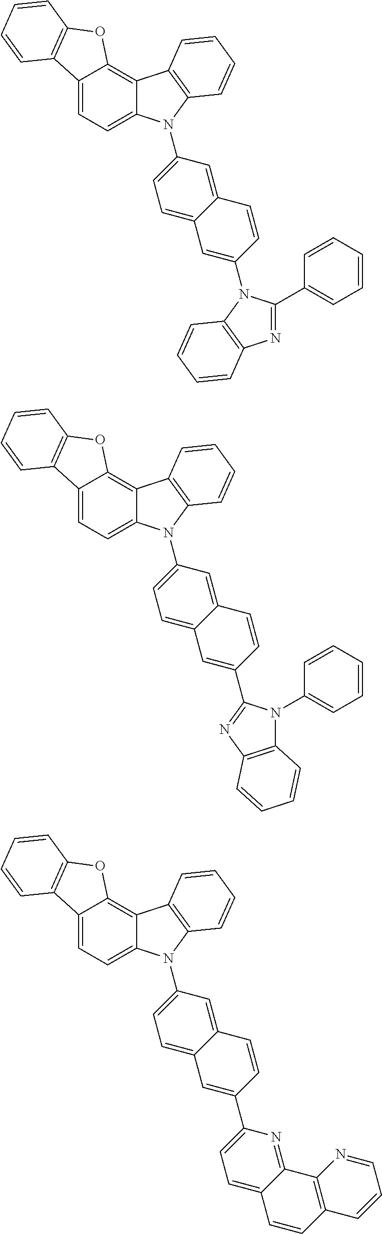 [SMILES: c1ccc(-c2nc3ccccc3n2-c2ccc3cc(-n4c5ccccc5c5c6oc7ccccc7c6ccc54)ccc3c2)cc1 ; c1ccc(-n2c(-c3ccc4cc(-n5c6ccccc6c6c7oc8ccccc8c7ccc65)ccc4c3)nc3ccccc32)cc1 ; c1cnc2c(c1)ccc1ccc(-c3ccc4cc(-n5c6ccccc6c6c7oc8ccccc8c7ccc65)ccc4c3)nc12]

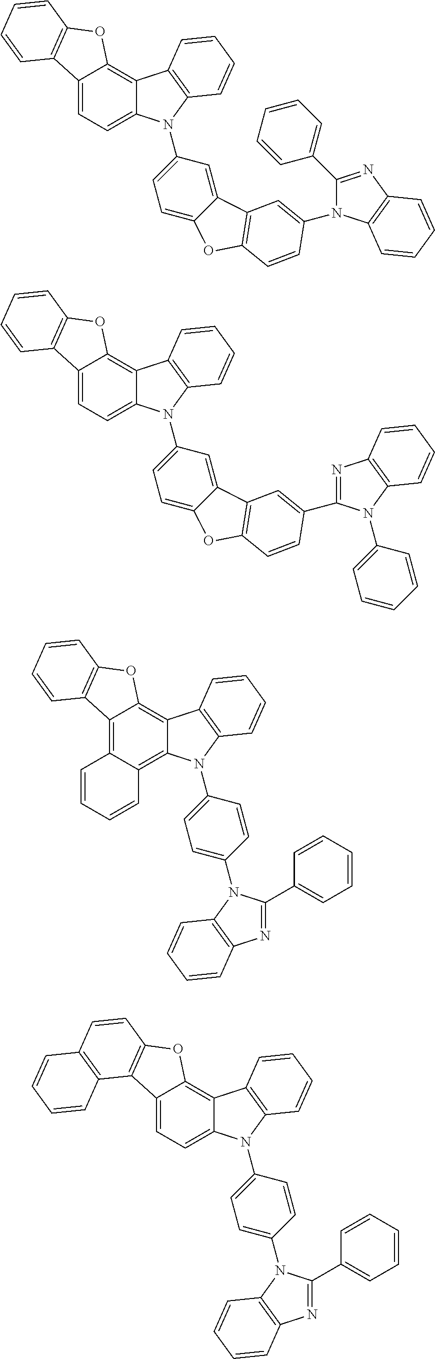 [SMILES: c1ccc(-c2nc3ccccc3n2-c2ccc3oc4ccc(-n5c6ccccc6c6c7oc8ccccc8c7ccc65)cc4c3c2)cc1 ; c1ccc(-n2c(-c3ccc4oc5ccc(-n6c7ccccc7c7c8oc9ccccc9c8ccc76)cc5c4c3)nc3ccccc32)cc1 ; c1ccc(-c2nc3ccccc3n2-c2ccc(-n3c4ccccc4c4c5oc6ccccc6c5c5ccccc5c43)cc2)cc1 ; c1ccc(-c2nc3ccccc3n2-c2ccc(-n3c4ccccc4c4c5oc6ccc7ccccc7c6c5ccc43)cc2)cc1]

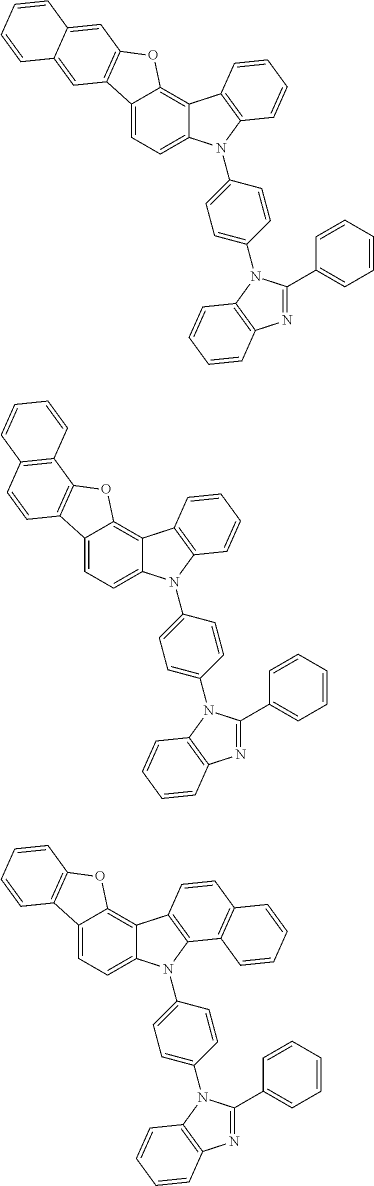 [SMILES: c1ccc(-c2nc3ccccc3n2-c2ccc(-n3c4ccccc4c4c5oc6cc7ccccc7cc6c5ccc43)cc2)cc1 ; c1ccc(-c2nc3ccccc3n2-c2ccc(-n3c4ccccc4c4c5oc6c7ccccc7ccc6c5ccc43)cc2)cc1 ; c1ccc(-c2nc3ccccc3n2-c2ccc(-n3c4ccc5c6ccccc6oc5c4c4ccc5ccccc5c43)cc2)cc1]

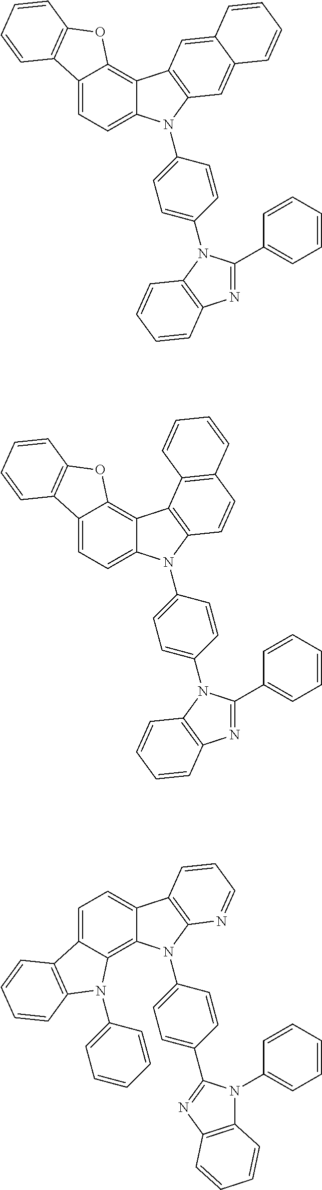 [SMILES: c1ccc(-c2nc3ccccc3n2-c2ccc(-n3c4cc5ccccc5cc4c4c5oc6ccccc6c5ccc43)cc2)cc1 ; c1ccc(-c2nc3ccccc3n2-c2ccc(-n3c4ccc5ccccc5c4c4c5oc6ccccc6c5ccc43)cc2)cc1 ; c1ccc(-n2c(-c3ccc(-n4c5ncccc5c5ccc6c7ccccc7n(-c7ccccc7)c6c54)cc3)nc3ccccc32)cc1]

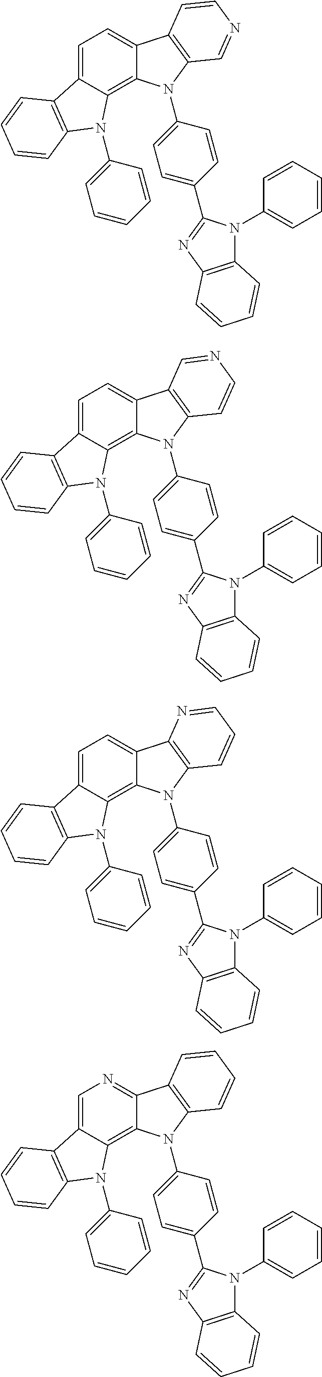

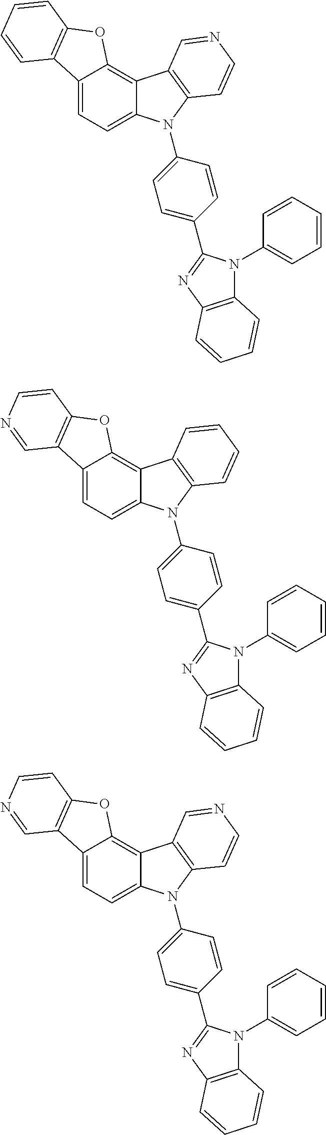 [SMILES: c1ccc(-n2c(-c3ccc(-n4c5ccncc5c5c6oc7ccccc7c6ccc54)cc3)nc3ccccc32)cc1 ; c1ccc(-n2c(-c3ccc(-n4c5ccccc5c5c6oc7ccncc7c6ccc54)cc3)nc3ccccc32)cc1 ; c1ccc(-n2c(-c3ccc(-n4c5ccncc5c5c6oc7ccncc7c6ccc54)cc3)nc3ccccc32)cc1]

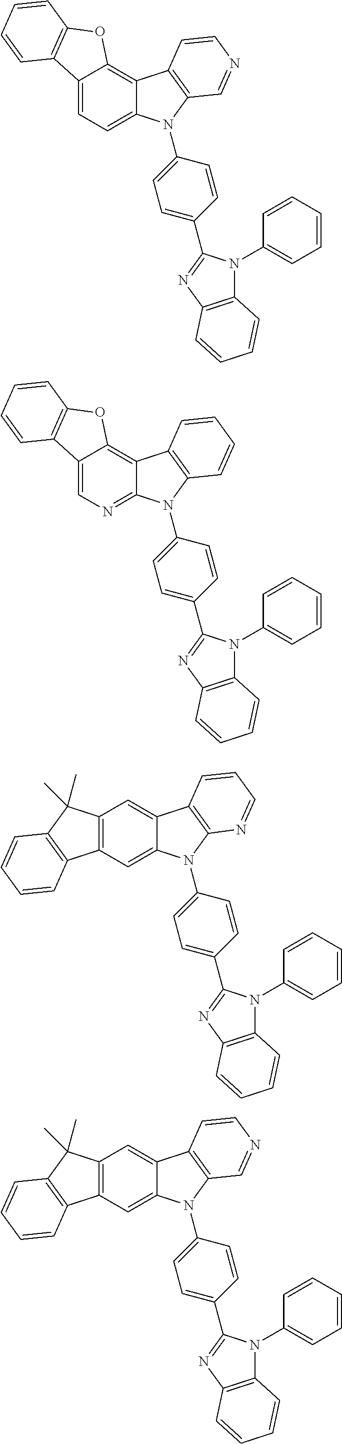

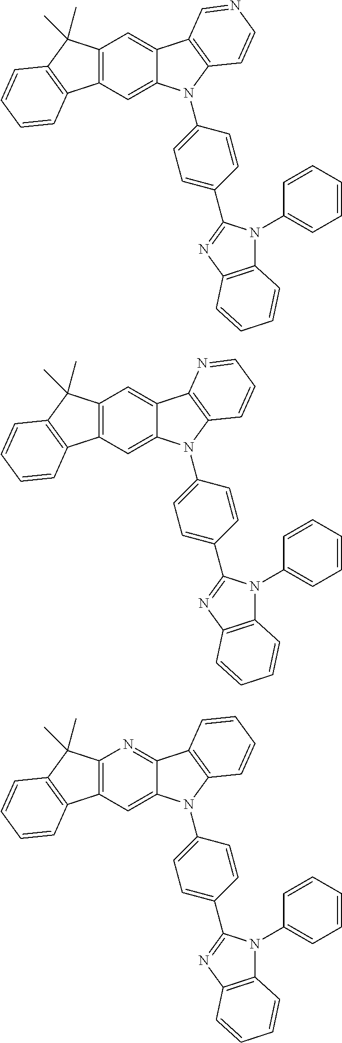

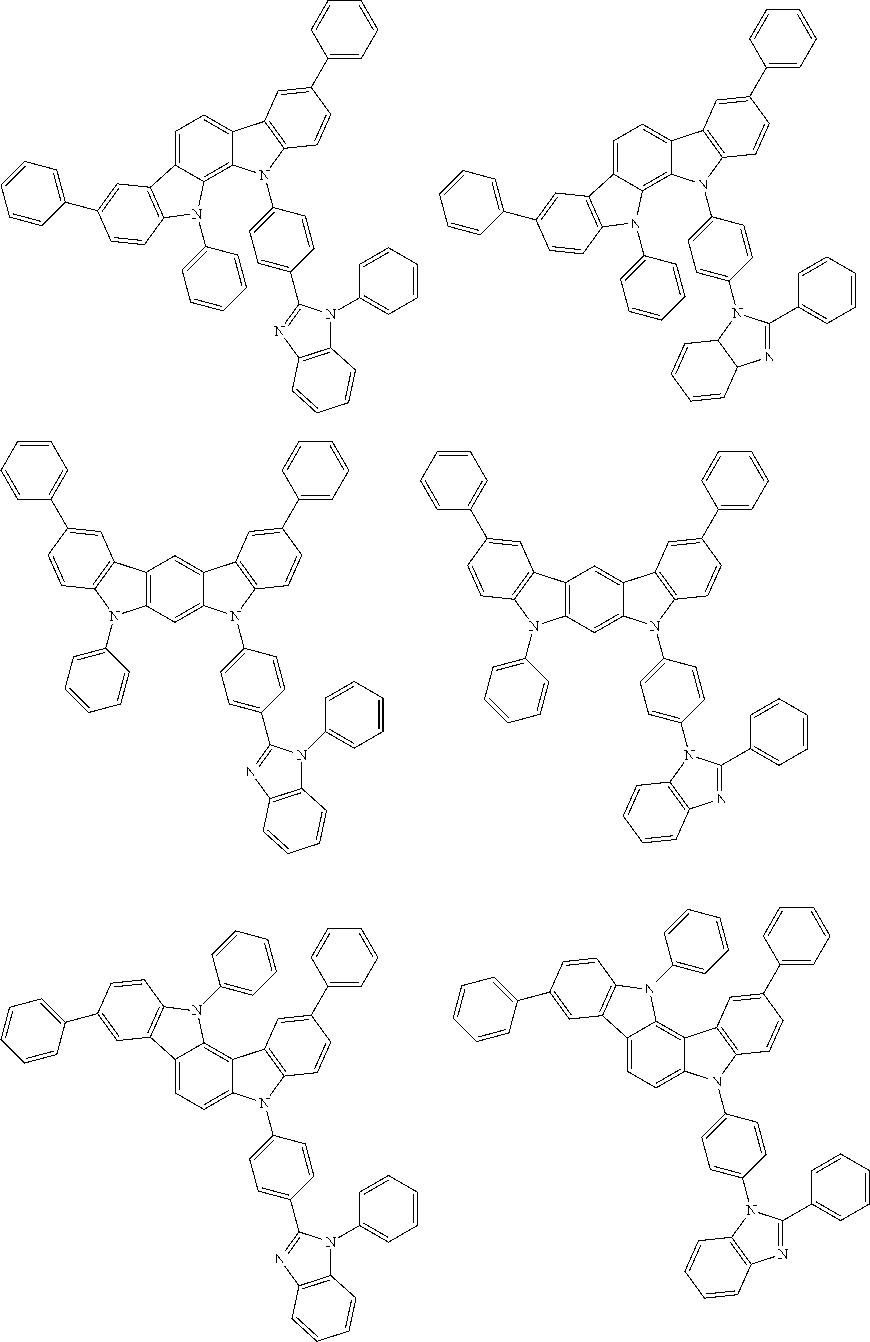

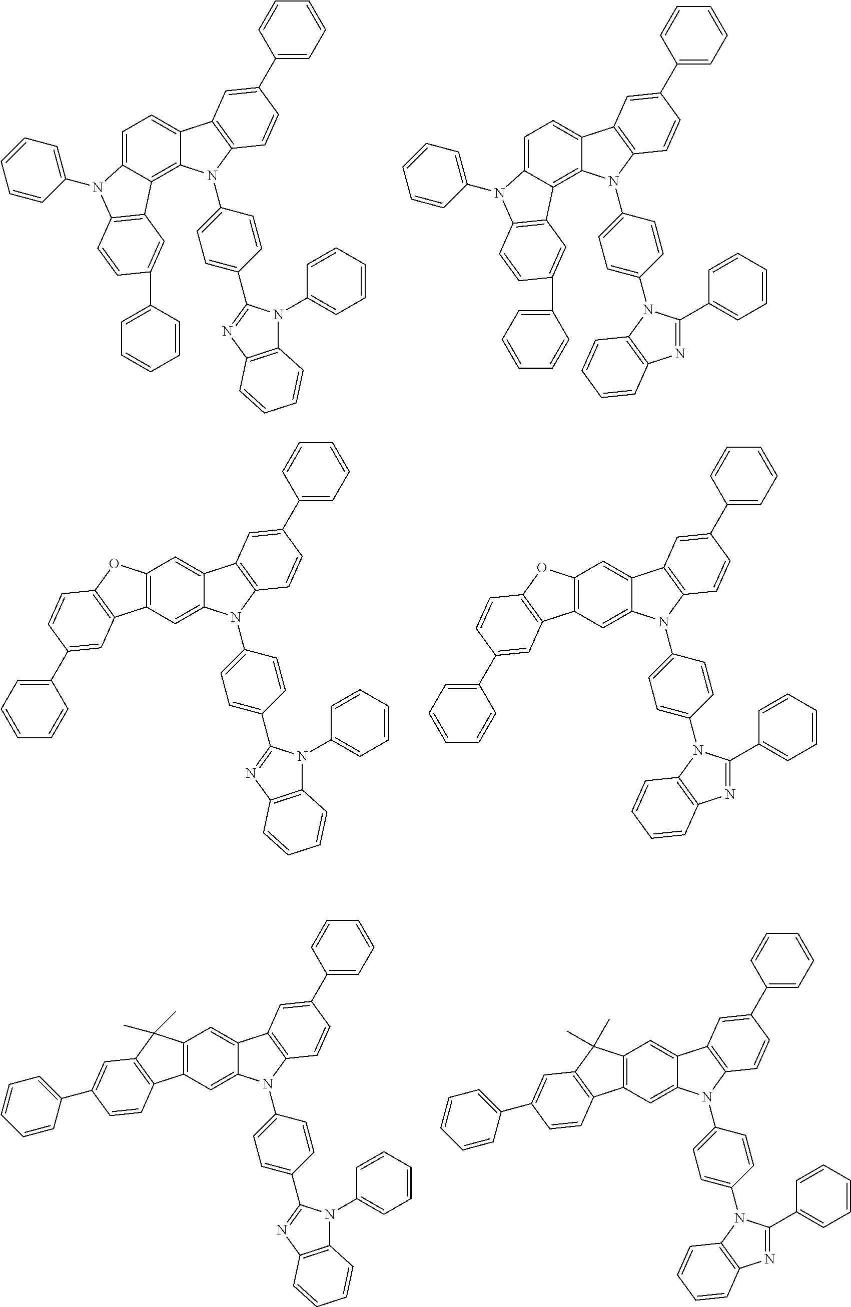

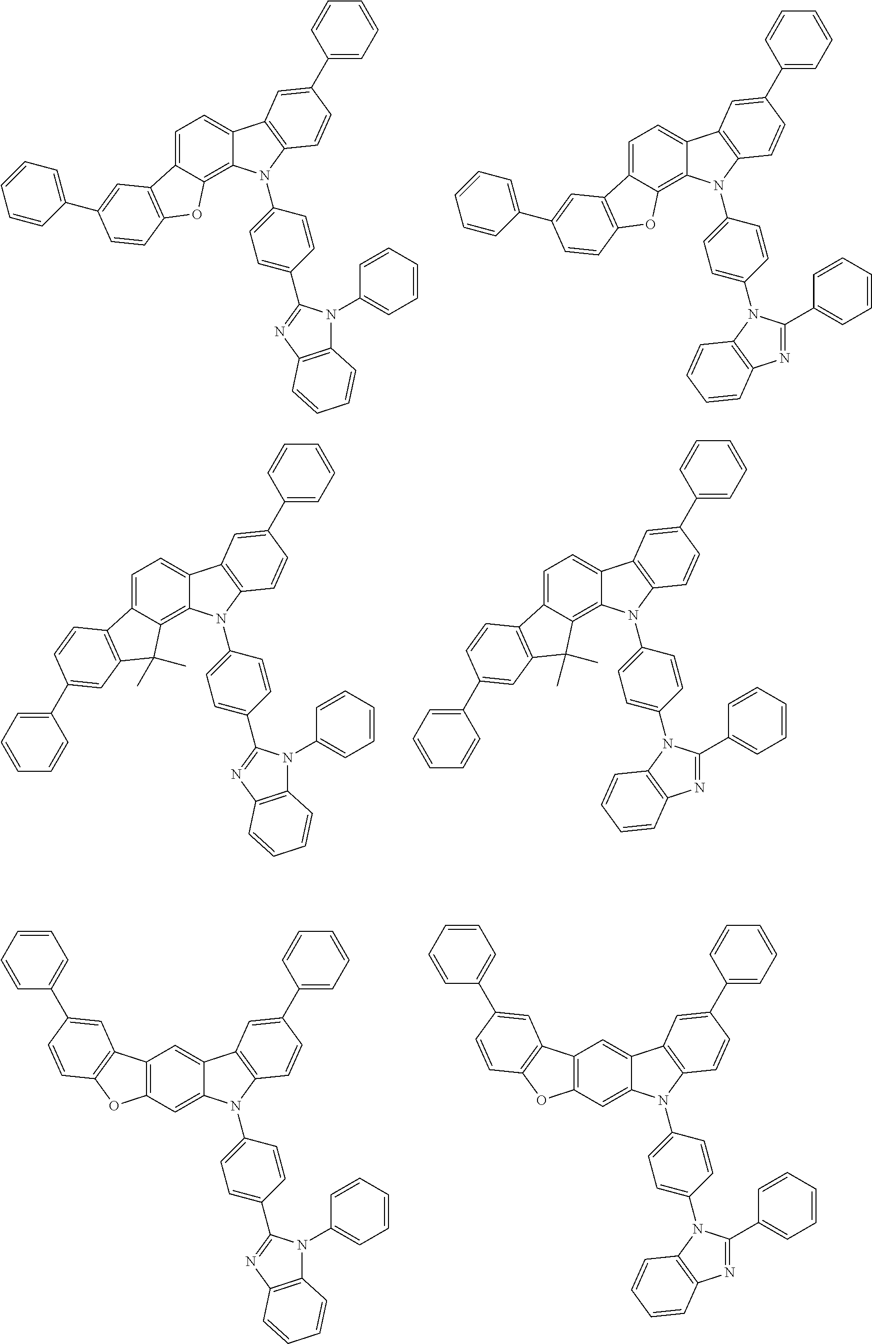

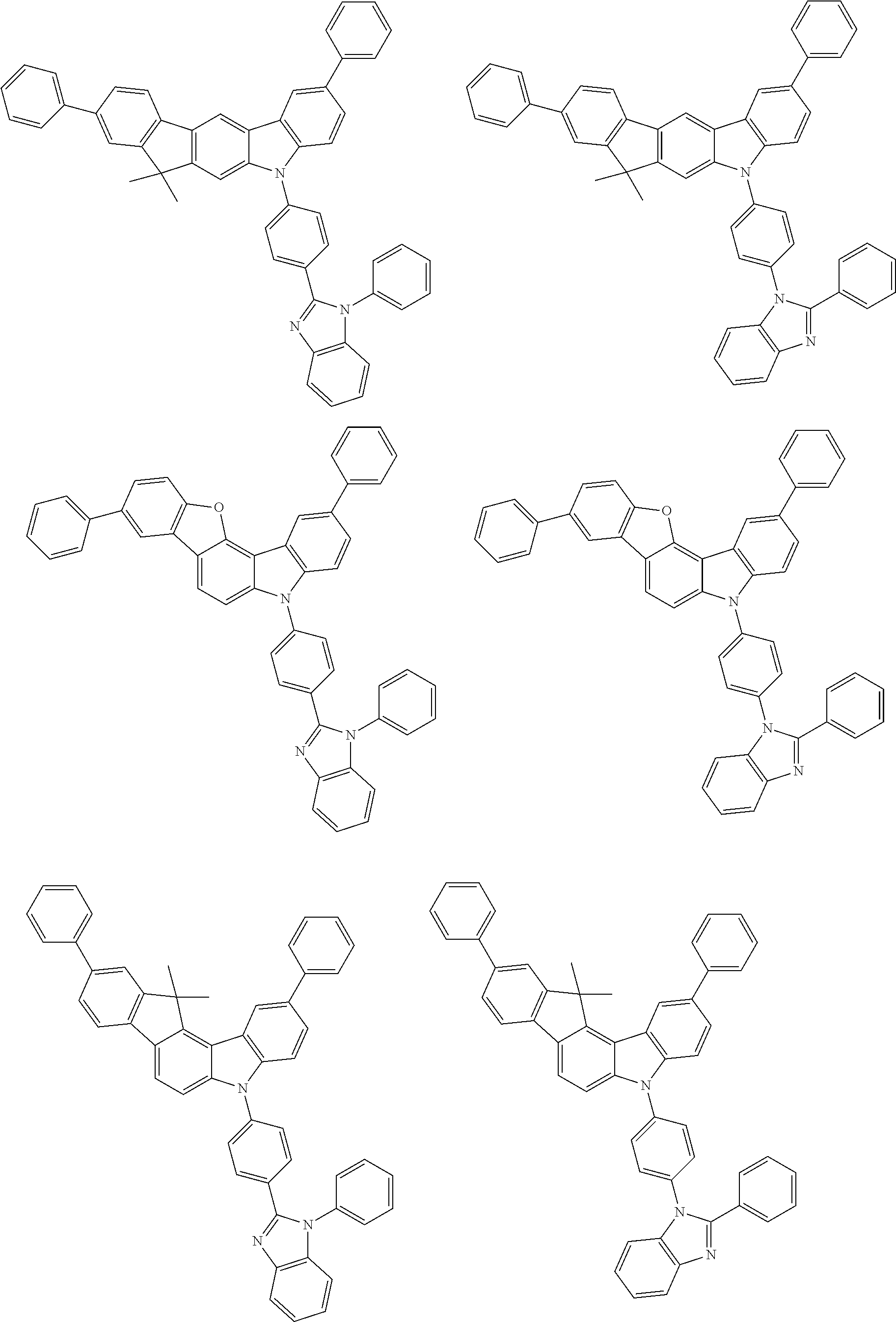

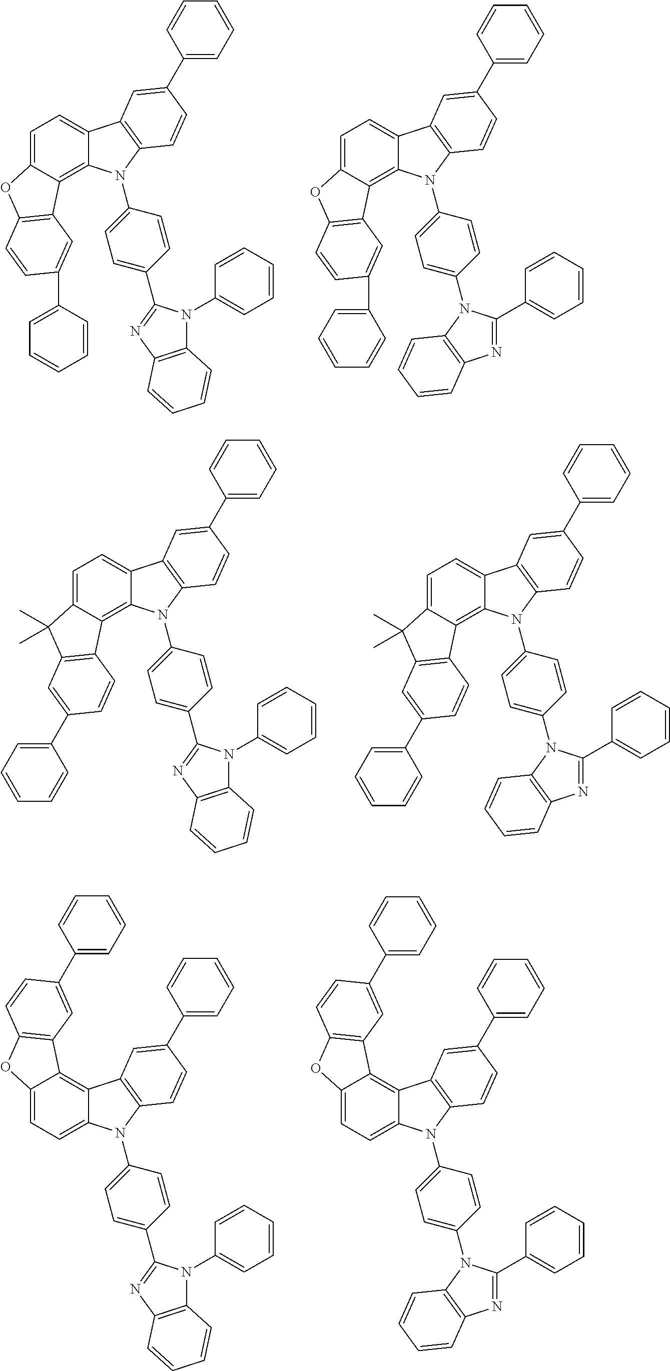

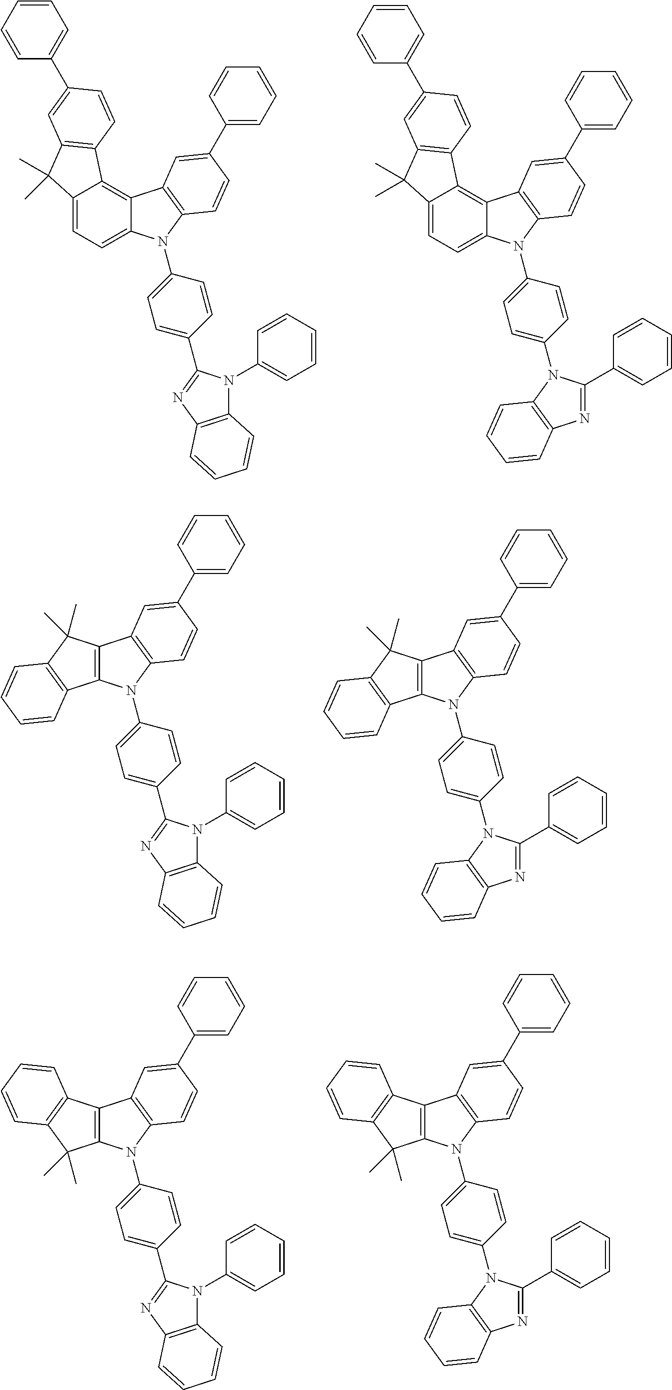

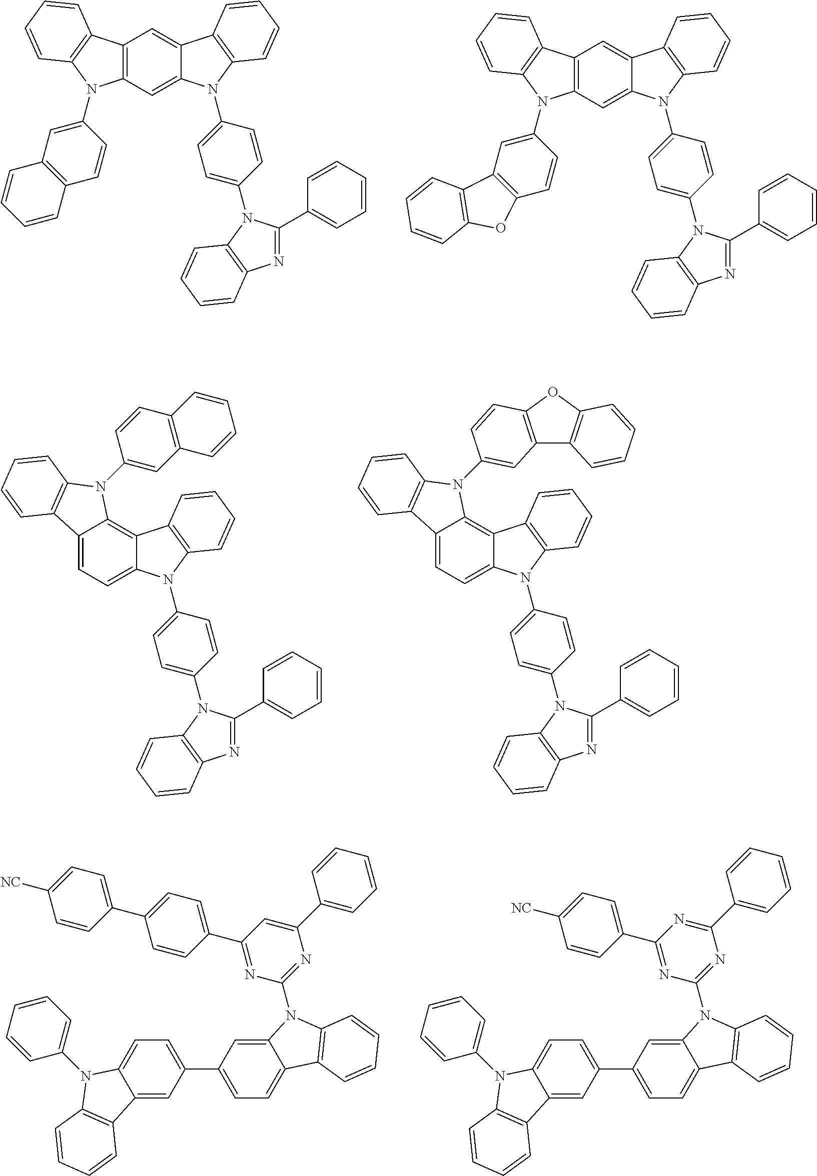

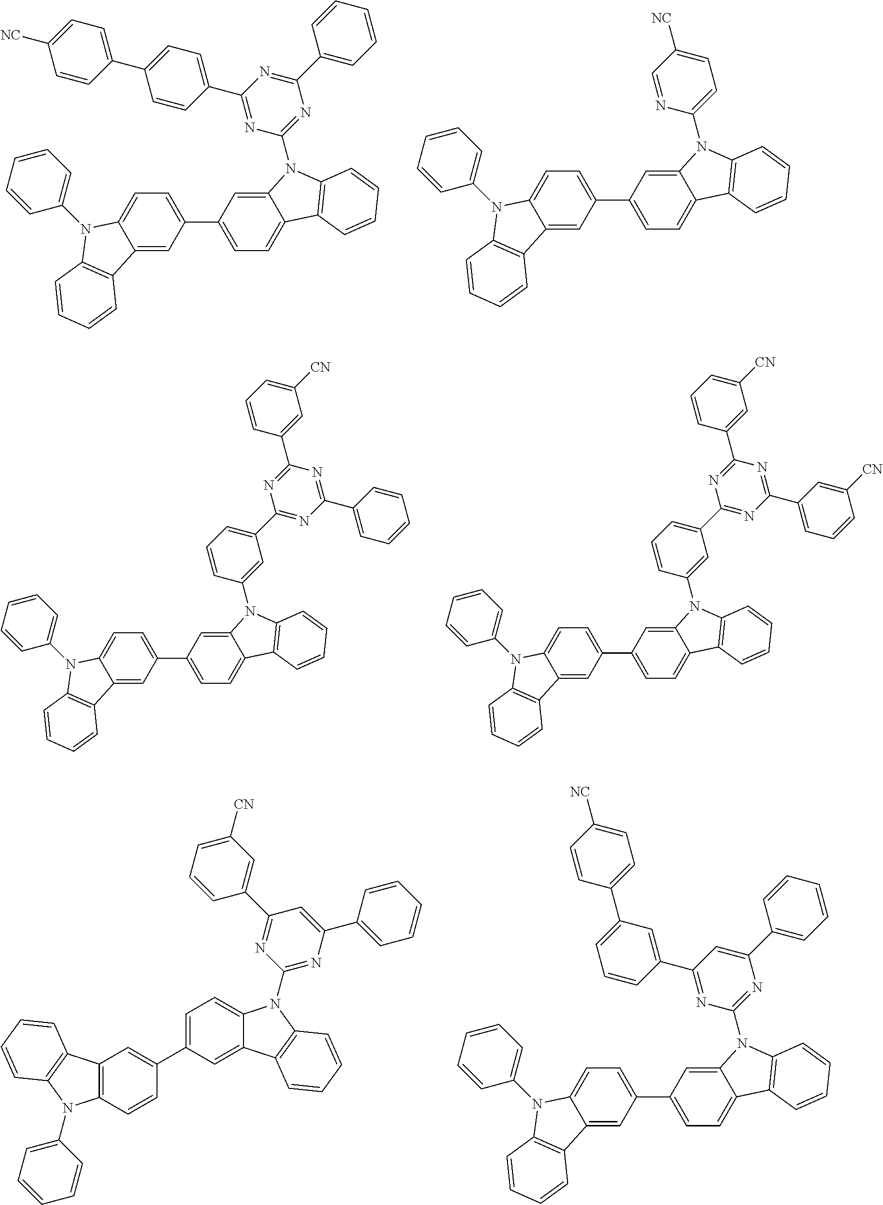

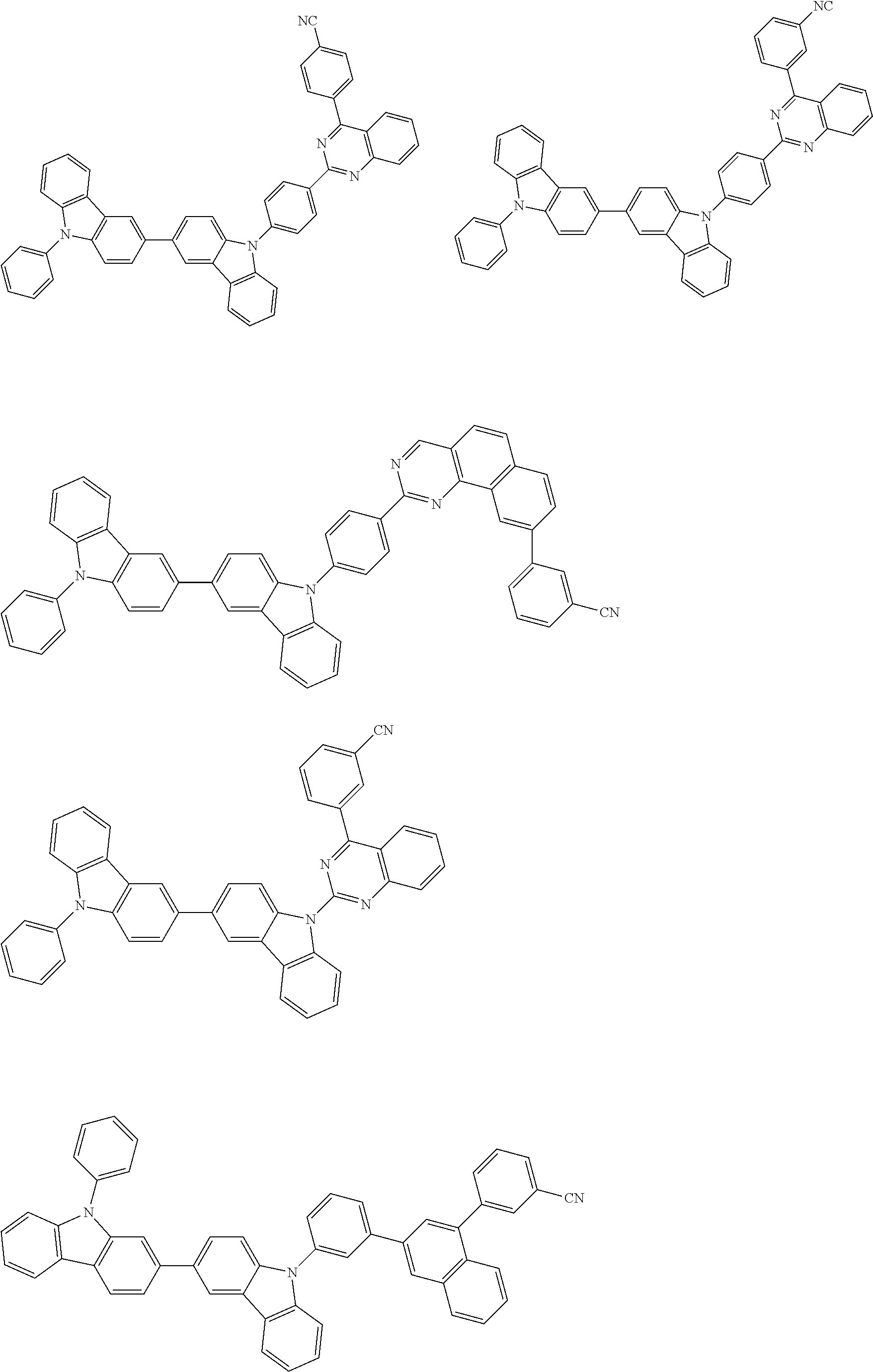

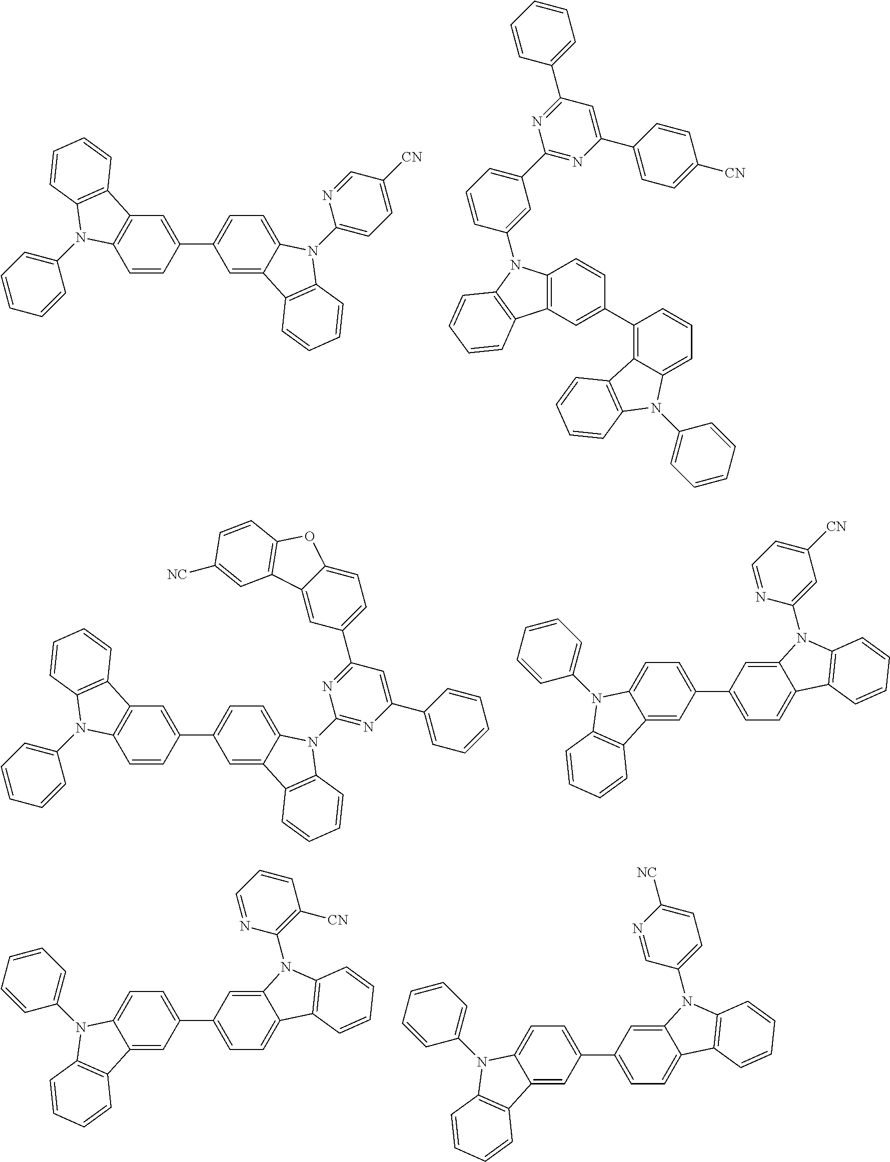

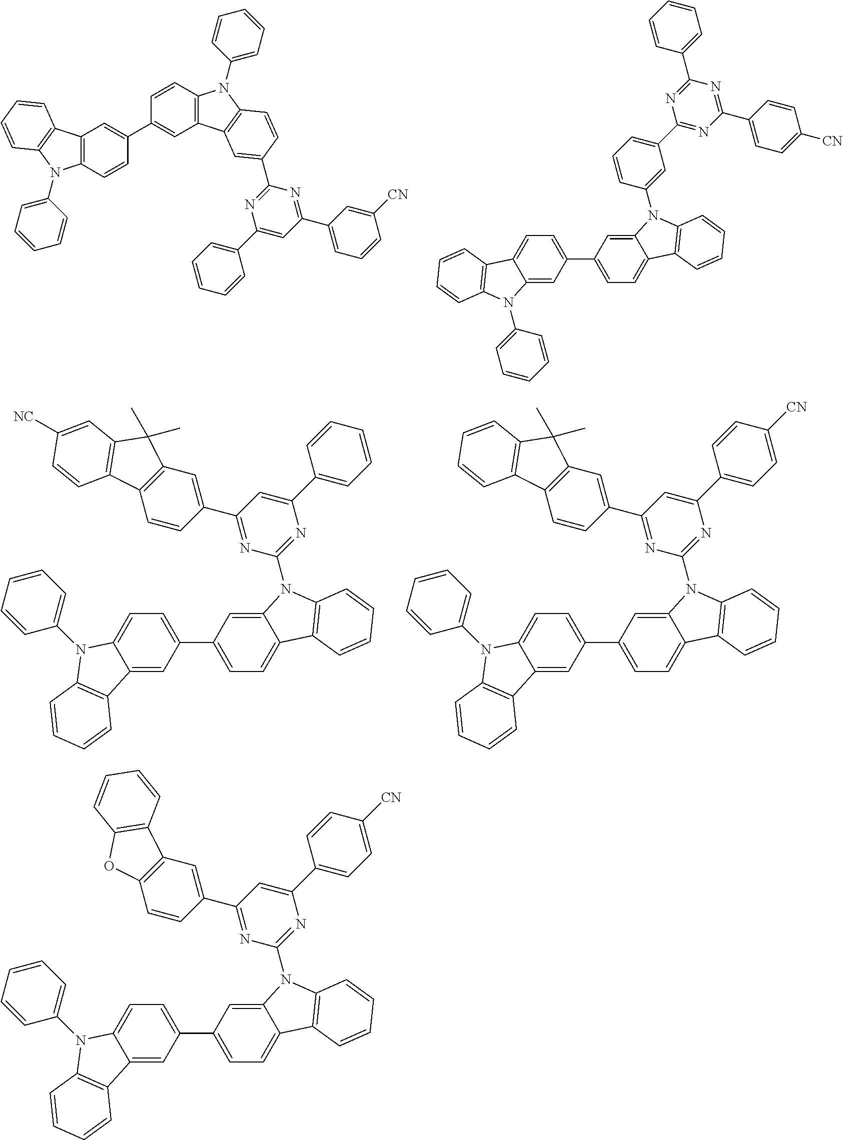

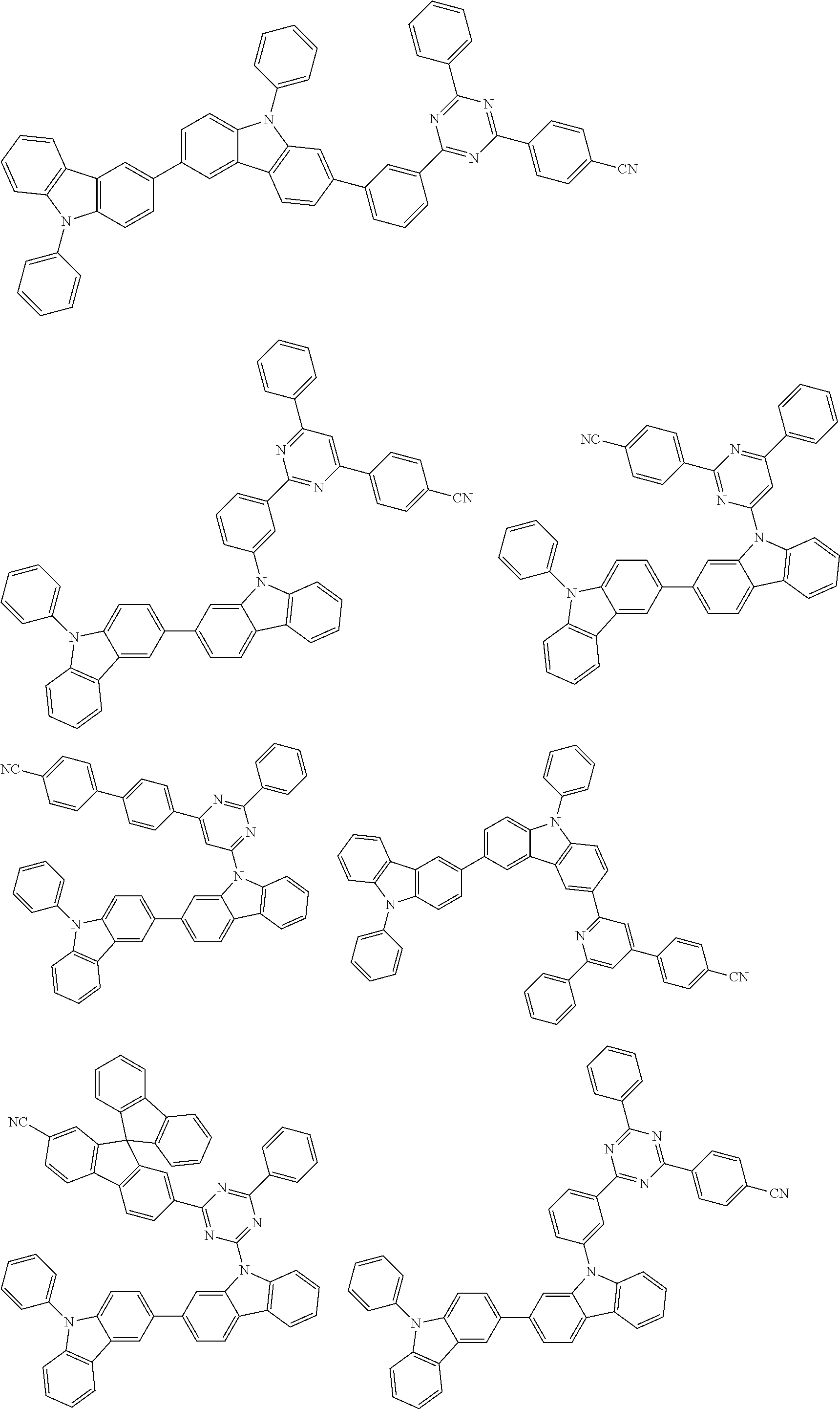

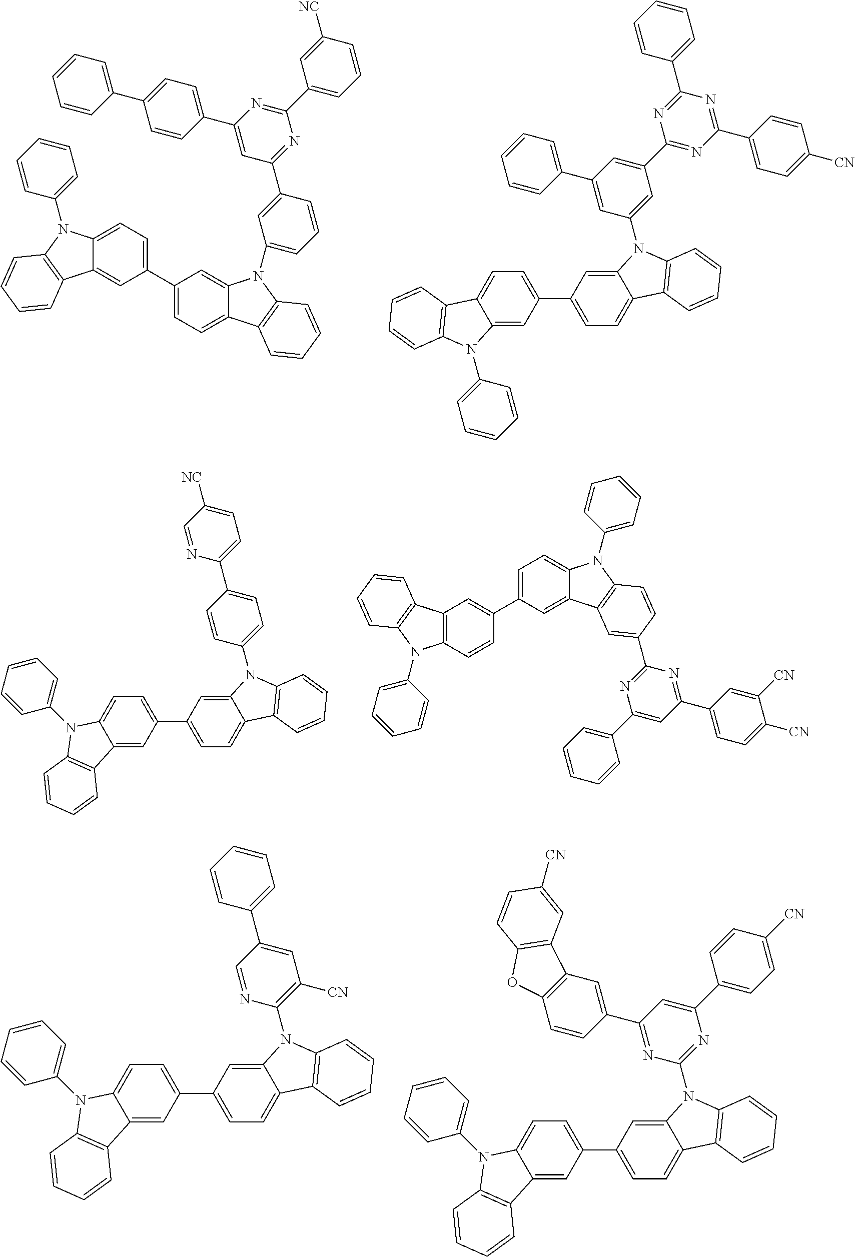

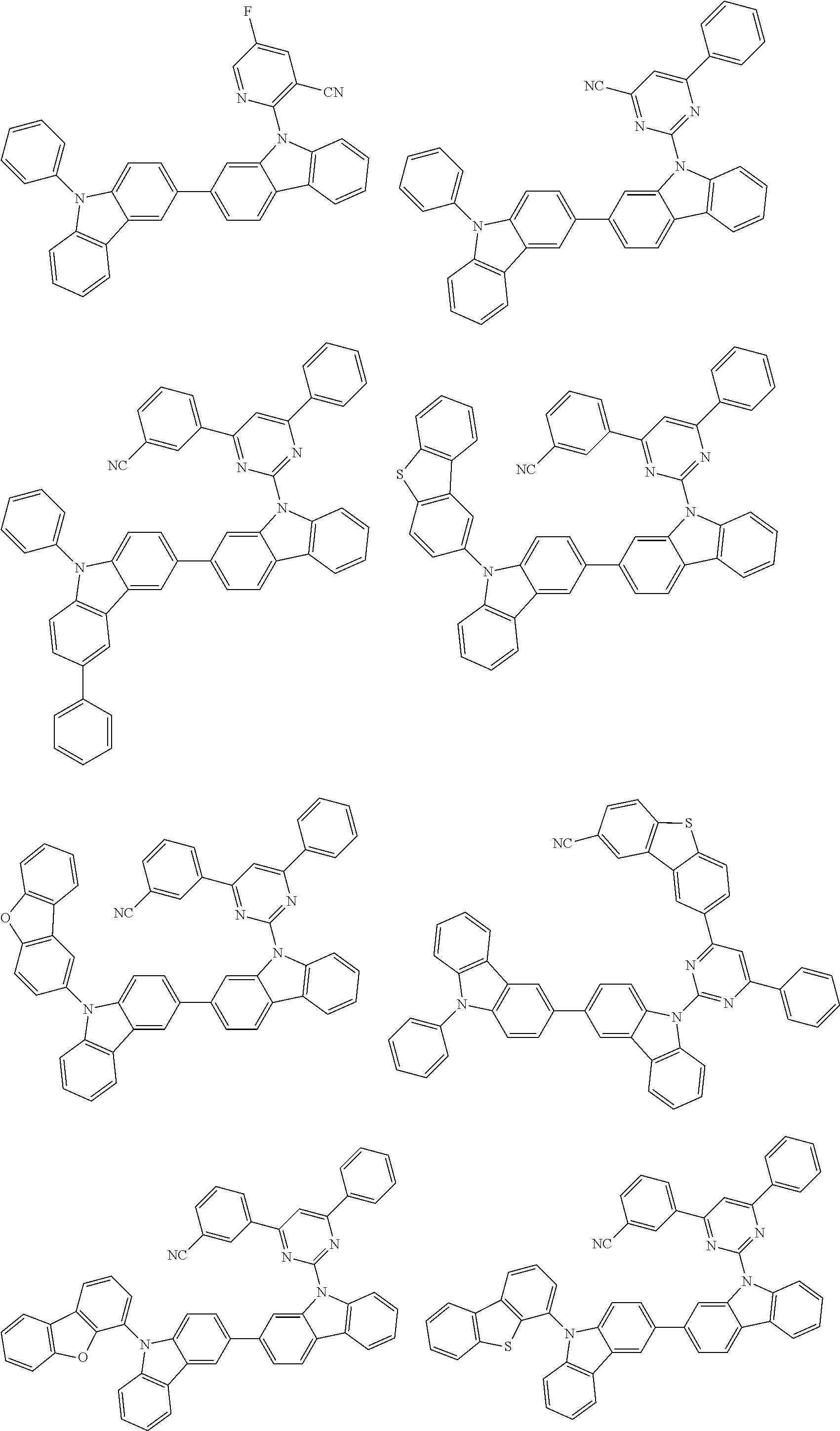

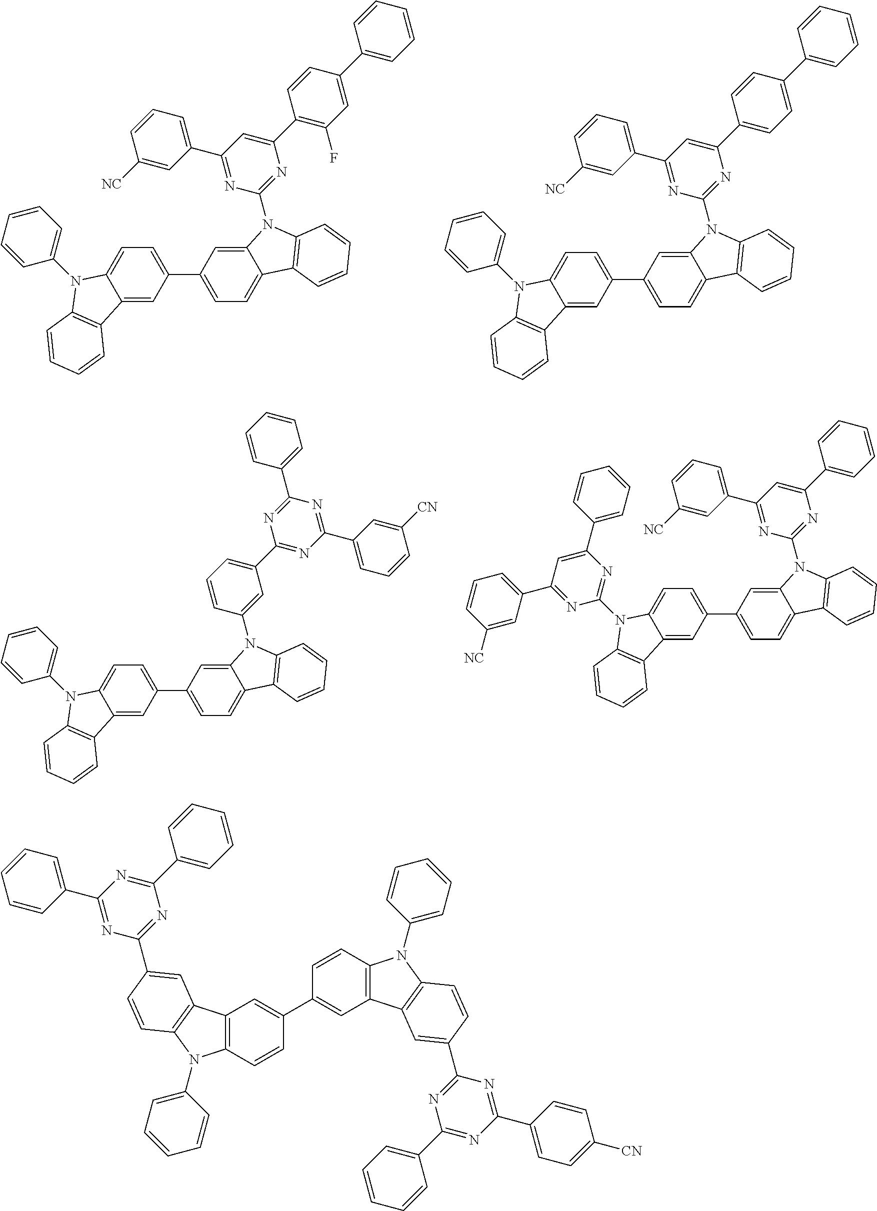

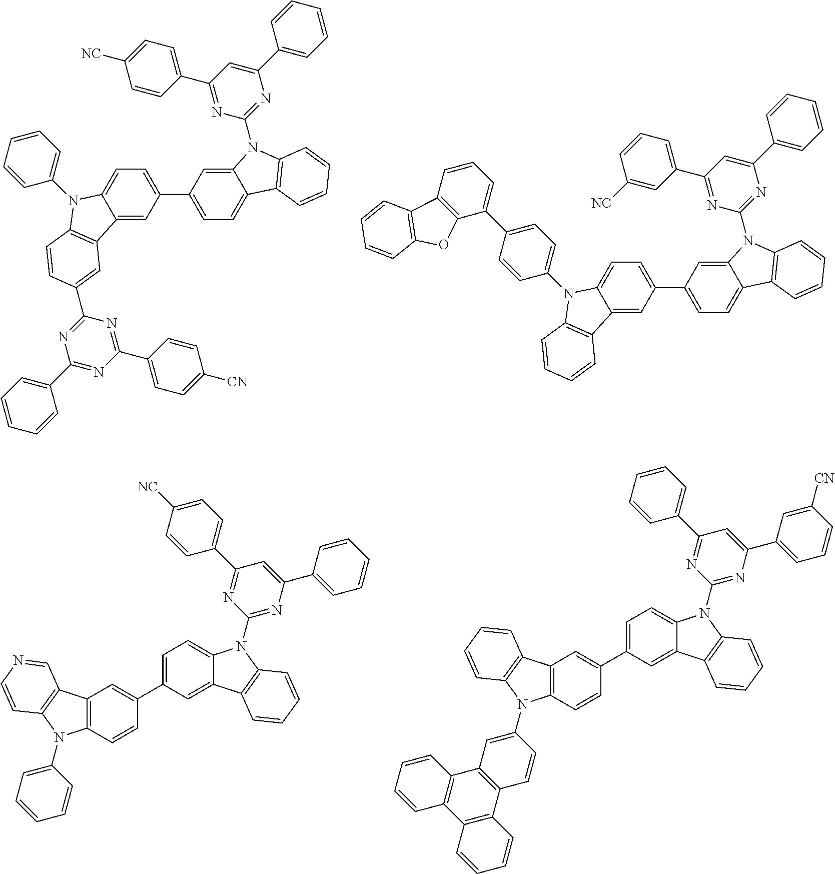 [SMILES: N#Cc1ccc(-c2cc(-c3ccccc3)nc(-n3c4ccccc4c4ccc(-c5ccc6c(c5)c5cc(-c7nc(-c8ccccc8)nc(-c8ccc(C#N)cc8)n7)ccc5n6-c5ccccc5)cc43)n2)cc1 ; N#Cc1cccc(-c2cc(-c3ccccc3)nc(-n3c4ccccc4c4ccc(-c5ccc6c(c5)c5ccccc5n6-c5ccc(-c6cccc7c6oc6ccccc67)cc5)cc43)n2)c1 ; N#Cc1ccc(-c2cc(-c3ccccc3)nc(-n3c4ccccc4c4cc(-c5ccc6c(c5)c5cnccc5n6-c5ccccc5)ccc43)n2)cc1 ; N#Cc1cccc(-c2cc(-c3ccccc3)nc(-n3c4ccccc4c4cc(-c5ccc6c(c5)c5ccccc5n6-c5ccc6c7ccccc7c7ccccc7c6c5)ccc43)n2)c1]

The aromatic heterocyclic derivative A can be synthesized by referring to WO2011/019156 or the like.

The aromatic heterocyclic derivative B can be synthesized by referring to WO2008/056746 or the like.

As the phosphorescent material (phosphorescent dopant) forming the first organic thin film layer, a metal complex compound can be given. The metal complex compound is preferably a compound comprising a metal atom selected from Ir, Pt, Os, Au, Re and Ru and a ligand. It is preferred that the ligand have an ortho-metalated bond.

In respect of capability of further improving the external quantum efficiency of an emitting device due to high phosphorescent quantum yield, a compound containing a metal atom selected from Ir, Os and Pt is preferable. A metal complex such as an iridium complex, an osmium complex and a platinum complex are further preferable, with an iridium complex and a platinum complex being more preferable. An ortho-metalated iridium complex is most preferable. The dopant may be used singly or in a mixture of two or more.

The concentration of the phosphorescent dopant in the first organic thin film layers is not particularly restricted, but is preferably 0.1 to 30 wt %, more preferably 0.1 to 10 wt %.

The configuration of the organic EL device of the invention is not particularly restricted as long as it has a structure in which the first organic thin film layer and the second organic thin film layer are stacked, and known device configurations can be used. Hereinbelow, the examples of the configuration of the organic EL device will be explained with reference to the drawings.

### Embodiment 1

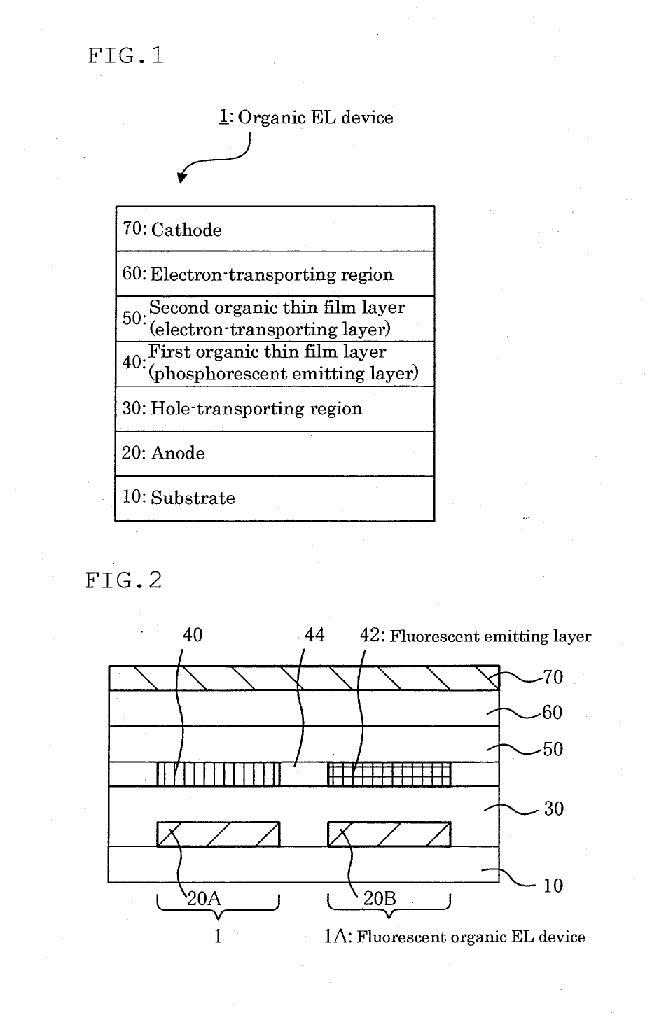

FIG. 1 is a schematic view showing the layer configuration of the organic EL device of the invention.

An organic EL device 1 has a configuration in which an anode 20, a hole-transporting region 30, a first organic thin film layer 40, a second organic thin film layer 50, an electron-transporting region 60 and a cathode 70 are stacked on a substrate 10 in this sequence. The hole-transporting region 30 means a hole-transporting layer, a hole-injecting layer or the like. Similarly, the electron-transporting region 60 means an electron-transporting layer or an electron-injecting layer or the like. They are not required to be formed. However, it is preferred that one or more of these layers be formed.

In the organic EL device 1, the first organic thin film layer 40 functions as a phosphorescent emitting layer, and the second organic thin film layer 50 functions as an electron-transporting layer and a hole-barrier layer.

When the first organic thin film layer 40 and the second organic thin film layer 50 are formed from the anode 20 side such that they are adjacent with each other, a gap in ionization potential is formed in the interface of the first organic thin film layer 40 and the second organic thin film layer 50. Therefore, holes supplied from the anode 20 side are blocked by the interface resistance of the first organic thin film layer 40 and the second organic thin film layer 50, and are retained in the first organic thin film layer 40. That is, the second organic thin film layer 50 functions as the hole-barrier layer. Further, since the aromatic heterocyclic derivative B has a large triplet energy, it also functions as an exciton-barrier layer.

On the other hand, the second organic thin film layer 50 has an excellent capability of withdrawing electrons from layers on the cathode 70 side, and hence, has excellent electron-transporting property. Therefore, electrons are also supplied to the first organic thin film layer 40 efficiently, and as a result, re-combination of holes and electrons in the first organic thin film layer 40 is promoted, whereby luminous efficiency is improved.

FIG. 1 is a view diagrammatically showing the organic EL device 1 as a single emitting unit. By combining the organic EL device 1 with other organic EL devices, an organic EL multi-layer emitting apparatus can be formed.

FIG. 2 is a schematic cross-sectional view showing an example of an organic EL emitting apparatus using an organic EL device 1.

The organic EL emitting apparatus shown in FIG. 2 is an apparatus in which the organic EL device 1 (first device) and a fluorescent organic EL device 1A as the second device are provided in parallel on the substrate 10.

The configuration of the organic EL device 1 is the same as that shown in FIG. 1, except that a patterned anode 20A is used. A fluorescent organic device 1A has the same configuration as that of the organic EL device 1, except that a fluorescent emitting layer 42 is formed as the emitting layer instead of the first organic thin film layer 40. Between the first organic thin film layer 40 and the fluorescent emitting layer 42, an insulating layer 44 that separates the emitting layers is provided.

The organic EL device 1 and the fluorescent organic EL device 1A have organic thin film layers (layers that form a hole-transporting region or an electron-transporting region) except for the emitting layers as common layers.

For example, by allowing the organic EL device 1 to emit yellow to red color light and the fluorescent organic EL device 1A to emit blue to green color light, an apparatus capable of multicolor emission can be obtained. In particular, when the fluorescent organic EL device 1A is allowed to be a device that emits blue color light and utilizes a TTF phenomenon (Triplet-Triplet-Fusion), the second organic thin film layer 50 functions as a triplet-barrier layer. As for a device utilizing a TTF phenomenon, reference can be made to WO2010/134350.

In this example, two types of organic EL devices are used. The configuration is, however, not limited thereto. Three or more types (three or more color) of organic EL devices can be used. A fluorescent organic EL device is exemplified as the second emitting device, but the second emitting device may be a phosphorescent emitting device.

In addition, although any of the layers forming the hole-transporting region or the electron-transporting region are formed as the common layer, it suffices that one of the layers be used as the common layer.

### Embodiment 2

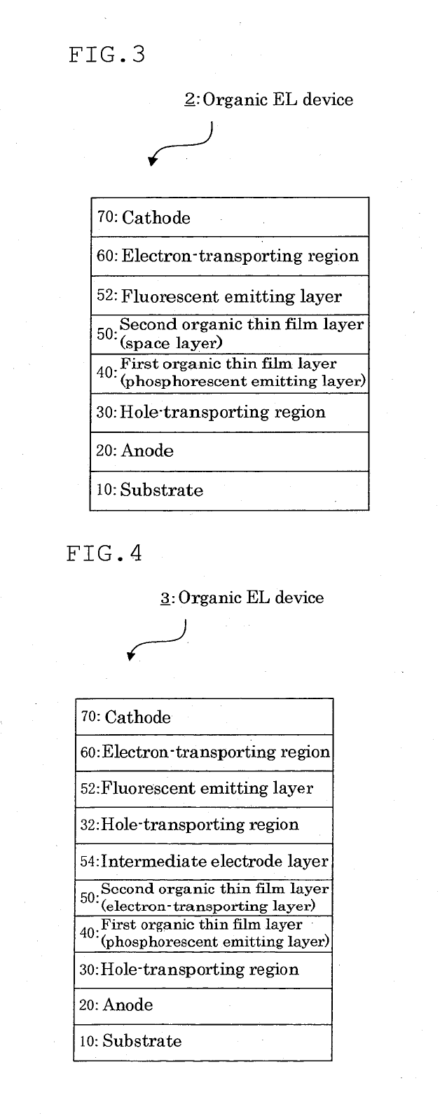

FIG. 3 is a schematic cross-sectional view showing the layer configuration of an organic EL device according to another embodiment of the invention.

An organic EL device 2 is an example of a hybrid-type organic EL device in which a phosphorescent emitting layer and a fluorescent emitting layer are stacked.

The organic EL device 2 has the same configuration as that of the above-mentioned organic EL device 1, except that a fluorescent emitting layer 52 is formed between the second organic thin film layer 50 and the electron-transporting region 60. In the organic EL device 2, the first organic thin film layer 40 functions as a phosphorescent emitting layer and the second organic thin film layer 50 functions as a space layer. In a configuration in which the phosphorescent emitting layer and the fluorescent emitting layer are stacked, in order to prevent excitons formed in the phosphorescent emitting layer from being diffused to the fluorescent emitting layer, there is a case where a space layer is formed between the fluorescent emitting layer and the phosphorescent emitting layer. The aromatic heterocyclic derivative B that forms the second organic thin film layer 50 has a large triplet energy (T1), and hence, it can function as a space layer.

In the organic EL device 2, by allowing the phosphorescent emitting layer to emit yellow color light and by allowing the fluorescent emitting layer to emit blue color light, a white-emitting organic EL device can be obtained. In this embodiment, one phosphorescent emitting layer and one fluorescent emitting layer are provided. The number of these layers is not limited thereto, and two or more of these layers may be formed. The number of these layers can be appropriately selected according to applications such as illuminations, displays, or the like. For example, when a full-color emitting apparatus is provided by utilizing a white color emitting device and a color filter, in respect of color rendering property, there is a case that it is preferred that emission of a plurality of wavelength regions such as red, green and blue (RGB) and red, green, blue and yellow (RGBY) be included.

### Embodiment 3

FIG. 4 is a schematic cross-sectional view showing the layer configuration of an organic EL device according to another embodiment of the invention.

An organic EL device 3 is an example of a tandem-type organic EL device in which a phosphorescent emitting layer and a fluorescent emitting layer are stacked through an intermediate electrode.

The organic EL device 3 has a configuration in which the anode 20, the hole-transporting region 30, the first organic thin film layer 40, the second organic thin film layer 50, an intermediate electrode layer 54, a hole-transporting region 32, a fluorescent emitting layer 52, the electron-transporting region 60 and a cathode 70 are stacked in this sequence on the substrate 10. A region disposed between the anode 20 and the intermediate electrode layer 54 is a first emitting unit (phosphorescent emission) and a region disposed between the intermediate electrode layer 54 and the cathode 70 is a second emitting unit (phosphorescent emission).

In the organic EL device 3, the first organic thin film layer functions as a phosphorescent emitting layer and the second organic thin film layer 50 functions as an electron-transporting layer and a hole-barrier layer.

In the organic EL device 3, by allowing the phosphorescent emitting layer to emit yellow color light and by allowing the fluorescent emitting layer to emit blue color light, a white-emitting organic EL device can be obtained. In this embodiment, two emitting units are provided. However, the number of emitting units is not limited to two, and three or more of emitting units can be formed. As in the case of the above-mentioned organic EL device 2, the number of emitting units can be appropriately selected according to applications such as illuminations, displays, or the like.

As in the case of the above-mentioned embodiments 1 to 3, the organic EL device of the invention can have various known configurations. Further, emission from the emitting layer can be outcoupled from the anode or the cathode, or the both of the anode and the cathode.

In the organic EL device of the invention, it is preferred that a layer comprising a compound represented by the following formula (10) be bonded to the anode. This compound has a strong accepter property and hence, due to the provision of this layer, the amount of holes injected to the emitting layer is further increased. In the device in which the amount of injected holes is large, the configuration of the invention exhibits further significantly advantageous effects.

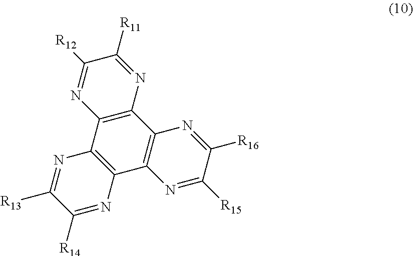

In the formula, R₁₁ to R₁₆ are independently a cyano group, —CONH₂, a carboxy group or —COOR₁₇ (R₁₇ is an alkyl group including 1 to 20 carbon atoms), or R₁₁ and R₁₂, R₁₃ and R₁₄ or R₁₅ and R₁₆ are bonded with each other to form —CO—O—CO—.

As the alkyl group including 1 to 20 carbon atoms represented by R₁₇, a linear or branched alkyl group can be given. Specifically, a methyl group, an ethyl group, a propyl group, an isopropyl group, an n-butyl group, an isobutyl group, a sec-butyl group, a tert-butyl group, an n-pentyl group, an n-hexyl group, an n-heptyl group, an n-octyl group or the like can be given. A methyl group, an ethyl group, a propyl group, an isopropyl group, an n-butyl group, an isobutyl group, a sec-butyl group and a tert-butyl group are preferable.

R₁₁ to R₁₆ are preferably a cyano group.

In the organic EL device of the invention, other configurations of the first organic thin film layer and the second organic thin film layer as mentioned above are not particularly restricted, and known materials or the like can be used. Hereinbelow, a brief explanation will be made on the layer of the device according to the embodiment 1. However, materials to be applied to the organic EL device of the invention are not limited to those mentioned below.

### [Substrate]

As the substrate, a glass sheet, a polymer sheet or the like can be used.

Examples of materials of the glass sheet include soda lime glass, barium-strontium-containing glass, lead glass, aluminosilicate glass, borosilicate glass, barium borosilicate glass, quartz, and the like. Examples of materials of the polymer sheet include polycarbonate, acryl, polyethylene terephthalate, polyethersulfone, polysulfone, and the like.

### [Anode]

The anode is formed of a conductive material, for example. A conductive material having a work function larger than 4 eV is suitable.

As the conductive material, carbon, aluminum, vanadium, iron, cobalt, nickel, tungsten, silver, gold, platinum, palladium, alloys thereof, an oxide metal such as tin oxide and indium oxide used in an ITO substrate and a NESA substrate and an organic conductive resin such as polythiophene and polypyrrole can be given.

If necessary, the anode may be formed of two or more layers.

### [Cathode]

The cathode is formed of a conductive material, for example. A conductive material having a work function smaller than 4 eV is suitable.

As the conductive material, magnesium, calcium, tin, lead, titanium, yttrium, lithium, ruthenium, manganese, aluminum, lithium fluoride and alloys thereof can be given. The conductive material is not limited thereto.

As the alloy, a magnesium/silver alloy, a magnesium/indium alloy, a lithium/aluminum alloy or the like can be given as representative examples. The alloys are not limited thereto. The amount ratio of metals forming an alloy is controlled by the temperature of a deposition source, the atmosphere, the degree of vacuum or the like, and an appropriate ratio is selected.

If necessary, the cathode may be formed of two or more layers. The cathode can be formed by forming a thin film by a method such as deposition, sputtering or the like.

When outcoupling light from the emitting layer through the cathode, it is preferable that the cathode have a light transmittance of more than 10%.

The sheet resistance of the cathode is preferably several hundred Ω/square or less. The thickness of the anode is normally 10 nm to 1 μm, and preferably 50 to 200 nm.

### [Emitting Layer]

In the invention, the first organic thin film layer serves as a phosphorescent emitting layer. However, as in the case of an apparatus shown in FIG. 2, it may be combined with an organic EL device having a fluorescent emitting layer.

The emitting layer may have a double-host (host-cohost) configuration. More specifically, the carrier balance within the emitting layer may be adjusted by incorporating an electron-transporting host and a hole-transporting host in the emitting layer.

The emitting layer may also have a double-dopant configuration. When the emitting layer includes two or more dopant materials having a high quantum yield, each dopant emits light. For example, a yellow emitting layer may be implemented by co-depositing a host, a red dopant, and a green dopant.

The emitting layer may include only a single layer, or may have a stacked structure. When the emitting layer has a stacked structure, the recombination region can be concentrated at the interface between the stacked layers due to accumulation of electrons and holes there. This makes it possible to improve the quantum efficiency.

### [Hole-Injecting Layer and Hole-Transporting Layer]

The hole-injecting/transporting layer is a layer that assists injection of holes into the emitting layer, and transports holes to the emitting region. The hole-injecting/transporting layer exhibits a high hole mobility, and normally has a low ionization energy of 5.6 eV or less.

It is preferable to form the hole-injecting/transporting layer using a material that transports holes to the emitting layer at a low field intensity. It is more preferable to use a material having a hole mobility of at least 10⁻⁴ cm²/V·s when an electric field of 10⁴ to 10⁶ V/cm is applied, for example.

Specific examples of the material for forming the hole-injecting/transporting layer include triazole derivatives (see U.S. Pat. No. 3,112,197, for example), oxadiazole derivatives (see U.S. Pat. No. 3,189,447, for example), imidazole derivatives (see JP-B-37-16096, for example), polyarylalkane derivatives (see U.S. Pat. No. 3,615,402, U.S. Pat. No. 3,820,989, U.S. Pat. No. 3,542,544, JP-B-45-555, JP-B-51-10983, JP-A-51-93224, JP-A-55-17105, JP-A-56-4148, JP-A-55-108667, JP-A-55-156953, and JP-A-56-36656, for example), pyrazoline derivatives and pyrazolone derivatives (U.S. Pat. No. 3,180,729, U.S. Pat. No. 4,278,746, JP-A-55-88064, JP-A-55-88065, JP-A-49-105537, JP-A-55-51086, JP-A-56-80051, JP-A-56-88141, JP-A-57-45545, JP-A-54-112637, and JP-A-55-74546, for example), phenylenediamine derivatives (U.S. Pat. No. 3,615,404, JP-B-51-10105, JP-B-46-3712, JP-B-47-25336, and JP-B-54-119925, for example), arylamine derivatives (U.S. Pat. No. 3,567,450, U.S. Pat. No. 3,240,597, U.S. Pat. No. 3,658,520, U.S. Pat. No. 4,232,103, U.S. Pat. No. 4,175,961, U.S. Pat. No. 4,012,376, JP-B-49-35702, JP-B-39-27577, JP-A-55-144250, JP-A-56-119132, JP-A-56-22437, and West German Patent No. 1,110,518, for example), amino-substituted chalcone derivatives (U.S. Pat. No. 3,526,501, for example), oxazole derivatives (see U.S. Pat. No. 3,257,203, for example), styrylanthracene derivatives (JP-A-56-46234, for example), fluorenone derivatives (JP-A-54-110837, for example), hydrazone derivatives (U.S. Pat. No. 3,717,462, JP-A-54-59143, JP-A-55-52063, JP-A-55-52064, JP-A-55-46760, JP-A-57-11350, JP-A-57-148749, and JP-A-2-311591, for example), stilbene derivatives (JP-A-61-210363, JP-A-61-228451, JP-A-61-14642, JP-A-61-72255, JP-A-62-47646, JP-A-62-36674, JP-A-62-10652, JP-A-62-30255, JP-A-60-93455, JP-A-60-94462, JP-A-60-174749, and JP-A-60-175052, for example), silazane derivatives (U.S. Pat. No. 4,950,950, for example), polysilane compounds (JP-A-2-204996, for example), aniline copolymers (JP-A-2-282263, for example), and the like.

An inorganic compound (e.g., p-type Si or p-type SiC) may also be used as the hole-injecting material.

A crosslinkable material may be used as the material for forming the hole-injecting/transporting layer. Examples of the crosslinkable hole-injecting/transporting layer include layers obtained by insolubilizing crosslinkable materials disclosed in Chem. Mater. 2008, 20, pp. 413-422, Chem. Mater. 2011, 23 (3), pp. 658-681, WO2008/108430, WO2009/102027, WO2009/123269, WO2010/016555, WO2010/018813, and the like by applying heat, light, and the like.

### [Electron-Injecting Layer and Electron-Transporting Layer]

The electron injecting/transporting layer is a layer that assists injection of electrons into the emitting layer, and transports electrons to the emitting region. The electron injecting/transporting layer exhibits high electron mobility.

In an organic EL device, since emitted light is reflected by an electrode (e.g., cathode), it is known that light that is outcoupled directly through the anode interferes with light that is outcoupled after being reflected by the electrode. The thickness of the electron-injecting/transporting layer is appropriately selected within the range of several nanometers to several micrometers in order to efficiently utilize this interference effect. In particular, when the electron-injecting/transporting layer has a large thickness, it is preferable that the electron mobility be at least 10⁻⁵ cm²/Vs or more at an applied electric field of 10⁴ to 10⁶ V/cm in order to prevent an increase in voltage.

An aromatic heterocyclic compound having one or more hetero atoms in the molecule is preferably used as an electron-transporting material used for forming the electron-injecting/transporting layer. It is particularly preferable to use a nitrogen-containing ring derivative. An aromatic ring having a nitrogen-containing 6-membered or 5-membered ring skeleton, or a fused aromatic ring compound having a nitrogen-containing 6-membered ring or a 5-membered ring skeleton is preferable as the nitrogen-containing ring derivative.

An organic layer that exhibits semiconductivity may be formed by doping (n) with a donor material and doping (p) with an acceptor material. Typical examples of N-doping include doping a material for an electron-transporting layer with a metal such as Li or Cs, and typical examples of P-doping include doping a material for a hole-transporting layer with an acceptor material such as F4TCNQ (see Japanese Patent No. 3695714, for example).

Each layer of the organic EL device according to the invention may be formed by a known method, e.g., a dry film-forming method such as vacuum deposition, sputtering, plasma coating, or ion plating, or a wet film-forming method such as spin coating, dipping, or flow coating.

The thickness of each layer is not particularly limited as long as each layer has an appropriate thickness. If the thickness of each layer is too large, a high applied voltage may be required to obtain constant optical output, so that the efficiency may deteriorate. If the thickness of each layer is too small, pinholes or the like may occur, so that sufficient luminance may not be obtained even if an electric field is applied. The thickness of each layer is preferably 5 nm to 10 μm, and more preferably 10 nm to 0.2 μm.

### EXAMPLES

### Synthesis Example 1

### Synthesis of Intermediate 1-1

An intermediate 1-1 was synthesized in accordance with the following synthesis scheme.

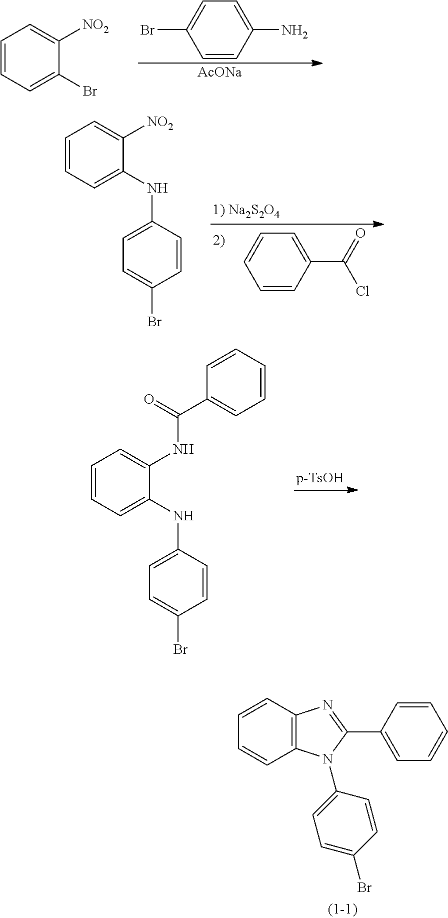

10 g (49.5 mmol) of 2-bromonitrobenzene, 13 g (163 mmol) of sodium acetate and 10 g (59 mmol) of 4-bromoaniline were heated with stirring at 180° C. for 8 hours in an argon atmosphere. The reaction solution was cooled to room temperature, diluted with ethyl acetate and filtered. The filtrate was concentrated, and residues were washed with methanol, whereby 3.8 g of (4-bromophenyl)-(2-nitrophenyl)amine was obtained in the form of orange crystals (yield: 22%).

3.8 g (13 mmol) of (4-bromophenyl)-(2-nitrophenyl)amine was dissolved in 30 mL of tetrahydrofuran. When the resulting solution was stirred at room temperature in an argon atmosphere, a solution of 11 g (64 mmol) of sodium hydrosulfate and 30 ml of water was added dropwise. After stirring for 5 hours, 20 mL of ethyl acetate was added, thereby to obtain a solution of 2.2 g (26 mmol) of sodium hydrogen carbonate and 20 ml of water. Further, a solution of 2.5 g (18 mmol) of benzoyl chloride and 10 ml of ethyl acetate was added dropwise, and stirred at room temperature for 1 hour. The resultant was extracted with ethyl acetate, and washed with a 10% aqueous solution of potassium carbonate, water and brine in this sequence, and dried with anhydrous sodium sulfate. The solvent was distilled off under reduced pressure, whereby 2.1 g (yield: 45%) of N-[2-(4-bromophenylamino)phenyl]benzamide was obtained.

2.1 g (5.7 mmol) of N-[2-(4-bromophenylamino)phenyl]benzamide was suspended in 30 ml of xylene. To the resulting suspension, 0.6 g (2.9 mmol) of p-toluenesulfonic acid monohydrate was added, and azeotropic dehydration was conducted under reflux while heating for 3 hours. After being allowed to be cooled, ethyl acetate, methylene chloride and water were added to the reaction solution, and insoluble matters were removed by filtration. An organic phase was extracted from the mother liquid, washed with water and brine, dried with anhydrous sodium sulfate. The solvent was distilled off under reduced pressure. Residues were purified by silica gel chromatography, whereby 1.0 g of slightly pinkish white crystals were obtained. By the FD-MS analysis, the crystals were identified as the intermediate 1-1 (yield: 52%).

### Synthesis Example 2

### Synthesis of Intermediate 1-2

An intermediate 1-2 was synthesized in accordance with the following synthesis scheme.

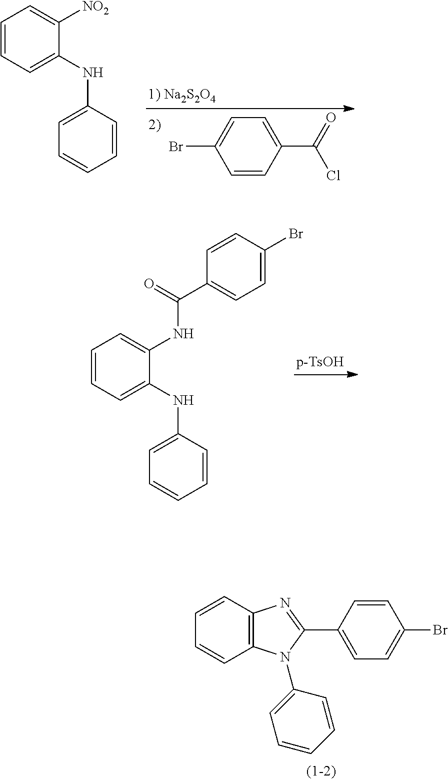 [SMILES: O=[N+]([O-])c1ccccc1Nc1ccccc1 ; O=C(Cl)c1ccc(Br)cc1 ; O=C(Nc1ccccc1Nc1ccccc1)c1ccc(Br)cc1 ; Brc1ccc(-c2nc3ccccc3n2-c2ccccc2)cc1]

2.8 g (13 mmol) of 2-nitrodiphenylamine was suspended in 30 mL of tetrahydrofuran. When the resulting solution was stirred at room temperature in an argon atmosphere, a solution of 11 g (64 mmol) of sodium hydrosulfate and 30 ml of water was added dropwise. After stirring for 5 hours, 20 mL of ethyl acetate was added, thereby to obtain a solution of 2.2 g (26 mmol) of sodium hydrogen carbonate and 20 ml of water. Further, a solution of 4.0 g (18 mmol) of 4-bromobenzoyl chloride and 10 ml of ethyl acetate was added dropwise, and stirred at room temperature for 1 hour. The resultant was extracted with ethyl acetate, and washed with a 10% aqueous solution of potassium carbonate, water and brine in this sequence, and dried with anhydrous sodium sulfate. The solvent was distilled off under reduced pressure, whereby 2.1 g (yield: 45%) of 4-bromo-N-(2-(phenylamino)phenyl)benzamide was obtained.

2.1 g (5.7 mmol) of 4-bromo-N-(2-(phenylamino)phenyl)benzamide was suspended in 30 ml of xylene. To the resulting suspension, 0.6 g (2.9 mmol) of p-toluenesulfonic acid monohydrate was added, and azeotropic dehydration was conducted under reflux while heating for 3 hours. After being allowed to be cooled, ethyl acetate, methylene chloride and water were added to the reaction solution, and insoluble matters were removed by filtration. An organic phase was extracted from the mother liquid, washed with water and brine, dried with anhydrous sodium sulfate. The solvent was distilled off under reduced pressure. Residues were purified by silica gel chromatography, whereby 1.2 g of slightly pinkish white crystals were obtained. By the FD-MS analysis, the crystals were identified as the intermediate 1-2 (yield: 54%).

### Synthesis Example 3

### Synthesis of Intermediate 1-3

The following intermediate 1-3 was synthesized.

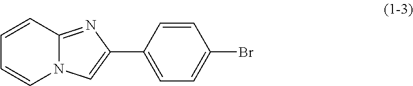 [SMILES: Brc1ccc(-c2cn3ccccc3n2)cc1]

15 g (54 mmol) of 4-bromobromophenacyl bromide and 5.2 g (55 mmol) of 2-aminopyridine were dissolved in 100 ml of ethanol. 7.0 g of sodium hydrogen carbonate was added, and the resultant was refluxed with heating for 6 hours. After the completion of the reaction, generated crystals were collected by filtration, washed with water and ethanol, whereby 12.5 g of white crystals were obtained. By the FD-MS analysis, the crystals were identified as the intermediate 1-3 (yield: 85%).

### Synthesis Example 4

### Synthesis of Intermediate 1-4

The following intermediate 1-4 was synthesized.

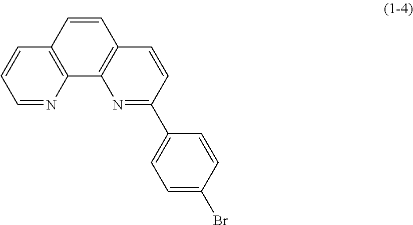 [SMILES: Brc1ccc(-c2ccc3ccc4cccnc4c3n2)cc1]

In a dark room and in an argon atmosphere, 32.7 g (138.6 mmol) of 1,4-dibromobenzene was dissolved in a mixed solvent of 80 ml of dehydrated ether and 240 ml of dehydrated toluene, and the resulting solution was cooled to −10° C. 76 ml (121.9 mmol) of a 1.6M n-butylllithium-hexane solution was added dropwise at 0° C., and stirred for 1 hour. In another reaction vessel, 10.0 g (55.4 mmol) of phenanthroline was dissolved in a mixed solvent of 30 ml of dehydrated ether and 100 ml of dehydrated toluene, and the resulting solution was cooled to 5° C. The L₁ body as prepared above was transferred by means of a cannula. After the lapse of 2.5 hours, 80 ml of water was added dropwise. The reaction liquid was separated, and an aqueous phase was extracted with ethyl acetate, washed with water and brine, and dried with Na₂SO₄. An organic phase was concentrated to about half, and then poured to another reaction vessel in an argon atmosphere. 38.5 g (443.9 mmol) of manganese oxide was added, and stirred for 20 hours. After celite filtration, the filtrate was concentrated and re-crystallized, whereby 15.3 g of white solids were obtained. By the FD-MS analysis, the crystals were identified as the intermediate 1-4 (yield: 82%).

### Synthesis Example 5

### Synthesis of Intermediate 2-1

The following intermediate 2-1 was synthesized.

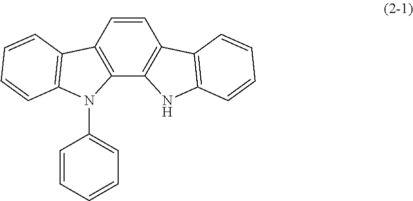 [SMILES: c1ccc(-n2c3ccccc3c3ccc4c5ccccc5[nH]c4c32)cc1]

In an argon atmosphere, 90 ml of dehydrated 1,4-dioxane was added to 15.0 g (58.5 mmol) of indolo[2,3-a]carbazole (synthesized by a method described in Synlett. p. 42-48 (2005)), 11.9 g (58.5 mmol) of iodobenzene, 11.2 g (58.5 mmol) of copper iodide, 20.0 g (175.5 mmol) of trans-1,2-cyclohexanediamine and 37.3 g (175.5 mmol) of tripotassium phosphate, and the resultant was stirred under reflux while heating for 24 hours. To residues obtained by concentrating the reaction solution under reduced pressure, 500 ml of toluene was added. The resultant was heated to 120° C., and insoluble matters were separated by filtration. The filtrate was concentrated under reduced pressure, and residues were purified by silica gel chromatography, whereby 10.0 g of white solids were obtained. By the FD-MS analysis, the solids were identified as the intermediate 2-1 (yield: 51%).

### Synthesis Example 6

### Synthesis of Intermediate 2-2

The following intermediate 2-2 was synthesized.

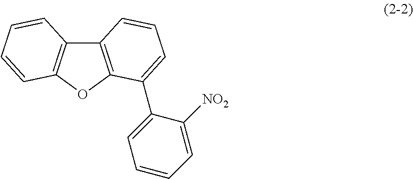 [SMILES: O=[N+]([O-])c1ccccc1-c1cccc2c1oc1ccccc12]

In an argon atmosphere, to 25.0 g (123.8 mmol) of 2-bromonitrobenzene and 31.5 g (148.5 mmol) of 4-benzofuranboronic acid, 124 ml (248 mmol) of a 2M aqueous solution of Na₂CO₃, DME (250 ml), toluene (250 ml) and 7.2 g (6.2 mmol) of Pd[PPh₃]₄ were added, and the resulting mixture was stirred under reflux while heating for 12 hours.

After completion of the reaction, the reaction solution was cooled to room temperature. The reaction solution was transferred to a separating funnel, and water (500 ml) was added and extracted with dichloromethane. After drying with MgSO₄, the extracted product was filtered and concentrated. The concentrate was purified by silica gel column chromatography, whereby 24.0 g of white solids were obtained. By the FD-MS analysis, the solids were identified as the intermediate 2-2 (yield: 67%).

### Synthesis Example 7

### Synthesis of Intermediate 2-3

The following intermediate 2-3 was synthesized.

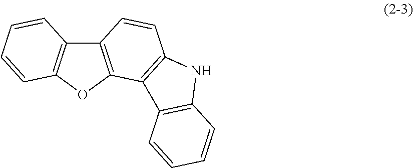 [SMILES: c1ccc2c(c1)[nH]c1ccc3c4ccccc4oc3c12]

In an argon atmosphere, to 24.0 g (83.0 mmol) of intermediate 2-4 and 54.4 g (207.4 mmol) of triphenylphosphine, dimethylacetamide (166 ml) was added, and the resulting mixture was stirred under reflux while heating for 20 hours.

After completion of the reaction, the reaction solution was cooled to room temperature. The sample was transferred to a separating funnel, and water (400 ml) was added and extracted with dichloromethane. After drying with MgSO₄, the extracted product was filtered and concentrated. The concentrate was purified by silica gel column chromatography, whereby 14.5 g of white solids were obtained. By the FD-MS analysis, the solids were identified as the intermediate 2-3 (yield: 68%).

### Synthesis Example 8

### Synthesis of Intermediate 2-4

The following intermediate 2-4 was synthesized.

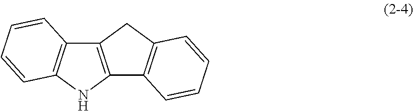 [SMILES: c1ccc2c(c1)Cc1c-2[nH]c2ccccc12]

18.7 g (142.0 mmol) of 1-indanone and 20.5 g (142.0 mmol) of phenylhydrazium chloride were added to 400 ml of ethanol. To the resulting solution, 2.0 ml of concentrated sulfuric acid was added, and the resultant was stirred under reflux while heating for 8 hours. The reaction solution was allowed to be cooled, and precipitates were collected by filtration. The solids collected by filtration were washed with 500 ml of methanol. A crude product was re-crystallized, whereby 17.5 g of white solids were obtained. By the FD-MS analysis, the solids were identified as the intermediate 2-4 (yield: 60%).

### Synthesis Example 9

### Production of Aromatic Heterocyclic Derivative (E1)

The following aromatic heterocyclic derivative (E1) was synthesized.

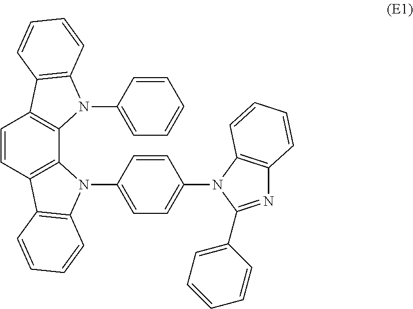 [SMILES: c1ccc(-c2nc3ccccc3n2-c2ccc(-n3c4ccccc4c4ccc5c6ccccc6n(-c6ccccc6)c5c43)cc2)cc1]

In an argon atmosphere, to 3.5 g (10.0 mmol) of intermediate 1-1, 3.3 g (10.0 mmol) of intermediate 2-1, 0.14 g (0.15 mmol) of Pd₂(dba)₃, 0.087 g (0.3 mmol) of P(tBu)₃HBF₄ and 1.9 g (20.0 mmol) of sodium t-butoxide, 50 ml of anhydrous xylene was added, and the resultant was refluxed while heating for 8 hours.

After completion of the reaction, the reaction liquid was cooled to 50° C., and filtered through celite and silica gel. The filtrate was concentrated. The resulting concentrated residues were purified by silica gel chromatography, whereby white solids were obtained. A crude product was re-crystallized with toluene, whereby 1.0 g of white crystals were obtained. By the FD-MS analysis, the solids were identified as the aromatic heterocyclic derivative (E1) (yield: 17%).

FD-MS analysis C43H28N4: Theoretical value: 600, Observed value: 600

### Synthesis Example 10

### Production of Aromatic Heterocyclic Derivative (E2)

The following aromatic heterocyclic derivative (E2) was synthesized.

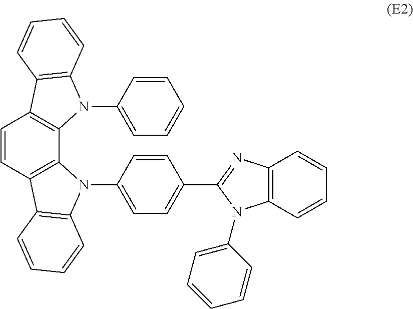 [SMILES: c1ccc(-n2c(-c3ccc(-n4c5ccccc5c5ccc6c7ccccc7n(-c7ccccc7)c6c54)cc3)nc3ccccc32)cc1]

A reaction was conducted in the same manner as in Synthesis Example 9, except that 3.5 g of intermediate 1-2 was used instead of intermediate 1-1. As a result, 1.2 g of white crystals were obtained. By the FD-MS analysis, the crystals were identified as the aromatic heterocyclic derivative (E2) (yield: 20%).

FD-MS analysis C43H28N4: Theoretical value: 600, Observed value: 600

### Synthesis Example 11

### Production of Aromatic Heterocyclic Derivative (E3)

The following aromatic heterocyclic derivative (E3) was synthesized.

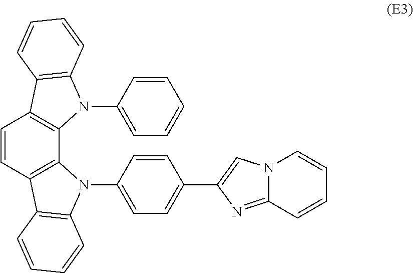 [SMILES: c1ccc(-n2c3ccccc3c3ccc4c5ccccc5n(-c5ccc(-c6cn7ccccc7n6)cc5)c4c32)cc1]

A reaction was conducted in the same manner as in Synthesis Example 9, except that 2.7 g of intermediate 1-3 was used instead of intermediate 1-1. As a result, 1.3 g of white crystals were obtained. By the FD-MS analysis, the crystals were identified as the aromatic heterocyclic derivative (E3) (yield: 25%).

FD-MS analysis C37H24N4: Theoretical value: 524, Observed value: 524

### Synthesis Example 12

### Production of Aromatic Heterocyclic Derivative (E4)

The following aromatic heterocyclic derivative (E4) was synthesized.

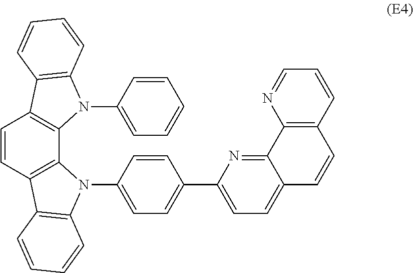 [SMILES: c1ccc(-n2c3ccccc3c3ccc4c5ccccc5n(-c5ccc(-c6ccc7ccc8cccnc8c7n6)cc5)c4c32)cc1]

A reaction was conducted in the same manner as in Synthesis Example 9, except that 3.4 g of intermediate 1-4 was used instead of intermediate 1-1. As a result, 1.1 g of white crystals were obtained. By the FD-MS analysis, the crystals were identified as the aromatic heterocyclic derivative (E4) (yield: 19%).

FD-MS analysis C42H26N4: Theoretical value: 586, Observed value: 586

### Synthesis Example 13

### Production of Aromatic Heterocyclic Derivative (E5)

The following aromatic heterocyclic derivative (E5) was synthesized.

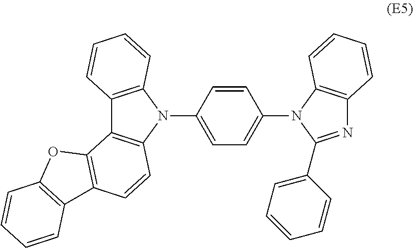 [SMILES: c1ccc(-c2nc3ccccc3n2-c2ccc(-n3c4ccccc4c4c5oc6ccccc6c5ccc43)cc2)cc1]

A reaction was conducted in the same manner as in Synthesis Example 9, except that 2.6 g of intermediate 2-3 was used instead of intermediate 2-1. As a result, 2.6 g of white crystals were obtained. By the FD-MS analysis, the crystals were identified as the aromatic heterocyclic derivative (E5) (yield: 50%).

FD-MS analysis C37H23N30: Theoretical value: 525, Observed value: 525

### Synthesis Example 14

### Production of Aromatic Heterocyclic Derivative (E6)

The following aromatic heterocyclic derivative (E6) was synthesized.

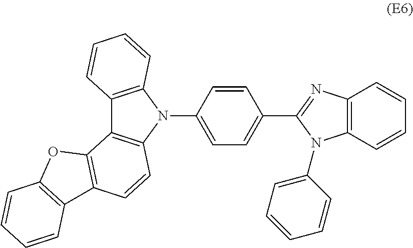 [SMILES: c1ccc(-n2c(-c3ccc(-n4c5ccccc5c5c6oc7ccccc7c6ccc54)cc3)nc3ccccc32)cc1]

A reaction was conducted in the same manner as in Synthesis Example 9, except that 3.5 g of intermediate 1-2 was used instead of intermediate 1-1 and 2.6 g of intermediate 2-3 was used instead of intermediate 2-1. As a result, 2.6 g of white crystals were obtained. By the FD-MS analysis, the crystals were identified as the aromatic heterocyclic derivative (E6) (yield: 50%).

FD-MS analysis C37H23N30: Theoretical value: 525, Observed value: 525

### Synthesis Example 15

### Production of Aromatic Heterocyclic Derivative (E7)

An aromatic heterocyclic derivative (E7) was synthesized.

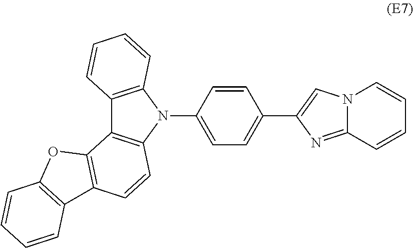 [SMILES: c1ccc2c(c1)oc1c2ccc2c1c1ccccc1n2-c1ccc(-c2cn3ccccc3n2)cc1]

A reaction was conducted in the same manner as in Synthesis Example 9, except that 2.7 g of intermediate 1-3 was used instead of intermediate 1-1 and 2.6 g of intermediate 2-3 was used instead of intermediate 2-1. As a result, 2.9 g of white crystals were obtained. By the FD-MS analysis, the crystals were identified as the aromatic heterocyclic derivative (E7) (yield: 65%).

FD-MS analysis C31H19N30: Theoretical value: 449, Observed value: 449

### Synthesis Example 16

### Production of Aromatic Heterocyclic Derivative (E8)

The following aromatic heterocyclic derivative (E8) was synthesized.

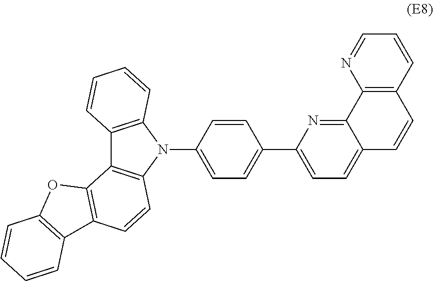 [SMILES: c1cnc2c(c1)ccc1ccc(-c3ccc(-n4c5ccccc5c5c6oc7ccccc7c6ccc54)cc3)nc12]

A reaction was conducted in the same manner as in Synthesis Example 9, except that 3.4 g of intermediate 1-4 was used instead of intermediate 1-1 and 2.6 g of intermediate 2-3 was used instead of intermediate 2-1. As a result, 2.0 g of white crystals were obtained. By the FD-MS analysis, the crystals were identified as the aromatic heterocyclic derivative (E8) (yield: 40%).

FD-MS analysis C36H21N30: Theoretical value: 511, Observed value: 511

### Synthesis Example 17

### Production of Aromatic Heterocyclic Derivative (E9)

The following aromatic heterocyclic derivative (E9) was synthesized according to the following synthesis scheme.

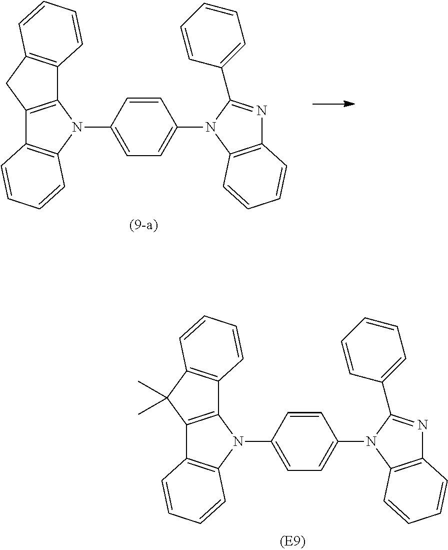 [SMILES: c1ccc(-c2nc3ccccc3n2-c2ccc(-n3c4c(c5ccccc53)Cc3ccccc3-4)cc2)cc1 ; CC1(C)c2ccccc2-c2c1c1ccccc1n2-c1ccc(-n2c(-c3ccccc3)nc3ccccc32)cc1]

In an argon atmosphere, to 7.0 g (20.0 mmol) of intermediate 1-1, 4.1 g (20.0 mmol) of intermediate 2-4, 3.8 g (20.0 mmol) of copper iodide, 6.9 g (60.0 mmol) of trans-1,2-cyclohexanediamine and 12.7 g (60.0 mmol) of tripotassium sulfate, 50 ml of dehydrated 1,4-dioxane was added, and the resulting mixture was stirred under reflux while heating for 48 hours. To residues obtained by concentrating the reaction solution under reduced pressure, 1000 ml of toluene was added. The resultant was heated to 120° C., and insoluble matters were separated by filtration. The filtrate was concentrated under reduced pressure, and residues were purified by silica gel chromatography, whereby 5.0 g of white solids were obtained. By the FD-MS analysis, the solids were identified as the intermediate (9-a).

FD-MS analysis C34H23N3: Theoretical value: 473, Observed value: 473

5.6 g (50.0 mmol) of potassium t-butoxide was added to dehydrated THF (300 ml), and the resulting mixture was cooled to 0° C. Further, 4.7 g (10.0 mmol) of the while solids obtained above were added, and stirred at 0° C. for 1 hour. Subsequently, 7.1 g (50.0 mmol) of methyl iodide was gradually added, and the mixture was stirred at room temperature for 4 hours.

After completion the reaction, water (100 ml) was added to the reaction solution, and the resultant was extracted with dichloromethane. After drying with MgSO₄, the extracted product was filtered and concentrated. Residues after concentration were purified by silica gel chromatography, whereby white solids were obtained. A crude product was re-crystallized with toluene, whereby 3.5 g of white solids were obtained. By the FD-MS analysis, the solids were identified as the aromatic heterocyclic derivative (E9). (yield: 35%)

FD-MS analysis C36H27N3: Theoretical value: 501, Observed value: 501

### Synthesis Example 18

### Production of Aromatic Heterocyclic Derivative (E10)

An aromatic heterocyclic derivative (E10) was synthesized according to the following synthesis scheme.

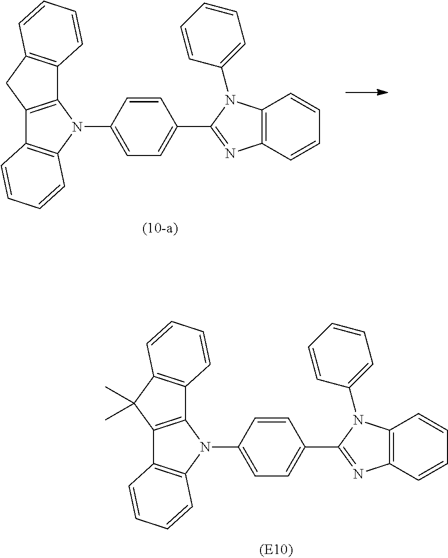 [SMILES: c1ccc(-n2c(-c3ccc(-n4c5c(c6ccccc64)Cc4ccccc4-5)cc3)nc3ccccc32)cc1 ; CC1(C)c2ccccc2-c2c1c1ccccc1n2-c1ccc(-c2nc3ccccc3n2-c2ccccc2)cc1]

A reaction was conducted in the same manner as in Synthesis Example 17, except that 7.0 g of intermediate 1-2 was used instead of intermediate 1-1. As a result, 4.0 g of white crystals were obtained. By the FD-MS analysis, the crystals were identified as the aromatic heterocyclic derivative (E10) (yield: 40%).

FD-MS analysis C36H27N3: Theoretical value: 501, Observed value: 501

### Example 1

### Fabrication of Organic EL Device

A glass substrate of 25 mm by 75 mm by 1.1 mm with an ITO transparent electrode (GEOMATEC CO., LTD.) was subjected to ultrasonic cleaning in isopropyl alcohol for 5 minutes, and cleaning with ultraviolet rays and ozone for 30 minutes.

The cleaned substrate with transparent electrode lines was mounted on a substrate holder in a vacuum deposition device. First, the following compound (A) was deposited to form a 10 nm-thick film A so as to cover the surface of the glass substrate on which the transparent electrode lines were formed. Subsequently, on this film A, the following aromatic amine derivative (X1) was deposited as the first hole-transporting material, whereby a first hole-transporting layer having a thickness of 65 nm was formed. Subsequent to the formation of the first hole-transporting layer, the following compound (H1) was deposited as the second hole-transporting material, whereby a second hole-transporting layer having a thickness of 10 nm was formed.

On the second hole-transporting layer, a compound (B1) as a phosphorescent host (aromatic heterocyclic derivative A) and the following Ir(ppy)₃ as the phosphorescent dopant were co-deposited in a thickness of 35 nm, whereby a phosphorescent emitting layer (first organic thin film layer) was obtained. The concentration of Ir(ppy)₃ was 10 mass %.

Subsequently, on the phosphorescent emitting layer, as the aromatic heterocyclic derivative B, the following compound (B3) was deposited, whereby a 5 nm-thick first electron-transporting layer (second organic thin film layer) was formed. Subsequent to the formation of the first electron-transporting layer, the following compound (C1) was deposited, whereby a 20 nm-thick second electron-transporting layer was formed. Further, LiF with a thickness of 1 nm and metal Al with a thickness of 80 nm were stacked sequentially to obtain a cathode. LiF as an electron-injecting electrode was formed at a film forming rate of 1 Å/min.

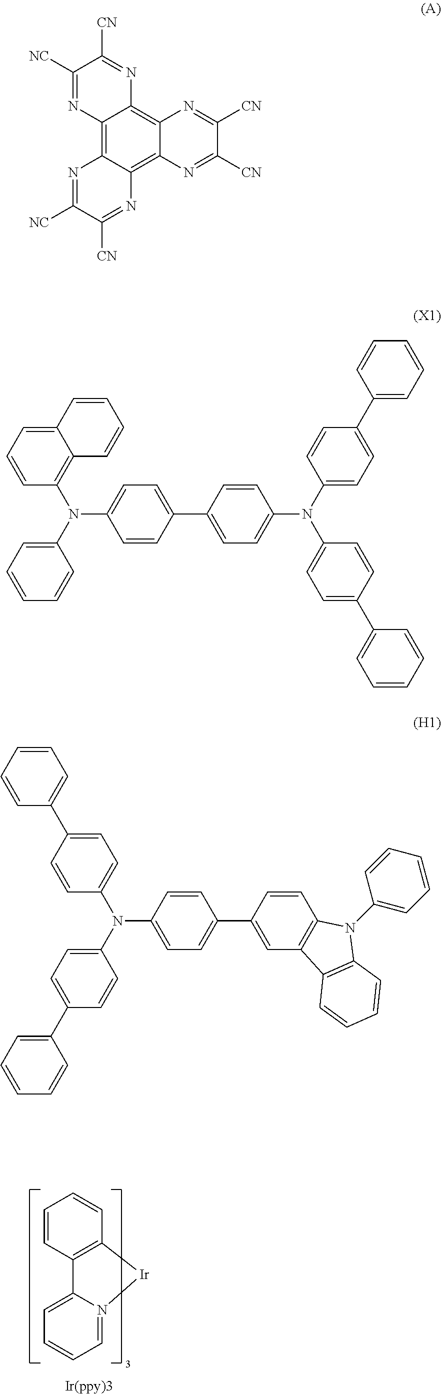

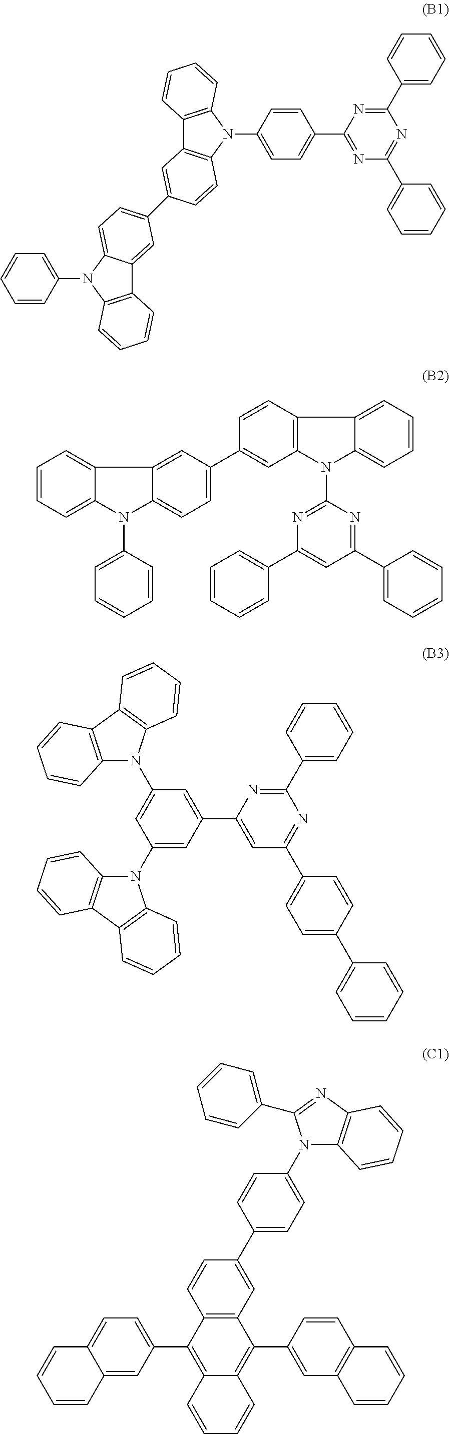 [SMILES: c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2cc(-c3ccccc3)nc(-n3c4ccccc4c4ccc(-c5ccc6c(c5)c5ccccc5n6-c5ccccc5)cc43)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2nc3ccccc3n2-c2ccc(-c3ccc4c(-c5ccc6ccccc6c5)c5ccccc5c(-c5ccc6ccccc6c5)c4c3)cc2)cc1]

By allowing the organic EL device produced as above to be emitted by DC driving, the luminance (L) and current density were measured to determine the current efficiency (L/J) and the driving voltage (V) at a current density of 10 mA/cm². Furthermore, the device life at a 20,000 cd/m² of initial luminance was determined. The results are shown in Table 1.

### Example 2

An organic EL device was fabricated and evaluated in the same manner as in Example 1, except that the compound (B2) shown above was used instead of compound (B1) as the host material. The results are shown in Table 1.

### Comparative Examples 1 to 3

Organic EL devices were fabricated and evaluated in the same manner as in Example 1, except that the materials shown in Table 1 were used as the host material and the electron-transporting material. The results are shown in Table 1.

TABLE 1

| | | | | Measurement results | | |
|---|---|---|---|---|---|---|
| | | | Electron- | Luminous | Driving voltage | |
| | | Host | transporting | efficiency (cd/A) | (V) | 80% |
| | | material | layer | @10 mA/cm² | @10 mA/cm² | life* (hour) |
| Examples | 1 | B1 | B3/C1 | 63.5 | 3.5 | 270 |
| | 2 | B2 | B3/C1 | 65.8 | 3.8 | 265 |
| Com. | 1 | B1 | C1 | 54.0 | 3.5 | 200 |
| Examples | 2 | B2 | C1 | 56.4 | 3.6 | 165 |
| | 3 | B3 | C1 | 57.5 | 3.5 | 80 |

*Time spent until the luminous efficiency was reduced to 80%.

As compared with Comparative Examples 1 and 2, since a layer comprising the compound B3 having a large triplet energy is stacked on the electron-transporting layer side, exciton barrier function is exhibited, whereby luminous efficiency is improved. Further, in Comparative Example 3, since the compound B3 having a large ionization potential was used as the host material, holes cannot be accumulated in the interface of the electron-transporting layer. As a result, the luminous efficiency is lowered and the device life is shortened.

As for the electron-transporting material and the host material mentioned above, the results of measuring the ionization potential (Ip) and the triplet energy (T1) are shown in Table 2. The measurement methods are as follows.

### (1) Ionization Potential (IP)

The ionization potential was measured by means of a photoelectron spectrometer (AC-3, manufactured by RIKEN Co., Ltd.) in the atmosphere. Specifically, a material was irradiated with light, and the amount of electrons formed by charge separation was measured.

The ionization potential (Ip) means energy required to remove electrons from the compound of host material for ioniziation.

### (2) Triplet Energy (T1)

The triplet energy was measured by means of a commercially available apparatus F-4500 (manufactured by Hitachi High Technologies Corporation). The conversion formula of T1 is as follows: Conversion formula: T1 (eV)=1239.85/λ_{edge}

The “λ_{edge} (unit: nm)” means, when the phosphorescent intensity and the wavelength are taken at the vertical axis and the horizontal axis respectively to express a phosphorescent spectrum and a tangential line is drawn against the rise on the shorter wavelength side of the phosphorescent spectrum, a wavelength value of the tangential line and the horizontal axis.

TABLE 2

| | Compound | Ip(eV) | Eg(T1)(eV) |
|---|---|---|---|
| Aromatic heterocyclic | B1 | 5.7 | 2.8 |
| derivative A | B2 | 5.5 | 2.7 |
| (host material) | | | |
| Aromatic heterocyclic | B3 | 6.1 | 2.7 |
| derivative B | C1 | 6.0 | 1.8 |
| (electron-transporting layer) | E1 | 6.0 | 2.8 |
| | E2 | 5.9 | 2.7 |
| | E3 | 5.8 | 2.8 |
| | E4 | 6.0 | 2.5 |
| | E5 | 6.0 | 2.9 |
| | E6 | 5.9 | 2.8 |
| | E7 | 5.8 | 2.8 |
| | E8 | 6.0 | 2.5 |
| | E9 | 6.0 | 2.5 |
| | E10 | 5.9 | 2.5 |

### Referential Example 1

An example is given in which the aromatic heterocyclic derivative B was used in the electron-transporting layer of a fluorescent organic EL device.

A glass substrate of 25 mm by 75 mm by 1.1 mm with an ITO transparent electrode (GEOMATEC CO., LTD.) was subjected to ultrasonic cleaning in isopropyl alcohol for 5 minutes, and cleaning with ultraviolet rays and ozone for 30 minutes.

The cleaned glass substrate with transparent electrode lines was mounted on a substrate holder in a vacuum deposition device. First, the above-mentioned electron acceptor compound (A) was deposited to form a 5 nm-thick film A so as to cover the surface of the glass substrate on which the transparent electrode lines were formed.

On this film A, as the first hole-transporting material, the following aromatic amine derivative (X2) was deposited to form an 85 nm-thick first hole-transporting layer.

Subsequent to the formation of the first hole-transporting layer, the above-mentioned compound (H1) was deposited as the second hole-transporting material to form a 10 nm-thick second hole-transporting layer was formed.

On this hole-transporting layer, the following compound (B4) as a fluorescent host and the following compound (BD1) as a fluorescent dopant were co-deposited in a thickness of 25 nm, whereby a fluorescent emitting layer was obtained. The concentration of BD1 was 5 mass %.

Subsequently, on this fluorescent emitting layer, the above-mentioned compound (B3) was deposited as the first electron-transporting material, whereby a 20 nm-thick first electron-transporting layer was formed. Subsequent to the formation of the first electron-transporting layer, the following compound (C2) was deposited as the second electron-transporting material, whereby a 5 nm-thick second electron-transporting layer was formed. Further, LiF with a thickness of 1 nm and metal Al with a thickness of 80 nm were stacked sequentially to obtain a cathode. LiF as an electron-injecting electrode was formed at a film forming rate of 1 Å/min.

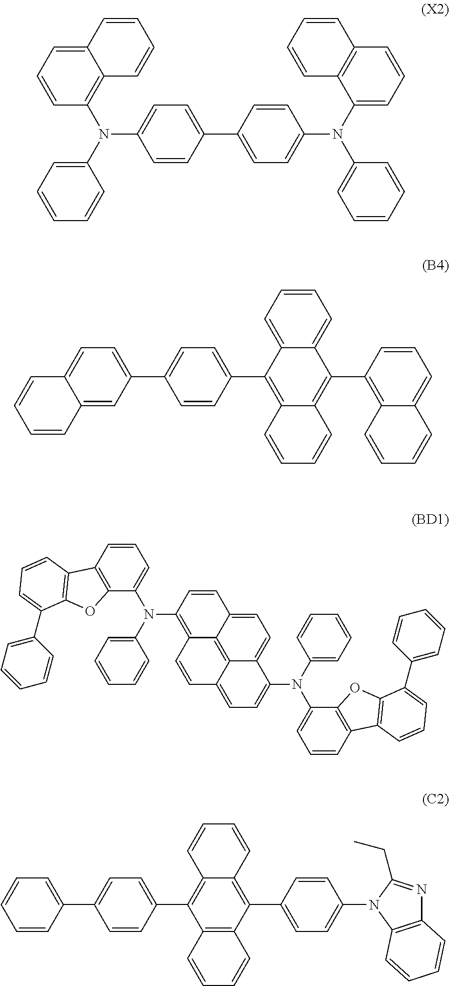

### (Evaluation of Luminous Performance of Organic EL Device)

By allowing the organic EL device produced as above to be emitted by DC driving, the luminance (L) and current density were measured to determine the current efficiency (L/J) and the driving voltage (V) at a current density of 10 mA/cm². Furthermore, the device life at a 20,000 cd/m² of initial luminance was determined. The results are shown in Table 2.

### Referential Example 2

An organic EL device was fabricated and evaluated in the same manner as in Referential Example 1, except that the materials shown in Table 1 were used as the electron-transporting material. The results are shown in Table 2.

TABLE 3

| | | | | Measurement results | | |
|---|---|---|---|---|---|---|
| | | | | Luminous | Driving voltage | |
| | | Host | Electron-transporting | efficiency (cd/A) | (V) | 80% life* |
| | | material | layer | @10 mA/cm² | @10 mA/cm² | (hour) |
| Ref. Ex. | 1 | B4 | B3/C2 | 7.3 | 3.9 | 130 |
| Ref. Ex. | 2 | B4 | C2 | 6.2 | 3.5 | 40 |

*Time spent until the luminous efficiency was reduced to 80%.

From the results of Referential Example 1, it can be confirmed that the aromatic heterocyclic derivative B can be used as an electron-transporting layer of a fluorescent organic EL device. Therefore, when an emitting apparatus in which the phosphorescent organic EL device in the above-mentioned examples and the fluorescent organic EL device in Referential Example 1 are arranged in parallel is formed, the electron-transporting layer can be formed as the common layer.

### INDUSTRIAL APPLICABILITY

The organic EL device of the invention has a long life and can be driven at a high efficiency.

Although only some exemplary embodiments and/or examples of this invention have been described in detail above, those skilled in the art will readily appreciate that many modifications are possible in the exemplary embodiments and/or examples without materially departing from the novel teachings and advantages of this invention. Accordingly, all such modifications are intended to be included within the scope of this invention.

The documents described in the specification of a Japanese application on the basis of which the present application claims Paris convention priority are incorporated herein by reference in its entirety.

1. An organic electroluminescence device comprising an anode and a cathode being opposed, wherein a first organic thin film layer and a second organic thin film layer are provided between the anode and the cathode sequentially from the anode side;
the first organic thin film layer comprising an aromatic heterocyclic derivative A represented by the following formula (1-1) and a phosphorescent emitting material; and
the second organic thin film layer comprising an aromatic heterocyclic derivative B represented by the following formula (2-1): 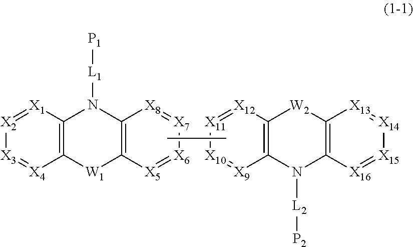
wherein in the formula (1-1),
W₁ and W₂ are independently a single bond, CR₁R₂ or SiR₁R₂;
R₁ and R₂ are independently a hydrogen atom, a substituted or unsubstituted alkyl group including 1 to 20 carbon atoms, a substituted or unsubstituted cycloalkyl group including 3 to 20 carbon atoms, a substituted or unsubstituted haloalkyl group including 1 to 20 carbon atoms, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms;
L₁ and L₂ are independently a single bond, a substituted or unsubstituted arylene group including 6 to 30 ring carbon atoms or a substituted or unsubstituted heteroarylene group including 5 to 30 ring atoms;
among X₁ to X₁₆, one of X₅ to X₈ and one of X₉ to X₁₂ are a carbon atom that is bonded with each other, the remainder of X₁ to X₁₆ are a carbon atom that is bonded to the following R₃, or a nitrogen atom, provided that, among X₁ to X₁₆, if adjacent two atoms are carbon atoms, a ring including the adjacent carbon atoms may be formed with the adjacent carbon atoms being not bonded to R₃;
R₃ is independently a hydrogen atom, a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atom or a substituted or unsubstituted heteroaryl group including 5 to 30 ring atoms;
P₁ and P₂ are independently a substituted or unsubstituted aryl group including 6 to 30 ring carbon atoms or a substituted or unsubstituted heteroaryl group including 5 to 30 ring atoms;
provided that at least one of P₁ and P₂ are a group represented by the following formula (1-a), (1-b) or (1-c); 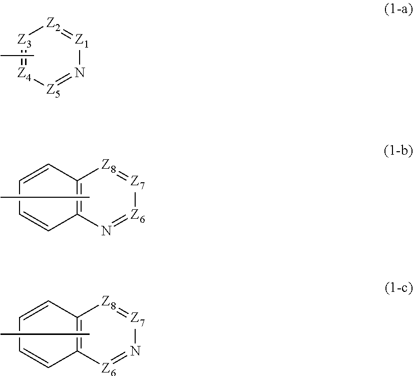
wherein in the formulas (1-a), (1-b) and (1-c),
Z₁ to Z₈ are independently a carbon atom that is bonded to L₁ or L₂, a carbon atom that is bonded to the following R₄, or a nitrogen atom; provided that if adjacent two atoms are carbon atoms, a ring including the adjacent carbon atoms may be fowled with the adjacent carbon atoms being not bonded to R₄;
R₄ is independently a hydrogen atom, a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms; 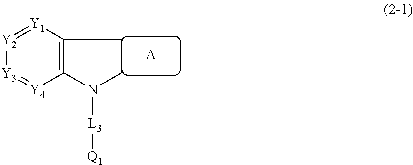
wherein in the formula (2-1),
the ring A is a substituted or unsubstituted aromatic ring that is fused to an adjacent ring;
Y₁ to Y₄ are independently a carbon atom that is bonded to the following R₅, or a nitrogen atom; provided that if adjacent two atoms are carbon atoms, a ring including the adjacent carbon atoms may be formed with the adjacent carbon atoms being not bonded to R₅;
R₅ is independently a hydrogen atom, a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms (excluding a substituted or unsubstituted carbazolyl group);
L₃ is a single bond, a substituted or unsubstituted arylene group including 6 to 30 ring carbon atoms or a substituted or unsubstituted heteroarylene group including 5 to 30 ring atoms;
Q₁ is a group represented by the above formula (1-a), (1-b) or (1-c) or the following formula (2-c), (2-d), (2-e) or (2-f); 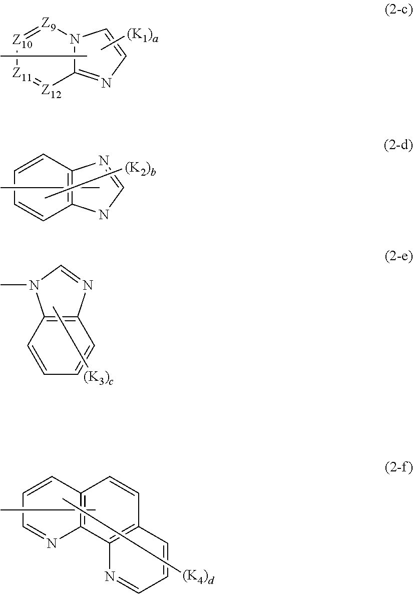
wherein in the formulas (2-c), (2-d), (2-e) and (2-f),
Z₉ to Z₁₂ are independently a carbon atom that is bonded to L₃, a carbon atom that is bonded to the following R₆, or a nitrogen atom, provided that if adjacent two atoms are carbon atoms, a ring including the adjacent carbon atoms may be formed with the adjacent carbon atoms being not bonded to R₆;
R₆ and K₁ to K₄ are independently a hydrogen atom, a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms;
a is an integer of 0 to 2;
b is an integer of 0 to 4;
c is an integer of 0 to 5; and
d is an integer of 0 to 7.

2. The organic electroluminescence device according to claim 1, wherein the aromatic heterocyclic derivative B is represented by any of the following formulas (2-2) to (2-4): 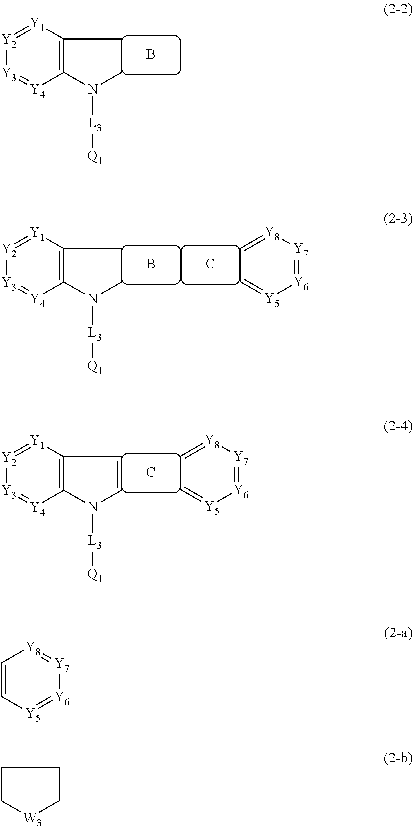
wherein in the formulas (2-2) to (2-4),
the ring B is a ring represented by the formula (2-a) that is fused to an adjacent ring (s) and the ring C is a ring represented by the formula (2-b) that is fused to adjacent rings;
W₃ is NR₇, CR₈R₉, SiR₈R₉, an oxygen atom or a sulfur atom;
R₇ to R₉ are independently a hydrogen atom, a substituted or unsubstituted alkyl group including 1 to 20 carbon atoms, a substituted or unsubstituted cycloalkyl group including 3 to 20 carbon atoms, a substituted or unsubstituted haloalkyl group including 1 to 20 carbon atoms, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms;
Y₁ to Y₈ are independently a carbon atom that is bonded to the following R₁₀, or a nitrogen atom, provided that if adjacent two atoms are carbon atoms, a ring including the two adjacent carbon atoms may be formed with the adjacent carbon atoms being not bonded to R₁₀;
R₁₀ is independently a hydrogen atom, a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms (excluding a substituted or unsubstituted carbazolyl group);
L₃ is a single bond, a substituted or unsubstituted arylene group including 6 to 30 ring carbon atoms or a substituted or unsubstituted heteroarylene group including 5 to 30 ring atoms; and
Q₁ is a group represented by the above formula (1-a), (1-b), (1-c), (2-c), (2-d), (2-e) or (2-f).

3. The organic electroluminescence device according to claim 1, wherein the aromatic heterocyclic derivative A is represented by the following formula (1-2): 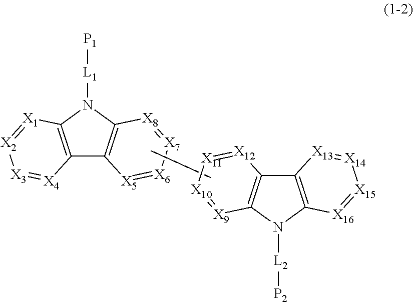
wherein X₁ to X₁₆, L₁, L₂, P₁ d P₂ are independently a group similar to X₁ to X₁₆, L₁, L₂, P₁ and P₂ in the formula (1-1).

4. The organic electroluminescence device according to claim 1, wherein the aromatic heterocyclic derivative A is represented by the following formula (1-3): 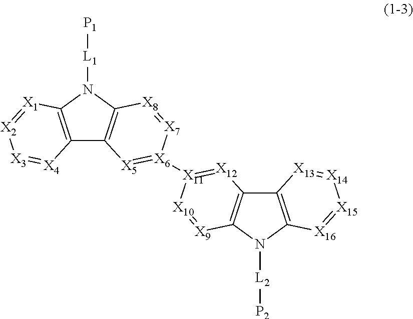
wherein X₁ to X₁₆, L₁, L₂, P₁ and P₂ are independently a group similar to X₁ to X₁₆, L₁, L₂, P₁ and P₂ in the formula (1-1).

5. The organic electroluminescence device according to claim 1, wherein the aromatic heterocyclic derivative A is represented by the following formula (1-4) or (1-5): 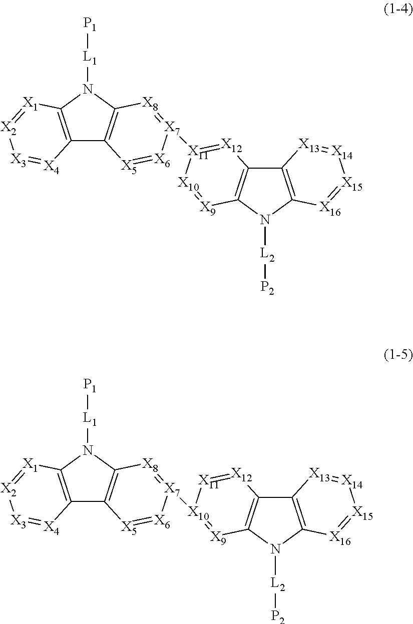
wherein X₁ to X₁₆, L₁, L₂, P₁ and P₂ are independently a group similar to X₁ to X₁₆, L₁, L₂, P₁ and P₂ in the formula (1-1).

6. The organic electroluminescence device according to claim 1, wherein the aromatic heterocyclic derivative B is represented by the formula (3-1): 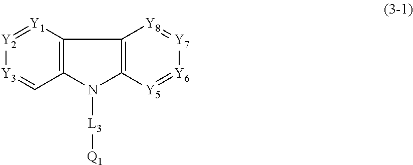
wherein L₃, Y₁ to Y₈ and Q₁ are independently a group similar to L₃, Y₁ to Y₄ and Q₁ in the formula (2-1).

7. The organic electroluminescence device according to claim 2, wherein the aromatic heterocyclic derivative B is represented by the following formula (4-1) or (4-2): 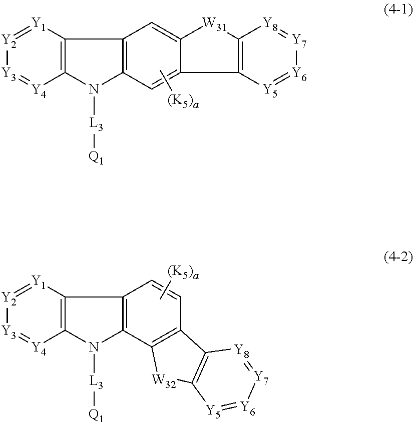
wherein in the formula (4-1) or (4-2),
L₃, Y₁ to Y₈ and Q₁ are independently a group similar to L₃, Y₁ to Y₈ and Q₁ in the above formula (2-3);
K₅ is a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms;
a is an integer of 0 to 2;
W₃₁ is CR₈R₉, SiR₈R₉, an oxygen atom or a sulfur atom;
W₃₂ is NR₇, CR₈R₉, SiR₈R₉, an oxygen atom or a sulfur atom; and
R₇ to R₉ are independently a group similar to R₇ to R₉ in W₃ in the formula (2-b).

8. The organic electroluminescence device according to claim 2, wherein the aromatic heterocyclic derivative B is represented by the following formula (5-1), (5-2) or (5-3): 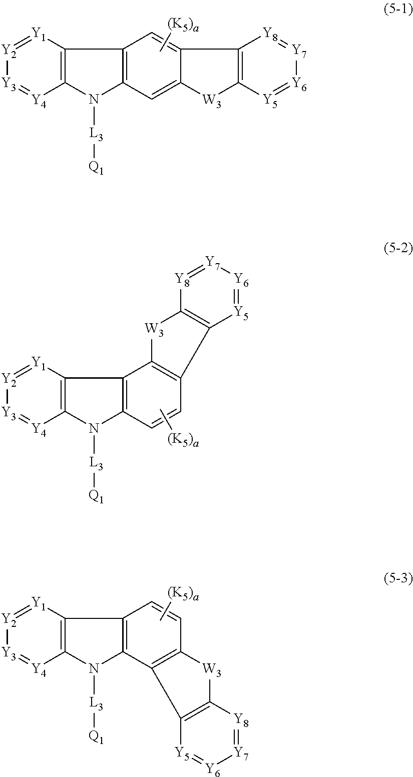
wherein in the formulas (5-1) to (5-3),
W₃, L₃, Y₁ to Y₈ and Q₁ are independently a group similar to W₃, L₃, Y₁ to Y₈ and Q₁ in the formula (2-3);
K₅ is a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms; and
a is an integer of 0 to 2.

9. The organic electroluminescence device according to claim 2, wherein the aromatic heterocyclic derivative B is represented by the following formula (6-1): 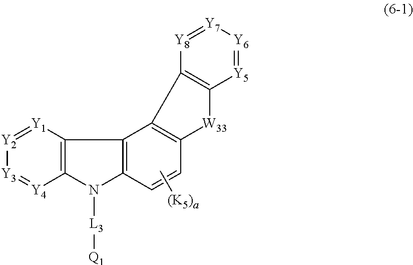
wherein in the formula (6-1),
L₃, Y₁ to Y₈ and Q₁ are independently a group similar to L₃, Y₁ to Y₈ and Q₁ in the formula (2-3);
K₅ is a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms;
a is an integer of 0 to 2;
W₃₃ is CR₈R₉, SiR₈R₉, an oxygen atom or a sulfur atom; and
R₇ to R₉ are independently a group similar to R₇ to R₉ in W₃ in the formula (2-b).

10. The organic electroluminescence device according to claim 2, wherein the aromatic heterocyclic derivative B is represented by the following formula (7-1): 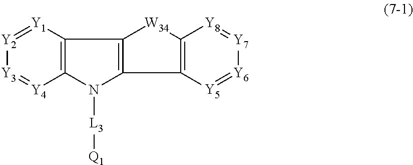
wherein in the formula (7-1),
L₃, Y₁ to Y₈ and Q₁ are independently a group similar to L₃, Y₁ to Y₈ and Q₁ in the formula (2-3);
W₃₄ is CR₈R₉ or SiR₈R₉; and
R₈ and R₉ are independently a group similar to R₈ and R₉ in W₃ in the formula (2-b).

11. The organic electroluminescence device according to claim 1, wherein a layer comprising a compound represented by the following formula (10) is bonded to the anode: 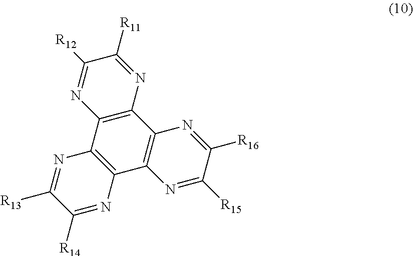
wherein R₁₁ to R₁₆ are independently a cyano group, —CONH₂, a carboxy group or —COOR₁₇ (R₁₇ is an alkyl group including 1 to 20 carbon atoms), or R₁₁ and R₁₂, R₁₃ and R₁₄ or R₁₅ and R₁₆ are bonded with each other to form —CO—O—CO—.

12. The organic electroluminescence device according to claim 1, wherein the phosphorescent emitting material is an ortho-metalated complex of iridium (Ir), osmium (Os) or platinum (Pt).

13. An organic electroluminescence emitting apparatus comprising a first device that is the organic electroluminescence device according to claim 1 and an organic electroluminescence device (second device) that emits fluorescent light,
the first device and the second device being provided in parallel on a substrate,
wherein at least one of layers forming a hole-transporting region or an electron-transporting region in the first device and the second device is a common layer.

14. A nitrogen-containing aromatic heterocyclic derivative represented by the following formula (11-1) or (11-2): 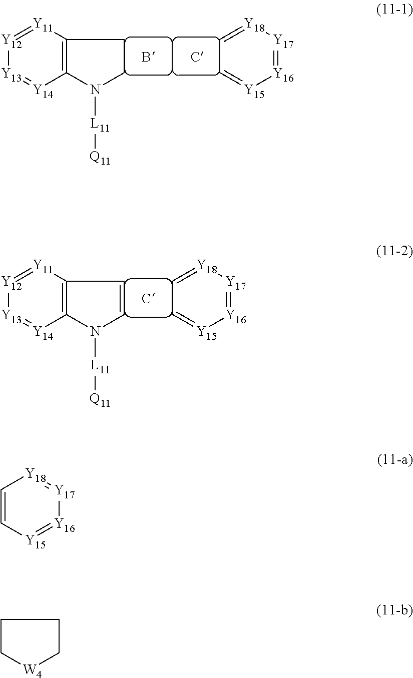
wherein in the formula (11-1) or (11-2),
the ring B′ is a ring represented by the formula (11-a) that is fused to adjacent rings;
the ring C′ is a ring represented by the formula (11-b) that is fused to adjacent rings;
W₄ is NR₂₁, CR₂₂R₂₃, SiR₂₂R₂₃ or an oxygen atom;
R₂₁ to R₂₃ are independently a hydrogen atom, a substituted or unsubstituted alkyl group including 1 to 20 carbon atoms, a substituted or unsubstituted cycloalkyl group including 3 to 20 carbon atoms, a substituted or unsubstituted haloalkyl group including 1 to 20 carbon atoms, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms;
Y₁₁ to Y₁₈ are independently a carbon atom that is bonded to the following R₂₄, or a nitrogen atom, provided that if adjacent two atoms are carbon atoms, a ring including the adjacent carbon atoms may be formed with the adjacent carbon atoms being not bonded to R₂₄;
R₂₄ is independently a hydrogen atom, a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms (excluding a substituted or unsubstituted carbazolyl group);
L₁₁ is a single bond, a substituted or unsubstituted arylene group including 6 to 30 ring carbon atoms or a substituted or unsubstituted heteroarylene group including 5 to 30 ring atoms;
Q₁₁ is a group represented by the following formula (11-c), (11-d), (11-e) or (11-f): 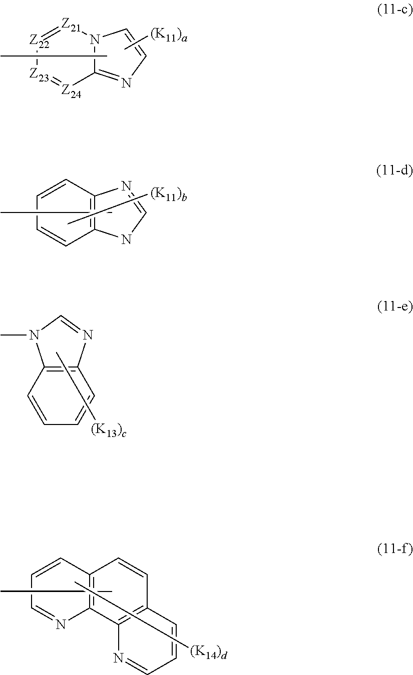
wherein in the formulas (11-c), (11-d), (11-e) and (11-f),
Z₂₁ to Z₂₄ are independently a carbon atom that is bonded to L₁₁ or a carbon atom that is bonded to the following R₂₅, or a nitrogen atom, provided that if the adjacent two atoms are carbon atoms, a ring including the adjacent carbon atoms may be formed with the adjacent two carbon atoms being not bonded to R₂₅;
R₂₅ and K₁₁ to K₁₄ are independently a hydrogen atom, a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms.

15. The nitrogen-containing aromatic heterocyclic derivative according to according to claim 14 that is represented by the following formula (12-1) or (12-2): 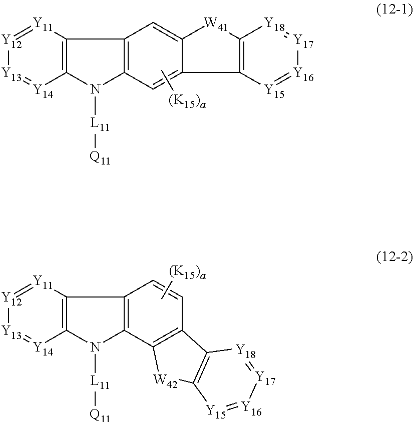
wherein in the formula (12-1) or (12-2),
L₁₁, Y₁₁ to Y₁₈ and Q₁₁ are independently a group similar to L₁₁, Y₁₁ to Y₁₈ and Q₁₁ in the above formula (11-1);
W₄₁ is CR₂₂R₂₃, SiR₂₂R₂₃ or an oxygen atom;
W₄₂ is NR₂₁, CR₂₂R₂₃, SiR₂₂R₂₃ or an oxygen atom;
R₂₁ to R₂₃ are independently a group similar to R₂₁ to R₂₃ in the formula (11-b);
K₁₅ is a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atom; and
a is an integer of 0 to 2.

16. The nitrogen-containing aromatic heterocyclic derivative according to claim 14 which is represented by the following formula (13-1), (13-2) or (13-3): 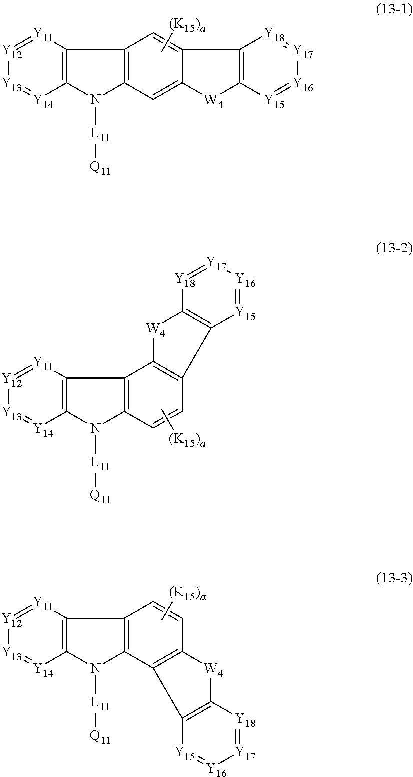
wherein in the formulas (13-1) to (13-3),
W₄, L₁₁, Y₁₁ to Y₁₈ and Q₁₁ are independently a group similar to W₄, L₁₁, Y₁₁ to Y₁₈ and Q₁₁ in the above formula (11-1);
K₁₅ is a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atom; and
a is an integer of 0 to 2.

17. The nitrogen-containing aromatic heterocyclic derivative according to claim 14 which is represented by the following formula (14-1): 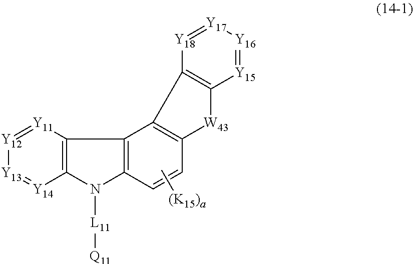
wherein in the formula (14-1),
L₁₁, Y₁₁ to Y₁₈ and Q₁₁ are independently a group similar to L₁₁, Y₁₁ to Y₁₈ and Q₁₁ in the above formula (11-1);
W₄₃ is CR₂₂R₂₃, SiR₂₂R₂₃ or an oxygen atom;
R₂₂ and R₂₃ are independently a group similar to R₂₂ and R₂₃ in the above formula (11-b);
K₁₅ is a fluorine atom, a cyano group, a substituted or unsubstituted alkyl group including 1 to 20 carbon atoms, a substituted or unsubstituted cycloalkyl group including 3 to 20 carbon atoms, a substituted or unsubstituted alkoxy group including 1 to 20 carbon atoms, a substituted or unsubstituted haloalkyl group including 1 to 20 carbon atoms, a substituted or unsubstituted haloalkoxy group including 1 to 20 carbon atoms, a substituted or unsubstituted silyl group, a substituted or unsubstituted aralkyl group including 7 to 30 carbon atoms, a substituted or unsubstituted aryl group including 6 to 30 ring carbon atoms or a substituted or unsubstituted heteroaryl group including 5 to 30 ring atoms; and
a is an integer of 0 to 2.

18. The nitrogen-containing aromatic heterocyclic derivative according to claim 14 which is represented by the following formula (15-1): 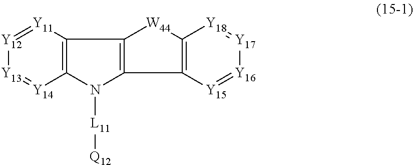
wherein in the formula (15-1),
L₁₁ and Y₁₁ to Y₁₈ are a group similar to L₁₁ and Y₁₁ to Y₁₈ in the above formula (11-1);
W₄₄ is CR₂₂R₂₃ or SiR₂₂R₂₃;
R₂₂ and R₂₃ are independently a group similar to R₂₂ and R₂₃ in the above formula (11-b); and
Q₁₂ is a group represented by the above formula (11-c), (11-d) or (11-e).

19. The nitrogen-containing aromatic heterocyclic derivative according to claim 14, which is a material for an organic electroluminescence device.

20. The nitrogen-containing aromatic heterocyclic derivative according to claim 14, which is an electron-transporting material for an organic electroluminescence device.
